(19) United States
(12) Patent Application Publication
(10) Pub. No.: US 2025/0044507 A1
(43) Pub. Date: Feb. 6, 2025

(54) LASER-BASED WAVEGUIDE-COUPLED WHITE LIGHT SYSTEM FOR A LIGHTING APPLICATION

(71) Applicant: KYOCERA SLD Laser, Inc., Goleta, CA (US)

(72) Inventors: James W. Raring, Santa Barbara, CA (US); Paul Rudy, Manhattan Beach, CA (US); Sten Heikman, Goleta, CA (US); Ryan Gresback, Santa Barbara, CA (US); Julian Carey, San Francisco, CA (US)

(73) Assignee: KYOCERA SLD Laser, Inc., Goleta, CA (US)

(21) Appl. No.: 18/803,277

(22) Filed: Aug. 13, 2024

Related U.S. Application Data
(63) Continuation of application No. 16/597,791, filed on Oct. 9, 2019, now abandoned.
Application No. 16/597,791 is a continuation-in-part of application No. 16/380,217, filed on Apr. 10, 2019, now Pat. No. 12,000,552.
Application No. 16/380,217 is a continuation-in-part of application No. 16/252,570, filed on Jan. 18, 2019, now Pat. No. 11,884,202.

(51) Int. Cl. G02B 6/122; F21K 9/61; F21K 9/64; F21K 9/68; F21V 8/00; F21V 14/04; H01S 5/00; H01S 5/023; H01S 5/0233

(52) U.S. Cl. CPC G02B 6/122; F21K 9/61; F21K 9/64; F21K 9/68; F21V 14/04; G02B 6/0006; G02B 6/0008; G02B 6/001; H01S 5/0087; H01S 5/023; H01S 5/0233

(57) ABSTRACT

A laser-based fiber-coupled white light system is provided. The system includes a laser device comprising a gallium and nitrogen containing emitting region having an output facet configured to output a laser emission with a first wavelength ranging from 385 nm to 495 nm. The system further includes a phosphor member integrated with light collimation elements. The phosphor member converts the laser emission with the first wavelength to a phosphor emission with a second wavelength in either reflective or transmissive mode and mixed partially with laser emission to produce a white light emission. The system includes a transport fiber coupled to the phosphor member via the light collimation elements to receive the white light emission and deliver the white light emission remotely to one or more passive luminaries substantially free of electrical or moving parts disposed at remote distances from a dedicated source area.

### CROSS-REFERENCE TO RELATED APPLICATIONS

This application is a continuation of U.S. application Ser. No. 16/597,791, filed Oct. 9, 2019, which is a continuation-in-part of U.S. application Ser. No. 16/380,217, filed Apr. 10, 2019, which is a continuation-in-part of U.S. application Ser. No. 16/252,570, filed Jan. 18, 2019, the entire contents of each of which are incorporated herein by reference in their entirety for all purposes.

### BACKGROUND

In the late 1800's, Thomas Edison invented the light bulb. The conventional light bulb, commonly called the “Edison bulb,” has been used for over one hundred years for a variety of applications including lighting and displays. The conventional light bulb uses a tungsten filament enclosed in a glass bulb sealed in a base, which is screwed into a socket. The socket is coupled to an AC power or DC power source. The conventional light bulb can be found commonly in houses, buildings, and outdoor lightings, and other areas requiring light or displays. Unfortunately, drawbacks exist with the conventional light bulb:
The conventional light bulb dissipates more than 90% of the energy used as thermal energy.
The conventional light bulb routinely fails due to thermal expansion and contraction of the filament element.
The conventional light bulb emits light over a broad spectrum, much of which is not perceived by the human eye.
The conventional light bulb emits in all directions, which is undesirable for applications requiring strong directionality or focus, e.g. projection displays, optical data storage, etc.

To overcome some of the drawbacks of the conventional light bulb, fluorescent lighting has been developed. Fluorescent lighting uses an optically clear tube structure filled with a halogen gas and, which typically also contains mercury. A pair of electrodes is coupled between the halogen gas and couples to an alternating power source through a ballast. Once the gas has been excited, it discharges to emit light. Typically, the optically clear tube is coated with phosphors, which are excited by the light. Many building structures use fluorescent lighting and, more recently, fluorescent lighting has been fitted onto a base structure, which couples into a standard socket.

Due to the high efficiency, long lifetimes, low cost, and non-toxicity offered by solid state lighting technology, light emitting diodes (LED) have rapidly emerged as the illumination technology of choice. An LED is a two-lead semiconductor light source typically based on a p-i-n junction diode, which emits electromagnetic radiation when activated. The emission from an LED is spontaneous and is typically in a Lambertian pattern. When a suitable voltage is applied to the leads, electrons and holes recombine within the device releasing energy in the form of photons. This effect is called electroluminescence, and the color of the light is determined by the energy band gap of the semiconductor.

Appearing as practical electronic components in 1962 the earliest LEDs emitted low-intensity infrared light. Infrared LEDs are still frequently used as transmitting elements in remote-control circuits, such as those in remote controls for a wide variety of consumer electronics. The first visible-light LEDs were also of low intensity, and limited to red. Modern LEDs are available across the visible, ultraviolet, and infrared wavelengths, with very high brightness.

The earliest blue and violet gallium nitride (GaN)-based LEDs were fabricated using a metal-insulator-semiconductor structure due to a lack of p-type GaN. The first p-n junction GaN LED was demonstrated by Amano et al. using the LEEBI treatment to obtain p-type GaN in 1989. They obtained the current-voltage (I-V) curve and electroluminescence of the LEDs, but did not record the output power or the efficiency of the LEDs. Nakamura et al. demonstrated the p-n junction GaN LED using the low-temperature GaN buffer and the LEEBI treatment in 1991 with an output power of 42 μW at 20 mA. The first p-GaN/n-InGaN/n-GaN DH blue LEDs were demonstrated by Nakamura et al. in 1993. The LED showed a strong band-edge emission of InGaN in a blue wavelength regime with an emission wavelength of 440 nm under a forward biased condition. The output power and the EQE were 125 μW and 0.22%, respectively, at a forward current of 20 mA. In 1994, Nakamura et al. demonstrated commercially available blue LEDs with an output power of 1.5 mW, an EQE of 2.7%, and the emission wavelength of 450 nm. On Oct. 7, 2014, the Nobel Prize in Physics was awarded to Isamu Akasaki, Hiroshi Amano and Shuji Nakamura for “the invention of efficient blue light-emitting diodes which has enabled bright and energy-saving white light sources” or, less formally, LED lamps.

By combining GaN-based LEDs with wavelength converting materials such as phosphors, solid-state white light sources were realized. This technology utilizing GaN-based LEDs and phosphor materials to produce white light is now illuminating the world around us as a result of the many advantages over incandescent light sources including lower energy consumption, longer lifetime, improved physical robustness, smaller size, and faster switching. Light-emitting diodes are now used in applications as diverse as aviation lighting, automotive headlamps, advertising, general lighting, traffic signals, and camera flashes. LEDs have allowed new text, video displays, and sensors to be developed, while their high switching rates are also useful in advanced communications technology.

Although useful, LEDs still have limitations that are desirable to overcome in accordance to the inventions described in the following disclosure.

### SUMMARY

The present invention provides a laser-based fiber-coupled white-light system or apparatus configured with a gallium and nitrogen containing laser diode, a wavelength converter member such as a phosphor, and an optical cable or fiber member to transport the laser-based light to a desired illumination location to provide illumination. In some embodiments the white light is transported with an optical transport fiber from the laser-based source to a remote illumination location. The high luminance provided by laser-based white light sources can enable substantially higher optical coupling efficiencies of the white light into an optical transport cable versus other solid-state lighting technologies such as LED technology. For example, laser-based white light sources can provide a luminance in the 500-1,000 cd/mm² range, in the 1,000 to 2,000 cd/mm² range, or in the 2,000 to 20,000 cd/mm² range, or in a higher range. These high luminance values range from about 2.5 times to about 100 times greater than LED sources. This drastically higher brightness or luminance can enable a substantially superior optical coupling efficiency in fiber optic cable. For example, for a 1 mm diameter core fiber optical cable, the coupling efficiency for the laser-based white light source may be in the range of 50% to about 90%. For the LED based white light source, the optical coupling efficiency may be in the range of 2% to about 10% for the same fiber optic cable. In short, the high brightness of the laser-based white light source provides an enabling superiority of the white light coupling efficiency into a transport fiber versus the LED source. Therefore, the laser-based white light source provides novel and unique opportunities to generate white light systems and devices that provide strong benefits over LED.

In some embodiments according to the present invention, the remote laser-based white light source is in the vicinity of the illumination location and can be configured to only provide white light for a single location or luminaire. In other embodiments according to the present invention, the remote laser-based white light source is located a greater distance from the illumination location, such as about 5 feet to about 500 feet from the illumination location. In this latter embodiment the laser-based white light system can comprise a central lighting system or a light distribution system wherein one or more laser-based white light sources are located in a designated source location and wherein multiple transport fibers are optically coupled to the one or more white light sources and are configured to transport the light to multiple illumination locations.

In one embodiment of a central lighting system including a laser-based white light source, the central light source is comprised of one or more laser-based white light sources is optically coupled to multiple transport fibers that carry the white light to multiple rooms in a residential home to provide a central white light system. In such as central lighting system, optical switches can be included to turn “on” and “off” optical transport fibers to turn the light on and off at illumination locations. Additionally, analog switches and light valves can be included to tune the brightness of the light such as providing a dimming function. Moreover, the brightness or luminous output of the laser-based white light source can be adjusted to tune the amount of white light launched into the optical transport fiber. Of course, some embodiments of the present invention include various sensor-based feedback loop configurations to provide adjustment for optimization of the operating condition of the lighting system.

In preferred embodiments of the present invention, the laser-based white light source provides novel and unique opportunities for the white light to be passively emitted from an apparatus as a so-called passive luminaire. Since the white light is transported with an optical cable of fiber, the actual light emitting surface or apparatus introducing the light to the outside world does not need to be co-located with actual light source. In some preferred embodiments of the present invention, passive luminaires are included as pendant lights, light fixtures, line sources of light, and other light emitting configurations and apparatuses.

The benefits of the present invention include but are not limited to an improved efficiency white light system such as white light systems in residential or commercial applications, cost reductions of lighting system, improved white lighting performance, adjustability and tune ability of the of the light characteristics such as the brightness or the color qualities. Additional benefits of the present invention include an improved styling and lighting aesthetics that result from the high luminance laser-based white light sources enabling highly efficient coupling of the white light into a fiber optic cable for transport to novel emitting configurations not possible with other white lighting technologies. For example, by generating the white light at an external location the luminaire or emitting apparatus can be designed with flexibility not efficiently possible with prior lighting technologies. In some embodiments, the luminaire members in laser-based white light systems are passive luminaires configured to provide a scattering effect, a waveguiding effect, a reflecting effect, a color tuning effect, a beam shaping effect, and/or providing precise illumination patterns. In one embodiment, the emitting apparatus is a 1-dimensional line source of white light such as in a scattering or leaky fiber. Such a ID source can be integrated into building materials such as crown molding, baseboards, ceiling beams etc. In another embodiment, a 2-dimensional emitting source or surface such as a troffer is emitting the white light. In some examples of this embodiment, the white light is coupled into building and architectural components such as window curtains, the windows themselves, walls, and other objects to provide a light emitting or glowing effect to provide a soft ambient lighting.

In some embodiments of the present invention, the fiber-coupled laser-based white light source provides remote and integrated smart laser lighting devices, systems, and methods, can be adapted with LiFi, and visible light communication devices and methods for communication, can be adapted with projection display and spatially dynamic lighting devices and methods, and the laser-based white light source can be configured for sensing such as depth sensing or LIDAR, and various combinations of above in applications of general lighting, commercial lighting and display, automotive lighting and communication, defense and security, industrial processing, and internet communications, and others. Examples are included in U.S. application Ser. No. 15/719,455, filed Sep. 28, 2017, the entire contents of which are incorporated herein by reference in their entirety for all purposes.

In a different group of smart laser-based lighting embodiments, the present invention provides gallium and nitrogen based lasers white light sources or systems is configured with sensors to provide a feedback loop. The feedback loops based on the sensor feedback enable responses to the light characteristics in the lighting system. In some examples the light responses comprise a light movement response, a light color response, a light brightness response, or other responses like an illumination spatial distribution response, an illumination pattern movement response, a light or communication signal response. The sensor feedback can be used to dynamically optimize the amount of light and the quality of the light delivered to various locations within a laser-based lighting system, as well as adjusting the amount of energy input to the white light source to result in an optimized energy efficiency for each lighting use requirements. Additionally, the smart laser lighting can be combined with sensing technology such as a LIDAR technology for enhanced system functionality and/or enhanced LIDAR function.

Specific embodiments of this invention employ a transferred gallium and nitrogen containing material process for fabricating laser diodes or other gallium and nitrogen containing devices (as shown in U.S. Pat. Nos. 9,666,677 and 9,379,525, the entire contents of which are incorporated herein by reference in their entirety for all purposes) enabling benefits over conventional fabrication technologies.

The present invention provides a device and method for an integrated white colored electromagnetic radiation source using a combination of laser diode excitation sources based on gallium and nitrogen containing materials and light emitting source based on phosphor materials. In this invention a violet, blue, or other wavelength laser diode source based on gallium and nitrogen materials is closely integrated with phosphor materials, such as yellow phosphors configured with designated scattering centers on an excitation surface or inside a bulk, to form a compact, high-brightness, and highly-efficient, white light source. In an example, the source can be provided for specialized applications, among general applications, and the like.

Additional benefits are achieved over pre-existing techniques using the present invention. In particular, the present invention enables a cost-effective white light source. In a specific embodiment, the present optical device can be manufactured in a relatively simple and cost-effective manner. Depending upon the embodiment, the present apparatus and method can be manufactured using conventional materials and/or methods according to one of ordinary skill in the art. In some embodiments of this invention the gallium and nitrogen containing laser diode source is based on c-plane gallium nitride material and in other embodiments the laser diode is based on nonpolar or semipolar gallium and nitride material. In one embodiment the white source is configured from a chip on submount (CoS) with an integrated phosphor on the submount to form a chip and phosphor on submount (CPoS) white light source. In some embodiments the light source and phosphor are configured on a common support member wherein the common support member may be a package member.

In various embodiments, the laser device and phosphor device are mounted on a common support member with or without intermediate submounts and the phosphor materials are operated in a transmissive mode, a reflective mode, or a side-pumped mode to result in a white emitting laser-based light source. Merely by way of example, the invention can be applied to applications such as white lighting, white spot lighting, flash lights, automobile headlights, all-terrain vehicle lighting, flash sources such as camera flashes, light sources used in recreational sports such as biking, surfing, running, racing, boating, light sources used for drones, planes, robots, other mobile or robotic applications, safety, counter measures in defense applications, multi-colored lighting, lighting for flat panels, medical, metrology, beam projectors and other displays, high intensity lamps, spectroscopy, entertainment, theater, music, and concerts, analysis fraud detection and/or authenticating, tools, water treatment, laser dazzlers, targeting, communications, LiFi, visible light communications (VLC), sensing, detecting, distance detecting, Light Detection And Ranging (LIDAR), transformations, transportations, leveling, curing and other chemical treatments, heating, cutting and/or ablating, pumping other optical devices, other optoelectronic devices and related applications, and source lighting and the like.

Laser diodes are ideal as phosphor excitation sources. With a spatial brightness (optical intensity per unit area) more than 10,000 times higher than conventional LEDs, extreme directionality of the laser emission, and without the droop phenomenon that plagues LEDs, laser diodes enable characteristics unachievable by LEDs and other light sources. Specifically, since the laser diodes output beams carrying over 0.5 W, over 1 W, over 3 W, over 10 W, or even over 100 W can be focused to very small spot sizes of less than 1 mm in diameter, less than 500 microns in diameter, less than 100 microns in diameter, or even less than 50 microns in diameter, power densities of over 1 W/mm², 100 W/mm², or even over 2,500 W/mm² can be achieved. When this very small and powerful beam of laser excitation light is incident on a phosphor material an extremely bright spot or point source of white light can be achieved. Assuming a phosphor conversion ratio of 200 lumens of emitted white light per optical watt of excitation light, a 5 W excitation power could generate 1000 lumens in a beam diameter of 100 microns, or 50 microns, or less. This unprecedented source brightness can be game changing in applications such as spotlighting or range finding where parabolic reflectors or lensing optics can be combined with the point source to create highly collimated white light spots that can travel drastically higher distances than ever possible before using LEDs or bulb technology.

In one embodiment, the present invention provides a CPOS laser-based white light source comprising a form factor characterized by a length, a width, and a height. In an example, the height is characterized by a dimension of less than 25 mm, and greater than 0.5 mm, although there may be variations. In an alternative example, the height is characterized by a dimension of less than 12.5 mm, and greater than 0.5 mm, although there may be variations. In yet an alternative example, the length and width are characterized by a dimension of less than 30 mm, less than 15 mm, or less than 5 mm, although there may be variations. The apparatus has a support member and at least one gallium and nitrogen containing laser diode devices and phosphor material overlying the support member. The laser device is capable of an emission of a laser beam with a wavelength preferably in the blue region of 425 nm to 475 nm or in the ultra violet or violet region of 380 nm to 425 nm, but can be other such as in the cyan region of 475 nm to 510 nm or the green region of 510 nm to 560 nm. In some embodiments two or more laser diodes or laser stripes are included in the integrated white light source. Combining multiple laser sources can offer many potential benefits according to this invention. First, the excitation power can be increased by beam combining to provide a more powerful excitation spit and hence produce a brighter light source. Similarly, the reliability of the source can be increased by using multiple sources at lower drive conditions to achieve the same excitation power as a single source driven at more harsh conditions such as higher current and voltage. A second advantage is the potential for a more circular spot by rotating the first free space diverging elliptical laser beam by 90 degrees relative to the second free space diverging elliptical laser beam and overlapping the centered ellipses on the phosphor. Alternatively, a more circular spot can be achieved by rotating the first free space diverging elliptical laser beam by 180 degrees relative to the second free space diverging elliptical laser beam and off-centered overlapping the ellipses on the phosphor to increase spot diameter in slow axis diverging direction. In another configuration, more than 2 lasers are included and some combination of the above described beam shaping spot geometry shaping is achieved. A third and important advantage is that multiple color or wavelength lasers can be included to offer improved performance such as an improved color rendering or color quality. For example, two or more blue excitation lasers with slightly detuned wavelengths (e.g., 5 nm, 10 nm, 15 nm, etc.) can be included to create a larger blue spectrum. In one embodiment, separate individual laser chips are configured within the laser-phosphor light source. By positioning multiple laser chips in a predetermined configuration, multiple excitation beams can be overlapped on the phosphor spot to create a more ideal spot geometry. In alternative embodiments, laser diodes with multiple adjacent laser stripes, multi-stripe lasers” are included in the integrated white light source. The multiple stripes can enable an increased excitation power for a brighter light source and/or an improved or modified spot pattern on the phosphor. In a preferred embodiment the phosphor material can provide a yellowish emission in the 550 nm to 590 nm range such that when mixed with the blue emission of the laser diode a white light is produced. In other embodiments, phosphors with red, green, yellow, and even blue emission can be used in combination with the laser diode excitation source to produce a white light with color mixing.

In an embodiment, the device layers comprise a super-luminescent light emitting diode or SLED. A SLED is in many ways similar to an edge emitting laser diode; however, the emitting facet of the device is designed so as to have a very low reflectivity. A SLED is similar to a laser diode as it is based on an electrically driven junction that when injected with current becomes optically active and generates amplified spontaneous emission (ASE) and gain over a wide range of wavelengths. When the optical output becomes dominated by ASE there is a knee in the light output versus current (LI) characteristic wherein the unit of light output becomes drastically larger per unit of injected current. This knee in the LI curve resembles the threshold of a laser diode, but is much softer. A SLED would have a layer structure engineered to have a light emitting layer or layers clad above and below with material of lower optical index such that a laterally guided optical mode can be formed. The SLED would also be fabricated with features providing lateral optical confinement. These lateral confinement features may consist of an etched ridge, with air, vacuum, metal or dielectric material surrounding the ridge and providing a low optical-index cladding. The lateral confinement feature may also be provided by shaping the electrical contacts such that injected current is confined to a finite region in the device. In such a “gain guided” structure, dispersion in the optical index of the light emitting layer with injected carrier density provides the optical-index contrast needed to provide lateral confinement of the optical mode. The emission spectral width is typically substantially wider (>5 nm) than that of a laser diode and offer advantages with respect to reduced image distortion in displays, increased eye safety, and enhanced capability in measurement and spectroscopy applications.

SLEDs are designed to have high single pass gain or amplification for the spontaneous emission generated along the waveguide. The SLED device would also be engineered to have a low internal loss, preferably below 1 cm⁻¹, however SLEDs can operate with internal losses higher than this. In the ideal case, the emitting facet reflectivity would be zero, however in practical applications a reflectivity of zero is difficult to achieve and the emitting facet reflectivity is designs to be less than 1%, less than 0.1%, less than 0.001%, or less than 0.0001% reflectivity. Reducing the emitting facet reflectivity reduces feedback into the device cavity, thereby increasing the injected current density at which the device will begin to lase. Very low reflectivity emitting facets can be achieved by a combination of addition of anti-reflection coatings and by angling the emitting facet relative to the SLED cavity such that the surface normal of the facet and the propagation direction of the guided modes are substantially non-parallel. In general, this would mean a deviation of more than 1-2 degrees. In practice, the ideal angle depends in part on the anti-reflection coating used and the tilt angle must be carefully designed around a null in the reflectivity versus angle relationship for optimum performance. Tilting of the facet with respect to the propagation direction of the guided modes can be done in any direction relative to the direction of propagation of the guided modes, though some directions may be easier to fabricate depending on the method of facet formation. Etched facets provide high flexibility for facet angle determination. Alternatively, a very common method to achieve an angled output for reduced constructive interference in the cavity would to curve and/or angle the waveguide with respect to a cleaved facet that forms on a pre-determined crystallographic plane in the semiconductor chip. In this configuration the angle of light propagation is off-normal at a specified angle designed for low reflectivity to the cleaved facet. A low reflectivity facet may also be formed by roughening the emitting facet in such a way that light extraction is enhanced and coupling of reflected light back into the guided modes is limited. SLEDs are applicable to all embodiments according to the present invention and the device can be used interchangeably with laser diode device when applicable.

The apparatus typically has a free space with a non-guided laser beam characteristic transmitting the emission of the laser beam from the laser device to the phosphor material. The laser beam spectral width, wavelength, size, shape, intensity, and polarization are configured to excite the phosphor material. The beam can be configured by positioning it at the precise distance from the phosphor to exploit the beam divergence properties of the laser diode and achieve the desired spot size. In one embodiment, the incident angle from the laser to the phosphor is optimized to achieve a desired beam shape on the phosphor. For example, due to the asymmetry of the laser aperture and the different divergent angles on the fast and slow axis of the beam the spot on the phosphor produced from a laser that is configured normal to the phosphor would be elliptical in shape, typically with the fast axis diameter being larger than the slow axis diameter. To compensate this, the laser beam incident angle on the phosphor can be optimized to stretch the beam in the slow axis direction such that the beam is more circular on phosphor. In alternative embodiments laser diodes with multiple parallel adjacent emitter stripes can be configured to result in a wider and/or more powerful excitation spot on the phosphor. By making the spot wider in the lateral direction the spot could become more circular to the faster divergence angle of the laser emission in the vertical direction. For example, two or more laser stripes may be spaced by 10-30 μm, 30-60 μm, 60-100 μm, or 100-300 μm. In some embodiments the parallel stripes have slightly detuned wavelengths for an improved color quality. In other embodiments free space optics such as collimating lenses can be used to shape the beam prior to incidence on the phosphor. In one example, a re-imaging optic is used to reflect and reshape the beam onto the phosphor member. In an alternative example, the otherwise wasted reflected incident light from the phosphor is recycled with a re-imaging optic by being reflected back to the phosphor.

The excitation beam can be characterized by a polarization purity of greater than 50% and less than 100%. As used herein, the term “polarization purity” means greater than 50% of the emitted electromagnetic radiation is in a substantially similar polarization state such as the transverse electric (TE) or transverse magnetic (TM) polarization states, but can have other meanings consistent with ordinary meaning. In an example, the laser beam incident on the phosphor has a power of less than 0.1 W, greater than 0.1 W, greater than 0.5 W, greater than 1 W, greater than 5 W, greater than 10 W, or greater than 20 W.

The phosphor material can be operated in a transmissive mode, a reflective mode, or a combination of a transmissive mode and reflective mode, or a side-pumped mode, or other modes. The phosphor material is characterized by a conversion efficiency, a resistance to thermal damage, a resistance to optical damage, a thermal quenching characteristic, a porosity to scatter excitation light, and a thermal conductivity. The phosphor may have an intentionally roughened surface to increase the light extraction from the phosphor. In a preferred embodiment the phosphor material is comprised of a yellow emitting YAG material doped with Ce with a conversion efficiency of greater than 100 lumens per optical watt, greater than 200 lumens per optical watt, or greater than 300 lumens per optical watt, and can be a polycrystalline ceramic material or a single crystal material. The white light apparatus also has an electrical input interface configured to couple electrical input power to the laser diode device to generate the laser beam and excite the phosphor material. The white light source configured to produce greater than 1 lumen, 10 lumens, 100 lumens, 250 lumens, 500 lumens, 1000 lumens, 3000 lumens, or 10000 lumens of white light output. The support member is configured to transport thermal energy from the at least one laser diode device and the phosphor material to a heat sink. The support member is configured to provide thermal impedance of less than 10 degrees Celsius per watt or less than 5 degrees Celsius per watt of dissipated power characterizing a thermal path from the laser device to a heat sink. The support member is comprised of a thermally conductive material such as copper, copper tungsten, aluminum, alumina, SiC, sapphire, AlN, or other metals, ceramics, or semiconductors.

In a preferred configuration of this integrated white light source, the common support member comprises the same submount that the gallium and nitrogen containing laser diode chip is directly bonded to. That is, the laser diode chip is mounted down or attached to a submount configured from a material such as SiC, AlN, or diamond and the phosphor material is also mounted to this submount, such that the submount is the common support member. The phosphor material may have an intermediate material positioned between the submount and the phosphor. The intermediate material may be comprised of a thermally conductive material such as copper. The laser diode can be attached to a first surface of the submount using conventional die attaching techniques using solders such as AuSn solder, SAC solder such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxem. Due to the extreme change in melt temperature from paste to sintered form, (260° C.-900° C.), processes can avoid thermal load restrictions on downstream processes, allowing completed devices to have very good and consistent bonds throughout. Similarly, the phosphor material may be bonded to the submount using a soldering technique, or a sintered Ag technique, but it can be other techniques such as gluing technique or epoxy technique. Optimizing the bond for the lowest thermal impedance is a key parameter for heat dissipation from the phosphor, which is critical to prevent phosphor degradation and thermal quenching of the phosphor material.

In an alternative configuration of this white light source, the laser diode is bonded to an intermediate submount configured between the gallium and nitrogen containing laser chip and the common support member. In this configuration, the intermediate submount can be comprised of SiC, AlN, diamond, or other, and the laser can be attached to a first surface of the submount using conventional die attaching techniques using solders such as AuSn solder, a SAC solder such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxem. Due to the extreme change in melt temperature from paste to sintered form, (260° C.-900° C.), processes can avoid thermal load restrictions on downstream processes, allowing completed devices to have very good and consistent bonds throughout. The second surface of the submount can be attached to the common support member using similar techniques, but could be others. Similarly, the phosphor material may have an intermediate material or submount positioned between the common support member and the phosphor. The intermediate material may be comprised of a thermally conductive material such as copper or copper tungsten. The phosphor material may be bonded using a soldering technique, a sintered Ag technique, or other technique. In this configuration, the common support member should be configured of a thermally conductive material such as copper or copper tungsten. Optimizing the bond for the lowest thermal impedance is a key parameter for heat dissipation from the phosphor, which is critical to prevent phosphor degradation and thermal quenching of the phosphor material.

In yet another preferred variation of this CPOS integrated white light source, a process for lifting-off gallium and nitrogen containing epitaxial material and transferring it to the common support member can be used to attach the gallium and nitrogen containing laser epitaxial material to a submount member. In this embodiment, the gallium and nitrogen epitaxial material is released from the gallium and nitrogen containing substrate it was epitaxially grown on. As an example, the epitaxial material can be released using a photoelectrochemical (PEC) etching technique. It is then transferred to a submount material using techniques such as wafer bonding wherein a bond interface is formed. For example, the bond interface can be comprised of an Au—Au bond. The submount material preferably has a high thermal conductivity such as SiC, wherein the epitaxial material is subsequently processed to form a laser diode with a cavity member, front and back facets, and electrical contacts for injecting current. After laser fabrication is complete, a phosphor material is introduced onto the submount to form an integrated white light source. The phosphor material may have an intermediate material positioned between the submount and the phosphor. The intermediate material may be comprised of a thermally conductive material such as copper. The phosphor material can be attached to the submount using conventional die attaching techniques using solders such as AuSn solder, SAC solder such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxcm whereas pressureless sintered Ag can have a thermal conductivity of about 125 W/(m·K) and electrical conductivity of about 4 micro-ohmxem, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. . . . Optimizing the bond for the lowest thermal impedance is a key parameter for heat dissipation from the phosphor, which is critical to prevent phosphor degradation and thermal quenching of the phosphor material. The benefits of using this embodiment with lifted-off and transferred gallium and nitrogen containing material are the reduced cost, improved laser performance, and higher degree of flexibility for integration using this technology.

In all embodiments of this integrated white light source, the present invention may include safety features and design considerations. In any laser-based source, safety is a key aspect. It is critical that the light source cannot be compromised or modified in such a way to create laser diode beam that can be harmful to human beings, animals, or the environment. Thus, the overall design should include safety considerations and features, and in some cases even active components for monitoring. Examples of design considerations and features for safety include positioning the laser beam with respect to the phosphor in a way such that if the phosphor is removed or damaged, the exposed laser beam would not make it to the outside environment in a harmful form such as collimated, coherent beam. More specifically, the white light source is designed such that laser beam is pointing away from the outside environment and toward a surface or feature that will prevent the beam from being reflected to the outside world. In an example of a passive design features for safety include beam dumps and/or absorbing material can be specifically positioned in the location the laser beam would hit in the event of a removed or damaged phosphor. In some embodiments thermal fuses are incorporated wherein the fuse creates an open circuit and turns the laser diode off in an un-safe condition.

In some embodiments of this invention, safety features and systems use active components. Example active components include photodiodes/photodetectors and thermistors. Strategically located detectors designed to detect direct blue emission from the laser, scatter blue emission, or phosphor emission such as yellow phosphor emission can be used to detect failures of the phosphor where a blue beam could be exposed. Upon detection of such an event, a close circuit or feedback loop would be configured to cease power supply to the laser diode and effectively turn it off. As an example, a detector used to detect phosphor emission could be used to determine if the phosphor emission rapidly reduced, which would indicate that the laser is no longer effectively hitting the phosphor for excitation and could mean that the phosphor was removed or damaged. In another example of active safety features, a blue sensitive photodetector could be positioned to detect reflected or scatter blue emission from the laser diode such that if the phosphor was removed or compromised the amount of blue light detected would rapidly increase and the laser would be shut off by the safety system. In yet another example of active safety features a thermistor could be positioned near or under the phosphor material to determine if there was a sudden increase in temperature which may be a result of increased direct irradiation from the blue laser diode indicating a compromised or removed phosphor. Again, in this case the thermistor signal would trip the feedback loop to cease electrical power to the laser diode and shut it off. Of course, these are merely example embodiments, there are several configurations for photodiodes and/or thermistors to be integrated with a laser-based white light source to form a safety feature such as a feedback loop to cease operation of the laser.

In many embodiments of the present invention an electrostatic discharge (ESD) protection element is included. For example, an ESD protection element would be used to protect the integrated white light source from damage that could occur with a sudden flow of current resulting from a build-up of charge. In one example a transient voltage suppression (TVS) element is employed.

In all embodiments of the integrated white light source final packaging would need to be considered. There are many aspects of the package that should be accounted for such as form factor, cost, functionality, thermal impedance, sealing characteristics, and basic compatibility with the application. Form factor will depend on the application, but in general making the smallest size packaged white source will be desirable. Cost should be minimized in all applications, but in some applications cost will be the most important consideration. In such cases using an off-the-shelf package produced in high volume may be desirable. Functionality options include direction and properties of the exiting light emission for the application as well as integration of features such as photodetectors, thermistors, or other electronics or optoelectronics. For best performance and lifetime the thermal impedance of the package should be minimized, especially in high power applications. Examples of scaling configurations include open environment, environmentally sealed, or hermetically sealed. Typically for GaN based lasers it is desirable for hermetically sealed packages, but other packages can be considered and deployed for various applications. Examples of off the shelf packages for the integrated white light source include TO cans such as TO38, TO56, TO9, TO5, or other TO can type packages. Flat packages configured with windows can also be used. Examples of flat packages include a butterfly package like a TOSA. Surface mount device (SMD) packages can also be used, which are attractive due to their low price, hermetic sealing, and potentially low thermal impedance. In other embodiments, custom packages are used. In another embodiment, a “Flash” package could be used for the integrated white light source. For example, this package could be used to adapt the laser-based white light source to camera flash applications. One of the standard packaging formats for today's LEDs employ the use of a flat ceramic package, sometimes called “Flash” packages as devices built on these platforms have primarily been used in Camera Flash and Cell Phone applications. The typical flash package consists of a flat ceramic substrate (Alumina or AlN) with attach pads for LED and ESD devices as well as leads providing a location for clipping or soldering external electrical connections to power the device. The phosphor is contained near the LED die via molding or other silicone containing dispensing application. This layer is then typically over molded with a clear silicone lens to improve light extraction. The primary benefits of a package in this format is a very small overall package dimension (˜3mmx˜5 mm), reasonable light output performance (hundreds of Lumens), small source size and overall low-cost LED device. This package style could also be achieved by employing a laser plus phosphor design style which would potentially could eliminate the encapsulation and lensing steps, providing an LED replacement with superior spot size and brightness. If a protective cover were needed to house the laser and phosphor subcomponents, a hollow glass dome could be used to provide protection.

In some embodiments of this invention, the integrated white light source is combined with optical members to manipulate the generated white light. In an example the white light source could serve in a spot light system such as a flashlight or an automobile headlamp or other light applications where the light must be directed or projected to a specified location or area. In one embodiment a reflector is coupled to the white light source. Specifically, a parabolic (or paraboloid or paraboloidal) reflector is deployed to project the white light. By positioning the white light source in the focus of a parabolic reflector, the plane waves will be reflected and propagate as a collimated beam along the axis of the parabolic reflector. In another example a lens is used to collimate the white light into a projected beam. In one example a simple aspheric lens would be positioned in front of the phosphor to collimate the white light. In another example, a total internal reflector optic is used for collimation. In other embodiments other types of collimating optics may be used such as spherical lenses or aspherical lenses. In several embodiments, a combination of optics is used.

In a specific embodiment of the general invention described above, the present invention is configured for a side-pumped phosphor operated in transmissive mode. In this configuration, the phosphor is positioned in front of the laser facet outputting the laser beam, wherein both the laser and the phosphor are configured on a support member. The gallium and nitrogen containing laser diode is configured with a cavity that has a length greater than 100 μm, greater than 500 μm, greater than 1000 μm, or greater than 1500 μm long and a width greater than 1 μm, greater than 10 μm, greater than 20 μm, greater than 30 μm, or greater than 45 μm. The cavity is configured with a front facets and back facet on the end wherein the front facet comprises the output facet and emits the laser beam incident on the phosphor. The output facet may contain an optical coating to reduce the reflectivity in the cavity. The back facet can be coated with a high reflectivity coating to reduce the amount of light exiting the back of the laser diode. The phosphor is comprised of Ce doped YAG and emits yellow emission. The phosphor is shaped as a block, plate, sphere, cylinder, or other geometrical form. Specifically, the phosphor geometry primary dimensions may be less than 50 μm, less than 100 μm, less than 200 μm, less than 500 μm, less than 1 mm, or less than 10 mm. Operated in transmissive mode, the phosphor has a first primary side for receiving the incident laser beam and at least a second primary side where most of the useful white light will exit the phosphor to be coupled to the application. To improve the efficiency by maximizing the amount of light exiting the second side of the phosphor, the phosphor may be coated with layers configured to modify the reflectivity for certain colors. In one example, a coating configured to increase the reflectivity for yellow light is applied to the first side of the phosphor such that the amount of yellow light emitted from the first side is reduce. In another example, a coating to increase the reflectivity of the blue light is spatially patterned on the first side of the phosphor to allow the excitation light to pass, but prevent backward propagating scattered light to escape. In another example, optical coatings configured to reduce the reflectivity to yellow and blue light are applied to at least the second side of the phosphor to maximize the light escaping from this primary side where the useful light exits. In an alternative embodiment, a powdered phosphor such as a yellow phosphor is dispensed onto a transparent plate or into a solid structure using a binder material and is configured to emit a white light when excited by and combined with the blue laser beam. The powdered phosphors could be comprised of YAG based phosphors, and other phosphors.

With respect to attaching the phosphor to the common support member, thermal impedance is a key consideration. The thermal impedance of this attachment joint should be minimized using the best attaching material, interface geometry, and attachment process practices for the lowest thermal impedance with sufficient reflectivity. Examples include AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohm·cm, or pressured sintered Ag can have a thermal conductivity of about 250 W/(m·K) and electrical conductivity of about 2.5 micro-ohmxem. Due to the extreme change in melt temperature from paste to sintered form, (260° C.-900° C.), processes can avoid thermal load restrictions on downstream processes, allowing completed devices to have very good and consistent bonds throughout. The joint could also be formed from thermally conductive glues, thermal epoxies such as silver epoxy, thermal adhesives, and other materials. Alternatively, the joint could be formed from a metal-metal bond such as an Au—Au bond. The common support member with the laser and phosphor material is configured to provide thermal impedance of less than 10 degrees Celsius per watt or less than 5 degrees Celsius per watt of dissipated power characterizing a thermal path from the laser device to a heat sink. The support member is comprised of a thermally conductive material such as copper, copper tungsten, aluminum, alumina, SiC, sapphire, AlN, or other metals, ceramics, or semiconductors. The side-pumped transmissive apparatus has a form factor characterized by a length, a width, and a height. In an example, the height is characterized by a dimension of less than 25 mm, and greater than 0.5 mm, although there may be variations. In an alternative example, the height is characterized by a dimension of less than 12.5 mm, and greater than 0.5 mm, although there may be variations. In yet an alternative example, the length and width are characterized by a dimension of less than 30 mm, less than 15 mm, or less than 5 mm, although there may be variations.

In alternative embodiments of the present invention, multiple phosphors are operated in a transmissive mode for a white emission. In one example, a violet laser diode configured to emit a wavelength of 395 nm to 425 nm and excite a first blue phosphor and a second yellow phosphor. In this configuration, a first blue phosphor plate could be fused or bonded to the second yellow phosphor plate. In a practical configuration the laser beam would be directly incident on the first blue phosphor wherein a fraction of the blue emission would excite the second yellow phosphor to emit yellow emission to combine with blue emission and generate a white light. Additionally, the violet pump would essentially all be absorbed since what may not be absorbed in the blue phosphor would then be absorbed in the yellow phosphor. In an alternative practical configuration, the laser beam would be directly incident on the second yellow phosphor wherein a fraction of the violet electromagnetic emission would be absorbed in the yellow phosphor to excite yellow emission and the remaining violet emission would pass to the blue phosphor and create a blue emission to combine a yellow emission with a blue emission and generate a white light. In an alternative embodiment, a powdered mixture of phosphors would be dispensed onto a transparent plate or into a solid structure using a binder material such that the different color phosphors such as blue and yellow phosphors are co-mingled and are configured to emit a white light when excited by the violet laser beam. The powdered phosphors could be comprised of YAG based phosphors, LuAG phosphors, and other phosphors.

In an alternative embodiment of a multi-phosphor transmissive example according to the present invention, a blue laser diode operating with a wavelength of 425 nm to 480 nm is configured to excite a first green phosphor and a second red phosphor. In this configuration, a first green phosphor plate could be fused or bonded to the second red phosphor plate. In a practical configuration the laser beam would be directly incident on the first green phosphor wherein a fraction of the green emission would excite the second red phosphor to emit red emission to combine with green phosphor emission and blue laser diode emission to generate a white light. In an alternative practical configuration the laser beam would be directly incident on the second red phosphor wherein a fraction of the blue electromagnetic emission would be absorbed in the red phosphor to excite red emission and a portion of the remaining blue laser emission would pass to the green phosphor and create a green emission to combine with the red phosphor emission and blue laser diode emission to generate a white light. In an alternative embodiment, a powdered mixture of phosphors would be dispensed onto a transparent plate or into a solid structure using a binder material such that the different color phosphors such as red and green phosphors are co-mingled and are configured to emit a white light when excited by and combined with the blue laser beam. The powdered phosphors could be comprised of YAG based phosphors, LuAG phosphors, and other phosphors. The benefit or feature of this embodiment is the higher color quality that could be achieved from a white light comprised of red, green, and blue emission. Of course, there could be other variants of this invention including integrating more than two phosphor and could include one of or a combination of a red, green, blue, and yellow phosphor.

In several embodiments according to the present invention, the laser-based integrated white light sources is configured as a high CRI white light source with a CRI over 70, over 80, or over 90. In these embodiments, multiple phosphors are used in the form of a mixed power phosphor composition or multiple phosphor plate configuration or others. Examples of such phosphors include, but are not limited to YAG, LuAG, red nitrides, aluminates, oxynitrides, CaMgSi₂O₆:Eu²⁺, BAM:Eu²⁺, AlN:Eu²⁺, (Sr, Ca)₃MgSi₂O₈:Eu²⁺, and JEM.

In some configurations of the high CRI embodiments of the integrated laser-based white light source a blue laser diode excitation source operating in the wavelength range of 430 nm to 470 nm is used to excite;
1) Yellow phosphor+red phosphor, or
2) Green phosphor+red phosphor, or
3) Cyan phosphor+orange phosphor, or
4) Cyan phosphor+orange phosphor+red phosphor, or
5) Cyan phosphor+yellow phosphor+red phosphor, or
6) Cyan phosphor+green phosphor+red phosphor

In some alternative configurations of the high CRI embodiments of the integrated laser-based white light source a violet laser diode excitation source operating in the wavelength range of 390 nm to 430 nm is used to excite;
1) Blue phosphor+yellow phosphor+red phosphor, or
2) Blue phosphor+green phosphor+red phosphor, or
3) Blue phosphor+cyan phosphor+orange phosphor, or
4) Blue phosphor+cyan phosphor+orange phosphor+red phosphor, or
5) Blue phosphor+cyan phosphor+yellow phosphor+red phosphor, or
6) Blue phosphor+cyan phosphor+green phosphor+red phosphor

In an alternative embodiment of a multi-phosphor transmissive example according to the present invention, a blue laser diode operating with a wavelength of 395 nm to 425 nm is configured to excite a first blue phosphor, a second green phosphor, and a third red phosphor. In this one embodiment of this configuration, a first blue phosphor plate could be fused or bonded to the second green phosphor plate which is fused or bonded to the third red phosphor plate. In a practical configuration the laser beam would be directly incident on the first blue phosphor wherein a fraction of the blue emission would excite the second green phosphor and third red phosphor to emit green and red emission to combine with first phosphor blue emission to generate a white light. In an alternative practical configuration the violet laser beam would be directly incident on the third red phosphor wherein a fraction of the violet electromagnetic emission would be absorbed in the red phosphor to excite red emission and a portion of the remaining violet laser emission would pass to the second green phosphor and create a green emission to combine with the red phosphor emission and a portion of the violet laser diode would pass to the first blue phosphor to create a blue emission to combine the red and green emission to generate a white light. In an alternative embodiment, a powdered mixture of phosphors would be dispensed onto a transparent plate or into a solid structure using a binder material such that the different color phosphors such as red, green, and blue phosphors are co-mingled and are configured to emit a white light when excited by the violet laser beam. The powdered phosphors could be comprised of YAG based phosphors, LuAG phosphors, and other phosphors. The benefit or feature of this embodiment is the higher color quality and color rendering quality that could be achieved from a white light comprised of red, green, and blue emission. Of course there could be other variants of this invention including integrating more than two phosphor and could include one of or a combination of a red, green, blue, and yellow phosphor.

In yet another variation of a side pumped phosphor configuration, a “point source” or “point source like” integrated white emitting device is achieved. In this configuration the phosphor would most likely have a cube geometry or spherical geometry such that white light can be emitted from more than 1 primary emission surface. For example, in a cube geometry up to all six faces of the cube can emit white light or in a sphere configuration the entire surface can emit to create a perfect point source. A first strong advantage to this configuration is that the white light spot size is controlled by the phosphor size, which can enable smaller spot sizes than alternative transmissive or reflective mode configurations by avoiding the spot size growth that happens within the phosphor due to scattering, reflection, and lack of efficient absorption in the phosphor. Ultra-small spot sizes are ideal for most efficient collimation in directional applications. A second advantage to this configuration is the ideal heat sinking configuration wherein for the phosphor member it is identical to a reflection mode configuration with the entire bottom surface of the phosphor can be thermally and mechanically attached to a heat-sink. Further, since the laser diode member does not require thick or angled intermediate support members to elevate the beam and dictate an angled incidence as in the reflection mode configurations, the laser can be mounted closer to the base member for a shorter thermal conduction path to the heat-sink. A third advantage is the inherent design for safety since the primary emission may be from the top surface of the phosphor orthogonal to the laser beam direction such that in the event of a phosphor breakage or compromise the laser beam would not be pointing the direction of white light capture. In this configuration, if the phosphor were to be removed or compromised the laser beam would be incident on the side of the package. Moreover, this configuration would avoid the potential issue in a reflective configuration where an escaped beam can result from a reflection of the incident beam on the top of the surface. In this side pumped configuration, the reflected beam would be substantially contained in the package. A fourth advantage is that since the laser diode or SLED device can be mounted flat on the base member, the assembly process and components can be simplified. In this side pumped configuration, it may be advantageous to promote primary emission from the top surface of the phosphor. This could be achieved with treatments to promote light escape from the top surface such as application of an anti-reflective coating or roughening, and treatments to reduce light escape from the side and bottom surfaces such as application of highly reflective layers such as metal or dielectric layers.

In some configurations of this embodiment the phosphor is attached to the common support member wherein the common support member may not be fully transparent. In this configuration the surface or side of the phosphor where it is attached would have impeded light emission and hence would reduce the overall efficiency or quality of the point source white light emitter. However, this emission impediment can be minimized or mitigated to provide a very efficient illumination. In other configurations, the phosphor is supported by a optically transparent member such that the light is free to emit in all directions from the phosphor point source. In one variation, the phosphor is fully surrounded in or encapsulated by an optically transparent material such as a solid material like SiC, diamond, GaN, or other, or a liquid material like water or a more thermally conductive liquid.

In another variation, the support member could also serve as a waveguide for the laser light to reach the phosphor. In another variation, the support member could also serve as a protective safety measure to ensure that no direct emitting laser light is exposed as it travels to reach the phosphor. Such point sources of light that produce true omni-directional emission are increasing useful as the point source becomes increasing smaller, due to the fact that product of the emission aperture and the emission angle is conserved or lost as subsequent optics and reflectors are added. Specifically, for example, a small point source can be collimated with small optics or reflectors. However, if the same small optics and/or reflector assembly are applied to a large point source, the optical control and collimation is diminished.

In some embodiments according to the present invention a periodic 2D photonic crystal structure can be applied to the single crystal or poly crystal phosphor materials structure. The photonic crystal structure would be employed to suppress emission in given directions and re-direct light out of the photonic crystal in a direction suitable and chosen for the device design. Phosphor structures today are largely Lambertian emitters except where waveguiding and critical angle comes into play. Many phosphors today satisfy the basic materials requirements needed to create photonic crystal structures-(dielectric or metallo-dielectric materials with low optical absorption). Adding photonic crystal structures to phosphor plate materials would allow light extraction to be enhanced in 1 direction over another in these materials. This can separate the excitation and emission characteristics thereby allowing greater flexibility in design.

In yet another variation of a side pumped phosphor embodiment, a phosphor is excited from the side and configured to emit a substantial portion of the white light from a top surface. In this configuration the phosphor would most likely have a cubic geometry, a cylindrical geometry, a faceted geometry, a hexagonal geometry, a triangular geometry, a pyramidal geometry, or other multi-sided geometries wherein the white light is configured to be emitted primarily from the top surface of the phosphor. In this configuration the laser beam would enter the phosphor from a first of side of the phosphor where a fraction of the laser excitation light with a first wavelength would be converted to a second wavelength. This first side of the phosphor may be configured for a modified reflectivity such as a coating or treatment to reduce the reflectivity in the blue or violet wavelength range and/or for increased reflectivity for the phosphor emission wavelength range such as yellow. In one example of the side pumped embodiment the laser excitation beam is incident on the first side of the phosphor at the Brewster angle. In further examples, the additional sides of the phosphor may be coated, treated, or shaped for an increased reflectivity to both the laser excitation wavelength and the phosphor conversion wavelength such that the light within the phosphor would be reflected inside the phosphor until it escaped from the top. Special phosphor shaping or coating techniques could be used to enhance the fraction of light escaping the top surface. A first strong advantage to this configuration is that the white light spot size is controlled by the phosphor size, which can enable smaller spot sizes than alternative transmissive or reflective mode configurations by avoiding the spot size growth that happens within the phosphor due to scattering, reflection, and lack of efficient absorption in the phosphor. Ultra-small spot sizes are ideal for most efficient collimation in directional applications. A second advantage to this configuration is the ideal heat sinking configuration wherein for the phosphor member it is identical to a reflection mode configuration with the entire bottom surface of the phosphor can be thermally and mechanically attached to a heat-sink. Further, since the laser diode member does not require thick or angled intermediate support members to elevate the beam and dictate an angled incidence as in the reflection mode configurations, the laser can be mounted closer to the base member for a shorter thermal conduction path to the heat-sink. A third advantage is the inherent design for safety since the primary emission may be from the top surface of the phosphor orthogonal to the laser beam direction such that in the event of a phosphor breakage or compromise the laser beam would not be pointing the direction of white light capture. In this configuration, if the phosphor were to be removed or compromised the laser beam would be incident on the side of the package. Moreover, this configuration would avoid the potential issue in a reflective configuration where an escaped beam can result from a reflection of the incident beam on the top of the surface. In this side pumped configuration, the reflected beam would be substantially contained in the package. A fourth advantage is that since the laser diode or SLED device can be mounted flat on the base member, the assembly process and components can be simplified. In this side pumped configuration, it may be advantageous to promote primary emission from the top surface of the phosphor.

In all of the side pumped and transmissive embodiments of this invention the additional features and designs can be included. For example, shaping of the excitation laser beam for optimizing the beam spot characteristics on the phosphor can be achieved by careful design considerations of the laser beam incident angle to the phosphor or with using integrated optics such as free space optics like collimating lens. In some embodiments re-imaging optics such as re-imaging reflectors are used to shape the excitation beam and/or re-capture excitation light reflected from the phosphor. Safety features can be included such as passive features like physical design considerations and beam dumps and/or active features such as thermal fuses, photodetectors, or thermistors that can be used in a closed loop to turn the laser off when a signal is indicated.

A point source omni-directional light source is configurable into several types of illumination patterns including 4-pi steradian illumination to provide a wide illumination to a three-dimensional volume such as a room, lecture hall, or stadium. Moreover, optical elements can be included to manipulate the generated white light to produce highly directional illumination. In some embodiments, reflectors such as parabolic reflectors or lenses such as collimating lenses are used to collimate the white light or create a spot light that could be applicable in an automobile headlight, flashlight, spotlight, or other lights. In other embodiments, the point source illumination can be modified with cylindrical optics and reflectors into linear omni-directional illumination, or linear directional illumination. Additionally, the point source illumination coupled into planar waveguides for planar 2-pi steradian emission, planar 4-pi steradian emission to produce glare-free illumination patterns that emit from a plane.

In a specific preferred embodiment of the integrated white light source, the present invention is configured for a reflective mode phosphor operation. In one example the excitation laser beam enters the phosphor through the same primary surface as the useful white light is emitted from. That is, operated in reflective mode the phosphor could have a first primary surface configured for both receiving the incident excitation laser beam and emitting useful white light. In this configuration, the phosphor is positioned in front of the laser facet outputting the laser beam, wherein both the laser and the phosphor are configured on a support member. The gallium and nitrogen containing laser diode is configured with a cavity that has a length greater than 100 μm, greater than 500 μm, greater than 1000 μm, or greater than 1500 μm long and a width greater than 1 μm, greater than 10 μm, greater than 20 μm, greater than 30 μm, or greater than 45 μm. The cavity is configured with a front facets and back facet on the end wherein the front facet comprises the output facet and emits the laser beam incident on the phosphor. The output facet may contain an optical coating to reduce the reflectivity in the cavity. The back facet can be coated with a high reflectivity coating to reduce the amount of light exiting the back facet of the laser diode. In one example, the phosphor can be comprised of Ce doped YAG and emits yellow emission. The phosphor may be a powdered ceramic phosphor, a ceramic phosphor plate, or could be a single crystal phosphor. The phosphor is preferably shaped as a substantially flat member such as a plate or a sheet with a shape such as a square, rectangle, polygon, circle, or ellipse, and is characterized by a thickness. In a preferred embodiment the length, width, and or diameter dimensions of the large surface area of the phosphor are larger than the thickness of the phosphor. For example, the diameter, length, and/or width dimensions may be 2× greater than the thickness, 5× greater than the thickness, 10× greater than the thickness, or 50× greater than the thickness. Specifically, the phosphor plate may be configured as a circle with a diameter of greater than 50 μm, greater than 100 μm, greater than 200 μm, greater than 500 μm, greater than 1 mm, or greater than 10 mm and a thickness of less than 500 μm, less than 200 μm, less than 100 μm or less than 50 μm.

In one example of the reflective mode CPOS white light source embodiment of this invention optical coatings, material selections are made, or special design considerations are taken to improve the efficiency by maximizing the amount of light exiting the primary surface of the phosphor. In one example, the backside of the phosphor may be coated with reflective layers or have reflective materials positioned on the back surface of the phosphor adjacent to the primary emission surface. The reflective layers, coatings, or materials help to reflect the light that hits the back surface of the phosphor such that the light will bounce and exit through the primary surface where the useful light is captured. In one example, a coating configured to increase the reflectivity for yellow light and blue light and is applied to the phosphor prior to attaching the phosphor to the common support member. In another example, a reflective material is used as a bonding medium that attaches the phosphor to the support member or to an intermediate submount member. Examples of reflective materials include reflective solders and reflective glues, but could be others. In some configurations the top primary surface of the phosphor wherein the laser excitation beam is incident is configured for a reduced reflectivity to the blue or violet excitation beam wavelength and/or the phosphor emission wavelength such as a yellow wavelength. The reduced reflectivity can be achieved with an optical coating of the phosphor using dielectric layers, a shaping of the phosphor surface, and roughening of the phosphor surface, or other techniques. In some examples the laser beam incident angle is configured at or near Brewster's angle, wherein the light with a particular polarization is perfectly transmitted through the primary surface of the phosphor. Due to the divergence of the laser resulting in a variation of incident angles for the plane waves within the beam a perfect transmission may be challenging, but ideally a substantial fraction of the light incident on the phosphor could be at or near Brewster's angle. For example, a YAG or LuAG phosphor may have a refractive index of about 1.8 in the violet and blue wavelength range. With the Brewster angle, OB, given as arctan (n2/n1), where n1 is the index of air and n2 is the index of the phosphor, would be about 61 degrees [or about 55 to 65 degrees], off of the axis of normal incidence. Or alternatively, about 29 degrees [or about 25 to 35 degrees] rotated from the axis parallel to the phosphor surface.

With respect to attaching the phosphor to the common support member, thermal impedance is a key consideration. The thermal impedance of this attachment joint should be minimized using the best attaching material, interface geometry, and attachment process practices for the lowest thermal impedance with sufficient reflectivity. Examples include AuSn solders, such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. . . . The joint could also be formed from thermally conductive glues, thermal epoxies, and other materials. The common support member with the laser and phosphor material is configured to provide thermal impedance of less than 10 degrees Celsius per watt or less than 5 degrees Celsius per watt of dissipated power characterizing a thermal path from the laser device to a heat sink. The support member is comprised of a thermally conductive material such as copper, copper tungsten, aluminum, SiC, sapphire, AlN, or other metals, ceramics, or semiconductors. The reflective mode white light source apparatus has a form factor characterized by a length, a width, and a height. In an example, the height is characterized by a dimension of less than 25 mm and greater than 0.5 mm, although there may be variations. In an alternative example, the height is characterized by a dimension of less than 12.5 mm, and greater than 0.5 mm, although there may be variations. In yet an alternative example, the length and width are characterized by a dimension of less than 30 mm, less than 15 mm, or less than 5 mm, although there may be variations.

The reflective mode integrated white light source embodiment of this invention is configured with the phosphor member attached to the common support member with the large primary surface configured for receiving laser excitation light and emitting useful white light positioned at an angle normal (about 90 degrees) or off-normal (about 0 degrees to about 89 degrees) to the axis of the laser diode output beam functioning to excite the phosphor. That is, the laser output beam is pointing toward the phosphor's emission surface at an angle of between 0 and 90 degrees. The nature of this configuration wherein the laser beam is not directed in the same direction the primary phosphor emission surface emits is a built-in safety feature. That is, the laser beam is directed away from or opposite of the direction the useful white light will exit the phosphor. As a result, if the phosphor is to break or get damaged during normal operation or from tampering, the laser beam would not be directed to the outside world where it could be harmful. Instead, the laser beam would be incident on the backing surface where the phosphor was attached. As a result, the laser beam could be scattered or absorbed instead of exiting the white light source and into the surrounding environment. Additional safety measure can be taken such as using a beam dump feature or use of an absorbing material such as a thermal fuse that heats up and creates an open circuit within the laser diode drive circuit.

One example of this reflective mode integrated white light source embodiment is configured with the laser beam normal to the primary phosphor emission surface. In this configuration the laser diode would be positioned in front of the primary emission surface of the phosphor where it could impede the useful white light emitted from the phosphor. In a preferable embodiment of this reflective mode integrated white light source, the laser beam would be configured with an incident angle that is off-axis to the phosphor such that it hits the phosphor surface at an angle of between 0 and 89 degrees or at a “grazing” angle. In some configurations the incident angle is configured at or near Brewster's angle to maximize the transmission of the laser excitation light into the phosphor. In this preferable embodiment the laser diode device is positioned to the side of the phosphor instead of in front of the phosphor where it will not substantially block or impede the emitted white light. Moreover, in this configuration the built in safety feature is more optimal than in the normal incidence configuration since when incident at an angle in the case of phosphor damage or removal the incident laser beam would not reflect directly off the back surface of the support member where the phosphor was attached. By hitting the surface at an off-angle or a grazing angle any potential reflected components of the beam can be directed to stay within the apparatus and not exit the outside environment where it can be a hazard to human beings, animals, and the environment.

In all of the reflective mode embodiments of this invention the additional features and designs can be included. For example, shaping of the excitation laser beam for optimizing the beam spot characteristics on the phosphor can be achieved by careful design considerations of the laser beam incident angle to the phosphor or with using integrated optics such as free space optics like collimating lens. Beam shaping can also be achieved by using two or more adjacent parallel emitter stripes spaced by 10 μm to 30 μm, or 30 μm to 50 μm, or 100 μm to 250 μm such that the beam is enlarged in the slow-divergence axis from the laser emission apertures. Beam shaping may also be achieved with re-imaging optics. Safety features can be included such as passive features like physical design considerations and beam dumps and/or active features such as photodetectors or thermistors that can be used in a closed loop or a type of feedback loop to turn the laser off when a signal is indicated. Moreover, optical elements can be included to manipulate the generated white light. In some embodiments, reflectors such as parabolic reflectors or lenses such as collimating lenses are used to collimate the white light or create a spot light that could be applicable in an automobile headlight, flashlight, spotlight, or other lights.

In some embodiments according to the present invention, multiple laser diode sources are configured to excite the same phosphor or phosphor network. Combining multiple laser sources can offer many potential benefits according to this invention. First, the excitation power can be increased by beam combining to provide a more powerful excitation spit and hence produce a brighter light source. In some embodiments, separate individual laser chips are configured within the laser-phosphor light source. By including multiple lasers emitting 1 W, 2 W, 3 W, 4 W, 5 W or more power each, the excitation power can be increased and hence the source brightness would be increased. For example, by including two 3 W lasers exciting the same phosphor area, the excitation power can be increased to 6 W for double the white light brightness. In an example where about 200 lumens of white are generated per 1 watt of laser excitation power, the white light output would be increased from 600 lumens to 1200 lumens. Similarly, the reliability of the source can be increased by using multiple sources at lower drive conditions to achieve the same excitation power as a single source driven at more harsh conditions such as higher current and voltage. A second advantage is the potential for a more circular spot by rotating the first free space diverging elliptical laser beam by 90 degrees relative to the second free space diverging elliptical laser beam and overlapping the centered ellipses on the phosphor. Alternatively, a more circular spot can be achieved by rotating the first free space diverging elliptical laser beam by 180 degrees relative to the second free space diverging elliptical laser beam and off-centered overlapping the ellipses on the phosphor to increase spot diameter in slow axis diverging direction. In another configuration, more than 2 lasers are included and some combination of the above described beam shaping spot geometry shaping is achieved. A third and important advantage is that multiple color lasers in a emitting device can significantly improve color quality (CRI and CQS) by improving the fill of the spectra in the violet/blue and cyan region of the visible spectrum. For example, two or more blue excitation lasers with slightly detuned wavelengths (e.g. 5 nm 10 nm, 15 nm, etc.) can be included to excite a yellow phosphor and create a larger blue spectrum.

In a specific embodiment, the present invention provides a laser-based fiber-coupled white light system. The white light system includes a laser device including a gallium and nitrogen containing material and configured as an excitation source with an output facet configured to output a laser emission with a first wavelength ranging from 385 nm to 495 nm. The white light system further includes a phosphor member configured as a wavelength converter and an emitter and coupled to the laser device in a free space between the output facet and an excitation surface of the phosphor member to receive the laser emission in a range of off-normal angles of incidence so that the laser beam lands from one side of the excitation surface to a spot on the excitation surface with a size greater than 5 μm. Additionally, the white light system includes a support member configured to support the laser device and/or the phosphor member. Furthermore, the phosphor member converts the laser emission with the first wavelength to a phosphor emission with a second wavelength that is longer than the first wavelength, the phosphor emission being reflected from the spot to the same side of the excitation surface to mix at least partially with laser emission to produce a white light emission. Moreover, the white light system includes a fiber coupled to the phosphor member to capture the white light emission with at least 20% efficiency to deliver or distribute the white light emission.

In another specific embodiment, the present invention provides a laser-based fiber-coupled white light system. The white light system includes a laser device comprising a gallium and nitrogen containing material and configured as an excitation source with an output facet configured to emit a laser emission with a first wavelength ranging from 385 nm to 495 nm. Additionally, the white light system includes a phosphor plate configured as a wavelength converter and an emitter in a free space with a receiving surface to receive the laser emission in a substantial normal direction. The phosphor plate converts the laser emission with the first wavelength to a phosphor emission with a second wavelength that is longer than the first wavelength. The phosphor emission is mixed at least partially with laser emission in the phosphor plate to generate a white light emission transmitted through the phosphor plate to exit from an output surface at opposite side of the receiving surface. Furthermore, the white light system includes a support member configured to support the laser device and/or the phosphor plate. Moreover, the white light system includes a fiber coupled to the phosphor plate to capture the white light emission with at least 20% efficiency to deliver or distribute the white light emission. The leaky fiber could be a bundled leaky fiber. For example, the leak fiber could be a bundle of fibers comprised of glass fibers or plastic fibers.

In yet another specific embodiment, the present invention provides a laser-based fiber-delivered white automobile headlight system. The automobile headlight system includes one or more white light source modules. Each of the one or more white light source modules includes a laser device comprising a gallium and nitrogen containing material and configured as an excitation source having an output facet configured to output a laser emission with a first wavelength ranging from 385 nm to 495 nm. Each of the one or more white light sources further includes a phosphor member configured as a wavelength converter and an emitter and coupled to the laser device in a free space between the output facet and an excitation surface of the phosphor member to receive the laser emission in a range of off-normal angles of incidence so that the laser beam lands from one side of the excitation surface to a spot on the excitation surface with a size greater than 5 μm. Additionally, each of the one or more white light sources includes a support member configured to support the laser device and/or the phosphor member. The phosphor member converts the laser emission with the first wavelength to a phosphor emission with a second wavelength that is longer than the first wavelength. The phosphor emission is reflected from the spot to the same side of the excitation surface to mix at least partially with laser emission to produce a white light emission. Furthermore, the automobile headlight system includes one or more transport fibers configured to have first ends to couple with the one or more white light source modules to capture the white light emission and transport the white light emission to second ends. Moreover, the automobile headlight system includes a headlight module attached at a remote location and coupled with the second ends of the one or more transport fibers, the headlight module being configured to project the white light onto road.

In an alternative embodiment, the present invention provides a laser-based fiber-coupled white light illumination source for automobile. The laser-based fiber-coupled white light illumination source includes one or more white light source modules. Each white light source module includes a laser device comprising a gallium and nitrogen containing material and configured as an excitation source. The laser device includes an output facet configured to output a laser emission with a first wavelength ranging from 385 nm to 495 nm. Each white light source module also includes a phosphor member configured as a wavelength converter and an emitter and disposed to allow the laser electromagnetic radiation being optically coupled to a primary surface of the phosphor member. Additionally, each white light source module includes an angle of incidence configured between the laser electromagnetic radiation and the primary surface of the phosphor member. The phosphor member is configured to convert at least a fraction of the laser electromagnetic radiation with the first wavelength landed in a spot greater than 5 μm on the primary surface to a phosphor emission with a second wavelength that is longer than the first wavelength. Furthermore, each white light source module includes a reflection mode characterizing the phosphor member with a white light emission being generated from at least an interaction of the laser electromagnetic radiation with the phosphor emission emitted from the primary surface. The white light emission includes of a mixture of wavelengths characterized by at least the second wavelength from the phosphor member. The laser-based fiber-coupled white light illumination source further includes one or more fibers configured to have first ends to couple with the one or more white light source modules to capture the white light emission and transport the white light emission to respective second ends, each of the one or more fibers being configured at least partially as a leaky fiber to form an illumination source for the automobile. The leaky fiber could be a bundle of leaky fibers comprised of glass fibers or plastic fibers.

In another alternative embodiment, the present invention provides a laser-based-fiber-coupled white light illumination source for a vehicle. The fiber-coupled white light illumination source includes a laser device comprising a gallium and nitrogen containing material and configured as an excitation source. The laser device includes an output facet configured to output a laser emission with a first wavelength ranging from 385 nm to 495 nm. The fiber-coupled white light illumination source further includes a phosphor member configured as a wavelength converter and an emitter and disposed to convert the laser emission to emit an electromagnetic radiation with a second wavelength longer than the first wavelength. The electromagnetic radiation is combined with the laser emission partially to generate a white light, the phosphor member is integrated with an optical collimator to focus the white light. Furthermore, the fiber-coupled white light illumination source includes a fiber configured to couple the collimated white light and deliver the white light. The fiber also is at least partially configured as a leaky fiber to scatter the white light partially out of fiber body arranged in a custom shape at a feature location.

In yet another alternative embodiment, the present invention provides a fiber-coupled white light illumination source for vehicle lighting applications. The fiber-coupled white light illumination source includes a laser module disposed in vehicle power system. The laser module includes a gallium and nitrogen containing laser chip and a driver receiving power from the vehicle power system to drive the laser chip to output a laser emission with a first wavelength ranging from 385 nm to 495 nm. The fiber-coupled white light illumination source further includes a white light module comprising a phosphor member coupled with the laser module. The phosphor member is configured as a wavelength converter and an emitter to convert the laser emission to a phosphor radiation with a second wavelength longer than the first wavelength and to combine the phosphor radiation with the laser emission partially to generate a white light. The phosphor member is integrated with an optical collimator to focus the white light. Furthermore, the fiber-coupled white light illumination source includes a fiber configured to couple the collimated white light and deliver the white light to an exterior or interior feature location of the vehicle. The fiber includes a leaky fiber configured as an illumination element disposed at the exterior or interior feature location. The leaky fiber is configured to emit the white light partially by directional side scattering to generate effective luminous flux of greater than 25 lumens, or greater than 50 lumens, or greater than 150 lumens, or greater than 300 lumens, or greater than 600 lumens, or greater than 800 lumens, or greater than 1200 lumens in an optical efficiency of greater than 35% out of a surface of the leaky fiber. The feature location of the vehicle includes, but not limited to, front grill structure, license plate, lower and side bumper, dashboard, door handle and panel, entry sill, window frame, ceiling, moon roof, floor, and seat. The leaky fiber could be a bundle of fibers comprised of glass fibers or plastic fibers.

In still another alternative embodiment, the present invention provides a laser-based fiber-coupled white headlight for vehicle. The laser-based fiber-coupled white headlight for vehicle includes a laser module disposed in vehicle power system, the laser module comprising a gallium and nitrogen containing laser chip and a driver receiving power from the vehicle power system to drive the laser chip to output a laser emission with a first wavelength ranging from 385 nm to 495 nm. The laser-based fiber-coupled white headlight for vehicle also includes a white light module comprising a phosphor member coupled with the laser module. The phosphor member is configured as a wavelength converter and an emitter to convert the laser emission to a phosphor radiation with a second wavelength longer than the first wavelength and to combine the phosphor radiation with the laser emission partially to generate a white light. The phosphor member is integrated with an optical collimator to focus the white light. Additionally, the laser-based fiber-coupled white headlight for vehicle includes a transport fiber configured to couple the collimated white light and deliver the white light to a feature location for headlight of the vehicle. Furthermore, the laser-based fiber-coupled white headlight for vehicle includes a headlight module disposed at the feature location comprising a beam projection unit configured to receive the white light from the transport fiber and project a beam of the white light onto road with effective luminous flux of greater than 150 lumens, or greater than 300 lumens, or greater than 600 lumens, or greater than 800 lumens, or greater than 1200 lumens in an optical efficiency of greater than 35%. The feature location of the vehicle includes some area in front grill structure, some area on each wheel cover, some area between the hood and front bumper. The beam projection unit is configured to have a miniaturized size of less than 5 cm, less than 3 cm, or less than 1 cm.

In the present invention, the fiber coupled white light system is configured for a lighting application such as a specialty lighting application, a general lighting application, an infrastructure lighting application such as bridge lighting, tunnel lighting, down-hole lighting, an architectural lighting application, a safety lighting application, an appliance lighting application such as refrigerator, freezer, oven, or other appliance, a leisure or medical lighting device such as for lighting spas, jacuzzis, swimming pools, etc.

A further understanding of the nature and advantages of the present invention may be realized by reference to the latter portions of the specification and attached drawings.

### BRIEF DESCRIPTION OF THE DRAWINGS

The following drawings are merely examples for illustrative purposes according to various disclosed embodiments and are not intended to limit the scope of the present invention.

FIG. 1 is a schematic diagram showing dependence of internal quantum efficiency in a laser diode on carrier concentration in the light emitting layers of the device.

FIG. 2 is a plot of external quantum efficiency as a function of current density for a high-power blue laser diode compared to the high-power blue light emitting diode.

FIG. 3 is a simplified schematic diagram of a laser diode formed on a gallium and nitrogen containing substrate with the cavity aligned in a direction ended with cleaved or etched mirrors according to some embodiments of the present invention.

FIG. 4 is a cross-sectional view of a laser device according to an embodiment of the present invention.

FIG. 5 is a schematic diagram illustrating a chip on submount (CoS) based on a conventional laser diode formed on gallium and nitrogen containing substrate technology according to an embodiment of the present invention.

FIG. 6 is a simplified diagram illustrating a side view of die expansion with selective area bonding according to the present invention.

FIG. 7 is a schematic diagram illustrating a CoS based on lifted off and transferred epitaxial gallium and nitrogen containing layers according to an embodiment of this present invention.

FIG. 8 is a simplified diagram illustrating a laser-based white light source with a laser diode fabricated in gallium and nitrogen containing epitaxial layers transferred to a submount member and a phosphor member integrated onto the submount member wherein the phosphor member is configured for transmissive operation according to an embodiment of the present invention.

FIG. 9 is a simplified diagram illustrating the apparatus configuration of FIG. 8 but with modification of the phosphor member configured with a coating or modification to increase the useful white light output according to an embodiment of the present invention.

FIG. 10 is a simplified diagram illustrating the apparatus configuration of FIG. 8 but with modification of the laser beam configured through a collimating optic prior to incidence on the phosphor member according to an embodiment of the present invention.

FIG. 11 is a simplified diagram illustrating an integrated laser-based white light source with a laser diode and a phosphor member integrated onto a common support member wherein the phosphor member is configured for reflective operation and the laser beam has an off-normal incidence to the phosphor member according to an embodiment of the present invention.

FIG. 12 is a simplified diagram illustrating a reflective mode phosphor member integrated laser-based white light source mounted in a surface mount package according to an embodiment of the present invention.

FIG. 13 is a simplified diagram illustrating a reflective mode phosphor member integrated laser-based white light source with multiple laser diode devices mounted in a surface mount package according to an embodiment of the present invention.

FIG. 14 is a simplified diagram illustrating an integrated laser-induced white light source mounted in a surface mount-type package and sealed with a cap member according to an embodiment of the present invention.

FIG. 15 is a simplified diagram illustrating an integrated laser-induced white light source mounted in a surface mount-type package and sealed with a cap member according to another embodiment of the present invention.

FIG. 16 is a simplified diagram illustrating an integrated laser-induced white light source mounted in a surface mount package mounted onto a starboard according to an embodiment of the present invention.

FIG. 17 is a simplified diagram illustrating an integrated laser-induced white light source mounted in a flat-type package with a collimating optic according to an embodiment of the present invention.

FIG. 18 is a simplified diagram illustrating an integrated laser-induced white light source mounted in a flat-type package with a collimating optic according to an embodiment of the present invention.

FIG. 19 is a simplified diagram illustrating an integrated laser-induced white light source mounted in a flat-type package and sealed with a cap member according to an embodiment of the present invention.

FIG. 20 is a simplified diagram illustrating an integrated laser-induced white light source mounted in a can-type package with a collimating lens according to an embodiment of the present invention.

FIG. 21 is a simplified diagram illustrating an integrated laser-induced white light source mounted in a surface mount type package mounted on a heat sink with a collimating reflector according to an embodiment of the present invention.

FIG. 22 is a simplified diagram illustrating an integrated laser-induced white light source mounted in a surface mount type package mounted on a starboard with a collimating reflector according to an embodiment of the present invention.

FIG. 23 is a simplified diagram illustrating an integrated laser-induced white light source mounted in a surface mount type package mounted on a heat sink with a collimating lens according to an embodiment of the present invention.

FIG. 24 is a simplified diagram illustrating an integrated laser-induced white light source mounted in a surface mount type package mounted on a heat sink with a collimating lens and reflector member according to an embodiment of the present invention.

FIG. 25 is a simplified block diagram of a laser-based fiber-coupled white light system according to an embodiment of the present invention.

FIG. 25A is an exemplary diagram of a laser-based fiber-coupled white light system according to an embodiment of the present invention.

FIG. 26 is a simplified block diagram of a laser-based fiber-coupled white light system according to another embodiment of the present invention.

FIG. 27 is a simplified block diagram of a laser-based fiber-coupled white light system according to yet another embodiment of the present invention.

FIG. 28 is a simplified block diagram of a laser-based fiber-coupled white light system according to still another embodiment of the present invention.

FIG. 29 is a simplified diagram of A) a laser-based fiber-coupled white light system based on surface mount device (SMD) white light source and B) a laser-based fiber-coupled white light system with partially exposed SMD white light source according to an embodiment of the present invention.

FIG. 30 is a simplified diagram of a laser-based fiber-coupled white light system based on fiber-in and fiber-out configuration according to another embodiment of the present invention.

FIG. 31 is a schematic diagram of a leaky fiber used for a laser-based fiber-coupled white light system according to an embodiment of the present invention.

FIG. 32 is an exemplary image of a leaky fiber with a plurality of holes in fiber core according to an embodiment of the present invention.

FIG. 33 shows light capture rate for Lambertian emitters according to an embodiment of the present invention.

FIG. 34 is a schematic diagram of a fiber-delivered white light for automotive headlight according to an embodiment of the present invention.

FIG. 34A is a schematic diagram of an automobile with multiple laser-based fiber-delivered headlight modules with small form factor according to an embodiment of the present invention.

FIG. 34B is a schematic diagram of a laser-based fiber-delivered automotive headlight modules hidden in front grill pattern according to an embodiment of the present invention.

FIG. 35 is a schematic diagram of a laser-based white light source coupled to a leaky fiber according to an embodiment of the present invention.

FIG. 36 is a schematic diagram of a laser-based fiber-coupled white light bulb according to an embodiment of the present invention.

FIG. 37 is a schematic diagram of a laser light bulb according to another embodiment of the present invention.

FIG. 38 is a schematic diagram of a multi-filament laser light bulb according to yet another embodiment of the present invention.

FIG. 39 is a schematic diagram of a laser-based white lighting system according to an embodiment of the present invention.

FIG. 40 is a schematic diagram of a laser-based white light source coupled to more-than-one optical fibers according to an embodiment of the present invention.

FIG. 41 is a schematic diagram of a laser-based white light source coupled to more than one optical fibers according to another embodiment of the present invention.

FIG. 42 is a schematic diagram of a laser-based white light system including an optical switch device or module according to an embodiment of the present invention.

FIG. 43 is a schematic illustration of a laser-based white light system including a fast switching optical switch unit according to a specific embodiment of the present invention.

FIG. 44 is a schematic illustration of a smart lighting system according to an embodiment of the present invention.

FIG. 45 is a schematic diagram of a pendant light for a laser-based fiber delivered lighting system according to an embodiment of the present invention.

FIG. 46 is a schematic diagram of a pendant light for a laser-based fiber delivered lighting system according to another embodiment of the present invention.

FIG. 47 is a schematic diagram of passive assembly optics attachments according to some embodiments of the present invention.

FIG. 48 is a schematic diagram of a passive decorative luminaire according to an embodiment of the present invention.

FIG. 49 is a schematic diagram of some exemplary high luminance sources that are coupled to a light guide and/or a remote phosphor according to some embodiments of the present invention.

FIG. 50 shows simulation results indicating that CRI value of the light source can be adjusted by wavelength red shift of red phosphor according to some embodiments of the present invention.

FIG. 51 shows examples of luminous intensity distribution curves emitted by a directional line light source according to an embodiment of the present invention.

FIG. 52 shows a directional line source configured with a light-emitting fiber with A) light extraction features producing a radially non-symmetric pattern, B) light extraction features producing a symmetric pattern, and equipped with a reflector element, and C) light extraction features producing a symmetric pattern, and equipped with an alternative reflector element according to an embodiment of the present invention.

FIG. 53 shows a schematic configuration for applying laser-based white light directional line sources according to an embodiment of the present disclosure.

FIG. 54 shows a schematic configuration for applying laser-based white light directional line sources according to another embodiment of the present disclosure.

FIG. 55 shows a schematic configuration for applying laser-based white light directional line sources according to yet another embodiment of the present disclosure.

FIG. 56 shows a schematic configuration for applying laser-based white light directional line sources according to still another embodiment of the present disclosure.

FIG. 57 shows a schematic diagram of inputting laser-based white light into window curtain material according to an embodiment of the present disclosure.

FIG. 58 shows a schematic diagram of a window curtain made by luminous material receiving laser-based white light according to an embodiment of the present disclosure.

FIG. 59A is a schematic illustration of an application of fiber delivered laser-based white light for refrigerator according to an embodiment of the present disclosure.

FIG. 59B is a schematic illustration of an application of fiber delivered laser-based white light for refrigerator according to another embodiment of the present disclosure.

FIG. 59C is a schematic illustration of an application of fiber delivered laser-based white light for refrigerator according to yet another embodiment of the present disclosure.

FIG. 60A is a schematic illustration of an application of fiber delivered laser-based white light for swimming pool according to an embodiment of the present disclosure.

FIG. 60B is a schematic illustration of an application of fiber delivered laser-based white light for swimming pool according to another embodiment of the present disclosure.

FIG. 61 is a schematic illustration of an application of fiber delivered laser-based white light for jacuzzi according to an embodiment of the present disclosure.

### DETAILED DESCRIPTION

The present invention provides a method and device for emitting white colored electromagnetic radiation using a combination of laser diode excitation sources based on gallium and nitrogen containing materials and light emitting source based on phosphor materials. In this invention a violet, blue, or other wavelength laser diode source based on gallium and nitrogen materials is closely integrated with phosphor materials to form a compact, high-brightness, and highly-efficient, white light source.

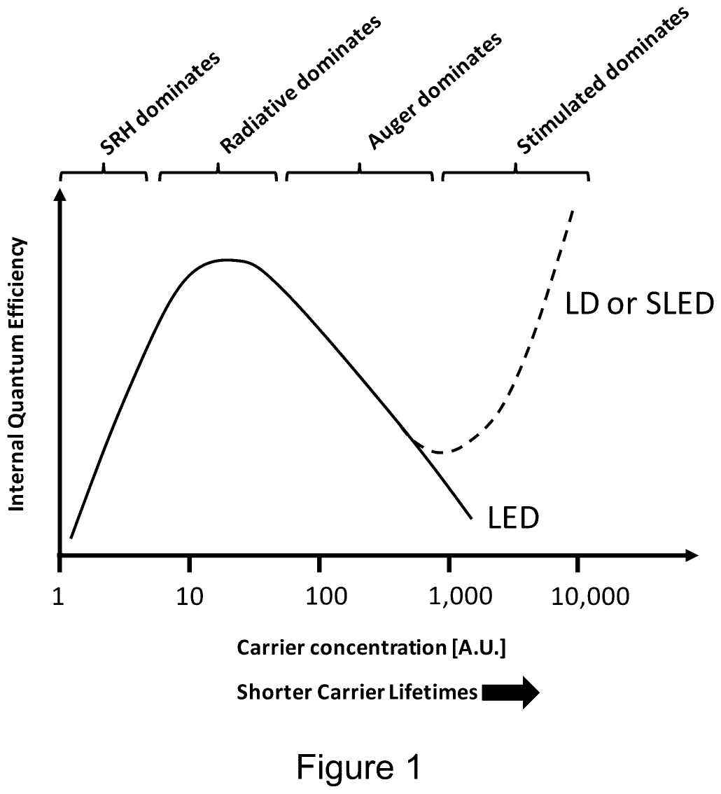

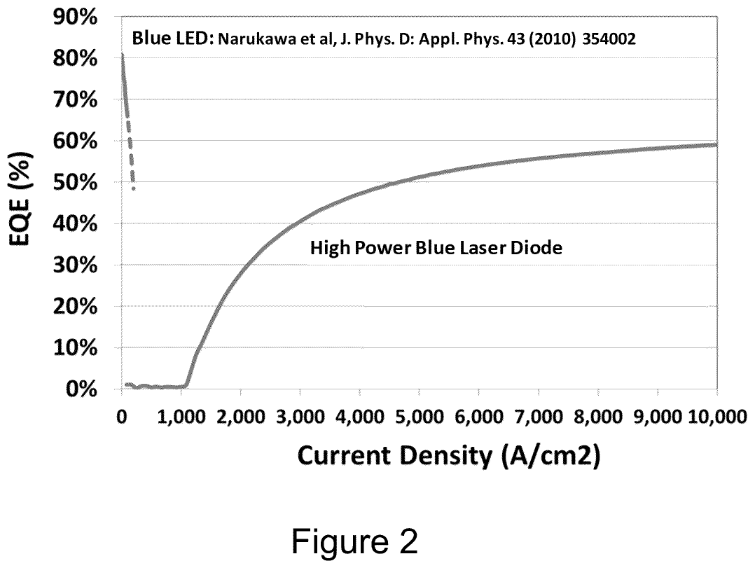

As background, while LED-based light sources offer great advantages over incandescent based sources, there are still challenges and limitations associated with LED device physics. The first limitation is the so called “droop” phenomenon that plagues GaN based LEDs. The droop effect leads to power rollover with increased current density, which forces LEDs to hit peak external quantum efficiency at very low current densities in the 10-200 A/cm² range. FIG. 1 shows a schematic diagram of the relationship between internal quantum efficiency [IQE] and carrier concentration in the light emitting layers of a light emitting diode [LED] and light-emitting devices where stimulated emission is significant such as laser diodes [LDs] or super-luminescent LEDs. IQE is defined as the ratio of the radiative recombination rate to the total recombination rate in the device. At low carrier concentrations Shockley-Reed-Hall recombination at crystal defects dominates recombination rates such that IQE is low. At moderate carrier concentrations, spontaneous radiative recombination dominates such that IQE is relatively high. At high carrier concentrations, non-radiative auger recombination dominates such that IQE is again relatively low. In devices such as LDs or SLEDs, stimulated emission at very high carrier densities leads to a fourth regime where IQE is relatively high. FIG. 2 shows a plot of the external quantum efficiency [EQE] for a typical blue LED and for a high-power blue laser diode. EQE is defined as the product of the IQE and the fraction of generated photons that is able to exit the device. While the blue LED achieves a very high EQE at very low current densities, it exhibits very low EQE at high current densities due to the dominance of auger recombination at high current densities. The LD, however, is dominated by stimulated emission at high current densities, and exhibits very high EQE. At low current densities, the LD has relatively poor EQE due to re-absorption of photons in the device. Thus, to maximize efficiency of the LED based light source, the current density must be limited to low values where the light output is also limited. The result is low output power per unit area of LED die [flux], which forces the use large LED die areas to meet the brightness requirements for most applications. For example, a typical LED based light bulb will require 3 mm² to 30 mm² of epi area.

A second limitation of LEDs is also related to their brightness, more specifically it is related to their spatial brightness. A conventional high brightness LED emits ˜1 W per mm² of epi area. With some advances and breakthrough this can be increased up to 5-10× to 5-10 W per mm² of epi area. Finally, LEDs fabricated on conventional c-plane GaN suffer from strong internal polarization fields, which spatially separate the electron and hole wave functions and lead to poor radiative recombination efficiency. Since this phenomenon becomes more pronounced in InGaN layers with increased indium content for increased wavelength emission, extending the performance of UV or blue GaN-based LEDs to the blue-green or green regime has been difficult.

An exciting new class of solid-state lighting based on laser diodes is rapidly emerging. Like an LED, a laser diode is a two-lead semiconductor light source that that emits electromagnetic radiation. However, unlike the output from an LED that is primarily spontaneous emission, the output of a laser diode is comprised primarily of stimulated emission. The laser diode contains a gain medium that functions to provide emission through the recombination of electron-hole pairs and a cavity region that functions as a resonator for the emission from the gain medium. When a suitable voltage is applied to the leads to sufficiently pump the gain medium, the cavity losses are overcome by the gain and the laser diode reaches the so-called threshold condition, wherein a steep increase in the light output versus current input characteristic is observed. At the threshold condition, the carrier density clamps and stimulated emission dominates the emission. Since the droop phenomenon that plagues LEDs is dependent on carrier density, the clamped carrier density within laser diodes provides a solution to the droop challenge. Further, laser diodes emit highly directional and coherent light with orders of magnitude higher spatial brightness than LEDs. For example, a commercially available edge emitting GaN-based laser diode can reliably produce about 2 W of power in an aperture that is 15 μm wide by about 0.5 μm tall, which equates to over 250,000 W/mm². This spatial brightness is over 5 orders of magnitude higher than LEDs or put another way, 10,000 times brighter than an LED.

Based on essentially all the pioneering work on GaN LEDs, visible laser diodes based on GaN technology have rapidly emerged over the past 20 years. Currently the only viable direct blue and green laser diode structures are fabricated from the wurtzite AlGalnN material system. The manufacturing of light emitting diodes from GaN related materials is dominated by the heteroepitaxial growth of GaN on foreign substrates such as Si, SiC and sapphire. Laser diode devices operate at such high current densities that the crystalline defects associated with heteroepitaxial growth are not acceptable. Because of this, very low defect-density, free-standing GaN substrates have become the substrate of choice for GaN laser diode manufacturing. Unfortunately, such bulk GaN substrates are costly and not widely available in large diameters. For example, 2″ diameter is the most common laser-quality bulk GaN c-plane substrate size today with recent progress enabling 4″ diameter, which are still relatively small compared to the 6″ and greater diameters that are commercially available for mature substrate technologies. Further details of the present invention can be found throughout the present specification and more particularly below.

Additional benefits are achieved over pre-existing techniques using the present invention. In particular, the present invention enables a cost-effective laser-based remotely delivered white light source. In a specific embodiment, the present optical device can be manufactured in a relatively simple and cost-effective manner. Depending upon the embodiment, the present apparatus and method can be manufactured using conventional materials and/or methods according to one of ordinary skill in the art. In some embodiments of this invention the gallium and nitrogen containing laser diode source is based on c-plane gallium nitride material and in other embodiments the laser diode is based on nonpolar or semipolar gallium and nitride material. In one embodiment the white source is configured from a laser chip on submount (CoS) with the laser light being delivered by a waveguide to a phosphor supported on a remotely disposed submount and/or a remote support member to form a remotely-delivered white light source. In some embodiments, the waveguide is a semiconductor waveguide integrated on an intermediate submount coupled with the CoS. In some embodiments the waveguide includes an optical fiber disposed substantially free in space or in custom layout, making the white light source a fiber-delivered white light source. In some embodiments the white light source includes beam collimation and focus elements to couple the laser light into the waveguide or fiber. In some embodiments, the white light source includes multiple laser chips either independently or co-packaged in a same package case and the phosphor member are supported in a separate submount heatsink packaged in a remote case. In some embodiments there could be additional beam shaping optical elements included for shaping or controlling the white light out of the phosphor.

In various embodiments, the laser device and phosphor device are separately packaged or mounted on respective support member and the phosphor materials are operated in a reflective mode to result in a white emitting laser-based light source. In additional various embodiments, the electromagnetic radiation from the laser device is remotely coupled to the phosphor device through means such as free space coupling or coupling with a waveguide such as a fiber optic cable or other solid waveguide material, and wherein the phosphor materials are operated in a reflective mode to result in a white emitting laser-based light source. Merely by way of example, the invention can be applied to applications such as white lighting, white spot lighting, flash lights, automobile headlights, all-terrain vehicle lighting, flash sources such as camera flashes, light sources used in recreational sports such as biking, surfing, running, racing, boating, light sources used for drones, planes, robots, other mobile or robotic applications, safety, counter measures in defense applications, multi-colored lighting, lighting for flat panels, medical, metrology, beam projectors and other displays, high intensity lamps, spectroscopy, entertainment, theater, music, and concerts, analysis fraud detection and/or authenticating, tools, water treatment, laser dazzlers, targeting, communications, LiFi, visible light communications (VLC), sensing, detecting, distance detecting, Light Detection And Ranging (LIDAR), transformations, autonomous vehicles, transportations, leveling, curing and other chemical treatments, heating, cutting and/or ablating, pumping other optical devices, other optoelectronic devices and related applications, and source lighting and the like.

Laser diodes are ideal as phosphor excitation sources. With a spatial brightness (optical intensity per unit area) greater than 10,000 times higher than conventional LEDs and the extreme directionality of the laser emission, laser diodes enable characteristics unachievable by LEDs and other light sources. Specifically, since the laser diodes output beams carrying over 1 W, over 5 W, over 10 W, or even over 100 W can be focused to very small spot sizes of less than 1 mm in diameter, less than 500 μm in diameter, less than 100 μm in diameter, or even less than 50 μm in diameter, power densities of over 1 W/mm², 100 W/mm², or even over 2,500 W/mm² can be achieved. When this very small and powerful beam of laser excitation light is incident on a phosphor material the ultimate point source of white light can be achieved. Assuming a phosphor conversion ratio of 200 lumens of emitted white light per optical watt of excitation light, a 5 W excitation power could generate 1000 lumens in a beam diameter of 100 μm, or 50 μm, or less. Such a point source is game changing in applications such as spotlighting or range finding where parabolic reflectors or lensing optics can be combined with the point source to create highly collimated white light spots that can travel drastically higher distances than ever possible before using LEDs or bulb technology.

In some embodiments of the present invention the gallium and nitrogen containing light emitting device may not be a laser device, but instead may be configured as a superluminescent diode or superluminescent light emitting diode (SLED) device. For the purposes of this invention, a SLED device and laser diode device can be used interchangeably. A SLED is similar to a laser diode as it is based on an electrically driven junction that when injected with current becomes optically active and generates amplified spontaneous emission (ASE) and gain over a wide range of wavelengths. When the optical output becomes dominated by ASE there is a knee in the light output versus current (LI) characteristic wherein the unit of light output becomes drastically larger per unit of injected current. This knee in the LI curve resembles the threshold of a laser diode, but is much softer. The advantage of a SLED device is that SLED it can combine the unique properties of high optical emission power and extremely high spatial brightness of laser diodes that make them ideal for highly efficient long throw illumination and high brightness phosphor excitation applications with a broad spectral width of (>5 nm) that provides for an improved eye safety and image quality in some cases. The broad spectral width results in a low coherence length similar to an LED. The low coherence length provides for an improved safety such has improved eye safety. Moreover, the broad spectral width can drastically reduce optical distortions in display or illumination applications. As an example, the well-known distortion pattern referred to as “speckle” is the result of an intensity pattern produced by the mutual interference of a set of wavefronts on a surface or in a viewing plane. The general equations typically used to quantify the degree of speckle are inversely proportional to the spectral width. In the present specification, both a laser diode (LD) device and a superluminescent light emitting diode (SLED) device are sometime simply referred to “laser device”.

A gallium and nitrogen containing laser diode (LD) or super luminescent light emitting diode (SLED) may comprise at least a gallium and nitrogen containing device having an active region and a cavity member and are characterized by emitted spectra generated by the stimulated emission of photons. In some embodiments a laser device emitting red laser light, i.e. light with wavelength between about 600 nm to 750 nm, are provided. These red laser diodes may comprise at least a gallium phosphorus and arsenic containing device having an active region and a cavity member and are characterized by emitted spectra generated by the stimulated emission of photons. The ideal wavelength for a red device for display applications is ˜635 nm, for green ˜530 nm and for blue 440-470 nm. There may be tradeoffs between what colors are rendered with a display using different wavelength lasers and also how bright the display is as the eye is more sensitive to some wavelengths than to others.

In some embodiments according to the present invention, multiple laser diode sources are configured to excite the same phosphor or phosphor network. Combining multiple laser sources can offer many potential benefits according to this invention. First, the excitation power can be increased by beam combining to provide a more powerful excitation spit and hence produce a brighter light source. In some embodiments, separate individual laser chips are configured within the laser-phosphor light source. By including multiple lasers emitting 1 W, 2 W, 3 W, 4 W, 5 W or more power each, the excitation power can be increased and hence the source brightness would be increased. For example, by including two 3 W lasers exciting the same phosphor area, the excitation power can be increased to 6 W for double the white light brightness. In an example where about 200 lumens of white are generated per 1 watt of laser excitation power, the white light output would be increased from 600 lumens to 1200 lumens. Beyond scaling the power of each single laser diode emitter, the total luminous flux of the white light source can be increased by continuing to increase the total number of laser diodes, which can range from 10s, to 100s, and even to 1000s of laser diode emitters resulting in 10s to 100s of kW of laser diode excitation power. Scaling the number of laser diode emitters can be accomplished in many ways such as including multiple lasers in a co-package, spatial beam combining through conventional refractive optics or polarization combining, and others. Moreover, laser diode bars or arrays, and mini-bars can be utilized where each laser chip includes many adjacent laser diode emitters. For example, a bar could include from 2 to 100 laser diode emitters spaced from about 10 microns to about 400 microns apart. Similarly, the reliability of the source can be increased by using multiple sources at lower drive conditions to achieve the same excitation power as a single source driven at more harsh conditions such as higher current and voltage.

In a specific area of light source application is automobile headlamp. Semiconductor based light emitting diode (LED) headlight sources were fielded in 2004, the first solid-state sources. These featured high efficiency, reliability, and compactness, but the limited light output per device and brightness caused the optics and heat sinks to be still are quite large, and the elevated temperature requirements in auto applications were challenging. Color uniformity from the blue LED excited yellow phosphor needed managed with special reflector design. Single LED failure meant the entire headlamp needed to be scrapped, resulting in challenging costs for maintenance, repair, and warranty. Moreover, the LED components are based on spontaneous emission, and therefore are not conducive to high-speed modulation required for advanced applications such as 3D sensing (LiDAR), or optical communication (LiFi). The low luminance also creates challenges for spatially dynamic automotive lighting systems that utilize spatial modulators such as MEMS or liquid crystal devices. Semiconductor laser diode (LD) based headlights started production in 2014 based on laser pumped phosphor architectures, since direct emitting lasers such as R-G-B lasers are not safe to deploy onto the road and since R-G-B sources leave gaps in the spectrum that would leave common roadside targets such as yellow or orange with insufficient reflection back to the eye. Laser pumped phosphor are solid state light sources and therefore featured the same benefits of LEDs, but with higher brightness and range from more compact headlamp reflectors. Initially, these sources exhibited high costs, reduced reliability compared to LEDs, due to being newer technology. In some cases, the laser and phosphor were combined in a single unit, and in other cases, the blue laser light was delivered by fiber to a remotely disposed phosphor module to produce white light emission. Special precautions were needed to ensure safe white light emission occurred with passive and active safety measures. Color uniformity from the blue laser excited yellow phosphor needed managed with special reflector design.

In some embodiments, the invention described herein can be applied to a fiber delivered headlight comprised of one or more gallium and nitrogen containing visible laser diode for emitting laser light that is efficiently coupled into a waveguide (such as an optical fiber) to deliver the laser emission to a remote phosphor member configured on the other end of the optical fiber. The laser emission serves to excite the phosphor member and generate a high brightness white light. In a headlight application, the phosphor member and white light generation occurs in a final headlight module, from where the light is collimated and shaped onto the road to achieve the desired light pattern.

This disclosure utilizes fiber delivery of visible laser light from a gallium and nitrogen containing laser diode to a remote phosphor member to generate a white light emission with high luminance, and has several key benefits over other approaches. One advantage lies in production of controllable light output or amount of light for low beam or high beam using modular design in a miniature headlight module footprint. Another advantage is to provide high luminance and long range of visibility. For example, based on recent driving speeds and safe stopping distances, a range of 800 meters to 1 km is possible from 200 lumens on the road using a size <35 mm optic structure with light sources that are 1000 cd per mm². Using higher luminance light sources allows one to achieve longer-range visibility for the same optics size. Further advantage of the fiber-delivered white-light headlight is able to provide high contrast. It is important to minimize glare and maximize safety and visibility for drivers and others including oncoming traffic, pedestrians, animals, and drivers headed in the same direction traffic ahead. High luminance is required to produce sharp light gradients and the specific regulated light patterns for automotive lighting. Moreover, using a waveguide such as an optical fiber, extremely sharp light gradients and ultra-safe glare reduction can be generated by reshaping and projecting the decisive light cutoff that exists from core to cladding in the light emission profile.

Another advantage of the present invention is to provide rich spectrum white color light. Laser pumped phosphors are broadband solid-state light sources and therefore featured the same benefits of LEDs, but with higher luminance. Direct emitting lasers such as R-G-B lasers are not safe to deploy onto the road since R-G-B sources leave gaps in the spectrum that would leave common roadside targets such as yellow or orange with insufficient reflection back to the eye. Also, because of the remote nature of the light sources, the headlight module can be mounted onto a pre-existing heat sink with adequate thermal mass that is located anywhere in the vehicle, eliminating the need for heat sink in the headlight.

One big advantage is small form factor of the light source and a low-cost solution for swiveling the light for glare mitigation and enhancing aerodynamic performance. For example, miniature optics <1 cm in diameter in a headlight module can be utilized to capture nearly 100% of the light from the fiber. The white light can be collimated and shaped with tiny diffusers or simple optical elements to produce the desired beam pattern on the road, it is desired to have extremely small optics sizes for styling of the vehicle. Using higher luminance light sources allows one to achieve smaller optics sizes for the same range of visibility. This headlight design allows one to integrate the headlight module into the grill, onto wheel cover, into seams between the hood and front bumper, etc. This headlight design features a headlight module that is extremely low mass and lightweight, and therefore minimized weight in the front of the car, contributing to safety, fuel economy, and speed/acceleration performance. For electric vehicles, this translates to increased vehicle range. Moreover, the decoupled fiber delivered architecture use pre-existing heat sink thermal mass already in vehicle, further minimizing the weight in the car. Furthermore, this headlight module is based on solid-state light source, and has long lifetime >10,000 hours. Redundancy and interchangeability are straightforward by simply replacing the fiber-delivered laser light source.

Because of the fiber configuration in the design of the fiber-delivered laser-induced white light headlight module, reliability is maximized by positioning the laser-induced light source away from the hot area near engine and other heat producing components. This allows the headlight module to operate at extremely high temperatures >100° C., while the laser module can operate in a cool spot with ample heat sinking. In a specific embodiment, the present invention utilizes thermally stable, military standard style, telcordia type packaging technology. The only elements exposed to the front of the car are the complexly passive headlight module, comprised tiny macro-optical elements. There is no laser directly deployed in the headlight module, only incoherent white light and a reflective phosphor architecture inside. Direct emitting lasers such as R-G-B lasers are not safe to deploy onto the road at high power and are not used in this design. It is safe and cost efficient to assemble this fiber-delivered white light source into the car while manufacturing the vehicle.

In LED-based headlights, if one high power LED element dies, the entire headlamp is typically scrapped. The fiber-delivered headlight design enables “plug and play” replacement of the light source, eliminating wasted action of completely scrapping headlights due to a failed component. The plug and play can occur without alignment, like replacing a battery, minimize warranty costs. This eliminates excessive replacement cost, customer wait times, dangerous driving conditions, and expensive loaner vehicles. Because of the case of generating new light patterns, and the modular approach to lumen scaling, this fiber-delivered light source allows for changing lumens and beam pattern for any region without retooling for an entirely new headlamp. This convenient capability to change beam pattern can be achieved by changing tiny optics and or diffusers instead of retooling for new large reflectors. Moreover, the fiber-delivered white light source can be used in interior lights and daytime running lights (DRL), with transport or side emitting plastic optical fiber (POF).

Spatially dynamic beam shaping devices such as digital-light processing (DLP), liquid-crystal display (LCD), 1 or 2 MEMS or Galvo mirror systems, lightweight swivels, scanning fiber tips. Future spatially dynamic sources may require even brighter light, such as 5000-10000 lumens from the source, to produce high definition spatial light modulation on the road using MEMS or liquid crystal components. Such dynamic lighting systems are incredibly bulky and expensive when co-locating the light source, electronics, heat sink, optics, and light modulators, and secondary optics. Therefore, they require-fiber delivered high luminance white light to enable spatial light modulation in a compact and more cost-effective manner.

A additional advantage of combining the emission from multiple laser diode emitters is the potential for a more circular spot by rotating the first free space diverging elliptical laser beam by 90 degrees relative to the second free space diverging elliptical laser beam and overlapping the centered ellipses on the phosphor. Alternatively, a more circular spot can be achieved by rotating the first free space diverging elliptical laser beam by 180 degrees relative to the second free space diverging elliptical laser beam and off-centered overlapping the ellipses on the phosphor to increase spot diameter in slow axis diverging direction. In another configuration, more than 2 lasers are included and some combination of the above described beam shaping spot geometry shaping is achieved. A third and important advantage is that multiple color lasers in an emitting device can significantly improve color quality (CRI and CQS) by improving the fill of the spectra in the violet/blue and cyan region of the visible spectrum. For example, two or more blue excitation lasers with slightly detuned wavelengths (e.g. 5 nm, 10 nm, 15 nm, etc.) can be included to excite a yellow phosphor and create a larger blue spectrum.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k 1) plane wherein h=k=0, and 1 is non-zero), non-polar GaN substrates (i.e., substrate material where the largest area surface is oriented at an angle ranging from about 80-100 degrees from the polar orientation described above towards an (h k 1) plane wherein 1=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k 1) plane wherein 1=0, and at least one of h and k is non-zero). Of course, there can be other variations, modifications, and alternatives.

The laser diode device can be fabricated on a conventional orientation of a gallium and nitrogen containing film or substrate (e.g., GaN) such as the polar c-plane, on a nonpolar orientation such as the m-plane, or on a semipolar orientation such as the {30-31}, {20-21}, {30-32}, {11-22}, {10-11}, {30-3-1}, {20-2-1}, {30-3-2}, or offcuts of any of these polar, nonpolar, and semipolar planes within +/−10 degrees towards a c-plane, and/or +/−10 degrees towards an a-plane, and/or +/−10 degrees towards an m-plane. In some embodiments, a gallium and nitrogen containing laser diode laser diode comprises a gallium and nitrogen containing substrate. The substrate member may have a surface region on the polar {0001} plane (c-plane), nonpolar plane (m-plane, a-plane), and semipolar plain ({11-22}, {10-1-1}, {20-21}, {30-31}) or other planes of a gallium and nitrogen containing substrate. The laser device can be configured to emit a laser beam characterized by one or more wavelengths from about 390 nm to about 540 nm.

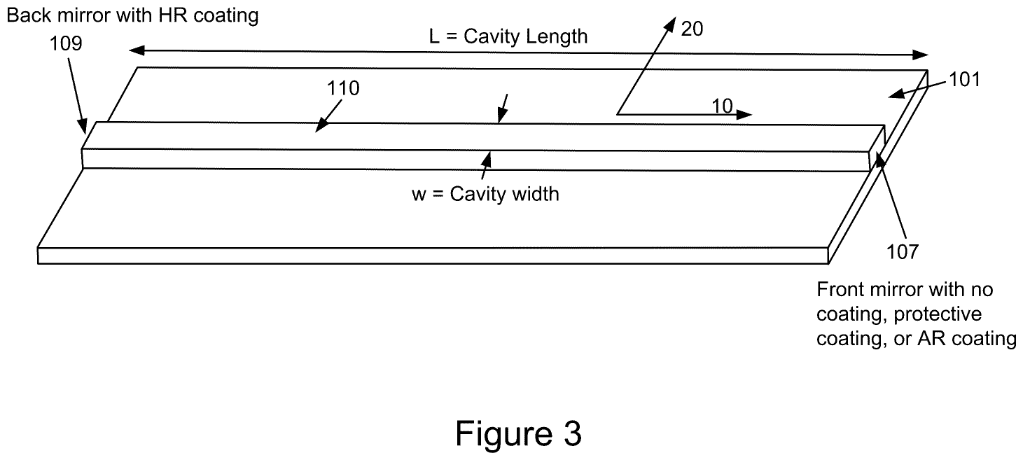

FIG. 3 is a simplified schematic diagram of a laser diode formed on a gallium and nitrogen containing substrate with the cavity aligned in a direction ended with cleaved or etched mirrors according to some embodiments of the present invention. In an example, the substrate surface 101 is a polar c-plane and the laser stripe region 110 is characterized by a cavity orientation substantially in an m-direction 10, which is substantially normal to an a-direction 20, but can be others such as cavity alignment substantially in the a-direction. The laser strip region 110 has a first end 107 and a second end 109 and is formed on an m-direction on a {0001} gallium and nitrogen containing substrate having a pair of cleaved or etched mirror structures, which face each other. In another example, the substrate surface 101 is a semipolar plane and the laser stripe region 110 is characterized by a cavity orientation substantially in a projection of a c-direction 10, which is substantially normal to an a-direction 20, but can be others such as cavity alignment substantially in the a-direction. The laser strip region 110 has a first end 107 and a second end 109 and is formed on a semipolar substrate such as a {40-41}, {30-31}, {20-21}, {40-4-1}, {30-3-1}, {20-2-1}, {20-21}, or an offcut of these planes within +/−5 degrees from the c-plane and a-plane gallium and nitrogen containing substrate. Optionally, the gallium nitride substrate member is a bulk GaN substrate characterized by having a nonpolar or semipolar crystalline surface region, but can be others. The bulk GaN substrate may have a surface dislocation density below 10⁵ cm⁻² or 10⁵ to 10⁷ cm⁻². The nitride crystal or wafer may comprise AlₓIn_{y}Ga_{1-x-y}N, where 0≤x, y, x+y≤1. In one specific embodiment, the nitride crystal comprises GaN. In some embodiments, the GaN substrate has threading dislocations, at a concentration between about 10⁵ cm⁻² and about 10⁸ cm⁻², in a direction that is substantially orthogonal or oblique with respect to the surface.

The exemplary laser diode devices in FIG. 3 have a pair of cleaved or etched mirror structures 109 and 107, which face each other. The first cleaved or etched facet 109 comprises a reflective coating and the second cleaved or etched facet 107 comprises no coating, an antireflective coating, or exposes gallium and nitrogen containing material. The first cleaved or etched facet 109 is substantially parallel with the second cleaved or etched facet 107. The first and second cleaved facets 109 and 107 are provided by a scribing and breaking process according to an embodiment or alternatively by etching techniques using etching technologies such as reactive ion etching (RIE), inductively coupled plasma etching (ICP), or chemical assisted ion beam etching (CAIBE), or other method. The reflective coating is selected from silicon dioxide, hafnia, and titania, tantalum pentoxide, zirconia, aluminum oxide, aluminum nitride, and aluminum oxynitride including combinations, and the like. Depending upon the design, the mirror surfaces can also comprise an anti-reflective coating.

In a specific embodiment, the method of facet formation includes subjecting the substrates to a laser for pattern formation. In a preferred embodiment, the pattern is configured for the formation of a pair of facets for a ridge laser. In a preferred embodiment, the pair of facets face each other and are in parallel alignment with each other. In a preferred embodiment, the method uses a UV (355 nm) laser to scribe the laser bars. In a specific embodiment, the laser is configured on a system, which allows for accurate scribe lines configured in a different patterns and profiles. In some embodiments, the laser scribing can be performed on the back-side, front-side, or both depending upon the application. Of course, there can be other variations, modifications, and alternatives.

In a specific embodiment, the method uses backside laser scribing or the like. With backside laser scribing, the method preferably forms a continuous line laser scribe that is perpendicular to the laser bars on the backside of the GaN substrate. In a specific embodiment, the laser scribe is generally about 15-20 μm deep or other suitable depth. Preferably, backside scribing can be advantageous. That is, the laser scribe process does not depend on the pitch of the laser bars or other like pattern. Accordingly, backside laser scribing can lead to a higher density of laser bars on each substrate according to a preferred embodiment. In a specific embodiment, backside laser scribing, however, may lead to residue from the tape on the facets. In a specific embodiment, backside laser scribe often requires that the substrates face down on the tape. With front-side laser scribing, the backside of the substrate is in contact with the tape. Of course, there can be other variations, modifications, and alternatives.

It is well known that etch techniques such as chemical assisted ion beam etching (CAIBE), inductively coupled plasma (ICP) etching, or reactive ion etching (RIE) can result in smooth and vertical etched sidewall regions, which could serve as facets in etched facet laser diodes. In the etched facet process a masking layer is deposited and patterned on the surface of the wafer. The etch mask layer could be comprised of dielectrics such as silicon dioxide (SiO₂), silicon nitride (SiₓN_{y}), a combination thereof or other dielectric materials. Further, the mask layer could be comprised of metal layers such as Ni or Cr, but could be comprised of metal combination stacks or stacks comprising metal and dielectrics. In another approach, photoresist masks can be used either alone or in combination with dielectrics and/or metals. The etch mask layer is patterned using conventional photolithography and etch steps. The alignment lithography could be performed with a contact aligner or stepper aligner. Such lithographically defined mirrors provide a high level of control to the design engineer. After patterning of the photoresist mask on top of the etch mask is complete, the patterns in then transferred to the etch mask using a wet etch or dry etch technique. Finally, the facet pattern is then etched into the wafer using a dry etching technique selected from CAIBE, ICP, RIE and/or other techniques. The etched facet surfaces must be highly vertical of between about 87 and about 93 degrees or between about 89 and about 91 degrees from the surface plane of the wafer. The etched facet surface region must be very smooth with root mean square roughness values of less than about 50 nm, 20 nm, 5 nm, or 1 nm. Lastly, the etched must be substantially free from damage, which could act as non-radiative recombination centers and hence reduce the catastrophic optical mirror damage (COMD) threshold. CAIBE is known to provide very smooth and low damage sidewalls due to the chemical nature of the etch, while it can provide highly vertical etches due to the ability to tilt the wafer stage to compensate for any inherent angle in etch.

The laser stripe 110 is characterized by a length and width. The length ranges from about 50 μm to about 3000 μm, but is preferably between about 10 μm and about 400 μm, between about 400 μm and about 800 μm, or about 800 μm and about 1600 μm, but could be others. The stripe also has a width ranging from about 0.5 μm to about 50 μm, but is preferably between about 0.8 μm and about 2.5 μm for single lateral mode operation or between about 2.5 μm and about 50 μm for multi-lateral mode operation, but can be other dimensions. In a specific embodiment, the present device has a width ranging from about 0.5 μm to about 1.5 μm, a width ranging from about 1.5 μm to about 3.0 μm, a width ranging from about 3.0 μm to about 50 μm, and others. In a specific embodiment, the width is substantially constant in dimension, although there may be slight variations. The width and length are often formed using a masking and etching process, which are commonly used in the art.

The laser stripe region 110 is provided by an etching process selected from dry etching or wet etching. The device also has an overlying dielectric region, which exposes a p-type contact region. Overlying the contact region is a contact material, which may be metal or a conductive oxide or a combination thereof. The p-type electrical contact may be deposited by thermal evaporation, electron beam evaporation, electroplating, sputtering, or another suitable technique. Overlying the polished region of the substrate is a second contact material, which may be metal or a conductive oxide or a combination thereof and which comprises the n-type electrical contact. The n-type electrical contact may be deposited by thermal evaporation, electron beam evaporation, electroplating, sputtering, or another suitable technique.

In a specific embodiment, the laser device may emit red light with a center wavelength between 600 nm and 750 nm. Such a device may comprise layers of varying compositions of AlₓIn_{y}Ga_{1-x-y}As_{z}P_{1-z}, where x+y≤1 and z≤1. The red laser device comprises at least an n-type and p-type cladding layer, an n-type SCH of higher refractive index than the n-type cladding, a p-type SCH of higher refractive index than the p-type cladding and an active region where light is emitted. In a specific embodiment, the laser stripe is provided by an etching process selected from dry etching or wet etching. In a preferred embodiment, the etching process is dry, but can be others. The device also has an overlying dielectric region, which exposes the contact region. In a specific embodiment, the dielectric region is an oxide such as silicon dioxide, but can be others. Of course, there can be other variations, modifications, and alternatives. The laser stripe is characterized by a length and width. The length ranges from about 50 μm to about 3000 μm, but is preferably between 10 μm and 400 μm, between about 400 μm and 800 μm, or about 800 μm and 1600 μm, but could be others such as greater than 1600 μm. The stripe also has a width ranging from about 0.5 μm to about 80 μm, but is preferably between 0.8 μm and 2.5 μm for single lateral mode operation or between 2.5 μm and 60 μm for multi-lateral mode operation, but can be other dimensions. The laser strip region has a first end and a second end having a pair of cleaved or etched mirror structures, which face each other. The first facet comprises a reflective coating and the second facet comprises no coating, an antireflective coating, or exposes gallium and nitrogen containing material. The first facet is substantially parallel with the second cleaved or etched facet.

Given the high gallium and nitrogen containing substrate costs, difficulty in scaling up gallium and nitrogen containing substrate size, the inefficiencies inherent in the processing of small wafers, and potential supply limitations it becomes extremely desirable to maximize utilization of available gallium and nitrogen containing substrate and overlying epitaxial material. In the fabrication of lateral cavity laser diodes, it is typically the case that minimum die size is determined by device components such as the wire bonding pads or mechanical handling considerations, rather than by laser cavity widths. Minimizing die size is critical to reducing manufacturing costs as smaller die sizes allow a greater number of devices to be fabricated on a single wafer in a single processing run. The current invention is a method of maximizing the number of devices which can be fabricated from a given gallium and nitrogen containing substrate and overlying epitaxial material by spreading out the epitaxial material onto a carrier wafer via a die expansion process.

Similar to an edge emitting laser diode, a SLED is typically configured as an edge-emitting device wherein the high brightness, highly directional optical emission exits a waveguide directed outward from the side of the semiconductor chip. SLEDs are designed to have high single pass gain or amplification for the spontaneous emission generated along the waveguide. However, unlike laser diodes, they are designed to provide insufficient feedback to in the cavity to achieve the lasing condition where the gain equals the total losses in the waveguide cavity. In a typical example, at least one of the waveguide ends or facets is designed to provide very low reflectivity back into the waveguide. Several methods can be used to achieve reduced reflectivity on the waveguide end or facet. In one approach an optical coating is applied to at least one of the facets, wherein the optical coating is designed for low reflectivity such as less than 1%, less than 0.1%, less than 0.001%, or less than 0.0001% reflectivity. In another approach for reduced reflectivity the waveguide ends are designed to be tilted or angled with respect to the direction of light propagation such that the light that is reflected back into the chip does not constructively interfere with the light in the cavity to provide feedback. The tilt angle must be carefully designed around a null in the reflectivity versus angle relationship for optimum performance. The tilted or angled facet approach can be achieved in a number of ways including providing an etched facet that is designed with an optimized angle lateral angle with respect to the direction of light propagation. The angle of the tilt is pre-determined by the lithographically defined etched facet patter. Alternatively, the angled output could be achieved by curving and/or angling the waveguide with respect to a cleaved facet that forms on a pre-determined crystallographic plane in the semiconductor chip. Another approach to reduce the reflectivity is to provide a roughened or patterned surface on the facet to reduce the feedback to the cavity. The roughening could be achieved using chemical etching and/or a dry etching, or with an alternative technique. Of course, there may be other methods for reduced feedback to the cavity to form a SLED device. In many embodiments a number of techniques can be used in combination to reduce the facet reflectivity including using low reflectivity coatings in combination with angled or tilted output facets with respect to the light propagation.

In a specific embodiment on a nonpolar Ga-containing substrate, the device is characterized by a spontaneously emitted light is polarized in substantially perpendicular to the c-direction. In a preferred embodiment, the spontaneously emitted light is characterized by a polarization ratio of greater than 0.1 to about 1 perpendicular to the c-direction. In a preferred embodiment, the spontaneously emitted light characterized by a wavelength ranging from about 430 nanometers to about 470 nm to yield a blue emission, or about 500 nanometers to about 540 nanometers to yield a green emission, and others. For example, the spontaneously emitted light can be violet (e.g., 395 to 420 nanometers), blue (e.g., 420 to 470 nm); green (e.g., 500 to 540 nm), or others. In a preferred embodiment, the spontaneously emitted light is highly polarized and is characterized by a polarization ratio of greater than 0.4. In another specific embodiment on a semipolar {20-21} Ga-containing substrate, the device is also characterized by a spontaneously emitted light is polarized in substantially parallel to the a-direction or perpendicular to the cavity direction, which is oriented in the projection of the c-direction.

In a specific embodiment, the present invention provides an alternative device structure capable of emitting 501 nm and greater light in a ridge laser embodiment. The device is provided with a of the following epitaxially grown elements:
an n-GaN or n-AlGaN cladding layer with a thickness from 100 nm to 3000 nm with Si doping level of 5×10¹⁷ cm⁻³ to 3×10¹⁸ cm⁻³;
an n-side SCH layer comprised of InGaN with molar fraction of indium of between 2% and 15% and thickness from 20 nm to 250 nm;
a single quantum well or a multiple quantum well active region comprised of at least two 2.0 nm to 8.5 nm InGaN quantum wells separated by 1.5 nm and greater, and optionally up to about 12 nm, GaN or InGaN barriers;
a p-side SCH layer comprised of InGaN with molar a fraction of indium of between 1% and 10% and a thickness from 15 nm to 250 nm or an upper GaN-guide layer;
an electron blocking layer comprised of AlGaN with molar fraction of aluminum of between 0% and 22% and thickness from 5 nm to 20 nm and doped with Mg;
a p-GaN or p-AlGaN cladding layer with a thickness from 400 nm to 1500 nm with Mg doping level of 2×10¹⁷ cm⁻³ to 2×10¹⁹ cm⁻³; and
a p⁺⁺—GaN contact layer with a thickness from 20 nm to 40 nm with Mg doping level of 1×10¹⁹ cm⁻³ to 1×10²¹ cm⁻³.

A gallium and nitrogen containing laser diode laser device may also include other structures, such as a surface ridge architecture, a buried heterostructure architecture, and/or a plurality of metal electrodes for selectively exciting the active region. For example, the active region may comprise first and second gallium and nitrogen containing cladding layers and an indium and gallium containing emitting layer positioned between the first and second cladding layers. A laser device may further include an n-type gallium and nitrogen containing material and an n-type cladding material overlying the n-type gallium and nitrogen containing material. In a specific embodiment, the device also has an overlying n-type gallium nitride layer, an active region, and an overlying p-type gallium nitride layer structured as a laser stripe region. Additionally, the device may also include an n-side separate confinement heterostructure (SCH), p-side guiding layer or SCH, p-AlGaN EBL, among other features. In a specific embodiment, the device also has a p⁺⁺ type gallium nitride material to form a contact region. In a specific embodiment, the p⁺⁺ type contact region has a suitable thickness and may range from about 10 nm 50 nm, or other thicknesses. In a specific embodiment, the doping level can be higher than the p-type cladding region and/or bulk region. In a specific embodiment, the p⁺⁺ type region has doping concentration ranging from about 10¹⁹ to 10²¹ Mg/am³, and others. The p⁺⁺ type region preferably causes tunneling between the semiconductor region and overlying metal contact region. In a specific embodiment, each of these regions is formed using at least an epitaxial deposition technique of metal organic chemical vapor deposition (MOCVD), molecular beam epitaxy (MBE), or other epitaxial growth techniques suitable for GaN growth. In a specific embodiment, the epitaxial layer is a high-quality epitaxial layer overlying the n-type gallium nitride layer. In some embodiments the high-quality layer is doped, for example, with Si or O to form n-type material, with a dopant concentration between about 10¹⁶ cm⁻³ and 10²⁰ cm⁻³.

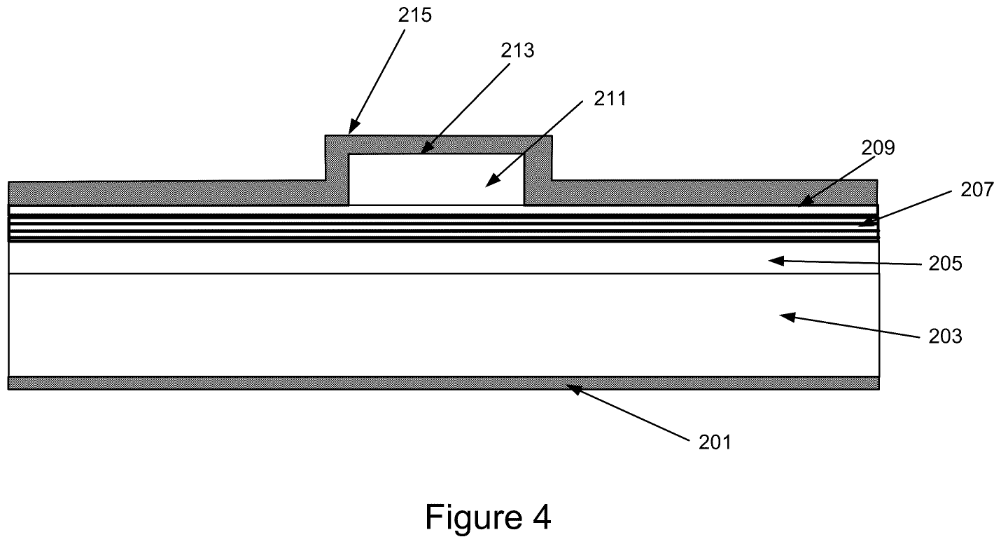

FIG. 4 is a cross-sectional view of a laser device 200 according to some embodiments of the present disclosure. As shown, the laser device includes gallium nitride substrate 203, which has an underlying n-type metal back contact region 201. For example, the substrate 203 may be characterized by a semipolar or nonpolar orientation. The device also has an overlying n-type gallium nitride layer 205, an active region 207, and an overlying p-type gallium nitride layer structured as a laser stripe region 209. Each of these regions is formed using at least an epitaxial deposition technique of metal organic chemical vapor deposition (MOCVD), molecular beam epitaxy (MBE), or other epitaxial growth techniques suitable for GaN growth. The epitaxial layer is a high-quality epitaxial layer overlying the n-type gallium nitride layer. In some embodiments the high-quality layer is doped, for example, with Si or O to form n-type material, with a dopant concentration between about 10¹⁶ cm⁻³ and 10²⁰ cm⁻³.

An n-type AlᵤInᵥGa₁₋ᵤ₋ᵥN layer, where 0≤u, v, u+v≤1, is deposited on the substrate. The carrier concentration may lie in the range between about 10¹⁶ cm⁻³ and 10²⁰ cm⁻³. The deposition may be performed using metalorganic chemical vapor deposition (MOCVD) or molecular beam epitaxy (MBE).

For example, the bulk GaN substrate is placed on a susceptor in an MOCVD reactor. After closing, evacuating, and back-filling the reactor (or using a load lock configuration) to atmospheric pressure, the susceptor is heated to a temperature between about 1000 and about 1200 degrees Celsius in the presence of a nitrogen-containing gas. The susceptor is heated to approximately 900 to 1200 degrees Celsius under flowing ammonia. A flow of a gallium-containing metalorganic precursor, such as trimethylgallium (TMG) or tricthylgallium (TEG) is initiated, in a carrier gas, at a total rate between approximately 1 and 50 standard cubic centimeters per minute (sccm). The carrier gas may comprise hydrogen, helium, nitrogen, or argon. The ratio of the flow rate of the group V precursor (ammonia) to that of the group III precursor (trimethylgallium, triethylgallium, trimethylindium, trimethylaluminum) during growth is between about 2000 and about 12000. A flow of disilane in a carrier gas, with a total flow rate of between about 0.1 sccm and 10 sccm, is initiated.

In one embodiment, the laser stripe region is p-type gallium nitride layer 209. The laser stripe is provided by a dry etching process, but wet etching can be used. The dry etching process is an inductively coupled process using chlorine bearing species or a reactive ion etching process using similar chemistries. The chlorine bearing species are commonly derived from chlorine gas or the like. The device also has an overlying dielectric region, which exposes a contact region 213. The dielectric region is an oxide such as silicon dioxide or silicon nitride, and a contact region is coupled to an overlying metal layer 215. The overlying metal layer is preferably a multilayered structure containing gold and platinum (Pt/Au), palladium and gold (Pd/Au), or nickel gold (Ni/Au), or a combination thereof. In some embodiments, barrier layers and more complex metal stacks are included.

Active region 207 preferably includes one to ten quantum-well regions or a double heterostructure region for light emission. Following deposition of the n-type AlᵤInᵥGa₁₋ᵤ₋ᵥ N layer to achieve a desired thickness, an active layer is deposited. The quantum wells are preferably InGaN with GaN, AlGaN, InAlGaN, or InGaN barrier layers separating them. In other embodiments, the well layers and barrier layers comprise Al_{w}InₓGa_{1-w-x}N and Al_{y}In_{z}Ga_{1-y-z} N, respectively, where 0≤w, x, y, z, w+x, y+z≤1, where w<u, y and/or x>v, z so that the bandgap of the well layer(s) is less than that of the barrier layer(s) and the n-type layer. The well layers and barrier layers each have a thickness between about 1 nm and about 20 nm. The composition and structure of the active layer are chosen to provide light emission at a preselected wavelength. The active layer may be left undoped (or unintentionally doped) or may be doped n-type or p-type.

The active region can also include an electron blocking region, and a separate confinement heterostructure. The electron-blocking layer may comprise AlₛInₜGa₁₋ₛ₋ₜN, where 0≤s, t, s+t≤1, with a higher bandgap than the active layer, and may be doped p-type. In one specific embodiment, the electron blocking layer includes AlGaN. In another embodiment, the electron blocking layer includes an AlGaN/GaN super-lattice structure, comprising alternating layers of AlGaN and GaN, each with a thickness between about 0.2 nm and about 5 nm.

As noted, the p-type gallium nitride or aluminum gallium nitride structure is deposited above the electron blocking layer and active layer(s). The p-type layer may be doped with Mg, to a level between about 10¹⁶ cm⁻³ and 10²² cm⁻³, with a thickness between about 5 nm and about 1000 nm. The outermost 1-50 nm of the p-type layer may be doped more heavily than the rest of the layer, so as to enable an improved electrical contact. The device also has an overlying dielectric region, for example, silicon dioxide, which exposes the contact region 213.

The metal contact is made of suitable material such as silver, gold, aluminum, nickel, platinum, rhodium, palladium, chromium, or the like. The contact may be deposited by thermal evaporation, electron beam evaporation, electroplating, sputtering, or another suitable technique. In a preferred embodiment, the electrical contact serves as a p-type electrode for the optical device. In another embodiment, the electrical contact serves as an n-type electrode for the optical device. The laser devices illustrated in FIG. 3 and FIG. 4 and described above are typically suitable for low-power applications.

In various embodiments, the present invention realizes high output power from a diode laser is by widening a portion of the laser cavity member from the single lateral mode regime of 1.0-3.0 μm to the multi-lateral mode range 5.0-20 μm. In some cases, laser diodes having cavities at a width of 50 μm or greater are employed.

The laser stripe length, or cavity length ranges from 100 to 3000 μm and employs growth and fabrication techniques such as those described in U.S. patent application Ser. No. 12/759,273, filed Apr. 13, 2010, which is incorporated by reference herein. As an example, laser diodes are fabricated on nonpolar or semipolar gallium containing substrates, where the internal electric fields are substantially eliminated or mitigated relative to polar c-plane oriented devices. It is to be appreciated that reduction in internal fields often enables more efficient radiative recombination. Further, the heavy hole mass is expected to be lighter on nonpolar and semipolar substrates, such that better gain properties from the lasers can be achieved.

Optionally, FIG. 4 illustrates an example cross-sectional diagram of a gallium and nitrogen based laser diode device. The epitaxial device structure is formed on top of the gallium and nitrogen containing substrate member 203. The substrate member may be n-type doped with O and/or Si doping. The epitaxial structures will contain n-side layers 205 such as an n-type buffer layer comprised of GaN, AlGaN, AlINGaN, or InGaN and n-type cladding layers comprised of GaN, AlGaN, or AlInGaN. The n-typed layers may have thickness in the range of 0.3 μm to about 3 μm or to about 5 μm and may be doped with an n-type carrier such as Si or O to concentrations between 1×10¹⁶ cm⁻³ to 1×10¹⁹ cm⁻³. Overlying the n-type layers is the active region and waveguide layers 207. This region could contain an n-side waveguide layer or separate confinement heterostructure (SCH) such as InGaN to help with optical guiding of the mode. The InGaN layer be comprised of 1 to 15% molar fraction of InN with a thickness ranging from about 30 nm to about 250 nm and may be doped with an n-type species such as Si. Overlying the SCH layer is the light emitting regions which could be comprised of a double heterostructure or a quantum well active region. A quantum well active region could be comprised of 1 to 10 quantum wells ranging in thickness from 1 nm to 20 nm comprised of InGaN. Barrier layers comprised of GaN, InGaN, or AlGaN separate the quantum well light emitting layers. The barriers range in thickness from 1 nm to about 25 nm. Overlying the light emitting layers are optionally an AlGaN or InAlGaN electron blocking layer with 5% to about 35% AlN and optionally doped with a p-type species such as Mg. Also optional is a p-side waveguide layer or SCH such as InGaN to help with optical guiding of the mode. The InGaN layer be comprised of 1 to 15% molar fraction of InN with a thickness ranging from 30 nm to about 250 nm and may be doped with an p-type species such as Mg. Overlying the active region and optional electron blocking layer and p-side waveguide layers is a p-cladding region and a p⁺⁺ contact layer. The p-type cladding region is comprised of GaN, AlGaN, AlINGaN, or a combination thereof. The thickness of the p-type cladding layers is in the range of 0.3 μm to about 2 μm and is doped with Mg to a concentration of between 1×10¹⁶ cm⁻³ to 1×10¹⁹ cm⁻³. A ridge 211 is formed in the p-cladding region for lateral confinement in the waveguide using an etching process selected from a dry etching or a wet etching process. A dielectric material 213 such as silicon dioxide or silicon nitride or deposited on the surface region of the device and an opening is created on top of the ridge to expose a portion of the p⁺⁺ GaN layer. A p-contact 215 is deposited on the top of the device to contact the exposed p⁺⁺ contact region. The p-type contact may be comprised of a metal stack containing a of Au, Pd, Pt, Ni, Ti, or Ag and may be deposited with electron beam deposition, sputter deposition, or thermal evaporation. A n-contact 201 is formed to the bottom of the substrate member. The n-type contact may be comprised of a metal stack containing Au, Al, Pd, Pt, Ni, Ti, or Ag and may be deposited with electron beam deposition, sputter deposition, or thermal evaporation.

In multiple embodiments according to the present invention, the device layers comprise a super-luminescent light emitting diode or SLED. In all applicable embodiments a SLED device can be interchanged with or combined with laser diode devices according to the methods and architectures described in this invention. A SLED is in many ways similar to an edge emitting laser diode; however, the emitting facet of the device is designed so as to have a very low reflectivity. A SLED is similar to a laser diode as it is based on an electrically driven junction that when injected with current becomes optically active and generates amplified spontaneous emission (ASE) and gain over a wide range of wavelengths. When the optical output becomes dominated by ASE there is a knee in the light output versus current (LI) characteristic wherein the unit of light output becomes drastically larger per unit of injected current. This knee in the LI curve resembles the threshold of a laser diode, but is much softer. A SLED would have a layer structure engineered to have a light emitting layer or layers clad above and below with material of lower optical index such that a laterally guided optical mode can be formed. The SLED would also be fabricated with features providing lateral optical confinement. These lateral confinement features may consist of an etched ridge, with air, vacuum, metal or dielectric material surrounding the ridge and providing a low optical-index cladding. The lateral confinement feature may also be provided by shaping the electrical contacts such that injected current is confined to a finite region in the device. In such a “gain guided” structure, dispersion in the optical index of the light emitting layer with injected carrier density provides the optical-index contrast needed to provide lateral confinement of the optical mode.

In an embodiment, the LD or SLED device is characterized by a ridge with non-uniform width. The ridge is comprised by a first section of uniform width and a second section of varying width. The first section has a length between 100 and 500 μm long, though it may be longer. The first section has a width of between 1 and 2.5 μm, with a width preferably between 1 and 1.5 μm. The second section of the ridge has a first end and a second end. The first end connects with the first section of the ridge and has the same width as the first section of the ridge. The second end of the second section of the ridge is wider than the first section of the ridge, with a width between 5 and 50 μm and more preferably with a width between 15 and 35 μm. The second section of the ridge waveguide varies in width between its first and second end smoothly. In some embodiments the second derivative of the ridge width versus length is zero such that the taper of the ridge is linear. In some embodiments, the second derivative is chosen to be positive or negative. In general, the rate of width increase is chosen such that the ridge does not expand in width significantly faster than the optical mode. In specific embodiments, the electrically injected area is patterned such that only a part of the tapered portion of the waveguide is electrically injected.

In an embodiment, multiple laser dice emitting at different wavelengths are transferred to the same carrier wafer in close proximity to one another; preferably within one millimeter of each other, more preferably within about 200 micrometers of each other and most preferably within about 50 μm of each other. The laser die wavelengths are chosen to be separated in wavelength by at least twice the full width at half maximum of their spectra. For example, three dice, emitting at 440 nm, 450 nm and 460 nm, respectively, are transferred to a single carrier chip with a separation between die of less than 50 μm and die widths of less than 50 μm such that the total lateral separation, center to center, of the laser light emitted by the die is less than 200 μm. The closeness of the laser die allows for their emission to be easily coupled into the same optical train or fiber optic waveguide or projected in the far field into overlapping spots. In a sense, the lasers can be operated effectively as a single laser light source.

Such a configuration offers an advantage in that each individual laser light source could be operated independently to convey information using for example frequency and phase modulation of an RF signal superimposed on DC offset. The time-averaged proportion of light from the different sources could be adjusted by adjusting the DC offset of each signal. At a receiver, the signals from the individual laser sources would be demultiplexed by use of notch filters over individual photodetectors that filter out both the phosphor derived component of the white light spectra as well as the pump light from all but one of the laser sources. Such a configuration would offer an advantage over an LED based visible light communication (VLC) source in that bandwidth would scale easily with the number of laser emitters. Of course, a similar embodiment with similar advantages could be constructed from SLED emitters.

After the laser diode chip fabrication as described above, the laser diode can be mounted to a submount. In some examples the submount is comprised of AlN, SiC, BeO, diamond, or other materials such as metals, ceramics, or composites. Alternatively, the submount can be an intermediate submount intended to be mounted to the common support member wherein the phosphor material is attached. The submount member may be characterized by a width, length, and thickness. In an example wherein the submount is the common support member for the phosphor and the laser diode chip the submount would have a width and length ranging in dimension from about 0.5 mm to about 5 mm or to about 15 mm and a thickness ranging from about 150 μm to about 2 mm. In the example wherein the submount is an intermediate submount between the laser diode chip and the common support member it could be characterized by width and length ranging in dimension from about 0.5 mm to about 5 mm and the thickness may range from about 50 μm to about 500 μm. The laser diode is attached to the submount using a bonding process, a soldering process, a gluing process, or a combination thereof. In one embodiment the submount is electrically isolating and has metal bond pads deposited on top. The laser chip is mounted to at least one of those metal pads. The laser chip can be mounted in a p-side down or a p-side up configuration. After bonding the laser chip, wire bonds are formed from the chip to the submount such that the final chip on submount (CoS) is completed and ready for integration.

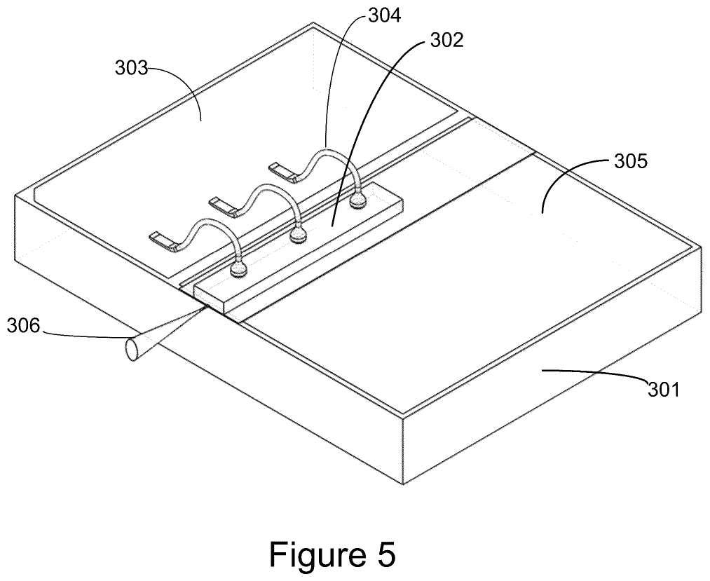

A schematic diagram illustrating a CoS based on a conventional laser diode formed on gallium and nitrogen containing substrate technology according to this present invention is shown in FIG. 5. The CoS is comprised of submount material 301 configured to act as an intermediate material between a laser diode chip 302 and a final mounting surface. The submount is configured with electrodes 303 and 305 that may be formed with deposited metal layers such as Au. In one example, Ti/Pt/Au is used for the electrodes. Wirebonds 304 are configured to couple the electrical power from the electrodes 303 and 305 on the submount to the laser diode chip to generate a laser beam output 306 from the laser diode. The electrodes 303 and 305 are configured for an electrical connection to an external power source such as a laser driver, a current source, or a voltage source. Wirebonds 304 can be formed on the electrodes to couple electrical power to the laser diode device and activate the laser.

In another embodiment, the gallium and nitrogen containing laser diode fabrication includes an epitaxial release step to lift off the epitaxially grown gallium and nitrogen layers and prepare them for transferring to a carrier wafer which could comprise the submount after laser fabrication. The transfer step requires precise placement of the epitaxial layers on the carrier wafer to enable subsequent processing of the epitaxial layers into laser diode devices. The attachment process to the carrier wafer could include a wafer bonding step with a bond interface comprised of metal-metal, semiconductor-semiconductor, glass-glass, dielectric-dielectric, or a combination thereof.

In this embodiment, gallium and nitrogen containing epitaxial layers are grown on a bulk gallium and nitrogen containing substrate. The epitaxial layer stack comprises at least a sacrificial release layer and the laser diode device layers overlying the release layers. Following the growth of the epitaxial layers on the bulk gallium and nitrogen containing substrate, the semiconductor device layers are separated from the substrate by a selective wet etching process such as a PEC etch configured to selectively remove the sacrificial layers and enable release of the device layers to a carrier wafer. In one embodiment, a bonding material is deposited on the surface overlying the semiconductor device layers. A bonding material is also deposited either as a blanket coating or patterned on the carrier wafer. Standard lithographic processes are used to selectively mask the semiconductor device layers. The wafer is then subjected to an etch process such as dry etch or wet etch processes to define via structures that expose the sacrificial layers on the sidewall of the mesa structure. As used herein, the term mesa region or mesa is used to describe the patterned epitaxial material on the gallium and nitrogen containing substrate and prepared for transferring to the carrier wafer. The mesa region can be any shape or form including a rectangular shape, a square shape, a triangular shape, a circular shape, an elliptical shape, a polyhedron shape, or other shape. The term mesa shall not limit the scope of the present invention.

Following the definition of the mesa, a selective etch process is performed to fully or partially remove the sacrificial layers while leaving the semiconductor device layers intact. The resulting structure comprises undercut mesas comprised of epitaxial device layers. The undercut mesas correspond to dice from which semiconductor devices will be formed on. In some embodiments a protective passivation layer can be employed on the sidewall of the mesa regions to prevent the device layers from being exposed to the selective etch when the etch selectivity is not perfect. In other embodiments a protective passivation is not needed because the device layers are not sensitive to the selective etch or measures are taken to prevent etching of sensitive layers such as shorting the anode and cathode. The undercut mesas corresponding to device dice are then transferred to the carrier wafer using a bonding technique wherein the bonding material overlying the semiconductor device layers is joined with the bonding material on the carrier wafer. The resulting structure is a carrier wafer comprising gallium and nitrogen containing epitaxial device layers overlying the bonding region.

In a preferred embodiment PEC etching is deployed as the selective etch to remove the sacrificial layers. PEC is a photo-assisted wet etch technique that can be used to etch GaN and its alloys. The process involves an above-band-gap excitation source and an electrochemical cell formed by the semiconductor and the electrolyte solution. In this case, the exposed (Al,In,Ga) N material surface acts as the anode, while a metal pad deposited on the semiconductor acts as the cathode. The above-band-gap light source generates electron-hole pairs in the semiconductor. Electrons are extracted from the semiconductor via the cathode while holes diffuse to the surface of material to form an oxide. Since the diffusion of holes to the surface requires the band bending at the surface to favor a collection of holes, PEC etching typically works only for n-type material although some methods have been developed for etching p-type material. The oxide is then dissolved by the electrolyte resulting in wet etching of the semiconductor. Different types of electrolyte including HCl, KOH, and HNO₃ have been shown to be effective in PEC etching of GaN and its alloys. The etch selectivity and etch rate can be optimized by selecting a favorable electrolyte. It is also possible to generate an external bias between the semiconductor and the cathode to assist with the PEC etching process.

In a preferred embodiment, a semiconductor device epitaxy material with the underlying sacrificial region is fabricated into a dense array of mesas on the gallium and nitrogen containing bulk substrate with the overlying semiconductor device layers. The mesas are formed using a patterning and a wet or dry etching process wherein the patterning comprises a lithography step to define the size and pitch of the mesa regions. Dry etching techniques such as reactive ion etching, inductively coupled plasma etching, or chemical assisted ion beam etching are candidate methods. Alternatively, a wet etch can be used. The etch is configured to terminate at or below a sacrificial region below the device layers. This is followed by a selective etch process such as PEC to fully or partially etch the exposed sacrificial region such that the mesas are undercut. This undercut mesa pattern pitch will be referred to as the ‘first pitch’. The first pitch is often a design width that is suitable for fabricating each of the epitaxial regions on the substrate, while not large enough for the desired completed semiconductor device design, which often desire larger non-active regions or regions for contacts and the like. For example, these mesas would have a first pitch ranging from about 5 μm to about 500 μm or to about 5000 μm. Each of these mesas is a ‘die’.

In a preferred embodiment, these dice are transferred to a carrier wafer at a second pitch using a selective bonding process such that the second pitch on the carrier wafer is greater than the first pitch on the gallium and nitrogen containing substrate. In this embodiment the dice are on an expanded pitch for so called “die expansion”. In an example, the second pitch is configured with the dice to allow each die with a portion of the carrier wafer to be a semiconductor device, including contacts and other components. For example, the second pitch would be about 50 μm to about 1000 μm or to about 5000 μm, but could be as large at about 3-10 mm or greater in the case where a large semiconductor device chip is required for the application. The larger second pitch could enable easier mechanical handling without the expense of the costly gallium and nitrogen containing substrate and epitaxial material, allow the real estate for additional features to be added to the semiconductor device chip such as bond pads that do not require the costly gallium and nitrogen containing substrate and epitaxial material, and/or allow a smaller gallium and nitrogen containing epitaxial wafer containing epitaxial layers to populate a much larger carrier wafer for subsequent processing for reduced processing cost. For example, a 4 to 1 die expansion ratio would reduce the density of the gallium and nitrogen containing material by a factor of 4, and hence populate an area on the carrier wafer 4 times larger than the gallium and nitrogen containing substrate. This would be equivalent to turning a 2″ gallium and nitrogen substrate into a 4″ carrier wafer. In particular, the present invention increases utilization of substrate wafers and epitaxy material through a selective area bonding process to transfer individual die of epitaxy material to a carrier wafer in such a way that the die pitch is increased on the carrier wafer relative to the original epitaxy wafer. The arrangement of epitaxy material allows device components which do not require the presence of the expensive gallium and nitrogen containing substrate and overlying epitaxy material often fabricated on a gallium and nitrogen containing substrate to be fabricated on the lower cost carrier wafer, allowing for more efficient utilization of the gallium and nitrogen containing substrate and overlying epitaxy material.

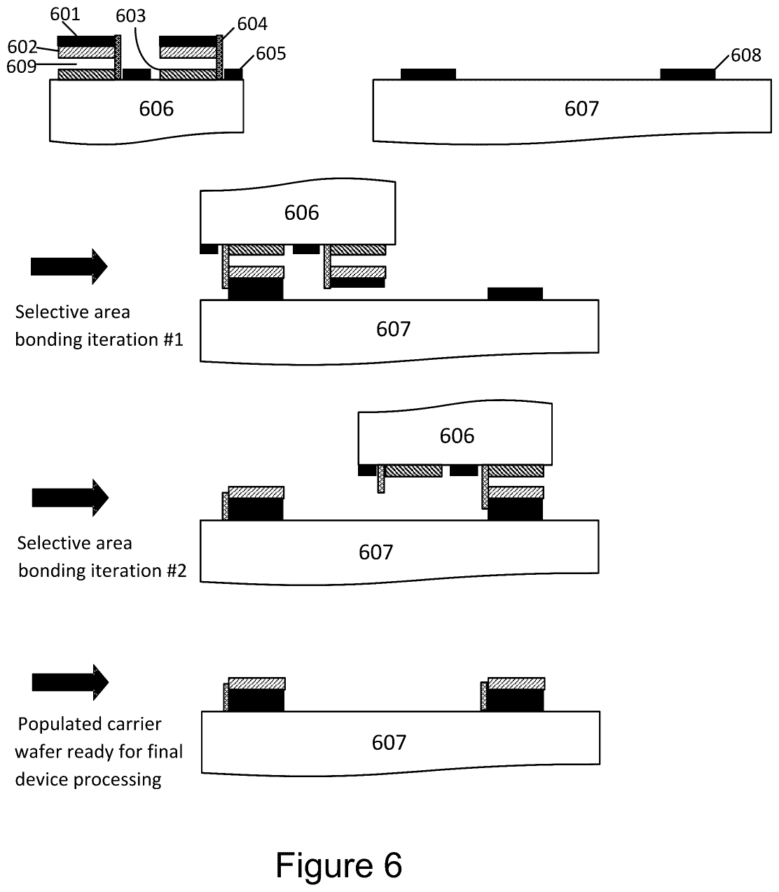

FIG. 6 is a schematic representation of the die expansion process with selective area bonding according to the present invention. A device wafer is prepared for bonding in accordance with an embodiment of this invention. The device wafer consists of a substrate 606, buffer layers 603, a fully removed sacrificial layer 609, device layers 602, bonding media 601, cathode metal 605, and an anchor material 604. The sacrificial layer 609 is removed in the PEC etch with the anchor material 604 is retained. The mesa regions formed in the gallium and nitrogen containing epitaxial wafer form dice of epitaxial material and release layers defined through processing. Individual epitaxial material die is formed at first pitch. A carrier wafer is prepared consisting of the carrier wafer substrate 607 and bond pads 608 at second pitch. The substrate 606 is aligned to the carrier wafer 607 such that a subset of the mesa on the gallium and nitrogen containing substrate 606 with a first pitch aligns with a subset of bond pads 608 on the carrier wafer 607 at a second pitch. Since the first pitch is greater than the second pitch and the mesas will comprise device die, the basis for die expansion is established. The bonding process is carried out and upon separation of the substrate from the carrier wafer 607 the subset of mesas on the substrate 606 are selectively transferred to the carrier wafer 607. The process is then repeated with a second set of mesas and bond pads 608 on the carrier wafer 607 until the carrier wafer 607 is populated fully by epitaxial mesas. The gallium and nitrogen containing epitaxy substrate 201 can now optionally be prepared for reuse.

In the example depicted in FIG. 6, one quarter of the epitaxial dice on the epitaxy wafer 606 are transferred in this first selective bond step, leaving three quarters on the epitaxy wafer 606. The selective area bonding step is then repeated to transfer the second quarter, third quarter, and fourth quarter of the epitaxial die to the patterned carrier wafer 607. This selective area bond may be repeated any number of times and is not limited to the four steps depicted in FIG. 6. The result is an array of epitaxial die on the carrier wafer 607 with a wider die pitch than the original die pitch on the epitaxy wafer 606. The die pitch on the epitaxial wafer 606 will be referred to as pitch 1, and the die pitch on the carrier wafer 607 will be referred to as pitch 2, where pitch 2 is greater than pitch 1.

In one embodiment the bonding between the carrier wafer and the gallium and nitrogen containing substrate with epitaxial layers is performed between bonding layers that have been applied to the carrier and the gallium and nitrogen containing substrate with epitaxial layers. The bonding layers can be a variety of bonding pairs including metal-metal, oxide-oxide, soldering alloys, photoresists, polymers, wax, etc. Only epitaxial dice which are in contact with a bond bad 608 on the carrier wafer 607 will bond. Sub-micron alignment tolerances are possible on commercial die bonders. The epitaxy wafer 606 is then pulled away, breaking the epitaxy material at a weakened epitaxial release layer 609 such that the desired epitaxial layers remain on the carrier wafer 607. Herein, a ‘selective area bonding step’ is defined as a single iteration of this process.

In one embodiment, the carrier wafer 607 is patterned in such a way that only selected mesas come in contact with the metallic bond pads 608 on the carrier wafer 607. When the epitaxy substrate 606 is pulled away the bonded mesas break off at the weakened sacrificial region, while the un-bonded mesas remain attached to the epitaxy substrate 606. This selective area bonding process can then be repeated to transfer the remaining mesas in the desired configuration. This process can be repeated through any number of iterations and is not limited to the two iterations depicted in FIG. 6. The carrier wafer can be of any size, including but not limited to about 2 inches, 3 inches, 4 inches, 6 inches, 8 inches, and 12 inches. After all desired mesas have been transferred, a second bandgap selective PEC etching can be optionally used to remove any remaining sacrificial region material to yield smooth surfaces. At this point standard semiconductor device processes can be carried out on the carrier wafer. Another embodiment of the invention incorporates the fabrication of device components on the dense epitaxy wafers before the selective area bonding steps.

In an example, the present invention provides a method for increasing the number of gallium and nitrogen containing semiconductor devices which can be fabricated from a given epitaxial surface area; where the gallium and nitrogen containing epitaxial layers overlay gallium and nitrogen containing substrates. The gallium and nitrogen containing epitaxial material is patterned into die with a first die pitch; the die from the gallium and nitrogen containing epitaxial material with a first pitch is transferred to a carrier wafer to form a second die pitch on the carrier wafer; the second die pitch is larger than the first die pitch.

In an example, each epitaxial device die is an etched mesa with a pitch of between about 1 μm and about 100 μm wide or between about 100 μm and about 500 μm wide or between about 500 μm and about 3000 μm wide and between about 100 and about 3000 μm long. In an example, the second die pitch on the carrier wafer is between about 100 μm and about 200 μm or between about 200 μm and about 1000 μm or between about 1000 μm and about 3000 μm. In an example, the second die pitch on the carrier wafer is between about 2 times and about 50 times larger than the die pitch on the epitaxy wafer. In an example, semiconductor LED devices, laser devices, or electronic devices are fabricated on the carrier wafer after epitaxial transfer. In an example, the semiconductor devices contain GaN, AlN, InN, InGaN, AlGaN, InAlN, and/or InAlGaN. In an example, the gallium and nitrogen containing material are grown on a polar, nonpolar, or semipolar plane. In an example, one or multiple semiconductor devices are fabricated on each die of epitaxial material. In an example, device components which do not require epitaxy material are placed in the space between cpitaxy dic.

In one embodiment, device dice are transferred to a carrier wafer such that the distance between die is expanded in both the transverse as well as lateral directions. This can be achieved by spacing bond pads on the carrier wafer with larger pitches than the spacing of device die on the substrate.

In another embodiment of the invention device dice from a plurality of epitaxial wafers are transferred to the carrier wafer such that each design width on the carrier wafer contains dice from a plurality of epitaxial wafers. When transferring dice at close spacing from multiple epitaxial wafers, it is important for the un-transferred dice on the epitaxial wafer to not inadvertently contact and bond to die already transferred to the carrier wafer. To achieve this, epitaxial dice from a first epitaxial wafer are transferred to a carrier wafer using the methods described above. A second set of bond pads are then deposited on the carrier wafer and are made with a thickness such that the bonding surface of the second pads is higher than the top surface of the first set of transferred die. This is done to provide adequate clearance for bonding of the dice from the second epitaxial wafer. A second epitaxial wafer transfers a second set of dice to the carrier wafer. Finally, the semiconductor devices are fabricated, and passivation layers are deposited followed by electrical contact layers that allow each die to be individually driven. The dice transferred from the first and second substrates are spaced at a pitch which is smaller than the second pitch of the carrier wafer. This process can be extended to transfer of dice from any number of epitaxial substrates, and to transfer of any number of devices per dice from each epitaxial substrate.

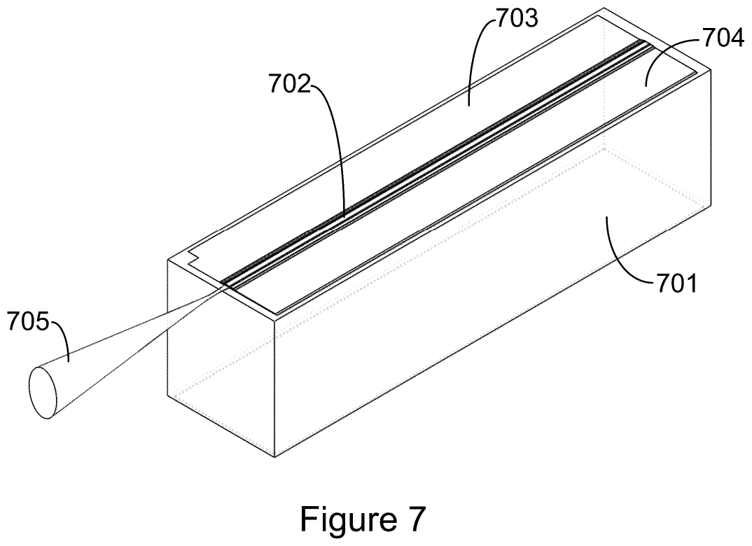

A schematic diagram illustrating a CoS based on lifted off and transferred epitaxial gallium and nitrogen containing layers according to this present invention is shown in FIG. 7. The CoS is comprised of submount material 701 configured from the carrier wafer with the transferred epitaxial material with a laser diode stripe configured within the epitaxy 702. Electrodes 703 and 704 are electrically coupled to the n-side and the p-side of the laser diode device and configured to transmit power from an external source to the laser diode to generate a laser beam output 705 from the laser diode. The electrodes are configured for an electrical connection to an external power source such as a laser driver, a current source, or a voltage source. Wirebonds can be formed on the electrodes to couple the power to the laser diode device. This integrated CoS device with transferred epitaxial material offers advantages over the conventional configuration such as size, cost, and performance due to the low thermal impedance.

Further process and device description for this embodiment describing laser diodes formed in gallium and nitrogen containing epitaxial layers that have been transferred from the native gallium and nitrogen containing substrates are described in U.S. patent application Ser. No. 14/312,427 and U.S. Patent Publication No. 2015/0140710, which are incorporated by reference herein. As an example, this technology of GaN transfer can enable lower cost, higher performance, and a more highly manufacturable process flow.

In this embodiment, the carrier wafer can be selected to provide an ideal submount material for the integrated CPoS white light source. That is, the carrier wafer serving as the laser diode submount would also serve as the common support member for the laser diode and the phosphor to enable an ultra-compact CPOS integrated white light source. In one example, the carrier wafer is formed from silicon carbide (SiC). SiC is an ideal candidate due to its high thermal conductivity, low electrical conductivity, high hardness and robustness, and wide availability. In other examples AlN, diamond, GaN, InP, GaAs, or other materials can be used as the carrier wafer and resulting submount for the CPoS. In one example, the laser chip is diced out such that there is an area in front of the front laser facet intended for the phosphor. The phosphor material would then be bonded to the carrier wafer and configured for laser excitation according to this embodiment.

After fabrication of the laser diode on a submount member, in some embodiments of this invention the construction of the integrated white source would proceed to integration of the phosphor with the laser diode and common support member. Phosphor selection is a key consideration within the laser-based integrated white light source. The phosphor must be able to withstand the extreme optical intensity and associated heating induced by the laser excitation spot without severe degradation. Important characteristics to consider for phosphor selection include;
A high conversion efficiency of optical excitation power to white light lumens. In the example of a blue laser diode exciting a yellow phosphor, a conversion efficiency of over 150 lumens per optical watt, or over 200 lumens per optical watt, or over 300 lumens per optical watt is desired.
A high optical damage threshold capable of withstanding 1-20 W of laser power in a spot comprising a diameter of 1 mm, 500 μm, 200 μm, 100 μm, or even 50 μm.
High thermal damage threshold capable of withstanding temperatures of over 150° C., over 200° C., or over 300° C. without decomposition.
A low thermal quenching characteristic such that the phosphor remains efficient as it reaches temperatures of over 150° C., 200° C., or 250° C.
A high thermal conductivity to dissipate the heat and regulate the temperature. Thermal conductivities of greater than 3 W/(m·K), greater than 5 W/(m·K), greater than 10 W/(m·K), and even greater than 15 W/(m·K) are desirable.
A proper phosphor emission color for the application.
A suitable porosity characteristic that leads to the desired scattering of the coherent excitation without unacceptable reduction in thermal conductivity or optical efficiency.
A proper form factor for the application. Such form factors include, but are not limited to blocks, plates, disks, spheres, cylinders, rods, or a similar geometrical element. Proper choice will be dependent on whether phosphor is operated in transmissive or reflective mode and on the absorption length of the excitation light in the phosphor.
A surface condition optimized for the application. In an example, the phosphor surfaces can be intentionally roughened for improved light extraction.

In a preferred embodiment, a blue laser diode operating in the 420 nm to 480 nm wavelength range would be combined with a phosphor material providing a yellowish emission in the 560 nm to 580 nm range such that when mixed with the blue emission of the laser diode a white light is produced. For example, to meet a white color point on the black body line the energy of the combined spectrum may be comprised of about 30% from the blue laser emission and about 70% from the yellow phosphor emission. In other embodiments phosphors with red, green, yellow, and even blue emission can be used in combination with the laser diode excitation sources in the violet, ultra-violet, or blue wavelength range to produce a white light with color mixing. Although such white light systems may be more complicated due to the use of more than one phosphor member, advantages such as improved color rendering could be achieved.

In an example, the light emitted from the laser diodes is partially converted by the phosphor element. In an example, the partially converted light emitted generated in the phosphor element results in a color point, which is white in appearance. In an example, the color point of the white light is located on the Planckian blackbody locus of points. In an example, the color point of the white light is located within du′v′ of less than 0.010 of the Planckian blackbody locus of points. In an example, the color point of the white light is preferably located within du′v′ of less than 0.03 of the Planckian blackbody locus of points.

The phosphor material can be operated in a transmissive mode, a reflective mode, or a combination of a transmissive mode and reflective mode, or other modes. The phosphor material is characterized by a conversion efficiency, a resistance to thermal damage, a resistance to optical damage, a thermal quenching characteristic, a porosity to scatter excitation light, and a thermal conductivity. In a preferred embodiment the phosphor material is comprised of a yellow emitting YAG material doped with Ce with a conversion efficiency of greater than 100 lumens per optical watt, greater than 200 lumens per optical watt, or greater than 300 lumens per optical watt, and can be a polycrystalline ceramic material or a single crystal material.

In some embodiments of the present invention, the environment of the phosphor can be independently tailored to result in high efficiency with little or no added cost. Phosphor optimization for laser diode excitation can include high transparency, scattering or non-scattering characteristics, and use of ceramic phosphor plates. Decreased temperature sensitivity can be determined by doping levels. A reflector can be added to the backside of a ceramic phosphor, reducing loss. The phosphor can be shaped to increase in-coupling, increase out-coupling, and/or reduce back reflections. Surface roughening is a well-known means to increase extraction of light from a solid material. Coatings, mirrors, or filters can be added to the phosphors to reduce the amount of light exiting the non-primary emission surfaces, to promote more efficient light exit through the primary emission surface, and to promote more efficient in-coupling of the laser excitation light. Of course, there can be additional variations, modifications, and alternatives.

In some embodiments, certain types of phosphors will be best suited in this demanding application with a laser excitation source. As an example, a ceramic yttrium aluminum garnets (YAG) doped with Ce³⁺ ions, or YAG based phosphors can be ideal candidates. They are doped with species such as Ce to achieve the proper emission color and are often comprised of a porosity characteristic to scatter the excitation source light, and nicely break up the coherence in laser excitation. As a result of its cubic crystal structure the YAG:Ce can be prepared as a highly transparent single crystal as well as a polycrystalline bulk material. The degree of transparency and the luminescence are depending on the stoichiometric composition, the content of dopant, and entire processing and sintering route. The transparency and degree of scattering centers can be optimized for a homogenous mixture of blue and yellow light. The YAG:Ce can be configured to emit a green emission. In some embodiments the YAG can be doped with Eu to emit a red emission.

In a preferred embodiment according to this invention, the white light source is configured with a ceramic polycrystalline YAG:Ce phosphors comprising an optical conversion efficiency of greater than 100 lumens per optical excitation watt, of greater than 200 lumens per optical excitation watt, or even greater than 300 lumens per optical excitation watt, or greater. Additionally, the ceramic YAG:Ce phosphors is characterized by a temperature quenching characteristics above 150° C., above 200° C., or above 250° C. and a high thermal conductivity of 5-10 W/(m·K) to effectively dissipate heat to a heat sink member and keep the phosphor at an operable temperature.

In another preferred embodiment according to this invention, the white light source is configured with a single crystal phosphor (SCP) such as YAG:Ce. In one example the Ce:Y3A15012 SCP can be grown by the Czochralski technique. In this embodiment according the present invention the SCP based on YAG:Ce is characterized by an optical conversion efficiency of greater than 100 lumens per optical excitation watt, of greater than 200 lumens per optical excitation watt, or even greater than 300 lumens per optical excitation watt, or greater. Additionally, the single crystal YAG:Ce phosphors is characterized by a temperature quenching characteristics above 150° C., above 200° C., or above 300° C. and a high thermal conductivity of 8-20 W/(m·K) to effectively dissipate heat to a heat sink member and keep the phosphor at an operable temperature. In addition to the high thermal conductivity, high thermal quenching threshold, and high conversion efficiency, the ability to shape the phosphors into tiny forms that can act as ideal “point” sources when excited with a laser is an attractive feature.

In some embodiments the YAG:Ce can be configured to emit a yellow emission. In alternative or the same embodiments a YAG:Ce can be configured to emit a green emission. In yet alternative or the same embodiments the YAG can be doped with Eu to emit a red emission. In some embodiments a LuAG is configured for emission. In alternative embodiments, silicon nitrides or aluminum-oxi-nitrides can be used as the crystal host materials for red, green, yellow, or blue emissions.

In an alternative embodiment, a powdered single crystal or ceramic phosphor such as a yellow phosphor or green phosphor is included. The powdered phosphor can be dispensed on a transparent member for a transmissive mode operation or on a solid member with a reflective layer on the back surface of the phosphor or between the phosphor and the solid member to operate in a reflective mode. The phosphor powder may be held together in a solid structure using a binder material wherein the binder material is preferable in inorganic material with a high optical damage threshold and a favorable thermal conductivity. The phosphor power may be comprised of colored phosphors and configured to emit a white light when excited by and combined with the blue laser beam or excited by a violet laser beam. The powdered phosphors could be comprised of YAG, LuAG, or other types of phosphors.

In one embodiment of the present invention the phosphor material contains a yttrium aluminum garnet host material and a rare earth doping element, and others. In an example, the wavelength conversion element is a phosphor which contains a rare earth doping element, selected from one of Ce, Nd, Er, Yb, Ho, Tm, Dy and Sm, or combinations thereof, and the like. In an example, the phosphor material is a high-density phosphor element. In an example, the high-density phosphor element has a density greater than 90% of pure host crystal. Cerium (III)-doped YAG (YAG:Ce³⁺, or Y₃Al₅O₁₂:Ce³⁺) can be used wherein the phosphor absorbs the light from the blue laser diode and emits in a broad range from greenish to reddish, with most of output in yellow. This yellow emission combined with the remaining blue emission gives the “white” light, which can be adjusted to color temperature as warm (yellowish) or cold (blueish) white. The yellow emission of the Ce³⁺:YAG can be tuned by substituting the cerium with other rare earth elements such as terbium and gadolinium and can even be further adjusted by substituting some or all of the aluminum in the YAG with gallium.

In alternative examples, various phosphors can be applied to this invention, which include, but are not limited to organic dyes, conjugated polymers, semiconductors such as AlInGaP or InGaN, yttrium aluminum garnets (YAGs) doped with Ce³⁺ ions (Y₁₋ₐGdₐ)₃(Al_{1-b}Ga_{b})₅O₁₂:Ce³⁺, SrGa₂S₄:Eu²⁺, SrS:Eu²⁺, terbium aluminum based garnets (TAGs) (Tb₃Al₅O₅), colloidal quantum dot thin films containing CdTe, ZnS, ZnSe, ZnTe, CdSe, or CdTe.

In further alternative examples, some rare-earth doped Sialons can serve as phosphors. Europium (II)-doped B-SiAION absorbs in ultraviolet and visible light spectrum and emits intense broadband visible emission. Its luminance and color does not change significantly with temperature, due to the temperature-stable crystal structure. In an alternative example, green and yellow SiAlON phosphor and a red CaAlSiN₃-based (CASN)phosphor may be used.

In yet a further example, white light sources can be made by combining near ultraviolet emitting laser diodes with a mixture of high efficiency europium based red and blue emitting phosphors plus green emitting copper and aluminum doped zinc sulfide (ZnS:Cu,Al).

In an example, a phosphor or phosphor blend can be selected from a of (Y, Gd, Tb, Sc, Lu, La)₃(Al, Ga, In)₅O₁₂:Ce³⁺, SrGa₂S₄:Eu²⁺, SrS:Eu²⁺, and colloidal quantum dot thin films comprising CdTe, ZnS, ZnSe, ZnTe, CdSe, or CdTe. In an example, a phosphor is capable of emitting substantially red light, wherein the phosphor is selected from the group consisting of (Gd,Y,Lu,La)₂O₃:Eu³⁺, Bi³⁺; (Gd,Y,Lu,La)₂O₂S:Eu³⁺, Bi³⁺; (Gd,Y,Lu,La)VO₄:Eu³⁺, Bi³⁺; Y₂(O,S)₃:Eu³⁺; Ca₁₋ₓMo_{1-y}Si_{y}O₄: where 0.05≤x≤0.5, 0≤y≤0.1; (Li,Na,K)₅Eu(W,Mo)O₄; (Ca,Sr)S:Eu²⁺; SrY₂S₄:Eu²⁺; CaLa₂S₄:Cc³⁺; (Ca,Sr)S:Eu²⁺; 3.5MgOx0.5MgF₂xGeO₂:Mn⁴⁺ (MFG); (Ba,Sr,Ca)MgₓP₂O₇:Eu²⁺, Mn²⁺; (Y,Lu)₂WO₆:Eu³⁺, Mo⁶⁺; (Ba,Sr,Ca)₃MgₓSi₂O₈:Eu²⁺, Mn²⁺, wherein 1<x≤2; (RE_{1-y}Ce_{y}) Mg₂₋ₓLiₓSi₃₋ₓPₓO₁₂, where RE is at least one of Sc, Lu, Gd, Y, and Tb, 0.0001<x<0.1 and 0.001<y<0.1; (Y, Gd, Lu, La)₂₋ₓEuₓW_{1-y}Mo_{y}O₆, where 0.5≤x≤1.0, 0.01≤y≤1.0; (SrCa)₁₋ₓEuₓSi₅N₈, where 0.≤x≤0.3; SrZnO₂:Sm³⁺; MₘOₙX, wherein M is selected from the group of Sc, Y, a lanthanide, an alkali earth metal and mixtures thereof; X is a halogen; 1≤m≤3; and 1≤n≤4, and wherein the lanthanide doping level can range from 0.1 to 40% spectral weight; and Eu³⁺ activated phosphate or borate phosphors; and mixtures thereof. Further details of other phosphor species and related techniques can be found in U.S. Pat. No. 8,956,894, in the name of Raring et al. issued Feb. 17, 2015, and titled White light devices using non-polar or semipolar gallium containing materials and phosphors, which is commonly owned, and hereby incorporated by reference herein.

In another preferred embodiment according to this invention, the white light source is configured with a single crystal phosphor (SCP) or Ceramic plate phosphor selected from a Lanthanum Silicon Nitride compound and Lanthanum aluminum Silicon Nitrogen Oxide compound containing Ce³⁺ ions atomic concentration ranging from 0.01% to 10%. Optionally, the Lanthanum Silicon Nitride compound and Lanthanum aluminum Silicon Nitrogen Oxide compound containing Ce³⁺ ions includes LaSi₃N₅:Ce³⁺ or LaAl(Si_{6-z}Al_{z}) (N_{10-z}O_{z}):Ce³⁺ (wherein z=1). In this embodiment according the present invention the SCP or Ceramic plate based on LaSi₃N₅:Ce³⁺ or LaAl(Si_{6-z}Al_{z}) (N_{10-z}O_{z}):Ce³⁺ (wherein z=1) is characterized by an optical conversion efficiency of greater than 100 lumens per optical excitation watt, or greater than 200 lumens per optical excitation watt, or even greater than 300 lumens per optical excitation watt, or greater. Additionally, the single crystal phosphor (SCP) or Ceramic plate phosphor LaSi₃N₅:Ce³⁺ or LaAl(Si_{6-z}Al_{z})(N_{10-z}O_{z}):Ce³⁺ (wherein z=1) is characterized by a temperature quenching characteristics above 150° C., above 200° C., or above 300° C. and a high thermal conductivity of >10 W/m· K to effectively dissipate heat to a heat sink member and keep the phosphor at an operable temperature. In addition to the high thermal conductivity, high thermal quenching threshold, and high conversion efficiency, the ability to shape the phosphors into tiny forms that can act as ideal “point” sources when excited with a laser is an attractive feature.

In some embodiments of the present invention, ceramic phosphor materials are embedded in a binder material such as silicone. This configuration is typically less desirable because the binder materials often have poor thermal conductivity, and thus get very hot wherein the rapidly degrade and even burn. Such “embedded” phosphors are often used in dynamic phosphor applications such as color wheels where the spinning wheel cools the phosphor and spreads the excitation spot around the phosphor in a radial pattern.

Sufficient heat dissipation from the phosphor is a critical design consideration for the integrated white light source based on laser diode excitation. Specifically, the optically pumped phosphor system has sources of loss in the phosphor that result is thermal energy and hence must be dissipated to a heat-sink for optimal performance. The two primary sources of loss are the Stokes loss which is a result of converting photons of higher energy to photons of lower energy such that difference in energy is a resulting loss of the system and is dissipated in the form of heat. Additionally, the quantum efficiency or quantum yield measuring the fraction of absorbed photons that are successfully re-emitted is not unity such that there is heat generation from other internal absorption processes related to the non-converted photons. Depending on the excitation wavelength and the converted wavelength, the Stokes loss can lead to greater than 10%, greater than 20%, and greater than 30%, and greater loss of the incident optical power to result in thermal power that must be dissipated. The quantum losses can lead to an additional 10%, greater than 20%, and greater than 30%, and greater of the incident optical power to result in thermal power that must be dissipated. With laser beam powers in the 0.5 W to 100 W range focused to spot sizes of less than 1 mm in diameter, less than 500 microns in diameter, or even less than 100 microns in diameter, power densities of over 1 W/mm², 100 W/mm², or even over 2,500 W/mm² can be generated. As an example, assuming that the spectrum is comprised of 30% of the blue pump light and 70% of the converted yellow light and a best case scenario on Stokes and quantum losses, we can compute the dissipated power density in the form of heat for a 10% total loss in the phosphor at 0.1 W/mm², 10 W/mm², or even over 250 W/mm². Thus, even for this best-case scenario example, this is a tremendous amount of heat to dissipate. This heat generated within the phosphor under the high intensity laser excitation can limit the phosphor conversion performance, color quality, and lifetime.

For optimal phosphor performance and lifetime, not only should the phosphor material itself have a high thermal conductivity, but it should also be attached to the submount or common support member with a high thermal conductivity joint to transmit the heat away from the phosphor and to a heat-sink. In this invention, the phosphor is either attached to the common support member as the laser diode as in the CPoS or is attached to an intermediate submount member that is subsequently attached to the common support member. Candidate materials for the common support member or intermediate submount member are SiC, AlN, BeO, diamond, copper, copper tungsten, sapphire, aluminum, or others. The interface joining the phosphor to the submount member or common support member must be carefully considered. The joining material should be comprised of a high thermal conductivity material such as solder (or other) and be substantially free from voids or other defects that can impede heat flow. In some embodiments, glue materials can be used to fasten the phosphor. Ideally the phosphor bond interface will have a substantially large area with a flat surface on both the phosphor side and the support member sides of the interface.

In the present invention, the laser diode output beam must be configured to be incident on the phosphor material to excite the phosphor. In some embodiments the laser beam may be directly incident on the phosphor and in other embodiments the laser beam may interact with an optic, reflector, or other object to manipulate the beam prior to incidence on the phosphor. Examples of such optics include, but are not limited to ball lenses, aspheric collimator, aspheric lens, fast or slow axis collimators, dichroic mirrors, turning mirrors, optical isolators, but could be others.

The apparatus typically has a free space with a non-guided laser beam characteristic transmitting the emission of the laser beam from the laser device to the phosphor material. The laser beam spectral width, wavelength, size, shape, intensity, and polarization are configured to excite the phosphor material. The beam can be configured by positioning it at the precise distance from the phosphor to exploit the beam divergence properties of the laser diode and achieve the desired spot size. In one embodiment, the incident angle from the laser to the phosphor is optimized to achieve a desired beam shape on the phosphor. For example, due to the asymmetry of the laser aperture and the different divergent angles on the fast and slow axis of the beam the spot on the phosphor produced from a laser that is configured normal to the phosphor would be elliptical in shape, typically with the fast axis diameter being larger than the slow axis diameter. To compensate this, the laser beam incident angle on the phosphor can be optimized to stretch the beam in the slow axis direction such that the beam is more circular on phosphor. In other embodiments free space optics such as collimating lenses can be used to shape the beam prior to incidence on the phosphor. The beam can be characterized by a polarization purity of greater than 50% and less than 100%. As used herein, the term “polarization purity” means greater than 50% of the emitted electromagnetic radiation is in a substantially similar polarization state such as the transverse electric (TE) or transverse magnetic (TM) polarization states, but can have other meanings consistent with ordinary meaning.

The white light apparatus also has an electrical input interface configured to couple electrical input power to the laser diode device to generate the laser beam and excite the phosphor material. In an example, the laser beam incident on the phosphor has a power of less than 0.1 W, greater than 0.1 W, greater than 0.5 W, greater than 1 W, greater than 5 W, greater than 10 W, or greater than 20 W. The white light source configured to produce greater than 1 lumen, 10 lumens, 100 lumens, 250 lumens, 500 lumens, 1000 lumens, 3000 lumens, 10,000 lumens, or greater of white light output.

The support member is configured to transport thermal energy from the at least one laser diode device and the phosphor material to a heat sink. The support member is configured to provide thermal impedance of less than 10 degrees Celsius per watt, less than 5 degrees Celsius per watt, or less than 3 degrees Celsius per watt of dissipated power characterizing a thermal path from the laser device to a heat sink. The support member is comprised of a thermally conductive material such as copper with a thermal conductivity of about 400 W/(m·K), aluminum with a thermal conductivity of about 200 W/(m·K), 4H—SiC with a thermal conductivity of about 370 W/(m·K), 6H—SiC with a thermal conductivity of about 490 W/(m·K), AlN with a thermal conductivity of about 230 W/(m·K), a synthetic diamond with a thermal conductivity of about >1000 W/(m·K), sapphire, or other metals, ceramics, or semiconductors. The support member may be formed from a growth process such as SiC, AlN, or synthetic diamond, and then mechanically shaped by machining, cutting, trimming, or molding. Alternatively, the support member may be formed from a metal such as copper, copper tungsten, aluminum, or other by machining, cutting, trimming, or molding.

In a preferred configuration of this CPOS white light source, the common support member comprises the same submount that the gallium and nitrogen containing laser diode chip is directly bonded to. That is, the laser diode chip is mounted down or attached to a submount configured from a material such as SiC, AlN, or diamond and the phosphor material is also mounted to this submount, such that the submount is the common support member. The phosphor material may have an intermediate material positioned between the submount and the phosphor. The intermediate material may be comprised of a thermally conductive material such as copper. The laser diode can be attached to a first surface of the submount using conventional die attaching techniques using solders such as AuSn solder, but can be other techniques such as SAC solder such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohm*cm, or pressured sintered Ag can have a thermal conductivity of about 250 W/(m·K) and electrical conductivity of about 2.5 micro-ohmxem. Due to the extreme change in melt temperature from paste to sintered form, (260° C.-900° C.), processes can avoid thermal load restrictions on downstream processes, allowing completed devices to have very good and consistent bonds throughout. . . . Similarly, the phosphor material may be bonded to the submount using a soldering technique such as AuSn solder, SAC solder, lead containing phosphor, or with indium, but it can be other techniques such as sintered Ag interface materials. The joint could also be formed from thermally conductive glues, thermal epoxies such as silver epoxy, thermal adhesives, and other materials. Alternatively, the joint could be formed from a metal-metal bond such as an Au—Au bond. Optimizing the bond for the lowest thermal impedance is a key parameter for heat dissipation from the phosphor, which is critical to prevent phosphor degradation and thermal quenching of the phosphor material.

In an alternative configuration of this CPOS white light source, the laser diode is bonded to an intermediate submount configured between the gallium and nitrogen containing laser chip and the common support member. In this configuration, the intermediate submount can be comprised of SiC, AlN, diamond, or other, and the laser can be attached to a first surface of the submount using conventional die attaching techniques using solders such as AuSn solder, but can be other techniques. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxem, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. The second surface of the submount can be attached to the common support member using similar techniques, but could be others. Similarly, the phosphor material may have an intermediate material or submount positioned between the common support member and the phosphor. The intermediate material may be comprised of a thermally conductive material such as copper. The phosphor material may be bonded using a soldering technique. In this configuration, the common support member should be configured of a thermally conductive material such as copper. Optimizing the bond for the lowest thermal impedance is a key parameter for heat dissipation from the phosphor, which is critical to prevent phosphor degradation and thermal quenching of the phosphor material.

In a specific embodiment of the present invention, the CPOS white light source is configured for a side-pumped phosphor operated in transmissive mode. In this configuration, the phosphor is positioned in front of the laser facet that outputs the laser beam such that upon activation the generated laser beam is incident on a backside of the phosphor, wherein both the laser and the phosphor are configured on a support member. The gallium and nitrogen containing laser diode is configured with a cavity that has a length greater than 100 μm, greater than 500 μm, greater than 1000 μm, or greater than 1500 μm long and a width greater than 1 μm, greater than 10 μm, greater than 20 μm, greater than 30 μm, or greater than 45 μm. The cavity is configured with a front facet or mirror and back facet or mirror on the end, wherein the front facet comprises the output facet and configured to emit the laser beam incident on the phosphor. The front facet can be configured with an anti-reflective coating to decrease the reflectivity or no coating at all thereby allowing radiation to pass through the mirror without excessive reflectivity. In some cases, the coating may be configured to slightly increase the reflectivity. Since no laser beam is to be emitted from the back end of the cavity member, the back facet or mirror is configured to reflect the radiation back into the cavity. For example, the back facet includes highly reflective coating with a reflectivity greater than 85% or 95%. In one example, the phosphor is comprised of a ceramic yttrium aluminum garnet (YAG) doped with Ce³⁺ ions and emits yellow emission. The phosphor is shaped as a block, plate, sphere, cylinder, or other geometrical form. Specifically, the phosphor geometry primary dimensions may be less than 50 μm, less than 100 μm, less than 200 μm, less than 500 μm, less than 1 mm, or less than 10 mm. Operated in transmissive mode, the phosphor has a first primary side (back side) for receiving the incident laser beam and at least a second primary side (front side) where most of the useful white light will exit the phosphor to be coupled to the application. The phosphor is attached to the common support member or submount positioned in front of the laser diode output facet such that the first primary side of the phosphor configured for receiving the excitation light will be in the optical pathway of the laser output beam. The laser beam geometrical shape, size, spectral width, wavelength, intensity, and polarization are configured to excite the phosphor material. An advantage to transmissive mode phosphor operation is mitigation of the excitation source blocking or impeding any useful white light emitted from the primary emitting surface. Additionally, by exciting from the backside of the phosphor there will not be an obstruction relating to the excitation source or beam that may make integration of optics to collimate or project the white light difficult. In alternative embodiments the YAG:Ce can be configured to emit a green emission. In yet alternative or the same embodiments the YAG can be doped with Eu to emit a red emission. In alternative embodiments, silicon nitrides or aluminum-oxi-nitrides can be used as the crystal host materials for red, green, yellow, or blue emissions.

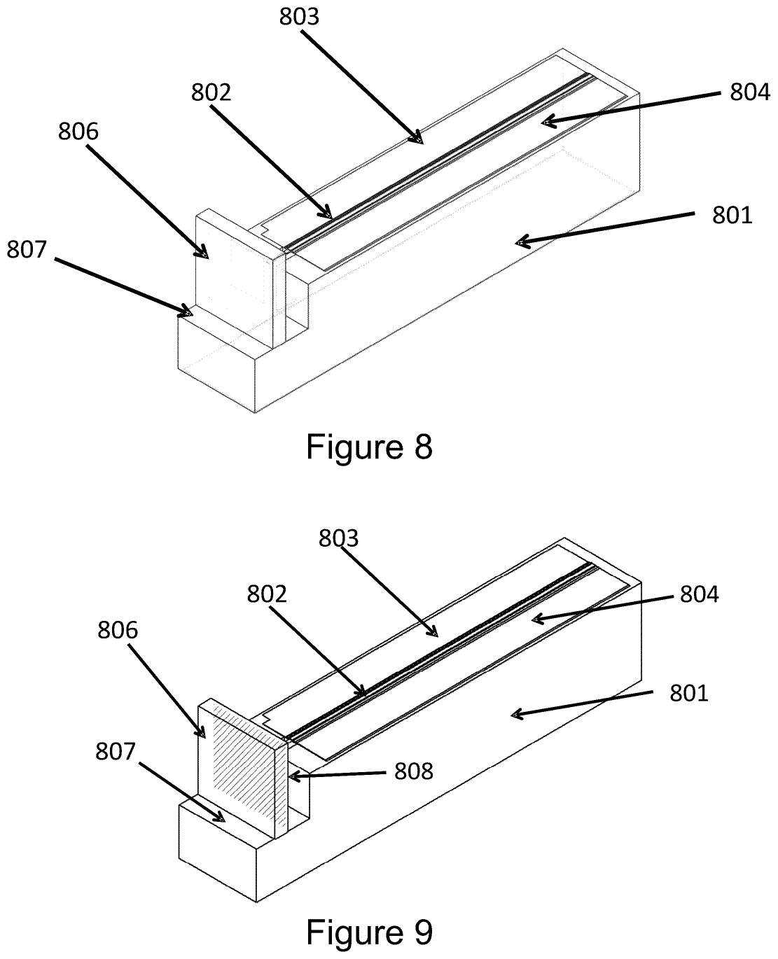

FIG. 8 presents a schematic diagram illustrating an alternative transmissive embodiment of a CPoS integrated white light source based according to the present invention. In this embodiment the gallium and nitrogen containing lift-off and transfer technique is deployed to fabricate a very small and compact submount member with the laser diode chip formed from transferred epitaxy layers. The laser-based CPOS white light device is comprised of submount material 801 that serves as the common support member configured to act as an intermediate material between a laser diode 802 formed in transferred gallium and nitrogen containing epitaxial layers and a final mounting surface and as an intermediate material between the phosphor plate material 806 and a final mounting surface 807. The laser diode or CoS submount 801 is configured with electrodes 803 and 804 that may be formed with deposited metal layers and combination of metal layers including, but not limited to Au, Pd, Pt, Ni, Al, titanium, or others. The laser beam output excites a phosphor plate 806 positioned in front of the output laser facet. The phosphor plate 806 is attached to the submount on a ledge 807 or recessed region. The electrodes 803 and 804 are configured for an electrical connection to an external power source such as a laser driver, a current source, or a voltage source. Wirebonds (not shown) can be formed on the electrodes to couple electrical power to the laser diode device 802 to generate a laser beam output from the laser diode. Of course, this is merely an example of a configuration and there could be many variants on this embodiment including but not limited to different shape phosphors, different geometrical designs of the submount or common support member, different orientations of the laser output beam with respect to the phosphor, different electrode and electrical designs, and others.

In many embodiments of the present invention the attachment interface between the phosphor and the common support member must be designed and processed with care. The thermal impedance of this attachment joint should be minimized using a suitable attaching material, interface geometry, and attachment process practices for a thermal impedance sufficiently low to allow the heat dissipation. Moreover, the attachment interface may be designed for an increased reflectivity to maximize the useful white light exiting the emission surface of the phosphor. Examples include AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxcm whereas pressureless sintered Ag can have a thermal conductivity of about 125 W/(m·K) and electrical conductivity of about 4 micro-ohmxem, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. The joint could also be formed from thermally conductive glues, thermal epoxies, and other materials. The common support member with the laser and phosphor material is configured to provide thermal impedance of less than 10 degrees Celsius per watt or less than 5 degrees Celsius per watt of dissipated power characterizing a thermal path from the laser device to a heat sink. The support member is comprised of a thermally conductive material such as copper, copper tungsten, aluminum, SiC, sapphire, AlN, or other metals, ceramics, or semiconductors. The side-pumped transmissive apparatus has a form factor characterized by a length, a width, and a height. In an example, the height is characterized by a dimension of less than 25 mm and greater than 0.5 mm, although there may be variations.

To improve the efficiency of the integrated white light source, measures can be taken to minimize the amount of light exiting from the first surface wherein the laser excitation light is incident on the phosphor and maximize the light exiting the second primary white light emission side of the phosphor where the useful white light exits. Such measures can include the use of filters, spectrally selective reflectors, conventional mirrors, spatial mirrors, polarization based filters, holographic elements, or coating layers, but can be others.

In one example for a transmissive mode phosphor, a filter is positioned on the backside of the phosphor to reflect the backward propagating yellow emission toward the front of the phosphor where it has another opportunity to exit the primary emitting surface into useful white light. In this configuration the reflector would have to be designed to not block the blue excitation light from the laser. The reflector could be configured from the spectrally selective distributed Bragg reflector (DBR) mirror comprised of 2 or more alternating layers with different refractive indices designed to reflect yellow light over a wide range of angles. The DBR could be deposited directly on the phosphor using techniques such as e-beam deposition, sputter deposition, or thermal evaporation. Alternatively, the DBR could be in the form of a plate-like element that is applied to the phosphor. Since in a typical white light source configured from a mixing of yellow and blue emission the yellow emission comprised about 70% of the energy, this approach of reflecting the yellow light may be a sufficient measure in many applications. Of course, there can be additional variations, modifications, and alternatives.

In another example for a transmissive mode phosphor, a filter system is positioned on the backside of the phosphor to reflect the backward propagating yellow emission and the scattered blue excitation light back toward the front of the phosphor where it has another opportunity to exit the primary emitting surface into useful white light. The challenge of this configuration is to allow the forward propagating blue pump excitation light to pass through the filter without allowing the scattered backward propagating blue light to pass. One approach to overcoming this challenge is deploying a filter designed for incident angular reflectivity dependence and configuring the laser at an incident angle wherein the reflectivity is a minimum such as a normal incidence. Again, in this configuration the reflector could be configured from DBR mirrors such that one DBR mirror pair would reflect yellow and a second DBR pair would serve to reflect the blue light with the determined angular dependence. The DBR could be deposited directly on the phosphor using techniques such as e-beam deposition, sputter deposition, or thermal evaporation. Alternatively, the DBR could be in the form of a plate-like element that is applied to the phosphor. Of course, there can be additional variations, modifications, and alternatives.

FIG. 9 presents a schematic diagram illustrating an alternative transmissive embodiment of a CPoS integrated white light source according to the present invention. In this embodiment the gallium and nitrogen containing lift-off and transfer technique is deployed to fabricate a very small and compact submount member with the laser diode chip formed from transferred epitaxy layers. The laser-based CPoS white light device is comprised of submount material 801 that serves as the common support member configured to act as an intermediate material between a laser diode 802 formed in transferred gallium and nitrogen containing epitaxial layers and a final mounting surface and as an intermediate material between the phosphor plate material 806 and a final mounting surface 807. The laser diode 802 or CoS submount 801 is configured with electrodes 803 and 804 that may be formed with deposited metal layers and combination of metal layers including, but not limited to Au, Pd, Pt, Ni, Al, titanium, or others. The laser beam output excites a phosphor plate 806 positioned in front of the output laser facet. In this embodiment, the phosphor plate 806 is coated with a material 808 configured to increase the efficiency of the white source such that more of the useful white light escapes from the primary emitting surface of the phosphor plate 806. In this embodiment, the coating 808 is configured to increase the reflectivity of yellow and possibly blue emission to reflect the light back toward the front emitting surface. The phosphor plate is attached to the submount on a ledge 807 or recessed region. The electrodes 803 and 804 are configured for an electrical connection to an external power source such as a laser driver, a current source, or a voltage source. Wirebonds can be formed on the electrodes to couple electrical power to the laser diode device to generate a laser beam output from the laser diode. Of course, this is merely an example of a configuration and there could be many variants on this embodiment including but not limited to different shape phosphors, different geometrical designs of the submount or common support member, different orientations of the laser output beam with respect to the phosphor, different electrode and electrical designs, and others.

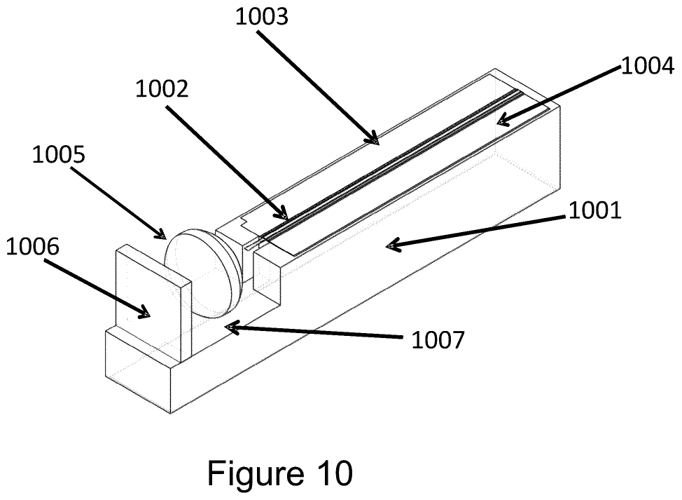

FIG. 10 presents a schematic diagram illustrating a transmissive phosphor embodiment of a CPoS integrated white light source including free-space optics to collimate and shape the laser beam for incidence on the phosphor according to the present invention. In this embodiment the gallium and nitrogen containing lift-off and transfer technique is deployed to fabricate a very small and compact submount member with the laser diode chip formed from transferred epitaxy layers. Of course, a conventional chip on submount could be used for this integrated free-space optic embodiment. The laser-based CPOS white light device is comprised of submount material 1001 that serves as the common support member configured to act as an intermediate material between a laser diode 1002 formed in transferred gallium and nitrogen containing epitaxial layers and a final mounting surface and as an intermediate material between the phosphor plate material 1005 and a final mounting surface. The laser diode 1002 and/or submount 1001 is configured with electrodes 1003 and 1004 that may be formed with deposited metal layers and combination of metal layers including, but not limited to Au, Pd, Pt, Ni, Al, titanium, or others. The laser beam output is coupled into an aspheric lens 1005 for collimation and beam shaping to create a more circular beam, which then excites a phosphor plate 1006 positioned in front of aspheric lens 1005. The phosphor plate 1006 is attached to the submount on a ledge 1007 or recessed region. The electrodes 1003 and 1004 are configured for an electrical connection to an external power source such as a laser driver, a current source, or a voltage source. Wirebonds can be formed on the electrodes to couple electrical power to the laser diode device to generate a laser beam output from the laser diode. Of course, this is merely an example of a configuration and there could be many variants on this embodiment including but not limited to different shape phosphors, different geometrical designs of the submount or common support member, different orientations of the laser output beam with respect to the phosphor, different electrode and electrical designs, and others.

In an alternative preferred embodiment, beam shaping can achieved by tilting the phosphor excitation surface with respect the laser diode aperture and positioning the laser diode at a designed distance from the phosphor to exploit the beam divergence properties of the laser diode and achieve the desired spot size. This “optics-less” beam shaping embodiment is advantageous over embodiments where optical elements are introduced for beam shaping and collimation. These advantages of this embodiment for the white light source apparatus include a simplified design, a lower cost bill of materials, a lower cost assembly process, and potentially a more compact white light source. In one embodiment, the incident angle from the laser to the phosphor is optimized to achieve a desired beam shape on the phosphor.

In another specific preferred embodiment of the CPOS white light source, the present invention is configured for a reflective mode phosphor operation. In one example the excitation laser beam enters the phosphor through the same primary surface as the useful white light is emitted from. That is, operated in reflective mode the phosphor could have a first primary surface configured for both receiving the incident excitation laser beam and emitting useful white light. In this configuration, the phosphor is positioned in front of the laser facet that outputs the laser beam, wherein both the laser and the phosphor are configured on a support member. The gallium and nitrogen containing laser diode is configured with a cavity that has a length greater than 100 μm, greater than 500 μm, greater than 1000 μm, or greater than 1500 μm long and a width greater than 1 μm, greater than 10 μm, greater than 20 μm, greater than 30 μm, or greater than 45 μm. The cavity is configured with a front facets and back facet on the end wherein the front facet comprises the output facet and emits the laser beam incident on the phosphor. The front facet can be configured with an anti-reflective coating to decrease the reflectivity or no coating at all thereby allowing radiation to pass through the mirror without excessive reflectivity. In some cases, the coating may be configured to slightly increase the reflectivity. Since no laser beam is to be emitted from the back end of the cavity member, the back facet or mirror is configured to reflect the radiation back into the cavity. For example, the back facet includes highly reflective coating with a reflectivity greater than 85% or 95%. In one example, the phosphor can be comprised of Ce doped YAG and emits yellow emission. The phosphor may be a ceramic phosphor and could be a single crystal phosphor. The phosphor is preferably shaped as a substantially flat member such as a plate or a sheet with a shape such as a square, rectangle, polygon, circle, or ellipse, and is characterized by a thickness. In a preferred embodiment the length, width, and or diameter dimensions of the large surface area of the phosphor are larger than the thickness of the phosphor. For example, the diameter, length, and/or width dimensions may be 2× greater than the thickness, 5× greater than the thickness, 10× greater than the thickness, or 50× greater than the thickness. Specifically, the phosphor plate may be configured as a circle with a diameter of greater than 50 μm, greater than 100 μm, greater than 200 μm, greater than 500 μm, greater than 1 mm, or greater than 10 mm and a thickness of less than 500 μm, less than 200 μm, less than 100 μm or less than 50 μm. A key benefit to a reflective mode phosphor is the ability to configure it for excellent heat dissipation since the backside of surface of the phosphor can be directly heat-sunk to the common support member or intermediate submount member. Since the phosphor is preferably thin, the thermal path is short and can rapidly travel to the support member. In alternative or the same embodiments a YAG:Ce can be configured to emit a green emission. In yet alternative or the same embodiments the YAG can be doped with Eu to emit a red emission. In alternative embodiments, silicon nitrides or aluminum-oxi-nitrides can be used as the crystal host materials for red, green, yellow, or blue emissions.

In one example of the reflective mode CPOS white light source embodiment of this invention optical coatings, material selections, or special design considerations are taken to improve the efficiency by maximizing the amount of light exiting the primary surface of the phosphor. In one example, the backside of the phosphor may be coated with reflective layers or have reflective materials positioned on the back surface of the phosphor adjacent to the primary emission surface. The reflective layers, coatings, or materials help to reflect the light that hits the back surface of the phosphor such that the light will bounce and exit through the primary surface where the useful light is captured. In one example, a coating configured to increase the reflectivity for yellow light and blue light is applied to the phosphor prior to attaching the phosphor to the common support member. Such coatings could be comprised of metal layers such as silver or aluminum, or others such as gold, which would offer good thermal conductivity and good reflectance or could be comprised of dielectric layers configured as single layers, multi layers, or DBR stacks, but could be others. In another example, a reflective material is used as a bonding medium that attaches the phosphor to the support member or to an intermediate submount member. Examples of reflective materials include reflective solders like AuSn, SnAgC(SAC), or Pb containing phosphors, or reflective glues, but could be others. With respect to attaching the phosphor to the common support member, thermal impedance is a key consideration. The thermal impedance of this attachment joint should be minimized using the best attaching material, interface geometry, and attachment process practices for the lowest thermal impedance with sufficient reflectivity. Examples include AuSn solders, SAC solders, Pb containing solders, indium, and other solders. In an alternative approach sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxem. Due to the extreme change in melt temperature from paste to sintered form, (260° C.-900° C.), processes can avoid thermal load restrictions on downstream processes, allowing completed devices to have very good and consistent bonds throughout. The joint could also be formed from thermally conductive glues, thermal epoxies such as silver epoxy, thermal adhesives, and other materials. Alternatively, the joint could be formed from a metal-metal bond such as an Au—Au bond. The common support member with the laser and phosphor material is configured to provide thermal impedance of less than 10 degrees Celsius per watt or less than 5 degrees Celsius per watt of dissipated power characterizing a thermal path from the laser device to a heat sink. The support member is comprised of a thermally conductive material such as copper, aluminum, SiC, sapphire, AlN, or other metals, ceramics, or semiconductors. The reflective mode white light source apparatus has a form factor characterized by a length, a width, and a height. In an example, the height is characterized by a dimension of less than 25 mm and greater than 0.5 mm, although there may be variations. In an alternative example, the height is characterized by a dimension of less than 12.5 mm, and greater than 0.5 mm, although there may be variations. In yet an alternative example, the length and width are characterized by a dimension of less than 30 mm, less than 15 mm, or less than 5 mm, although there may be variations.

The reflective mode CPoS white light source embodiment of this invention is configured with the phosphor member attached to the common support member with the large primary surface configured for receiving laser excitation light and emitting useful white light positioned at an angle normal (about 90 degrees) or off-normal (about 0 degrees to about 89 degrees) to the axis of the laser diode output beam functioning to excite the phosphor. That is, the laser output beam is pointing toward the phosphor's emission surface at an angle of between 0 and 90 degrees, wherein 90 degrees (orthogonal) is considered normal incidence. The inherent geometry of this configuration wherein the laser beam is directed away from or in an opposite direction that the useful white light will exit the phosphor toward the outside world is ideal for safety. As a result of this geometry, if the phosphor gets damaged or removed during operation or from tampering, the laser beam would not be directed to the outside world where it could be harmful. Instead, the laser beam would be incident on the backing surface where the phosphor was attached. With proper design of this backing surface the laser beam can be scattered, absorbed, or directed away from the outside world instead of exiting the white light source and into the surrounding environment.

In one embodiment of this reflective mode CPOS white light source the laser beam is configured normal to the primary phosphor emission surface. In this configuration the laser diode would be positioned in front of the primary emission surface of the phosphor where it could impede the useful white light emitted from the phosphor. This could create losses in or inefficiencies of the white light device and would lead to difficulty in efficiently capturing all white light emitted from the phosphor. Such optics and reflectors include, but are not limited to, aspheric lenses or parabolic reflectors. To overcome the challenges of normal incident reflective mode phosphor excitation, in a preferable embodiment the laser beam would be configured with an incident angle that is off-axis to the phosphor such that it hits the phosphor surface at an angle of between 0 and 89 degrees or at a “grazing” angle. In this preferable embodiment the laser diode device is positioned adjacent to or to the side of the phosphor instead of in front of the phosphor where it will not substantially block or impede the emitted white light, and importantly, allow for optics such as collimating lenses or reflectors to access the useful light and project it to the application. Additionally, in this configuration the built-in safety feature is more optimal than in the normal incidence configuration since when incident at an angle in the case of phosphor damage or removal the incident laser beam would not reflect directly off the back surface of the support member where the phosphor was attached. By hitting the surface at an off-angle or a grazing angle any potential reflected components of the beam can be directed to stay within the apparatus and not exit the outside environment where it can be a hazard to human beings, animals, and the environment.

In some configurations the top primary surface of the phosphor wherein the laser excitation beam is incident is configured for a reduced reflectivity to the blue or violet excitation beam wavelength and/or the phosphor emission wavelength such as a yellow wavelength. The reduced reflectivity can be achieved with an optical coating of the phosphor using dielectric layers, a shaping of the phosphor surface, and/or roughening of the phosphor surface, or other techniques. In some examples the laser beam incident angle is configured at or near Brewster's angle, wherein the light with a particular polarization mode is perfectly transmitted through the primary surface of the phosphor. Due to the divergence of the laser resulting in a variation of incident angles for the plane waves within the beam a perfect transmission may be challenging, but ideally a substantial fraction of the light incident on the phosphor could be at or near Brewster's angle. For example, a YAG or LuAG phosphor may have a refractive index of about 1.8 in the violet and blue wavelength range. With the Brewster angle, OB, given as arctan (n₂/n₁), where n₁ is the index of air and n₂ is the index of the phosphor, would be about 61 degrees [or about 55 to 65 degrees], off of the axis of normal incidence. Or alternatively, about 29 degrees [or about 25 to 35 degrees] rotated from the axis parallel to the phosphor surface.

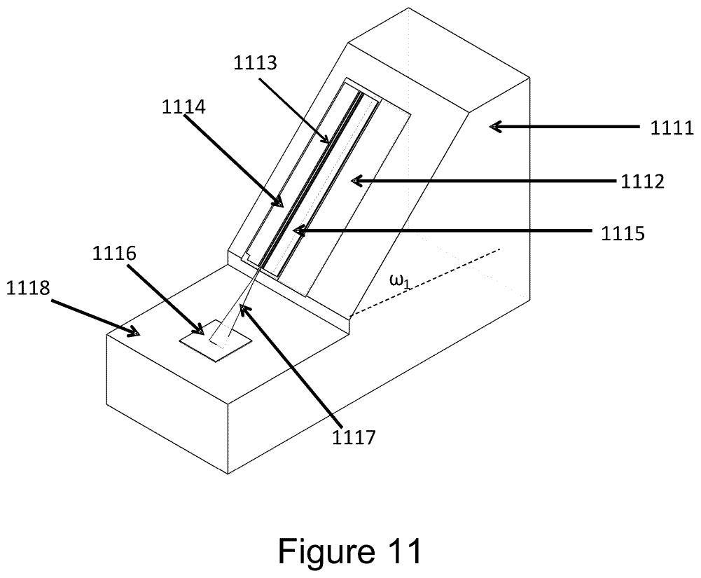

FIG. 11 presents a schematic diagram illustrating an off-axis reflective mode embodiment of a CPoS integrated white light source according to the present invention. In this embodiment the gallium and nitrogen containing lift-off and transfer technique is deployed to fabricate a very small and compact submount member with the laser diode chip formed from transferred epitaxy layers. Further, in this example the phosphor is tilted with respect to the fast axis of the laser beam at an angle ω₁. The laser-based CPOS white light device is comprised of a common support member 1111 that serves as the common support member configured to act as an intermediate material between a laser diode or laser diode CoS 1112 formed in transferred gallium and nitrogen containing epitaxial layers 1113 and a final mounting surface and as an intermediate material between the phosphor plate material 1116 and a final mounting surface. The laser diode or CoS 1112 is configured with electrodes 1114 and 1115 that may be formed with deposited metal layers and combination of metal layers including, but not limited to Au, Pd, Pt, Ni, Al, titanium, or others. A laser beam 1117 excites a phosphor plate 1116 positioned in front of the output laser facet. The phosphor plate 1116 is attached to the common support member on a flat surface 1118. The electrodes 1114 and 1115 are configured for an electrical connection to an external power source such as a laser driver, a current source, or a voltage source. Wirebonds can be formed on the electrodes to couple electrical power to the laser diode device 1112 to generate the laser beam 1117 output from the laser diode and incident on the phosphor 1116. Of course, this is merely an example of a configuration and there could be many variants on this embodiment including but not limited to different shape phosphors, different geometrical designs of the submount or common support member, different orientations of the laser output beam with respect to the phosphor, different electrode and electrical designs, and others.

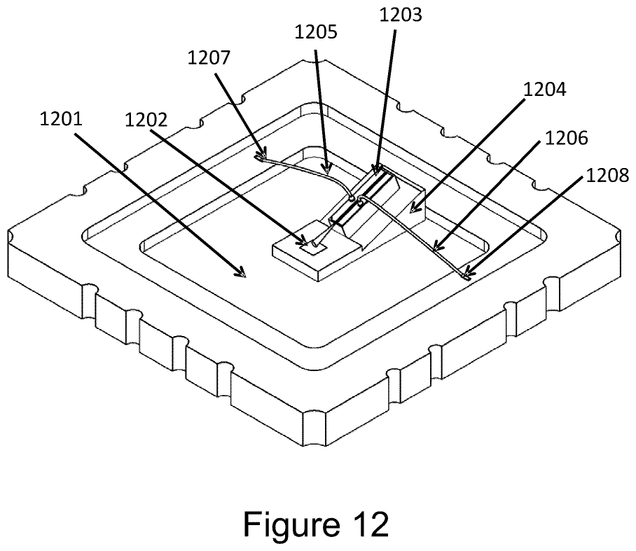

An example of a packaged CPoS white light source according to the present invention is provided in a reflective mode white light source configured in a surface mount device (SMD) type package. FIG. 12 is a simplified diagram illustrating a reflective mode phosphor integrated laser-based white light source mounted in a surface mount package according to an embodiment of the present invention. In this example, a reflective mode white light source is configured in a surface mount device (SMD) type package. The example SMD package has a base member 1201 with the reflective mode phosphor member 1202 mounted on a support member or on a base member. The laser diode device 1203 may be mounted on a support member 1204 or a base member. The support member and base members are configured to conduct heat away from the phosphor member and laser diode members. The base member is comprised of a thermally conductive material such as copper, copper tungsten, aluminum, SiC, steel, diamond, composite diamond, AlN, sapphire, or other metals, ceramics, or semiconductors. The mounting to the base member can be accomplished using a soldering or gluing technique such as using AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxcm whereas pressureless sintered Ag can have a thermal conductivity of about 125 W/(m·K) and electrical conductivity of about 4 micro-ohmxem, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. . . . The mounting joint could also be formed from thermally conductive glues, thermal epoxies such as silver epoxy, and other materials. Electrical connections from the p-electrode and n-electrode of the laser diode are made to using wirebonds 1205 and 1206 to internal feedthroughs 1207 and 1208. The feedthroughs are electrically coupled to external leads. The external leads can be electrically coupled to a power source to electrify the white light source and generate white light emission. The top surface of the base member 1201 may be comprised of, coated with, or filled with a reflective layer to prevent or mitigate any losses relating from downward directed or reflected light. Moreover, all surfaces within the package including the laser diode member and submount member may be enhanced for increased reflectivity to help improve the useful white light output. In this configuration the white light source is not capped or sealed such that is exposed to the open environment. In some examples of this embodiment of the integrated white light source apparatus, an electrostatic discharge (ESD) protection element such as a transient voltage suppression (TVS) element is included. Of course, FIG. 12 is merely an example and is intended to illustrate one possible simple configuration of a surface mount packaged white light source. Specifically, since surface mount type packages are widely popular for LEDs and other devices and are available off the shelf they could be one option for a low cost and highly adaptable solution.

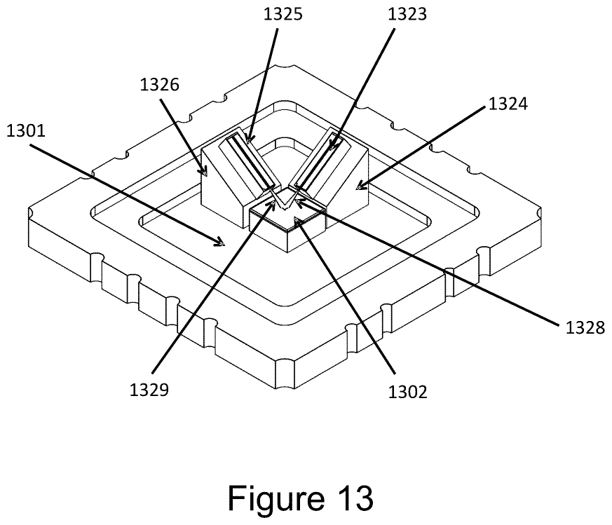

An alternative example of a packaged white light source including 2 laser diode chips according to the present invention is provided in the schematic diagram of FIG. 13. In this example, a reflective mode white light source is configured in a surface mount device (SMD) type package. The example SMD package has a base member 1301 with the reflective mode phosphor member 1302 mounted on a support member or on a base member. A first laser diode device 1323 may be mounted on a first support member 1324 or a base member. A second laser diode device 1325 may be mounted on a second support member 1326 or a base member. The first and second support members and base members are configured to conduct heat away from the phosphor member 1302 and laser diode members 1323 and 1325. The base member is comprised of a thermally conductive material such as copper, copper tungsten, aluminum, alumina, SiC, steel, diamond, composite diamond, AlN, sapphire, or other metals, ceramics, or semiconductors. The mounting to the base member can be accomplished using a soldering or gluing technique such as using AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. The mounting joint could also be formed from thermally conductive glues, thermal epoxies such as silver epoxy, and other materials. Electrical connections from the p-electrode and n-electrode of the laser diodes can be made to using wirebonds to internal feedthroughs. The feedthroughs are electrically coupled to external leads. The external leads can be electrically coupled to a power source to electrify the laser diode sources to emit a first laser beam 1328 from the first laser diode device 1323 and a second laser beam 1329 from a second laser diode device 1325. The laser beams are incident on the phosphor member 1302 to create an excitation spot and a white light emission. The laser beams are preferably overlapped on the phosphor 1302 to create an optimized geometry and/or size excitation spot. For example, in the example according to FIG. 13 the laser beams from the first and second laser diodes are rotated by 90 degrees with respect to each other such that the slow axis of the first laser beam is aligned with the fast axis of the second laser beam. The top surface of the base member 1301 may be comprised of, coated with, or filled with a reflective layer to prevent or mitigate any losses relating from downward directed or reflected light. Moreover, all surfaces within the package including the laser diode member and submount member may be enhanced for increased reflectivity to help improve the useful white light output. In this configuration the white light source is not capped or sealed such that is exposed to the open environment. In some examples of this embodiment of the integrated white light source apparatus, an electrostatic discharge (ESD) protection element such as a transient voltage suppression (TVS) element is included. Of course, FIG. 13 is merely an example and is intended to illustrate one possible simple configuration of a surface mount packaged white light source. Specifically, since surface mount type packages are widely popular for LEDs and other devices and are available off the shelves they could be one option for a low cost and highly adaptable solution.

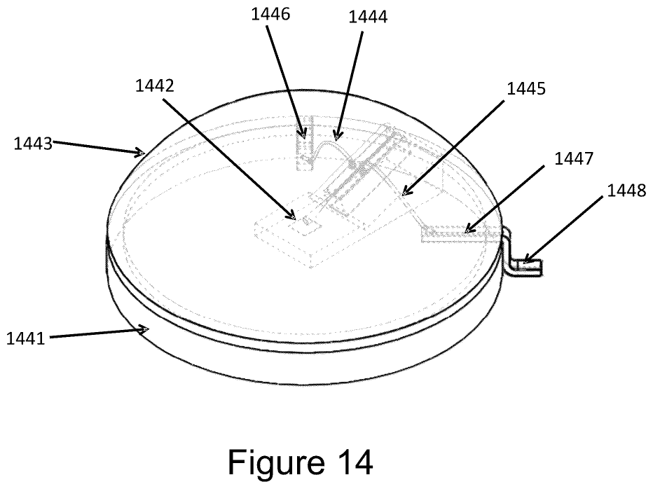

FIG. 14 is a schematic illustration of the CPoS white light source configured in a SMD type package, but with an additional cap member to form a seal around the white light source. As seen in FIG. 14, the SMD type package has a base member 1441 with the white light source 1442 mounted to the base. The mounting to the base can be accomplished using a soldering or gluing technique such as using AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxem, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. Overlying the white light source is a cap member 1443, which is attached to the base member around the peripheral. In an example, the attachment can be a soldered attachment, a brazed attachment, a welded attachment, or a glued attachment to the base member. The cap member 1443 has at least a transparent window region and in preferred embodiments would be primarily comprised of a transparent window region such as the transparent dome cap illustrated in FIG. 14. The transparent material can be a glass, a quartz, sapphire, silicon carbide, diamond, plastic, or any suitable transparent material. The sealing type can be an environmental seal or a hermetic seal, and in an example the sealed package is backfilled with a nitrogen gas or a combination of a nitrogen gas and an oxygen gas. Electrical connections from the p-electrode and n-electrode of the laser diode are made using wire bonds 1444 and 1445. The wirebonds connect the electrode to electrical feedthroughs 1446 and 1447 that are electrically connected to external leads such as 1448 on the outside of the sealed SMD package. The leads are then electrically coupled to a power source to electrify the white light source and generate white light emission. In some embodiments, a lens or other type of optical element to shape, direct, or collimate the white light is included directly in the cap member. Of course, the example in FIG. 14 is merely an example and is intended to illustrate one possible configuration of sealing a white light source. Specifically, since SMD type packages are easily hermetically sealed, this embodiment may be suitable for applications where hermetic seals are needed.

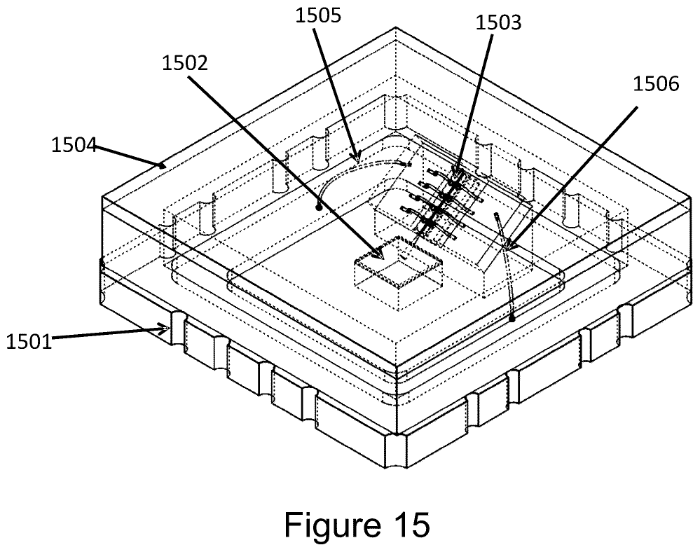

FIG. 15 is a schematic illustration of the white light source configured in a SMD type package, but with an additional cap member to form a seal around the white light source. As seen in FIG. 15, the SMD type package has a base member 1501 with the white light source comprised of a reflective mode phosphor member 1502 and a laser diode member 1503 mounted to submount members or the base member 1501. The mounting to submount and/or the base member 1501 can be accomplished using a soldering or gluing technique such as using AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxcm whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. Overlying the white light source is a cap member 1504, which is attached to the base member around the sides. In an example, the attachment can be a soldered attachment, a brazed attachment, a welded attachment, or a glued attachment to the base member. The cap member 1504 has at least a transparent window region and in preferred embodiments would be primarily comprised of a transparent window region such as the transparent flat cap member 1504 illustrated in FIG. 15. The transparent material can be a glass, a quartz, sapphire, silicon carbide, diamond, plastic, or any suitable transparent material. The sealing type can be an environmental seal or a hermetic seal, and in an example the sealed package is backfilled with a nitrogen gas or a combination of a nitrogen gas and an oxygen gas. Electrical connections from the p-electrode and n-electrode of the laser diode are made using wire bonds 1505 and 1506. The wirebonds connect the electrode to electrical feedthroughs that are electrically connected to external leads on the outside of the sealed SMD package. The leads are electrically coupled to a power source to electrify the white light source and generate white light emission. In some embodiments, a lens or other type of optical element to shape, direct, or collimate the white light is included directly in the cap member. Of course, the example in FIG. 15 is merely an example and is intended to illustrate one possible configuration of sealing a white light source. Specifically, since SMD type packages are easily hermetically sealed, this embodiment may be suitable for applications where hermetic seals are needed.

Of course, a suitable assembly process is required for the fabrication of integrated laser-based white light sources as shown in FIG. 15 and other embodiments according to the present invention. In many embodiments, assembly processes suitable for a such a device would follow standard semiconductor and LED assembly processes as they are today. As an example, a general assembly process would follow the subsequent steps:
I) The laser is attached to heat a conducting member such as a first submount member and optionally a second submount member, or a second and a third submount member
II) The composite laser and heat conducting member are attached to common support member such as the package member [e.g. SMD package], or substrate member.
III) The phosphor is attached to the common support member such as a package member [e.g. SMD] or a substrate member.
IV) An ESD protection device [e.g. TVS] or other peripheral component is attached to a package member, submount member, or substrate member.
V) The subcomponents that require electrical connection to package are wirebonded to feedthroughs.
VI) An operation verification test is performed.
VII) The frame assembly is attached to package or substrate or the frame+lid assembly is attached to the package or substrate.
VIII) The completed SMD package is attached to a next level board such as an MCPCB, FR4, or suitable carrier substrate.

In step I the laser device would be attached to the heat conducting member by a selection of various materials to provide mechanical stability, alignment and thermal conductivity to suit the particular requirements of the product application. These materials choices and processes could include but are not limited to a Au—Au interconnection, a standard Pb free solder attach via dispense or stencil application or the use of preform attach, a standard Pb containing solder attach via dispense or stencil application or the use of preform attach, a die attach epoxies using dispense and screening application, or a sintered silver solder using dispense, stencil or preform.

In step II the combined member consisting of a laser and heat conducting member would then be presented with a similar set of materials choices for its attachment into the package or onto the substrate. The materials choices and processes selection would be as follows. Depending on the materials selection, the process flow could be adjusted such that each subsequent step in the process puts a lower temperature excursion on the device than the previous steps. In this way, the early joints or connections do not experience a secondary reflow. A typical pick and place style operation either with in situ heating/pressure or post reflow would be utilized for this attach process. These materials choices and processes could include but are not limited to a Au—Au interconnection, a standard Pb free solder attach via dispense or stencil application or the use of preform attach, a standard Pb containing solder attach via dispense or stencil application or the use of preform attach, a die attach epoxies using dispense and screening application, or a sintered silver solder using dispense, stencil or preform.

In step III the phosphor subcomponent attach would depend on the structure and design of the subcomponent. For a single piece, solid state object. The phosphor could be handled by a pick and place operation, as one would handle an LED attach today. This requires that the base of the phosphor subcomponent be prepared for standard metallized attaches would could utilize the following materials. These materials choices and processes could include but are not limited to a Au—Au interconnection, a standard Pb free solder attach via dispense or stencil application or the use of preform attach, a standard Pb containing solder attach via dispense or stencil application or the use of preform attach, a die attach epoxies using dispense and screening application, or a sintered silver solder using dispense, stencil or preform.

In the case of a less rigid phosphor subcomponent, which utilizes phosphor powders and binders like silicones. The method of attach would simply be the adhesion of the phosphor and silicone slurry to the package surface during the silicone drying steps. Methods of application of a phosphor slurry would include but not limited to a dispense and cure process, a spray and cure process, an electrophoretic deposition with silicone dispense and cure process, a mechanical coining of powder/embedding into the surface of the package metallization process, a sedimentation deposition process, or a jet dispense and cure process.

In step IV an ESD or other peripheral component attach process could follow industry standard attach protocols which would include one or more of a solder dispense/stencil or preform attach process, an ESD or peripheral attach via pick and place operation, or a reflow process.

In step V wirebonding of the attached subcomponents would utilize industry standard materials and processes. This would include wire materials selection Al, Cu, Ag and Au. Alternatively ribbon bonding could be employed if necessary or suitable for the application. Normal wirebonding techniques would include ball bonding, wedge bonding and compliant bonding techniques known to the semiconductor industry.

In step VI with device fully connected with subcomponents, an operation verification test could be placed in the assembly process to verify proper operation before committing the final assembly pieces (frame and Lid) to the SMD component. In case of a non-working device, this provides an opportunity to repair the unit before being sealed. This test would consist of a simple electrical turn on for the device to verify proper operation of the laser and possibly a soft ESD test to verify the ESD/TVS component is working. Typical operating values for voltage, current, light output, color, spot size and shape would be used to determine proper operation.

In step VII the frame assembly and attach steps would be used to prepare the device to be sealed from the environment. The frame would be attached to the SMD via a choice of materials depending on the level of sealing required by the device. In one example of sealing materials and processes include a AuSn attach to metalized frame and package surface to provide a true hermetic seal. AuSn dispense, stencil processes would place AuSn in the proper locations on the SMD. This would be followed by a pick and place of the frame onto the wet AuSn and followed by a reflow step. In a second example of sealing materials and processes include epoxy materials are used if the hermeticity and gas leak requirements are sufficient for product use conditions. Epoxy materials would typically be stenciled or dispensed followed by a pick and place of the frame and subsequent epoxy cure. In a third example of scaling materials and processes includes indium metal used by placing thin indium wire on the attach surface and applying heat and pressure to the indium using the frame as a pressing member to compress and mechanical attach the Indium to both the SMD and Frame surfaces.

An alternative approach to the frame assembly process would first attach the transparent Lid (typically Glass) to the frame and this combined unit would then be attached to the SMD as described by the methods above otherwise the lid attach separately would follow the same processes and materials choices, but the surfaces would be the top of the frame and the bottom of the lid.

In step VIII the completed SMD attach to next level board would employ industry standard attach methodologies and materials. These materials choices and processes could include but are not limited to a Au—Au interconnection, a standard Pb free solder attach via dispense or stencil application or the use of preform attach, a standard Pb containing solder attach via dispense or stencil application or the use of preform attach, a die attach epoxies using dispense and screening application, or a sintered silver solder using dispense, stencil or preform.

In all embodiments, transmissive and reflective mode, of the integrated CPOS white light source according to the present invention safety features and design considerations can be included. In any laser-induced source, safety is a key aspect. It is critical that the light source cannot be compromised or modified in such a way to create laser diode beam that can be harmful to human beings, animals, or the environment. Thus, the overall design should include safety considerations and features, and in some cases even active components for monitoring. Examples of design considerations and features for safety include positioning the laser beam with respect to the phosphor in a way such that if the phosphor is removed or damaged, the exposed laser beam would not make it to the outside environment in a harmful form such as collimated, coherent beam. More specifically, the white light source is designed such that laser beam is pointing away from the outside environment and toward a surface or feature that will prevent the beam from being reflected to the outside world. In an example of a passive design features for safety include beam dumps and/or absorbing material can be specifically positioned in the location the laser beam would hit in the event of a removed or damaged phosphor.

In one embodiment, an optical beam dump serves as an optical element to absorb the laser beam that could otherwise be dangerous to the outside environment. Design concerns in the beam dump would include the management and reduction of laser beam back reflections and scattering as well as dissipation of heat generated by absorption. Simple solutions where the optical power is not too high, the absorbing material can be as simple as a piece of black velvet or flock paper attached to a backing material with a glue, solder, or other material. In high power applications such as those that would be incorporated into high power laser systems, beam dumps must often incorporate more elaborate features to avoid back-reflection, overheating, or excessive noise. Dumping the laser beam with a simple flat surface could result in unacceptably large amounts of light escaping to the outside world where it could be dangerous to the environment even though the direct reflection is mitigated. One approach to minimize scattering is to use a porous or deep dark cavity material deep lined with an absorbing material to dump the beam.

A commonly available type of beam dump suitable for most medium-power lasers is a cone of aluminum with greater diameter than the beam, anodized to a black color and enclosed in a canister with a black, ribbed interior. Only the point of the cone is exposed to the beam head-on; mostly, incoming light grazes the cone at an angle, which cases performance requirements. Any reflections from this black surface are then absorbed by the canister. The ribs both help to make light less likely to escape, and improve heat transfer to the surrounding air. (https://en.wikipedia.org/wiki/Bcam_dump).

In some embodiments of the present invention a thermal fuse is integrated into the package with the phosphor member. Thermal fuses are simple devices configured to conduct electricity under normal operation and typically consist of a low melting point alloy. In one example, the thermal fuse is comprised of metal material with a low melting point and configured to rapidly heat when irradiated directly or indirectly with the violet or blue laser beam light. The rapid heat rise in the thermal fuse material causes the material to melt, creating a discontinuity in the fuse metal, which opens the electrical conduction pathway and prevents current flow through the fuse.

In this embodiment of the present invention, a thermal fuse is contained within the electrical pathway providing the current input from an external power source to the gain element of the laser diode. The thermal fuse is physically positioned in locations where the output of the violet or blue laser beam would be incident in the case that the phosphor member is comprised, broken, or removed. That is, the thermal fuse is placed in the package where the beam is not expected to be unless an upstream failure in the beam line has occurred. In the case of such an event, the violet or blue laser light would irradiate the fuse material inducing a temperature rise at or above the melting point and hence causing a melting of thermal fuse element. This melting would then open the electrical pathway and break the electrical circuit from the external power supply to the laser diode gain element and thereby shutting the laser device off. In this preferred example, the thermal fuse could cutoff power to the laser without requiring external control mechanisms.

There are numbers of variations on the fusible alloy thermal fuse structure according to the present invention. In another example, one could utilize a tensioned spring which is soldered in place inside a ball of fusible allow. The spring and alloy are provided in the electrical circuit. When the alloy becomes soft enough, the spring pulls free, thereby breaking the circuit connection. In some embodiments the melting point could be suitably chosen to only break connection in the operating device when a sufficiently-high temperature had been met or exceeded.

In some embodiments of this invention, safety features and systems use active components. Example active components include photodetectors/photodiode and thermistors. A photodiode is a semiconductor device that converts light into current wherein a current is generated when light within a certain wavelength range is incident on the photodiode. A small amount of current is also produced when no light is present. Photodiodes may be combined with components such as optical filters to provide a wavelength or polarization selection of the light incident on the detector, built-in lenses to focus the light or manipulate the light incident on the detector, and may have large or small surface areas to select a certain responsivity and/or noise level. The most prevalent photodiode type is based on Si as the optical absorbing material, wherein a depletion region is formed. When a photon is absorbed in this region an electron-hole pair is formed, which results in a photocurrent. The primary parameter defining the sensitivity of a photodiode is its quantum efficiency (QE) which is defined as the percentage of incident photons generating electron-hole pairs which subsequently contribute to the output signal. Quantum efficiencies of about 80% are usual for silicon detectors operating at wavelengths in the 800-900 nm region. The sensitivity of a photodiode may also be expressed in units of amps of photodiode current per watt of incident illumination. This relationship leads to a tendency for responsivity to reduce as the wavelength becomes shorter. For example, at 900 nm, 80% QE represents a responsivity of 0.58 A/W, whereas at 430 nm, the same QE gives only 0.28 A/W. In alternative embodiments, photodiodes based on other materials such as Ge, InGaAs, GaAs, InGaAsP, InGaN, GaN, InP, or other semiconductor-based materials can be used. The photodiode can be a p-n type, a p-i-n type, an avalanche photodiode, a uni-traveling carrier photodiode, a partially depleted photodiode, or other type of diode.

The decreasing responsivity with such shorter wavelengths presents difficulty in achieving a high-performance silicon-based photodiode in the violet or blue wavelength range. To overcome this difficulty blue enhancement and/or filter techniques can be used to improve the responsivity this wavelength range. However, such techniques can lead to increased costs, which may not be compatible with some applications. Several techniques can be used to overcome this challenge including deploying new technologies for blue enhanced silicon photodiodes or using photodiodes based on different material systems such as photodiodes based on GaN/InGaN. In one embodiment an InGaN and/or GaN-containing photodiode is combined with the integrated white light source. In a specific embodiment, the photodiode is integrated with the laser diode either by a monolithic technique or by an integration onto a common submount or support member as the laser diode to form an integrated GaN/InGaN based photodiode.

In another embodiment of this invention to overcome the difficulty of achieving a low cost silicon based photodiode operable with high responsivity in the blue wavelength region, a wavelength converter material such as a phosphor can be used to down convert ultraviolet, violet, or blue laser light to a wavelength more suitable for high-responsivity photo-detection according to the criteria required in an embodiment for this invention. For example, if photodiodes operating in the green, yellow, or red wavelength regime can be lower cost and have a suitable responsivity for the power levels associated with a converted wavelength, the photodiode can be coated with phosphors to convert the laser light to a red, green, or yellow emission. In other embodiments the detectors are not coated, but a converter member such as a phosphor is place in the optical pathway of the laser beam or scattered laser beam light and the photodiode.

Strategically located detectors designed to detect direct blue emission from the laser, scattered blue emission, or phosphor emission such as yellow phosphor emission can be used to detect failures of the phosphor where a blue beam could be exposed or other malfunctions of the white light source. Upon detection of such an event, a close circuit or feedback loop would be configured to cease power supply to the laser diode and effectively turn it off.

As an example, a photodiode can be used to detect phosphor emission could be used to determine if the phosphor emission rapidly reduced, which would indicate that the laser is no longer effectively hitting the phosphor for excitation and could mean that the phosphor was removed or damaged. In another example of active safety features, a blue sensitive photodetector could be positioned to detect reflected or scatter blue emission from the laser diode such that if the phosphor was removed or compromised the amount of blue light detected would rapidly increase and the laser would be shut off by the safety system.

In a preferred embodiment, a InGaN/GaN-based photodiode is integrated with the white light source. The InGaN/GaN-based photodiode can be integrated using a discrete photodiode mounted in the package or can be directly integrated onto a common support member with the laser diode. In a preferable embodiment, the InGaN/GaN-based photodiode can be monolithically integrated with the laser diode.

In yet another example of active safety features a thermistor could be positioned near or under the phosphor material to determine if there was a sudden increase in temperature which may be a result of increased direct irradiation from the blue laser diode indicating a compromised or removed phosphor. Again, in this case the thermistor signal would trip the feedback loop to cease electrical power to the laser diode and shut it off.

In some embodiments additional optical elements are used to recycle reflected or stray excitation light. In one example, a re-imaging optic is used to re-image the reflected laser beam back onto the phosphor and hence re-cycle the reflected light.

In some embodiments of the present invention additional elements can be included within the package member to provide a shield or blocking function to stray or reflected light from the laser diode member. By blocking optical artifacts such as reflected excitation light, phosphor bloom patterns, or the light emitted from the laser diode not in the primary emission beam such as spontaneous light, scattered light, or light escaping a back facet the optical emission from the white light source can be more ideal for integration into lighting systems. Moreover, by blocking such stray light the integrated white light source will be inherently safer. Finally, a shield member can act as an aperture such that white emission from the phosphor member is aperture through a hole in the shield. This aperture feature can form the emission pattern from the white source.

In many applications according to the present invention, the packaged integrated white light source will be attached to a heat sink member. The heat sink is configured to transfer the thermal energy from the packaged white light source to a cooling medium. The cooling medium can be an actively cooled medium such as a thermoelectric cooler or a microchannel cooler, or can be a passively cooled medium such as an air-cooled design with features to maximize surface and increase the interaction with the air such as fins, pillars, posts, sheets, tubes, or other shapes. The heat sink will typically be formed from a metal member, but can be others such as thermally conductive ceramics, semiconductors, or composites.

The heat sink member is configured to transport thermal energy from the packaged laser diode based white light source to a cooling medium. The heat sink member can be comprised of a metal, ceramic, composite, semiconductor, plastic and is preferably comprised of a thermally conductive material. Examples of candidate materials include copper which may have a thermal conductivity of about 400 W/(m·K), aluminum which may have a thermal conductivity of about 200 W/(m·K), 4H—SiC which may have a thermal conductivity of about 370 W/(m·K), 6H—SiC which may have a thermal conductivity of about 490 W/(m·K), AlN which may have a thermal conductivity of about 230 W/(m·K), a synthetic diamond which may have a thermal conductivity of about >1000 W/(m·K), a composite diamond, sapphire, or other metals, ceramics, composites, or semiconductors. The heat sink member may be formed from a metal such as copper, copper tungsten, aluminum, or other by machining, cutting, trimming, or molding.

The attachment joint joining the packaged white light source according to this invention to the heat sink member should be carefully designed and processed to minimize the thermal impedance. Therefore, a suitable attaching material, interface geometry, and attachment process practice must be selected for appropriate thermal impedance with sufficient attachment strength. Examples include AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. The joint could also be formed from thermally conductive glues, thermal epoxies such as silver epoxy, thermal adhesives, and other materials. Alternatively, the joint could be formed from a metal-metal bond such as an Au—Au bond. The common support member with the laser and phosphor material is configured to provide thermal impedance of less than 10 degrees Celsius per watt or less than 5 degrees Celsius per watt of dissipated power characterizing a thermal path from the laser device to a heat sink.

In many embodiments according to the present invention the completed SMD is attached to the next level board would employ industry standard attach methodologies and materials. These materials choices and processes could include but are not limited to a Au—Au interconnection, a standard Pb free solder attach via dispense or stencil application or the use of preform attach, a standard Pb containing solder attach via dispense or stencil application or the use of preform attach, a die attach epoxies using dispense and screening application, or a sintered silver solder using dispense, stencil or preform.

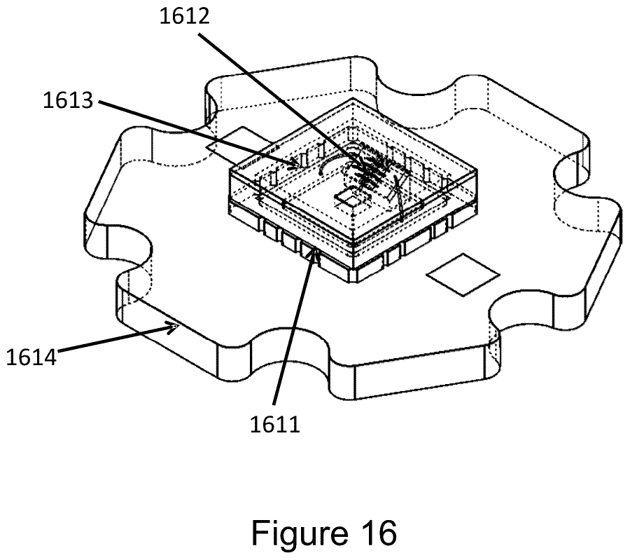

FIG. 16 is a schematic illustration of a white light source configured in a sealed SMD mounted on a board member such as a starboard according to the present invention. The sealed white light source 1612 in an SMD package is similar to that example shown in FIG. 15. As seen in FIG. 16, the SMD type package has a base member 1611 (i.e., the base member 1401 of FIG. 14) with the white light source 1612 mounted to the base and a cap member 1613 providing a seal for the light source 1612. The mounting to the base member 1611 can be accomplished using a soldering or gluing technique such as using AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxem. Due to the extreme change in melt temperature from paste to sintered form, (260° C.-900 xC), processes can avoid thermal load restrictions on downstream processes, allowing completed devices to have very good and consistent bonds throughout. The cap member 1613 has at least a transparent window region. The transparent material can be glass, quartz, sapphire, silicon carbide, diamond, plastic, or any suitable transparent material. The base member 1611 of the SMD package is attached to a starboard member 1614 configured to allow electrical and mechanical mounting of the integrated white light source, provide electrical and mechanical interfaces to the SMD package, and supply the thermal interface to the outside world such as a heat-sink. The heat sink member 1614 can be comprised of a material such as a metal, ceramic, composite, semiconductor, or plastic and is preferably comprised of a thermally conductive material. Examples of candidate materials include aluminum, alumina, copper, copper tungsten, steel, SiC, AlN, diamond, a composite diamond, sapphire, or other materials. Of course, FIG. 16 is merely an example and is intended to illustrate one possible configuration of a white light source according to the present invention mounted on a heat sink. Specifically, the heat sink could include features to help transfer heat such as fins.

In some embodiments of this invention, the CPoS integrated white light source is combined with an optical member to manipulate the generated white light. In an example the white light source could serve in a spot light system such as a flashlight or an automobile headlamp or other light applications where the light must be directed or projected to a specified location or area. As an example, to direct the light it should be collimated such that the photons comprising the white light are propagating parallel to each other along the desired axis of propagation. The degree of collimation depends on the light source and the optics using to collimate the light source. For the highest collimation a perfect point source of light with 4-pi emission and a sub-micron or micron-scale diameter is desirable. In one example, the point source is combined with a parabolic reflector wherein the light source is placed at the focal point of the reflector and the reflector transforms the spherical wave generated by the point source into a collimated beam of plane waves propagating along an axis.

In one embodiment a reflector is coupled to the white light source. Specifically, a parabolic (or paraboloid or paraboloidal) reflector is deployed to project the white light. By positioning the white light source in the focus of a parabolic reflector, the plane waves will be reflected and propagate as a collimated beam along the axis of the parabolic reflector.

In another example a simple singular lens or system of lenses is used to collimate the white light into a projected beam. In a specific example, a single aspheric lens is place in front of the phosphor member emitting white light and configured to collimate the emitted white light. In another embodiment, the lens is configured in the cap of the package containing the integrated white light source. In some embodiments, a lens or other type of optical element to shape, direct, or collimate the white light is included directly in the cap member. In an example the lens is comprised of a transparent material such as glass, SiC, sapphire, quartz, ceramic, composite, or semiconductor.

Such white light collimating optical members can be combined with the white light source at various levels of integration. For example, the collimating optics can reside within the same package as the integrated white light source in a co-packaged configuration. In a further level of integration, the collimating optics can reside on the same submount or support member as the white light source. In another embodiment, the collimating optics can reside outside the package containing the integrated white light source.

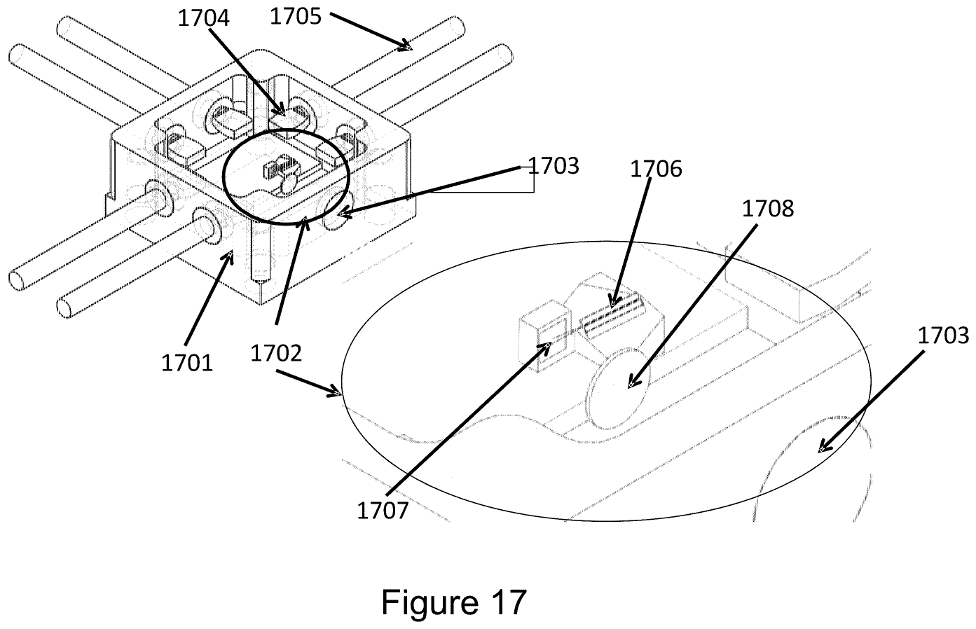

In one embodiment according to the present invention, a reflective mode integrated white light source is configured in a flat type package with a lens member to create a collimated white beam as illustrated in FIG. 17. As seen in FIG. 17, the flat type package has a base or housing member 1701 with a collimated white light source 1702 mounted to the base and configured to create a collimated white beam to exit a window 1703 configured in the side of the base or housing member 1701. The mounting to the base or housing can be accomplished using a soldering or gluing technique such as using AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxem whereas pressureless sintered Ag can have a thermal conductivity of about 125 W/(m·K) and electrical conductivity of about 4 micro-ohmxcm, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. Electrical connections to the white light source 1702 can be made with wire bonds to the feedthroughs 1704 that are electrically coupled to external pins 1705. In this example, the collimated reflective mode white light source 1702 comprises the laser diode 1706, the phosphor wavelength converter 1707 configured to accept a laser beam emitted from the laser diode 1706, and a collimating lens such as an aspheric lens 1708 configured in front of the phosphor 1707 to collect the emitted white light and form a collimated beam. The collimated beam is directed toward the window 1703 formed from a transparent material. The transparent material can be glass, quartz, sapphire, silicon carbide, diamond, plastic, or any suitable transparent material. The external pins 1705 are electrically coupled to a power source to electrify the white light source 1702 and generate white light emission. As seen in the Figure, any number of pins can be included on the flat pack. In this example there are 6 pins and a typical laser diode driver only requires 2 pins, one for the anode and one for the cathode. Thus, the extra pins can be used for additional elements such as safety features like photodiodes or thermistors to monitor and help control temperature. Of course, the example in FIG. 17 is merely an example and is intended to illustrate one possible configuration of scaling a white light source.

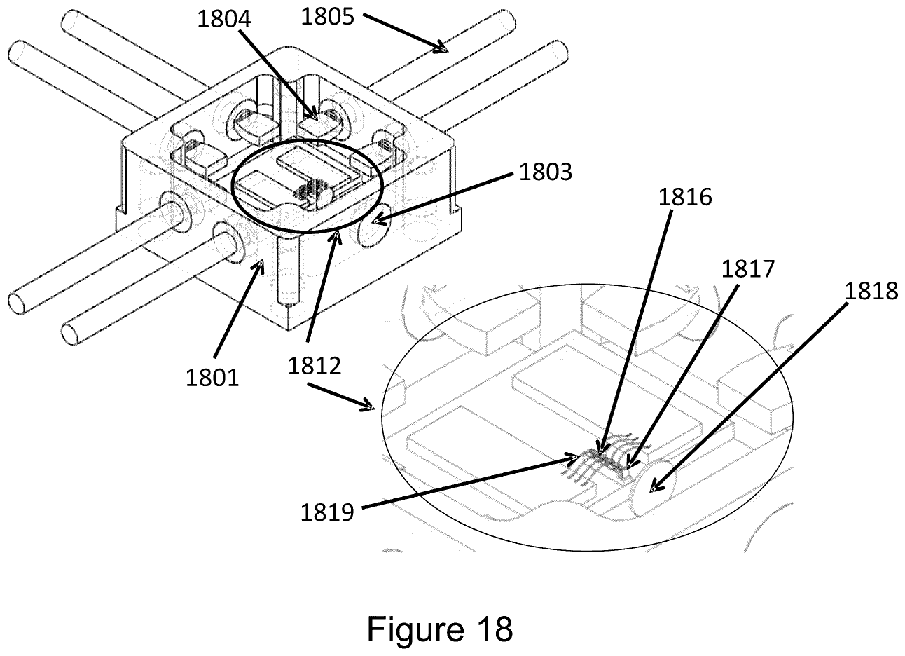

In one embodiment according to the present invention, a transmissive mode integrated white light source is configured in a flat type package with a lens member to create a collimated white beam as illustrated in FIG. 18. As seen in FIG. 18, the flat type package has a base or housing member 1801 with a collimated white light source 1812 mounted to the base member 1801 and configured to create a collimated white beam to exit a window 1803 configured in the side of the base or housing member 1801. The mounting to the base or housing member 1801 can be accomplished using a soldering or gluing technique such as using AuSn solders, SAC solders such as SAC305, lead containing solder, or indium, but can be others. In an alternative embodiment sintered Ag pastes or films can be used for the attach process at the interface. Sintered Ag attach material can be dispensed or deposited using standard processing equipment and cycle temperatures with the added benefit of higher thermal conductivity and improved electrical conductivity. For example, AuSn has a thermal conductivity of about 50 W/(m·K) and electrical conductivity of about 16 micro-ohmxcm whereas pressureless sintered Ag can have a thermal conductivity of about 125 W/(m·K) and electrical conductivity of about 4 micro-ohmxem, or pressured sintered Ag can have a thermal conductivity of about 250 W/(m·K) and electrical conductivity of about 2.5 micro-ohmxcm. Due to the extreme change in melt temperature from paste to sintered form, (260° C.-900° C.), processes can avoid thermal load restrictions on downstream processes, allowing completed devices to have very good and consistent bonds throughout. Electrical connections to the white light source 1812 can be made with wire bonds to the feedthroughs 1804 that are electrically coupled to external pins 1805. In this example, the collimated transmissive mode white light source 1812 comprises the laser diode 1816, the phosphor wavelength converter 1817 configured to accept a laser beam emitted from the laser diode 1816, and a collimating lens such as an aspheric lens 1818 configured in front of the phosphor 1817 to collect the emitted white light and form a collimated beam. The collimated beam is directed toward the window 1803 formed from a transparent material. The transparent material can be glass, quartz, sapphire, silicon carbide, diamond, plastic, or any suitable transparent material. The external pins 1805 are electrically coupled to a power source to electrify the white light source 1812 and generate white light emission. As seen in the FIG. 18, any number of pins can be included on the flat pack. In this example there are 6 pins and a typical laser diode driver only requires 2 pins, one for the anode and one for the cathode. Thus, the extra pins can be used for additional elements such as safety features like photodiodes or thermistors to monitor and help control temperature. Of course, the example in FIG. 18 is merely an example and is intended to illustrate one possible configuration of sealing a white light source.

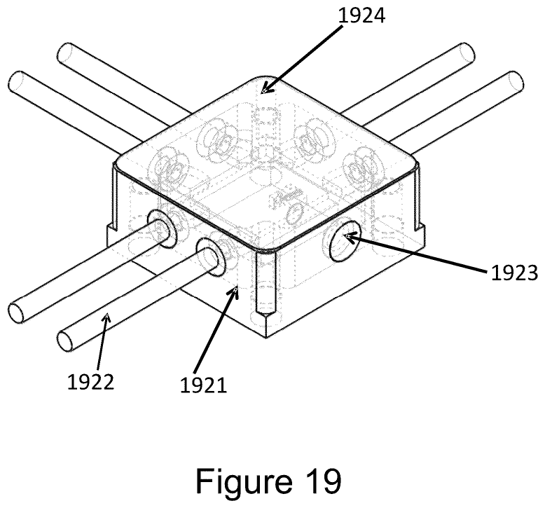

The flat type package examples shown in FIGS. 17 and 18 according to the present invention are illustrated in an unsealed configuration without a lid to show examples of internal configurations. However, flat packages are easily sealed with a lid or cap member. FIG. 19 is an example of a sealed flat package with a collimated white light source inside. As seen in FIG. 19, the flat type package has a base or housing member 1921 with external pins 1922 configured for electrical coupling to internal components such as the white light source, safety features, and thermistors. The sealed flat package is configured with a window 1923 for the collimated white beam to exit and a lid or cap 1924 to form a seal between the external environment and the internal components. The lid or cap can be soldered, brazed, welded, glued to the base, or other. The sealing type can be an environmental seal or a hermetic seal, and in an example the sealed package is backfilled with a nitrogen gas or a combination of a nitrogen gas and an oxygen gas.

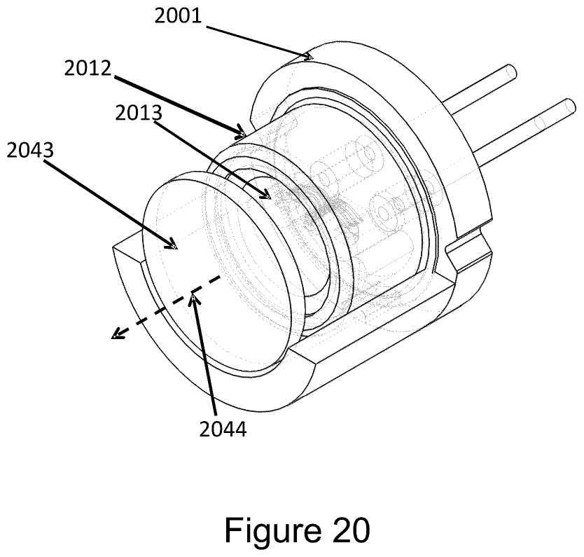

In an alternative embodiment, FIG. 20 provides a schematic illustration of the CPoS white light source configured in a TO-can type package, but with an additional lens member configured to collimate and project the white light. The example configuration for a collimated white light from TO-can type package according to FIG. 20 comprises a TO-can base 2001, a cap 2012 configured with a transparent window region 2013 mounted to the base 2001. The cap 2012 can be soldered, brazed, welded, or glue to the base. An aspheric lens member 2043 configured outside the window region 2013 wherein the lens 2043 functions to capture the emitted white light passing the window, collimate the light, and then project it along the axis 2044. Of course, this is merely an example and is intended to illustrate one possible configuration of combining the integrated white light source according to this invention with a collimation optic. In another example, the collimating lens could be integrated into the window member on the cap or could be included within the package member.

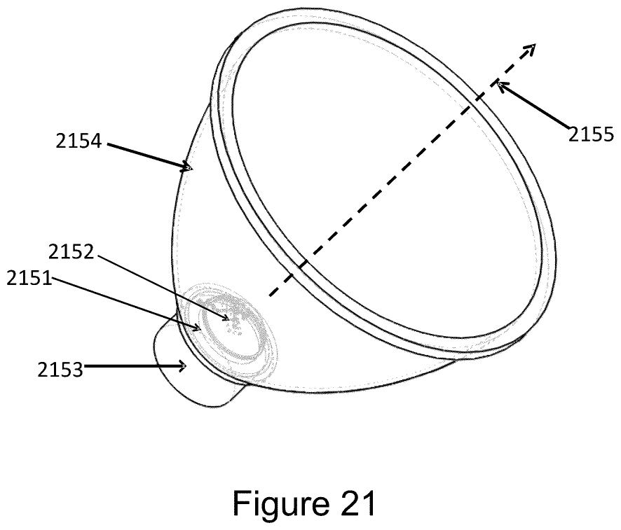

In an alternative embodiment, FIG. 21 provides a schematic illustration of a white light source according to this invention configured in an SMD-type package but with an additional parabolic member configured to collimate and project the white light. The example configuration for a collimated white light from SMD-type package according to FIG. 21 comprises an SMD type package 2151 comprising a based and a cap or window region and the integrated white light source 2152. The SMD package is mounted to a heat-sink member 2153 configured to transport and/or store the heat generated in the SMD package from the laser and phosphor member. A reflector member 2154 such as a parabolic reflector is configured with the white light emitting phosphor member of the white light source at or near the focal point of the parabolic reflector. The parabolic reflector functions to collimate and project the white light along the axis of projection 2155. Of course, this is merely an example and is intended to illustrate one possible configuration of combining the integrated white light source according to this invention with a reflector collimation optic. In another example, the collimating reflector could be integrated into the window member of the cap or could be included within the package member. In a preferred embodiment, the reflector is integrated with or attached to the submount.

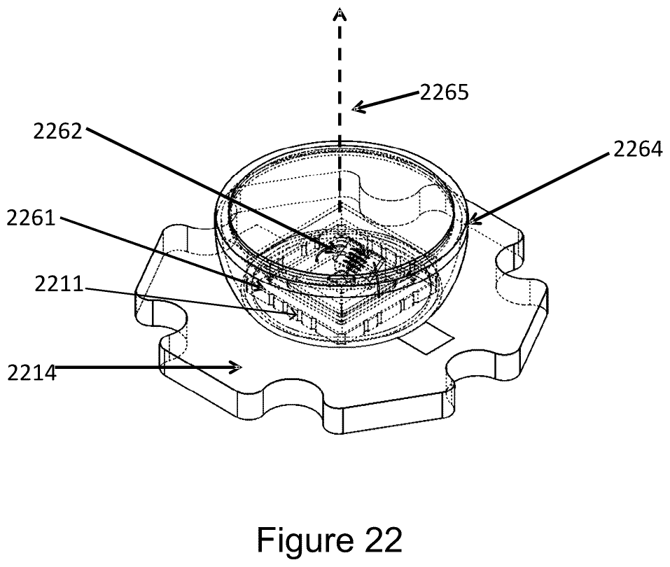

In an alternative embodiment, FIG. 22 provides a schematic illustration of a white light source according to this invention configured in an SMD-type package, but with an additional parabolic reflector member or alternative collimating optic member such as lens or TIR optic configured to collimate and project the white light. The example configuration for a collimated white light from SMD-type package according to FIG. 22 comprises an SMD type package 2261 comprising a based 2211 and a cap or window region and the integrated white laser-based light source 2262. The SMD package 2261 is mounted to a starboard member 2214 configured to allow electrical and mechanical mounting of the integrated white light source, provide electrical and mechanical interfaces to the SMD package 2261, and supply the thermal interface to the outside world such as a heat-sink. A reflector member 2264 such as a parabolic reflector is configured with the white light emitting phosphor member of the white light source at or near the focal point of the parabolic reflector. The parabolic reflector 2264 functions to collimate and project the white light along the axis of projection 2265. Of course, this is merely an example and is intended to illustrate one possible configuration of combining the integrated white light source according to this invention with a reflector collimation optic. In another example, the collimating reflector could be integrated into the window member of the cap or could be included within the package member. The collimating optic could be a lens member, a TIR optic member, a parabolic reflector member, or an alternative collimating technology, or a combination. In an alternative embodiment, the reflector is integrated with or attached to the submount.

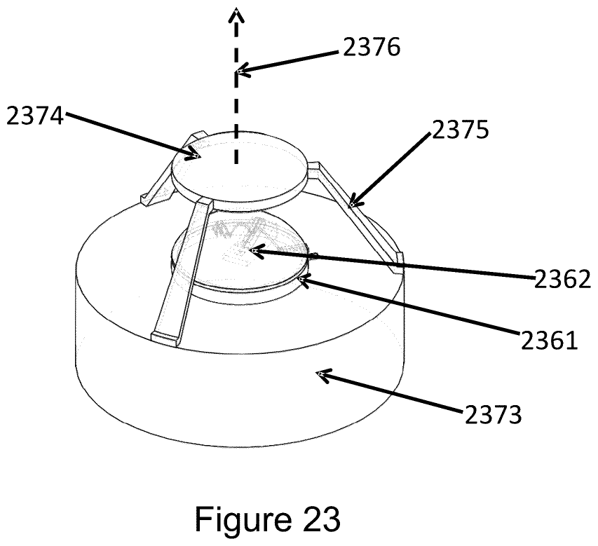

In an alternative embodiment, FIG. 23 provides a schematic illustration of a white light source according to this invention configured in an SMD-type package, but with an additional lens member configured to collimate and project the white light. The example configuration for a collimated white light from SMD-type package according to FIG. 23 comprises an SMD type package 2361 comprising a based and a cap or window region and the integrated white light source 2362. The SMD package 2361 is mounted to a heat-sink member 2373 configured to transport and/or store the heat generated in the SMD package 2361 from the laser and phosphor member. A lens member 2374 such as an aspheric lens is configured with the white light emitting phosphor member of the white light source 2362 to collect and collimate a substantial portion of the emitted white light. The lens member 2374 is supported by support members 2375 to mechanically brace the lens member 2374 in a fixed position with respect to the white light source 2362. The support members 2375 can be comprised of metals, plastics, ceramics, composites, semiconductors or other. The lens member 2374 functions to collimate and project the white light along the axis of projection 2376. Of course, this is merely an example and is intended to illustrate one possible configuration of combining the integrated white light source according to this invention with a reflector collimation optic. In another example, the collimating reflector could be integrated into the window member of the cap or could be included within the package member. In a preferred embodiment, the reflector is integrated with or attached to the submount.

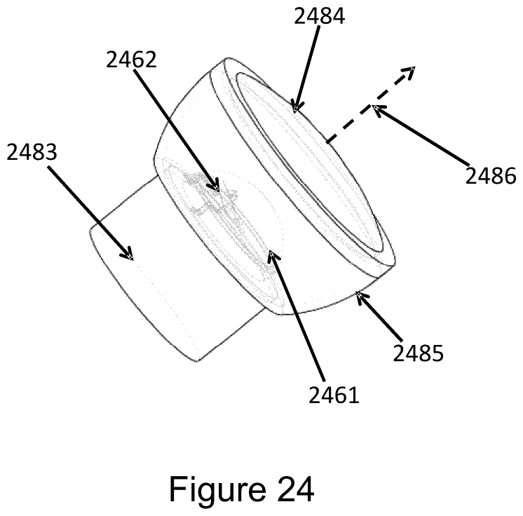

In an embodiment according to the present invention, FIG. 24 provides a schematic illustration of a white light source according to this invention configured in an SMD-type package, but with an additional lens member and reflector member configured to collimate and project the white light. The example configuration for a collimated white light from SMD-type package according to FIG. 24 comprises an SMD type package 2461 comprising a based and a cap or window region and the integrated white light source 2462. The SMD package 2461 is mounted to a heat-sink member 2483 configured to transport and/or store the heat generated in the SMD package 2461 from the laser and phosphor member. A lens member 2484 such as an aspheric lens is configured with the white light source 2462 to collect and collimate a substantial portion of the emitted white light. A reflector housing member 2485 or lens member 2484 is configured between the white light source 2462 and the lens member 2484 to reflect any stray light or light (that would not otherwise reach the lens member) into the lens member for collimation and contribution to the collimated beam. In one embodiment the lens member 2484 is supported by the reflector housing member 2485 to mechanically brace the lens member 2484 in a fixed position with respect to the white light source 2462. The lens member 2484 functions to collimate and project the white light along the axis of projection 2486. Of course, this is merely an example and is intended to illustrate one possible configuration of combining the integrated white light source according to this invention with a reflector collimation optic. In another example, the collimating reflector could be integrated into the window member of the cap or could be included within the package member. In a preferred embodiment, the reflector is integrated with or attached to the submount.

Laser device plus phosphor excitation sources integrated in packages such as an SMD can be attached to an external board to allow electrical and mechanical mounting of packages. In addition to providing electrical and mechanical interfaces to the SMD package, these boards also supply the thermal interface to the outside world such as a heat-sink. Such boards can also provide for improved handling for small packages such as an SMD (typically less than 2 cm×2 cm) during final assembly. In addition to custom board designs, there are a number of industry standard board designs that include metal core printed circuit board (MCPCB) with base being Cu, Al or Fe alloys, fiber filled epoxy boards such as the FR4, Flex/Hybrid Flex boards that are typically polyimide structures with Cu interlayers and dielectric isolation to be used in applications which need to be bent around a non-flat surface, or a standard heat sink material board that can be directly mounted to an existing metal frame in a larger system.

A further understanding of the nature and advantages of the present invention may be realized by reference to the latter portions of the specification and attached drawings.

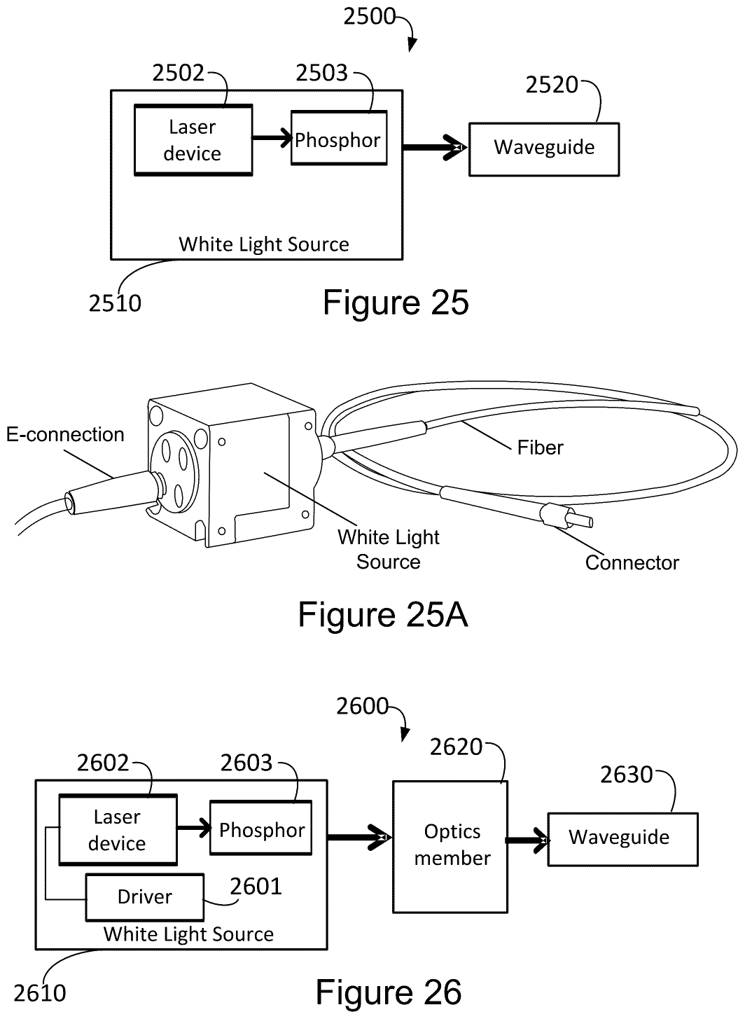

In an aspect, the present disclosure provides a waveguide-coupled white light system based on integrated laser-induced white light source. FIG. 25 shows a simplified block diagram of a functional waveguide-coupled white light system according to some embodiments of the present disclosure. This diagram is merely an example, which should not unduly limit the scope of the claims. One of ordinary skill in the art would recognize many variations, alternatives, and modifications. As shown, the waveguide-coupled white light system 2500 includes a white light source 2510 and a waveguide 2520 coupled to it to deliver the white light for various applications. In some embodiments, the white light source 2510 is a laser-based white light source including at least one laser device 2502 configured to emit a laser light with a blue wavelength in a range from about 385 nm to about 495 nm. Optionally, the at least one laser device 2502 is a laser diode (LD) chip configured as a chip-on-submount (CoS) form having a Gallium and Nitrogen containing emitting region operating in a first wavelength selected from 395 nm to 425 nm wavelength range, 425 nm to 490 nm wavelength range, and 490 nm to 550 nm range. Optionally, the laser device 2502 is configured as a chip-on-submount (CoS) structure based on lifted off and transferred epitaxial gallium and nitrogen containing layers according to this present invention is shown in FIG. 7. Optionally, the at least one laser device 2502 includes a set of multiple laser diode (LD) chips. Each includes an GaN-based emission stripe configured to be driven by independent driving current or voltage from a laser driver to emit a laser light. All emitted laser light from the multiple LD chips can be combined to one beam of electromagnetic radiation. Optionally, the multiple LD chips are blue laser diodes with an aggregated output power of less than 1 W, or about 1 W to about 10 W, or about 10 W to about 30 W, or about 30 W to 100 W, or greater. Optionally, each emitted light is driven and guided separately.

In some embodiments, the laser-based waveguide-coupled white light system 2500 further includes a phosphor member 2503. Optionally, the phosphor member 2503 is mounted on a remote/separate support member co-packaged within the white light source 2510. Optionally, the phosphor member 2503 is mounted on a common support member with the laser device 2502 in a chip-and-phosphor-on-submount (CPoS) structure. The phosphor member 2503 comprises a flat surface or a pixelated surface disposed at proximity of the laser device 2502 in a certain geometric configuration so that the beam of electromagnetic radiation emitted from the laser device 2502 can land in a spot on the excitation surface of the phosphor member 2503 with a spot size limited in a range of about 50 μm to 5 mm.

Optionally, the phosphor member 2503 is comprised of a ceramic yttrium aluminum garnet (YAG) doped with Ce or a single crystal YAG doped with Ce or a powdered YAG comprising a binder material. The phosphor plate has an optical conversion efficiency of greater than 50 lumen per optical watt, greater than 100 lumen per optical watt, greater than 200 lumen per optical watt, or greater than 300 lumen per optical watt.

Optionally, the phosphor member 2503 is comprised of a single crystal plate or ceramic plate selected from a Lanthanum Silicon Nitride compound and Lanthanum aluminum Silicon Nitrogen Oxide compound containing Ce³⁺ ions atomic concentration ranging from 0.01% to 10%.

Optionally, the phosphor member 2503 absorbs the laser emission of electromagnetic radiation of the first wavelength in violet, blue (or green) spectrum to induce a phosphor emission of a second wavelength in yellow spectra range. Optionally, the phosphor emission of the second wavelength is partially mixed with a portion of the incoming/reflecting laser beam of electromagnetic radiation of the first wavelength to produce a white light beam to form a laser induced white light source 2510. Optionally, the laser beam emitted from the laser device 2502 is configured with a relative angle of beam incidence with respect to a direction of the excitation surface of the phosphor member 2503 in a range from 5 degrees to 90 degrees to land in the spot on the excitation surface. Optionally, the angle of laser beam incidence is narrowed in a smaller range from 25 degrees to 35 degrees or from 35 degrees to 40 degrees. Optionally, the white light emission of the white light source 2510 is substantially reflected out of the same side of the excitation surface (or pixelated surface) of the phosphor member 2503. Optionally, the white light emission of the white light source 2510 can also be transmitted through the phosphor member 2503 to exit from another surface opposite to the excitation surface. Optionally, the white light emission reflected or transmitted from the phosphor member is redirected or shaped as a white light beam used for various applications. Optionally, the white light emission out of the phosphor material can be in a luminous flux of at least 250 lumens, at least 500 lumens, at least 1000 lumens, at least 3000 lumens, or at least 10,000 lumens. Alternatively, the white light emission out of the white light system 2500 with a luminance of 100 to 500 cd/mm², 500 to 1000 cd/mm², 1000 to 2000 cd/mm², 2000 to 5000 cd/mm², and greater than 5000 cd/mm².

In some embodiments, the white light source 2510 that co-packages the laser device 2502 and the phosphor member 2503 is a surface-mount device (SMD) package. Optionally, the SMD package is hermetically sealed. Optionally, the common support member is provided for supporting the laser device 2502 and the phosphor member 2503. Optionally, the common support member provides a heat sink configured to provide thermal impedance of less than 10 degrees Celsius per watt, an electronic board configured to provide electrical connections for the laser device, a driver for modulating the laser emission, and sensors associated with the SMD package to monitor temperature and optical power. Optionally, the electronic board is configured to provide electrical contact for anode(s) and cathode(s) of the SMD package. Optionally, the electronic board may include or embed a driver for providing temporal modulation for applications related to communication such as LiFi free-space light communication, and/or data communications using optic fiber. Or, the driver may be configured to provide temporal modulation for applications related to LiDAR remote sensing to measure distance, generate 3D images, or other enhanced 2D imaging techniques. Optionally, the sensors include a thermistor for monitor temperatures and photodetectors for providing alarm or operation condition signaling. Optionally, the sensors include fiber sensors. Optionally, the electronic board has a lateral dimension of 50 mm or smaller.

In some embodiments, the white light source 2510 includes one or more optics members to process the white light emission out of the phosphor member 2503 either in reflection mode or transmissive mode. Optionally, the one or more optics members include lenses with high numerical apertures to capture Lambertian emission (primarily for the white light emission out of the surface of the phosphor member 2503. Optionally, the one or more optics members include reflectors such as mirrors, MEMS devices, or other light deflectors. Optionally, the one or more optics members include a combination of lenses and reflectors (including total-internal-reflector). Optionally, each or all of the one or more optics members is configured to be less than 50 mm in dimension for ultra-compact packaging solution.

In some embodiments, the laser-based waveguide-coupled white light system 2500 also includes a waveguide device 2520 coupled to the white light source 2510 to deliver a beam of white light emission to a light head module at a remote destination or directly serve as a light releasing device in various lighting applications. In an embodiment, the waveguide device 2520 is an optical fiber to deliver the white light emission from a first end to a second end at a remote site. Optionally, the optical fiber is comprised of a single mode fiber (SMF) or a multi-mode fiber (MMF). Optionally, the fiber is a glass communication fiber with core diameters ranging from about 1 μm to 10 μm, about 10 μm to 50 μm, about 50 μm to 150 μm, about 150 μm to 500 μm, about 500 μm to 1 mm, or greater than 1 mm, yielding greater than 90% per meter transmissivity. The optical core material of the fiber may consist of a glass such as silica glass wherein the silica glass could be doped with various constituents and have a predetermined level of hydroxyl groups (OH) for an optimized propagation loss characteristic. The glass fiber material may also be comprised of a fluoride glass, a phosphate glass, or a chalcogenide glass. In an alternative embodiment, a plastic optical fiber is used to transport the white light emission with greater than 50% per meter transmissivity. In another alternative embodiment, the optical fiber is comprised of lensed fiber which optical lenses structure built in the fiber core for guiding the electromagnetic radiation inside the fiber through an arbitrary length required to deliver the white light emission to a remote destination. Optionally, the fiber is set in a 3-dimensional (3D) setting that fits in different lighting application designs along a path of delivering the white light emission to the remote destination. Optionally, the waveguide device 2520 is a planar waveguide (such as semiconductor waveguide formed in silicon wafer) to transport the light in a 2D setting.

In another embodiment, the waveguide device 2520 is configured to be a distributed light source. Optionally, the waveguide device 2520 is a waveguide or a fiber that allows light to be scattered out of its outer surface at least partially. In one embodiment, the waveguide device 2520 includes a leaky fiber to directly release the white light emission via side scattering out of the outer surface of the fiber. Optionally, the leaky fiber has a certain length depending on applications. Within the length, the white light emission coupled in from the white light source 2510 is substantially leaked out of the fiber as an illumination source. Optionally, the leaky fiber is a directional side scattering fiber to provide preferential illumination in a particular angle. Optionally, the leaky fiber provides a flexible 3D setting for different 3D illumination lighting applications. Optionally, the waveguide device 2520 is a form of leaky waveguide formed in a flat panel substrate that provides a 2D patterned illumination in specific 2D lighting applications.

In an alternative embodiment, the waveguide device 2520 is a leaky fiber that is directly coupled with the laser device to couple a laser light in blue spectrum. Optionally, the leaky fiber is coated or doped with phosphor material in or on surface to induce different colored phosphor emission and to modify colors of light emitted through the phosphor material coated thereover.

In a specific embodiment, as shown in FIG. 25A, the laser-based fiber-coupled white light system includes one white light source coupling a beam of white light emission into a section of fiber. Optionally, the white light source is in a SMD package that holds at least a laser device and a phosphor member supported on a common support member. The common support member may be configured as a heat sink coupled with an electronic board having an external electrical connection (E-connection). The SMD package may also be configured to hold one or more optics members for collimating and focusing the emitted white light emission out of the phosphor member to an input end of the second of fiber and transport the white light to an output end. Optionally, referred to FIG. 25A, the white light source is in a package having a cubic shape of with a compact dimension of about 60 mm. The E-connection is provided at one (bottom) side while the input end of the fiber is coupled to an opposite (front) side of the package. Optionally, the output end of the fiber, after an arbitrary length, includes an optical connector. Optionally, the optical connector is just at a middle point, instead of the output end, of the fiber and another section of fiber with a mated connector (not shown) may be included to further transport the white light to the output end. Thus, the fiber becomes a detachable fiber, convenient for making the laser-based fiber-coupled white light system a modular form that includes a white light source module separately and detachably coupled with a light head module. For example, a SMA-905 type connector is used. Optionally, the electronic board also includes a driver configured to modulate (at least temporarily the laser emission for LiFi communication or for LiDAR remote sensing.

In an alternative embodiment, the laser-based fiber coupled white light system includes a white light source in SMD package provided to couple one white light emission to split into multiple fibers. In yet another alternative embodiment, the laser-based fiber-coupled white light system includes multiple SMD-packaged white light sources coupling a combined beam of the white light emission into one fiber.

In an embodiment, the laser-based fiber-coupled white light system 2500 includes one white light source 2510 in SMD package coupled with two detachable sections of fibers joined by an optical connector. Optionally, SMA, FC, or other optical connectors can be used, such as SMA-905 type connector.

Optionally, the fiber 2520 includes additional optical elements at the second end for collimating or shaping or generating patterns of exiting white light emission in a cone angle of 5˜50 degrees. Optionally, the fiber 2520 is provided with a numerical aperture of 0.05˜ 0.7 and a diameter of less than 2 mm for flexibility and low-cost.

In an embodiment, the white light source 2510 can be made as one package selected from several different types of integrated laser-induced white light sources shown from FIG. 14 through FIG. 24. Optionally, the package is provided with a dimension of 60 mm for compactness. The package provides a mechanical frame for housing and fixing the SMD packaged white light source, phosphor members, electronic board, one or more optics members, etc., and optionally integrated with a driver. The phosphor member 2503 in the white light source 2510 can be set as either reflective mode or transmissive mode. Optionally, the laser device 2502 is mounted in a mounted in a surface mount-type package and sealed with a cap member. Optionally, the laser device 2502 is mounted in a surface mount package mounted onto a starboard. Optionally, the laser device 2502 is mounted in a flat-type package with a collimating optic member coupled. Optionally, the laser device 2502 is mounted in a flat-type package and sealed with a cap member. Optionally, the laser device 2502 is mounted in a can-type package with a collimating lens. Optionally, the laser device 2502 is mounted in a surface mount type package mounted on a heat sink with a collimating reflector. Optionally, the laser device 2502 is mounted in a surface mount type package mounted on a starboard with a collimating reflector. Optionally, the laser device 2502 is mounted in a surface mount type package mounted on a heat sink with a collimating lens. Optionally, the laser device 2502 is mounted in a surface mount type package mounted on a heat sink with a collimating lens and reflector member.

Many benefits and applications can be yielded out of the laser-based fiber-coupled white light system. For example, it is used as a distributed light source with thin plastic optical fiber for low-cost white fiber lighting, including daytime running lights for car headlights, interior lighting for cars, outdoor lighting in cities and shops. Alternatively, it can be used for communications and data centers. Also, a new linear light source is provided as a light wire with <1 mm in diameter, producing either white light or RGB color light. Optionally, the linear light source is provided with a laser-diode plus phosphor source to provide white light to enter the fiber that is a leaky fiber to distribute side scattered white light. Optionally, the linear light source is coupled RGB laser light in the fiber that is directly leak side-scattered RGB colored light. Optionally, the linear light source is configured to couple a blue laser light in the fiber that is coated with phosphor material(s) to allow laser-pumped phosphor emission be side-scattered out of the outer surface of the fiber. Analogously, a 2D patterned light source can be formed with either arranging the linear fiber into a 2D setting or using 2D solid-state waveguides instead formed on a planar substrate.

In an alternative embodiment, FIG. 26 shows a simplified block diagram of a functional laser-based waveguide-coupled white light system 2600. The laser-based waveguide-coupled white light system 2600 includes a white light source 2610, substantially similar to the white light source 2510 shown in FIG. 25, having at least one laser device 2602 configured to emit blue spectrum laser beam of a first wavelength to a phosphor member 2603. The at least one laser device 2602 is driven by a laser driver 2601. The laser driver 2601 generates a drive current adapted to drive one or more laser diodes. In a specific embodiment, the laser driver 2601 is configured to generate pulse-modulated signal at a frequency range of about 50 to 300 MHz. The phosphor member 2603 is substantially the same as the phosphor member 2503 as a wavelength converter and emitter being excited by the laser beam from the at least one laser device 2602 to produce a phosphor emission with a second wavelength in yellow spectrum. The phosphor member 2603 may be packaged together with the laser device 2602 in a CPoS structure on a common support member. The phosphor emission is partially mixed with the laser beam with the first wavelength in violet or blue spectrum to produce a white light emission. Optionally, the waveguide-coupled white light system 2600 includes an laser-induced white light source 2610 containing multiple laser diode devices 2602 in a co-package with a phosphor member 2603 and driven by a driver module 2601 to emit a laser light of 1 W, 2 W, 3 W, 4 W, 5 W or more power each, to produce brighter white light emission of combined power of 6 W, or 12 W, or 15 W, or more. Optionally, the white light emission out of the laser-induced white light source with a luminance of 100 to 500 cd/mm², 500 to 1000 cd/mm², 1000 to 2000 cd/mm², 2000 to 5000 cd/mm², and greater than 5000 cd/mm². Optionally, the white light emission is a reflective mode emission out of a spot of a size greater than 5 μm on an excitation surface of the phosphor member 2603 based on a configuration that the laser beam from the laser device 2602 is guided to the excitation surface of the phosphor member 2603 with an off-normal angle of incidence ranging between 0 degrees and 89 degrees.

In the embodiment, the laser-based waveguide-coupled white light system 2600 further includes an optics member 2620 configured to collimate and focus the white light emission out of the phosphor member 2603 of the white light source 2610. Furthermore, the laser-based waveguide-coupled white light system 2600 includes a waveguide device or assembly 2630 configured to couple with the optics member 2620 receive the focused white light emission with at least 20%, 40%, 60%, or 80% coupling efficiency. The waveguide device 2630 serves a transport member to deliver the white light to a remotely set device or light head module. Optionally, the waveguide device 2630 serves an illumination member to direct perform light illumination function. Preferably, the waveguide device 2630 is a fiber. Optionally, the waveguide device 2630 includes all of the types of fiber, including single mode fiber, multiple module, polarized fiber, leaky fiber, lensed fiber, plastic fiber, etc.,

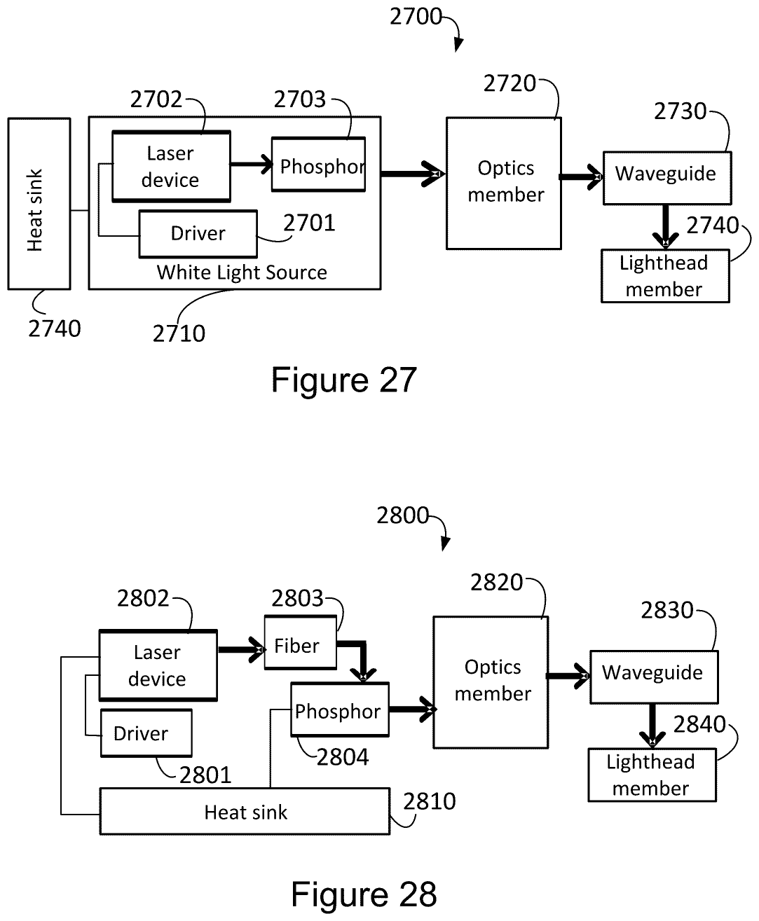

FIG. 27 shows a simplified block diagram of a laser-based waveguide-coupled white light system 2700 according to yet another alternative embodiment of the present disclosure. As shown, a laser-based white light source 2710 including a laser device 2702 driven by a driver module 2701 to emit a laser beam of electromagnetic radiation with a first wavelength in violet or blue spectrum range. The electromagnetic radiation with the first wavelength is landed to an excitation surface of a phosphor member 2703 co-packaged with the laser device 2702 in a CPOS structure in the white light source 2710. The phosphor member 2703 serves as a wavelength converter and an emitter to produce a phosphor emission with a second wavelength in yellow spectrum range which is partially mixed with the electromagnetic radiation of the first wavelength to produce a white light emission reflected out of a spot on the excitation surface. Optionally, the laser device 2702 includes one or more laser diodes containing gallium and nitrogen in active region to produce laser of the first wavelength in a range from 385 nm to 495 nm. Optionally, the one or more laser diodes are driven by the driver module 2701 and laser emission from each laser diode is combined to be guided to the excitation surface of the phosphor member 2703. Optionally, the phosphor member 2703 comprises a phosphor material characterized by a wavelength conversion efficiency, a resistance to thermal damage, a resistance to optical damage, a thermal quenching characteristic, a porosity to scatter excitation light, and a thermal conductivity. In a preferred embodiment the phosphor material is comprised of a yellow emitting YAG material doped with Ce with a conversion efficiency of greater than 100 lumens per optical watt, greater than 200 lumens per optical watt, or greater than 300 lumens per optical watt, and can be a polycrystalline ceramic material or a single crystal material. Additionally, the ceramic YAG:Ce phosphors is characterized by a temperature quenching characteristics above 150° C., above 200° C., or above 250° C. and a high thermal conductivity of 5-10 W/(m·K) to effectively dissipate heat to a heat sink member and keep the phosphor member at an operable temperature.

In the embodiment, the laser device 2702, the diver module 2710, and the phosphor member 2703 are mounted on a support member containing or in contact with a heat sink member 2740 configured to conduct heat generated by the laser device 2702 during laser emission and the phosphor member 2703 during phosphor emission. Optionally, the support member is comprised of a thermally conductive material such as copper with a thermal conductivity of about 400 W/(m·K), aluminum with a thermal conductivity of about 200 W/(m·K), 4H—SiC with a thermal conductivity of about 370 W/(m·K), 6H—SiC with a thermal conductivity of about 490 W/(m·K), AlN with a thermal conductivity of about 230 W/(m·K), a synthetic diamond with a thermal conductivity of about >1000 W/(m·K), sapphire, or other metals, ceramics, or semiconductors. The support member may be formed from a growth process such as SiC, AlN, or synthetic diamond, and then mechanically shaped by machining, cutting, trimming, or molding. Optionally, the support member is a High Temperature Co-fired Ceramic (HTCC) submount structure configured to embed electrical conducting wires therein. This type of ceramic support member provides high thermal conductivity for efficiently dissipating heat generated by the laser device 2702 and the phosphor member 2703 to a heatsink that is made to contact with the support member. The ceramic support member also can allow optimized conduction wire layout so that ESD can be prevented and thermal management of the whole module can be improved. Electrical pins are configured to connect external power with conducting wires embedded in the HTTC ceramic submount structure for providing drive signals for the laser device 2702. Optionally, the white light source 2710 includes a temperature sensor (not shown) that can be disposed on the support member. Alternatively, the support member may be formed from a metal such as copper, copper tungsten, aluminum, or other by machining, cutting, trimming, or molding. Optionally, the one or more laser diodes are producing an aggregated output power of less than 1 W, or about 1 W to about 10 W, or about 10 W to about 30 W, or about 30 W to 100 W, or greater. Each of the laser diodes is configured on a single ceramic or multiple chips on a ceramic, which are disposed on the heat sink member 2740.

In the embodiment, the laser-based waveguide-coupled white light source 2700 includes a package holding the one or more laser diodes 2702, the phosphor member 2703, the driver module 2701, and a heat sink member 2740. Optionally, the package also includes or couples to all free optics members 2720 such as couplers, collimators, mirrors, and more. The optics members 2720 are configured spatially with optical alignment to couple the white light emission out of the excitation surface of the phosphor member 2703 or refocus the white light emission into a waveguide 2730. Optionally, the waveguide 2730 is a fiber or a waveguide medium formed on a flat panel substrate. As an example, the package has a low profile and may include a flat pack ceramic multilayer or single layer. The layer may include a copper, a copper tungsten base such as butterfly package or covered CT mount, Q-mount, or others. In a specific embodiment, the laser devices are soldered on CTE matched material with low thermal resistance (e.g., AlN, diamond, diamond compound) and forms a sub-assembled chip on ceramics. The sub-assembled chip is then assembled together on a second material with low thermal resistance such as copper including, for example, active cooling (i.e., simple water channels or micro channels), or forming directly the base of the package equipped with all connections such as pins. The flatpack is equipped with an optical interface such as window, free space optics, connector or fiber to guide the light generated and a cover environmentally protective.

In the embodiment, the laser-based waveguide-coupled white light source 2700 further includes an optics member 2720 for coupling the white light emission out of the white light source 2710 to a waveguide device 2730. Optionally, the optics member 2720 includes free-space collimation lens, mirrors, focus lens, fiber adaptor, or others. Optionally, the waveguide device 2730 includes flat-panel waveguide formed on a substrate or optical fibers. Optionally, the optical fiber includes single-mode fiber, multi-mode fiber, lensed fiber, leaky fiber, or others. Optionally, the waveguide device 2730 is configured to deliver the white light emission to a lighthead member 2740 which re-shapes and projects the white light emission to different kinds of light beams for various illumination applications. Optionally, the waveguide device 2730 itself serves an illumination source or elements being integrated in the lighthead member 2740.

FIG. 28 shows a comprehensive diagram of a laser-based waveguide-coupled white light system 2800 according to a specific embodiment of the present disclosure. Referring to FIG. 28, the laser-based waveguide-coupled white light system 2800 includes a laser device 2802 configured as one or more laser diodes (LDs) mounted on a support member and driven by a driver 2801 to emit a beam of laser electromagnetic radiation characterized by a first wavelength ranging from 395 nm to 490 nm. The support member is formed or made in contact with a heat sink 2810 for sufficiently transporting thermal energy released during laser emission by the LDs. Optionally, the laser-based waveguide-coupled white light system 2800 includes a fiber for collecting the laser electromagnetic radiation with at least 20%, 40%, 60%, or 80% coupling efficiency and deliver it to a phosphor 2804 in a certain angular relationship to create laser spot on an excitation surface of the phosphor 2804. The phosphor 2804 also serves an emitter to convert the incoming laser electromagnetic radiation to a phosphor emission with a second wavelength longer than the first wavelength. Optionally, the phosphor 2804 is also mounted or made in contact with the heat sink 2810 common to the laser device 2802 in a CPoS structure to allow heat due to laser emission and wavelength conversion being properly released. Optionally, a blocking member may be installed to prevent leaking out the laser electromagnetic radiation by direct reflection from the excitation surface of the phosphor 2804.

In the embodiment, a combination of laser emission of the laser device 2802, the angular relationship between the fiber-delivered laser electromagnetic radiation and the excitation surface of the phosphor 2804, and the phosphor emission out of the spot on the excitation surface leads to at least a partial mixture of the phosphor emission with the laser electromagnetic radiation, which produces a white light emission. In the embodiment, the laser-based waveguide-coupled white light system 2800 includes an optics member 2820 configured to collimate and focus the white light emission into a waveguide 2830. Optionally, the optics member 2820 is configured to couple the white light emission into the waveguide 2830 with at least 20%, 40%, 60%, or 80% coupling efficiency. Optionally, the optics member 2820 includes free-space collimation lens, mirrors, focus lens, fiber adaptor, or others. Optionally, a non-transparent boot cover structure may be installed to reduce light loss to environment or causing unwanted damage.

In the embodiment, the laser-based waveguide-coupled white light source 2800 further includes a lighthead member 2840 coupled to the waveguide 2830 to receive the white light emission therein. Optionally, the waveguide 2830 includes flat-panel waveguide formed on a substrate or optical fibers. Optionally, the optical fiber includes single-mode fiber, multi-mode fiber, lensed fiber, leaky fiber, or others. Optionally, the waveguide 2830 is configured to deliver the white light emission to the lighthead member 2840 which is disposed at a remote location convenient for specific applications. The lighthead member 2840 is configured to amplify, re-shape, and project the collected white light emission to different kinds of light beams for various illumination applications. Optionally, the waveguide 2830 itself serves an illumination source or element being integrated in the lighthead member 2840.

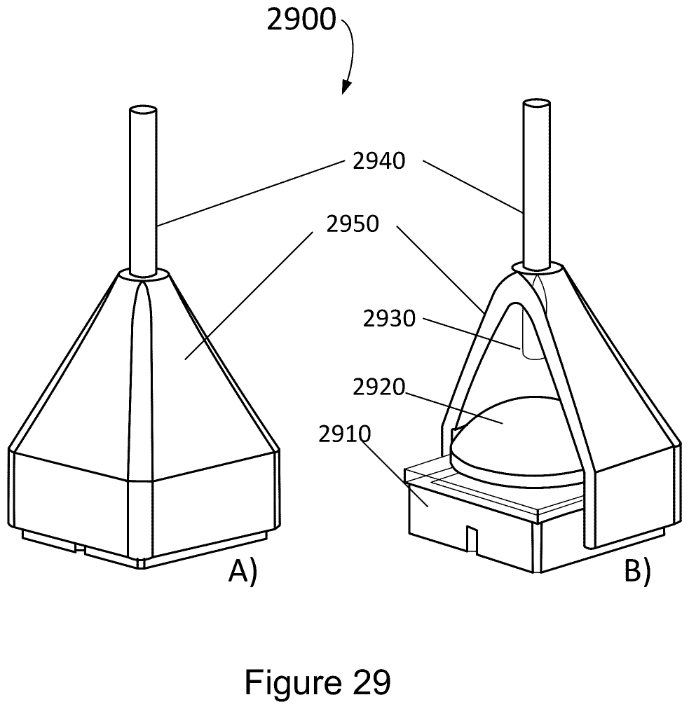

FIG. 29 is a simplified diagram of A) a laser-based fiber-coupled white light system based on surface mount device (SMD) white light source and B) a laser-based fiber-coupled white light system with partially exposed SMD white light source according to an embodiment of the present invention. This diagram is merely an example, which should not unduly limit the scope of the claims. One of ordinary skill in the art would recognize many variations, alternatives, and modifications. As shown, the laser-based fiber-coupled white light system 2900 is based on a laser-induced white light source 2910 configured in a surface-mount device (SMD) package. In some embodiments, the laser-induced white light source 2910 is provided as one selected from the SMD-packaged laser-based white light sources shown in FIG. 14 through FIG. 24, and configured to produce a white light emission with a luminance of 100 to 500 cd/mm², 500 to 1000 cd/mm², 1000 to 2000 cd/mm², 2000 to 5000 cd/mm², and greater than 5000 cd/mm². Optionally, the SMD-package white light source is made in contact with a heat sink to conduct the heat away during operation.

In an embodiment shown in FIG. 29, a lens structure 2920 is integrated with the SMD-packaged white light source 2910 and configured to collimate and focus the white light emission outputted by the white light source 2910. Optionally, the lens structure 2920 is mounted on top of the SMD-package. Optionally, the waveguide-coupled white light system 2900 includes a cone shaped boot cover 2950 and the lens structure 2920 is configured to have its peripheral being fixed to the boot cover 2950. The boot cover 2950 also is used for fixing a fiber 2940 with an end facet 2930 inside the boot cover 2950 to align with the lens structure 2920. A geometric combination of the lens structure 2920 and the cone shaped boot structure 2950 provides a physical alignment between the end facet 2930 of the fiber 2940 and the lens structure 2920 to couple the white light emission into the fiber with at least 20%, 40%, 60%, or 80% coupling efficiency. The fiber 2940 is then provided for delivering the white light emission for illumination applications. Optionally, the boot cover 2950 is made by non-transparent solid material, such as metal, plastic, ceramic, or other suitable materials.

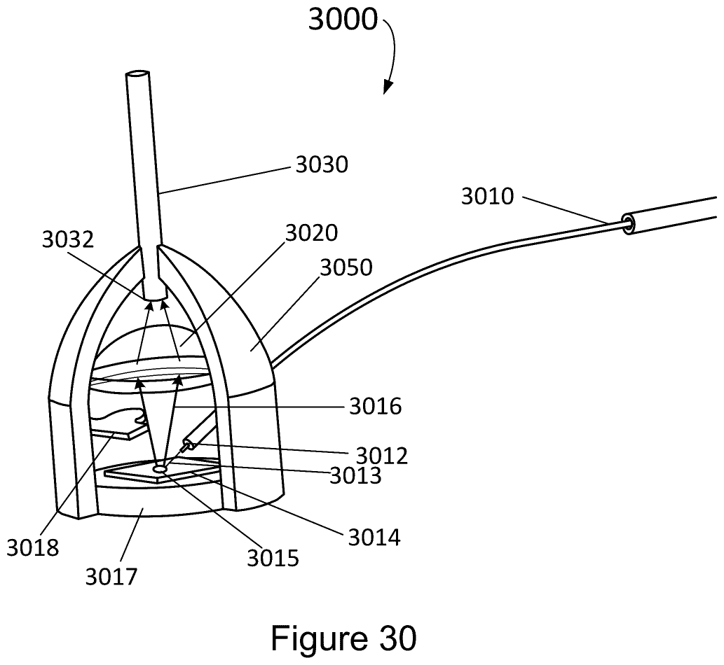

FIG. 30 is a simplified diagram of a fiber-delivered-laser-induced fiber-coupled white light system based on fiber-in and fiber-out configuration according to another embodiment of the present invention. In the embodiment, the fiber-delivered-laser-induced fiber-coupled white light system 3000 includes a phosphor plate 3014 mounted on a heat sink support member 3017 which is remoted from a laser device. The phosphor plate 3014 is configured as a wavelength converting material and an emission source to receive a laser beam 3013 generated by the laser device and delivered via a first optical fiber 3010 and exited a first fiber end 3012 in an angled configuration (as shown in FIG. 30) to land on a surface spot 3015 of the phosphor plate 3014. The laser beam 3013 includes electromagnetic radiation substantially at a first wavelength in violet or blue spectrum range from 385 nm to 495 nm. The laser beam 3013 exits the fiber end 3012 with a confined beam divergency to land in the surface spot 3015 where it is absorbed at least partially by the phosphor member 3914 and converted to a phosphor emission with a second wavelength substantially in yellow spectrum. At least partially, the phosphor emission is mixed with the laser beam 3013 exited from the first fiber end 3012 or reflected by the surface of the phosphor plate 3014 to produce a white light emission 3016. The white light emission 3016 is outputted substantially in a reflection mode from the surface of the phosphor plate 3014.

In an embodiment, the fiber-delivered-laser-induced fiber-coupled white light system 3000 further includes a lens 3020 configured to collimate and focus the white light emission 3016 to a second end facet 3032 of a second optical fiber 3030. The lens 3020 is mounted inside a boot cover structure 3050 and has its peripheral fixed to the inner side of the boot cover structure 3050. Optionally, the boot cover structure 3050 has a downward cone shape with bigger opening coupled to the heat sink support member 3017 and a smaller top to allow the second optical fiber 3030 to pass through. The second optical fiber 3030 is fixed to the smaller top of the boot cover structure 3050 with a section of fiber left inside thereof and the second end facet 3032 substantially aligned with the lens 3020. The lens 3020 is able to focus the white light emission 3016 into the second end facet 3032 of the second optical fiber 3030 with at least 20%, 40%, 60%, or 80% coupling efficiency. The second optical fiber 3020 can have arbitrary length to either deliver the white light emission coupled therein to a remote destination or functionally serve as an illumination element for direct lighting. For example, the second optical fiber 3030 is a leaky fiber that directly serves as an illumination element by side-scattering the light out of its outer surface either uniformly or restricted in a specific angle range.

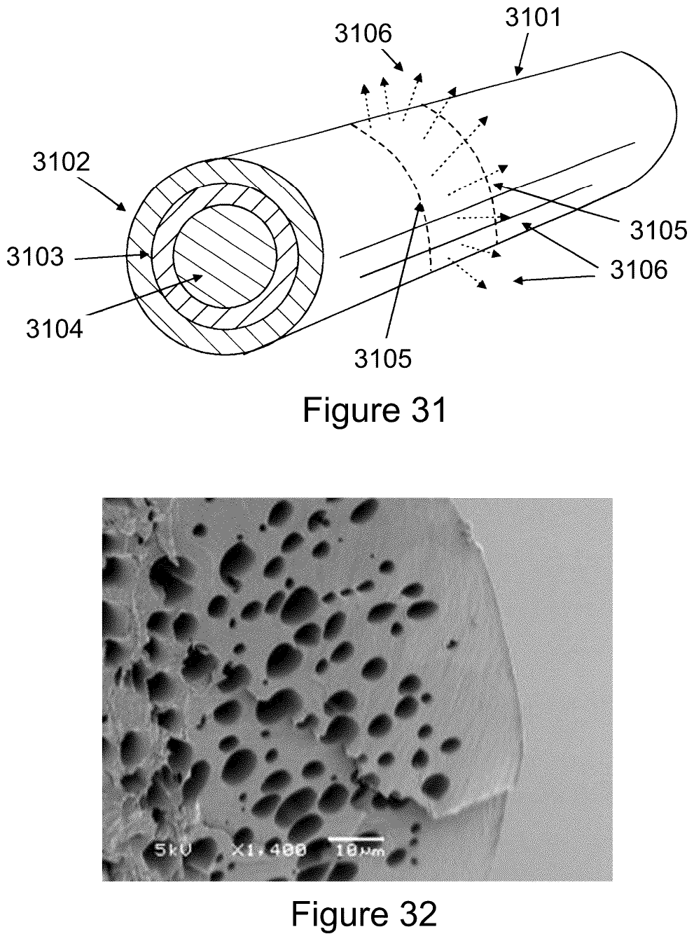

FIG. 31 is a schematic diagram of a leaky fiber used for a laser-based fiber-coupled white light system according to an embodiment of the present invention. Referring to the embodiment shown in FIG. 30, the optical fiber 3030 can be chosen from a leaky fiber that allows electromagnetic radiation coupled therein to leak out via a side firing effect like an illuminating filament. As shown in FIG. 31, a section 3105 of the leaky fiber 3101 allows radiation 3106 to leak from the fiber core 3104 through the cladding 3103. A buffer 3102 is a transparent material covering the cladding 3103. The radiation 3106 is leaked out substantially in a direction normal to the longitudinal axis of the optical fiber 3101.

FIG. 32 is an exemplary image of a leaky fiber with a plurality of holes in fiber core according to an embodiment of the present invention. Referring to FIG. 32, a polymer fiber is provided with a plurality of air bubbles formed in its core. The air bubbles act as light scattering centers to induce leaking from the fiber sidewalls.

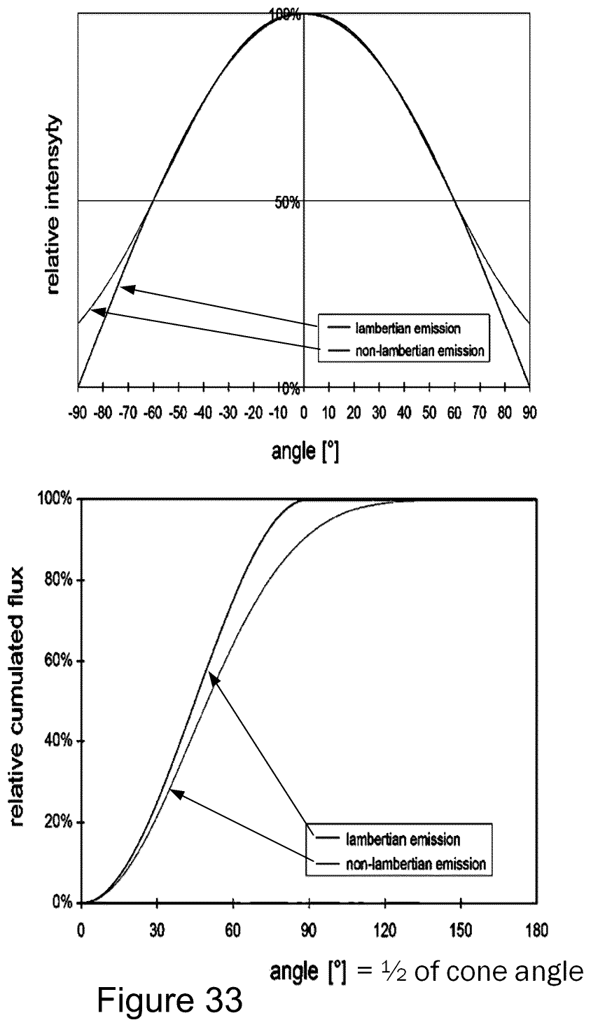

In some embodiments, each of the laser-based fiber-coupled white light systems described herein includes a white light emitter (such as phosphor-based emitter to convert a laser radiation with a first wavelength to a phosphor emission with a second wavelength) and a fiber configured to couple the emission from the white light emitter with high efficiency. Some assumptions can be laid out to calculate some fundamental features of the light capture requirement for the system. For example, the white light emitter is assumed to be a Lambertian emitter. FIG. 33 shows light capture rate for Lambertian emitters according to an embodiment of the present invention. As shown, a first plot shows relative intensity versus geometric angle of the Lambertian emission comparing with a non-Lambertian emission. A full-width half maximum (FWHM) of the spectrum is at ˜120 degrees (−60 deg to 60 deg) for the Lambertian emission. A second plot shows relative cumulated flux versus a half of cone angle for light capture. Apparently, with a FWHM cone angle of 120 deg., 60% of light of the Lambertian emission can be captured. Optionally, all the white emissions out of the phosphor surface in either a reflective mode or transmissive mode in the present disclosure are considered to be substantially Lambertian emission.

In an alternative aspect, the present disclosure provides an improve automobile headlamp based on the laser-based fiber-coupled white light system. In the 1880s, the world's first automobile headlamps were introduced based on acetylene and oil, similar to gas lamp sources used for general lighting at the time. Although these sources were somewhat robust to wind, rain, and snow, cost and size was an issue. The light sources were large, and light output was modest, and not quite sufficient for typical speed and roadway conditions at the time. The light was difficult to shape using small optics to achieve specific patterns. The first electric headlamp was produced in 1898. Although these were an improvement over previous approach, reliability was an issue due to burned filaments in rugged road conditions, and costs of the small energy sources were high. Low and the high beam electric headlamps were deployed in 1924.

The first halogen headlamp started production in 1962, and xenon high-intensity discharge lamps (HID) hit the road in 1991. These featured higher light output and brightness and range from more reliable and compact sources, and encountered cost challenges until the volumes and adoptions rates climbed high enough for economies of scale in production. Reliability was challenging due to the lamp style design. In order to mitigate the challenges with lamp replacement and alignment, fiber delivered lamps were attempted, but the light sources did not have high enough luminance, and therefore large, thick (5 mm-20 mm) expensive and lossy fiber bundles were used which became impractical for cost and manufacturability reasons.

Semiconductor based light emitting diode (LED) headlight sources were fielded in 2004, the first solid-state sources. These featured high efficiency, reliability, and compactness, but the limited light output per device and brightness caused the optics and heat sinks to be still are quite large, and the elevated temperature requirements in auto applications were challenging. Color uniformity from the blue LED excited yellow phosphor needed managed with special reflector design. Single LED failure meant the entire headlamp needed to be scrapped, resulting in challenging costs for maintenance, repair, and warranty. Moreover, the LED components are based on spontaneous emission, and therefore are not conducive to high-speed modulation required for advanced applications such as 3D sensing (LiDAR), or optical communication (LiFi). The low luminance also creates challenges for spatially dynamic automotive lighting systems that utilize spatial modulators such as MEMS or liquid crystal devices. Semiconductor laser diode (LD) based headlights started production in 2014 based on laser pumped phosphor architectures, since direct emitting lasers such as R-G-B lasers are not safe to deploy onto the road and since R-G-B sources leave gaps in the spectrum that would leave common roadside targets such as yellow or orange with insufficient reflection back to the eye. Laser pumped phosphor are solid state light sources and therefore featured the same benefits of LEDs, but with higher brightness and range from more compact headlamp reflectors. Initially, these sources exhibited high costs, reduced reliability compared to LEDs, due to being newer technology. In some cases, the laser and phosphor were combined in a single unit, and in other cases, the blue laser light was delivered by fiber to a phosphor module to produce white. Special precautions were needed to ensure safe white light emission occurred with passive and active safety measures. Color uniformity from the blue laser excited yellow phosphor needed managed with special reflector design.

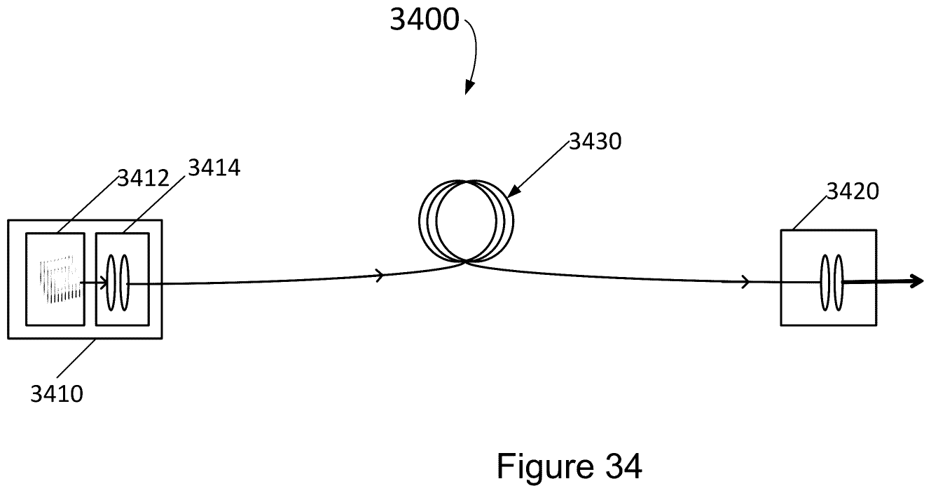

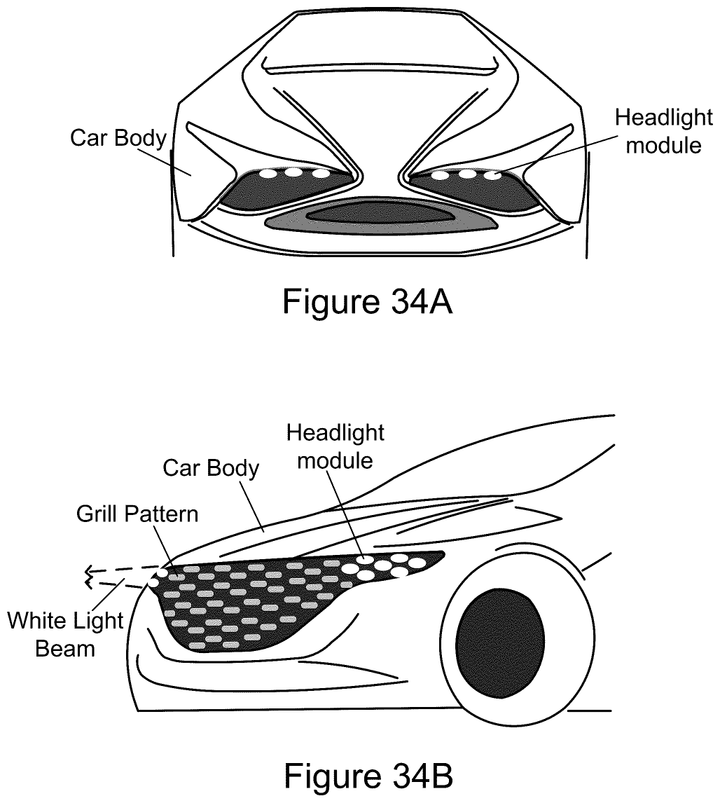

In an embodiment, the present disclosure provides a fiber delivered automobile headlight. FIG. 34 shows a schematic functional diagram of the fiber delivered automobile headlight 3400 comprised of a high luminance white light source 3410 that is efficiently coupled into a waveguide 3430 that used to deliver the white light to a final headlight module 3420 that collimates the light and shapes it onto the road to achieve the desired light pattern. The white light source 3410 is based on laser device 3412 configured to generate a blue laser outputted from a laser chip containing gallium and nitride material. The blue laser generated by the laser chip is led to a phosphor device 3414 integrated with optical beam collimation and shaping elements to excite a white light emission. Optionally, the white light source 3410 is a laser-based SMD-packaged white light source (LaserLight-SMD offered by Sorra Laser Diode, Inc), substantially selected from one of multiple SMD-package white light sources described in FIGS. 14 through 24. Optionally, the waveguide 3430 is an optical transport fiber. Optionally, the headlight module 3420 is configured to deliver 35% or 50% or more light from source 3410 to the road. In an example, the white light source 3410, based on etendue conservation and lumen budget from source to road and Lambertian emitter assumption of FIG. 33, is characterized by about 1570 lumens (assuming 60% optical efficiency for coupling the white light emission into a fiber), 120 deg FWHM cone angle, about 0.33 mm source diameter for the white light emission. In the example, the transport fiber 3430 applied in the fiber-delivered headlight 3400 is characterized by 942 lumens assuming 4 uncoated surfaces with about 4% loss in headlight module 3420, about 0.39 numerical aperture and cone angle of ˜40 deg, and about 1 mm fiber diameter. Additionally, in the example, the headlight module 3420 of the fiber-delivered headlight 3400 is configured to deliver light to the road with 800 lumens output in total efficiency of greater than 35%, +/−5 deg vertical and +/−10 deg horizontal beam divergency, and having 4×4 mm in size. Optionally, each individual element above is modular and can be duplicated for providing either higher lumens or reducing each individual lumen setting white increasing numbers of modules.

In another example, four SMD-packaged white light sources, each providing 400 lumens, can be combined in the white light source 3410 to provide at least 1570 lumens. The transport fiber needs for separate sections of fibers respectively guiding the white light emission to four headlight modules 3420, each outputting 200 lumens, with a combined size of 4×16 mm. In yet another example, each white light source 3410 yields about 0.625 mm diameter for the white light emission. While, the fiber 3430 can be chosen to have 0.50 numerical aperture, cone angle of ˜50 deg, and 1.55 mm fiber diameter. In this example, the headlight module 3420 is configured to output light in 800 lumens to the road with total efficiency of greater than 35% and a size as small as ˜7.5 mm.

In an embodiment, the design of the fiber delivered automobile headlight 3400 is modular and therefore can produce the required amount of light for low beam and/or high beam in a miniature Headlight Module footprint. An example of a high luminance white light source 3410 is the LaserLight-SMD packaged white light source which contains 1 or more high-power laser diodes (LDs) containing gallium-and-nitrogen-based emitters, producing 500 lumens to thousands of lumens per device. For example, low beams require 600-800 lumens on the road, and typical headlight optics/reflectors have 35% or greater, or 50% or greater optical throughput. High luminance light sources are required for long-range visibility from small optics. For example, based on recent driving speeds and safe stopping distances, a range of 800 meters to 1 km is possible from 200 lumens on the road using an optics layout smaller than 35 mm with source luminance of 1000 cd per mm². Using higher luminance light sources allows one to achieve longer-range visibility for the same optics size. High luminance is required to produce sharp light gradients and the specific regulated light patterns for automotive lighting. Moreover, using a waveguide 3430 such as an optical fiber, extremely sharp light gradients and ultra-safe glare reduction can be generated by reshaping and projecting the decisive light cutoff that exists from core to cladding in the light emission profile. As a result, the fiber delivered automobile headlight 3400 is configured to minimize glare and maximize safety and visibility for the car driver and others including oncoming traffic, pedestrians, animals, and drivers headed in the same direction traffic ahead.

Color uniformity from typical white LEDs are blue LED pumped phosphor sources, and therefore need careful integration with special reflector design, diffuser, and/or device design. Similarly, typical blue laser excited yellow phosphor needs managed with special reflector design. In an embodiment of the present invention, spatially homogenous white light is achieved by mixing of the light in the waveguide, such as a multimode fiber. In this case, a diffuser is typically not needed. Moreover, one can avoid costly and time-consuming delays associated with color uniformity tuning redesign of phosphor composition, or of reflector designs.

Laser pumped phosphors used in the laser-based fiber-delivered automobile headlight 3400 are broadband solid-state light sources and therefore featured the same benefits of LEDs, but with higher luminance. Direct emitting lasers such as R-G-B lasers are not safe to deploy onto the road since R-G-B sources leave gaps in the spectrum that would leave common roadside targets such as yellow or orange with insufficient reflection back to the eye. The present design is cost effective since it utilizes a high-luminance white light source with basic macro-optics, a low-cost transport fiber, and low-cost small macro-optics to product a miniature headlight module 3420. Because of the remote nature of the light sources 3410, the white light source 3410 can be mounted onto a pre-existing heat sink with adequate thermal mass that is located anywhere in the vehicle, eliminating the need for heat sink in the headlight.

In an embodiment, miniature optics member of <1 cm diameter in the headlight module 3420 can be utilized to capture nearly 100% of the white light from the transport fiber 3430. Using the optics member, the white light can be collimated and shaped with tiny diffusers or simple optical elements to produce the desired beam pattern on the road. This miniature size also enables low cost ability to swivel the light for glare mitigation, and small form factor for enhanced aerodynamic performance. FIG. 34A shows an example of an automobile with multiple laser-based fiber-delivered headlight modules installed in front. As seen, each headlight module has much smaller form factor than conventional auto headlamp. Each headlight module can be independently operated with high-luminance output. FIG. 34B shows an example of several laser-based fiber-delivered automotive headlight modules installed in front panel of car. The small form factor (<1 cm) of the headlight module allow it to be designed to become hidden in the grill pattern of car front panel. Each headlight module includes one or more optics members to shape, redirect, and project the white light beam to a specific shape with controls on direction and luminous flux.

For many vehicles, it is desired to have extremely small optics sizes for styling of the vehicle. Using higher luminance light sources allows one to achieve smaller optics sizes for the same range of visibility. This design of the laser-based fiber-delivered automobile headlight 3400 allows one to integrate the headlight module 3420 into the front grill structure, onto wheel cover, into seams between the hood and front bumper, etc. The headlight module 3420 can be extremely low mass and lightweight, adapting to a minimized weight in the front of the car, contributing to safety, fuel economy, and speed/acceleration performance. For electric vehicles, this translates to increased vehicle range. Moreover, the decoupled fiber delivered architecture use pre-existing heat sink thermal mass already in vehicle, further minimizing the weight in the car.

This headlight 3400 is based on solid-state light source, and has long lifetime >10,000 hours. Additionally, redundancy can be designed in by using multiple laser diodes on the LaserLight-SMD-based white light source 3410, and by using multiple such white light sources. If issues do occur in the field, interchangeability is straightforward by replacing individual white light source 3410. Using the high luminance light sources 3410, the delivered lumens per electrical watt are higher than that with LED sources with the same optic sizes and ranges that are typical of automotive lighting such as 100's of meters. In an embodiment, the headlight 3400 features at least 35% or 50% optical throughput efficiency, which is similar to LED headlights, however, the losses in this fiber delivered design occur at white light source 3410, thereby minimizing temp/size/weight of headlight module 3420.

Because of the fiber configuration in this design, reliability is maximized by positioning the white light source 3410 away from the hot area near engine and other heat producing components. This allows the headlight module 3420 to operate at extremely high temperatures >100° C., whereas the white light source 3410 can operate in a cool spot with ample heat sinking to keep its environment at a temperature less than 85° C. In an embodiment, the present design utilizes thermally stable, mil standard style telcordia type packaging technology. The only elements exposed to the front of the car are the complexly passive headlight module 3420, comprised tiny macro-optical elements. In an embodiment, using a white light source 3410 based on the high-luminance LaserLight-SMD package, UL and IEC safety certifications have been achieved. In this case, there is no laser through fiber, only incoherent white light, and the SMD uses a remote reflective phosphor architecture inside. Unlike direct emitting lasers such as R-G-B lasers that are not safe to deploy onto the road at high power, the headlight module 3400 does not use direct emitting laser for road illumination.

In an embodiment, because of the case of generating new light patterns, and the modular approach to lumen scaling, this headlight design allows for changing lumens and beam pattern for any region without retooling for an entirely new headlamp. This convenient capability to change beam pattern can be achieved by changing tiny optics and or diffusers instead of retooling for new large reflectors. Moreover, the white light source 3410 can be used in interior lights and daytime running lights (DRL), with transport or side emitting plastic optical fiber (POF). The detachable white light source 3410 can be located with the electronics, and therefore allows upgraded high speed or other specialty drivers for illumination for Lidar, LiFi, dynamic beam shaping, and other new applications with sensor integration.

In an embodiment, a laser-based fiber-coupled white light illumination source may include a high luminance white light source that is efficiently coupled into a transport fiber that is used to deliver the white light to a remote location for illumination application. At the location, optionally an optical connector is used to connect the transport fiber with a leaky fiber configured in a feature structure. Optionally, the white light source is based on laser device configured to generate a blue laser outputted from a laser chip containing gallium and nitride material. The blue laser generated by the laser chip is led to a phosphor device, integrated with optical beam collimation and shaping elements, to excite a white light emission collimated into the transport fiber. Optionally, the white light source is a laser-based SMD-packaged white light source, selected from one of multiple SMD-package white light sources described herein. Optionally, there can be multiple lasers disposed in a safe location in, for example, an automobile. One or more phosphors are used to be excited by the multiple blue laser chips to produce white light with different spectrum or luminance. Optionally, one of more transport fibers are disposed to couple with the one or more phosphors to couple the white light and are configured to deliver the white light to remote application locations. Optionally, the transport fiber and the leaky fiber are a same fiber. Optionally, the transport fiber is coupled with the leaky fiber via a connector or spliced together. Optionally, the leaky fiber includes one or more sections configured as illumination elements with custom shapes/arrangements and disposed around different feature locations for various lighting applications.

The leaky fibers are configured to induce a directional side scattering of the white light carried therein to provide preferential illumination in wide angular ranges off zero degrees along the length of the fibers up to 90 degrees perpendicular to the fiber. Optionally, the leaky fiber is configured to output partial white light therein with an effective luminous flux of greater than 25 lumens, or greater than 50 lumens, 150 lumens, or greater than 300 lumens, or greater than 600 lumens, or greater than 800 lumens, or greater than 1200 lumens in an optical efficiency of greater than 35% out of the fiber body. Optionally, multiple fiber connectors are included to couple the transport fibers and the leaky fibers. Optionally, the leaky fiber is spliced with the transport fiber. The transport fiber is non-leaky fiber. Optionally, the leaky fibers are configured to various linear or partial 2-dimensional shapes with different lengths or widths. Of course, more than one such white light illumination sources can be configured at different locations based on one or more blue lasers and one or more phosphors configured to produce a white spectrum with high luminance of 100 to 500 cd/mm², 500 to 1000 cd/mm², 1000 to 2000 cd/mm², 2000 to 5000 cd/mm², and greater than 5000 cd/mm² with long life-time and low cost.

In an embodiment, the leaky fiber, in general, is configured as an illumination element substantially flexibly disposed around the structure and forming a pattern matching with the structure yet delivering desired illumination.

In an embodiment, the laser-based fiber-coupled white light source based on leaky fiber is directly configured around a light module. Optionally, the leaky fiber of the laser-based fiber-coupled white light illumination source is applied to flexibly form various shaped illumination elements. Of course, the light module can be disposed at different locations.

Alternatively, the laser-based fiber-coupled white light illumination source based on leaky fiber is configured for interior application. Optionally, the laser-based fiber-coupled white light illumination source based on leaky fiber is designed as interior lighting around any interior feature. Optionally, the leaky fiber of the laser-based fiber-coupled white light illumination source is applied to the features. Optionally, the leaky fiber of the laser-based fiber-coupled white light illumination source is applied to ceiling features. Optionally, the lamination is controllable in brightness. Optionally, the illumination color can also be tuned.

In an embodiment, spatially dynamic beam shaping may be achieved with DLP, LCD, 1 or 2 Mems or galvo mirror systems, lightweight swivels, scanning fiber tips. Future spatially dynamic sources may require even more light, such as 5000-10000 lumens from the source, to produce high definition spatial light modulation on the road using MEMS or liquid crystal components. Such systems are incredibly bulky and expensive when co-locating the light source, electronics, heat sink, optics, and light modulators, and secondary optics. Therefore, they require fiber delivered high luminance white light to enable spatial light modulation in a compact and more cost-effective manner.

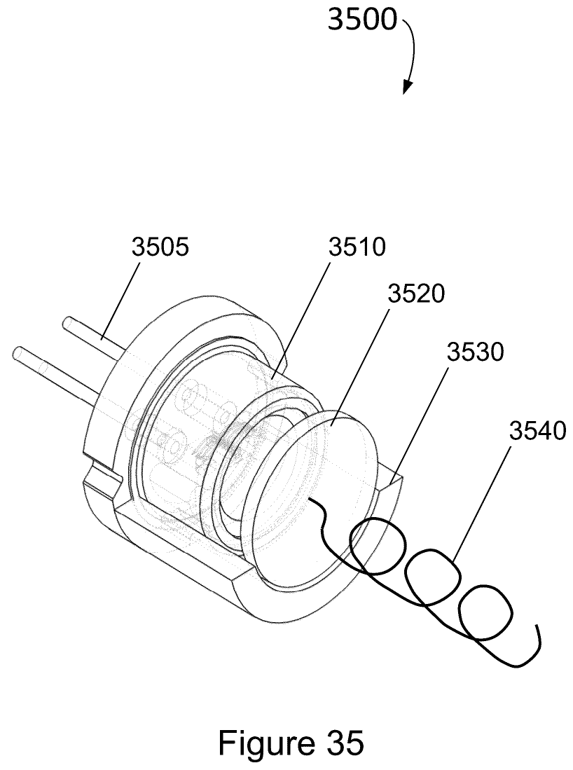

In another specific embodiment, the present disclosure provides a laser-based white light source coupled to a leaky fiber served as an illuminating filament for direct lighting application. FIG. 35 is a schematic diagram of a laser-based white light source coupled to a leaky fiber according to an embodiment of the present invention. As shown, the laser-based white light source 3500 includes a pre-packaged white light source 3510 configured to produce a white light emission. Optionally, the pre-packaged white light source 3510 is a LaserLight-SMD packaged white light source offered by Sorra Laser Diode, Inc, California, which is substantially vacuum sealed except with two electrical pins for providing external power to drive a laser device inside the package of the white light source 3510. The laser device (not fully shown in this figure) emit a blue laser radiation for inducing a phosphor emission out of a phosphor member that is also disposed inside the package of the white light source 3510. Partial mixture of the phosphor emission, which has a wavelength longer than that of the blue laser radiation, with the blue laser radiation produces the white light emission as mentioned earlier.

The laser-based white light source 3500 further includes an optics member 3520 integrated with the pre-packaged white light source 3510 within an outer housing 3530 (which is cut in half for illustration purpose). The optics member 3520 optionally is a collimation lens configured to couple the white light emission into a section of fiber 3540. Optionally, the section of fiber 3540 is disposed with a free-space gap between an end facet and the collimation lens 3520 that is substantially optical aligned at a focus point thereof. Optionally, the section of fiber 3540 is mounted with a terminal adaptor (not explicitly shown) that is fixed with the outer housing 3530. In the embodiment, the section of fiber 3540 is a leaky fiber that allows the white light incorporated therein to leak out in radial direction through its length. The leaky fiber 3540, once the white light emission being coupled in, becomes an illuminating element that can be used for direct lighting applications.

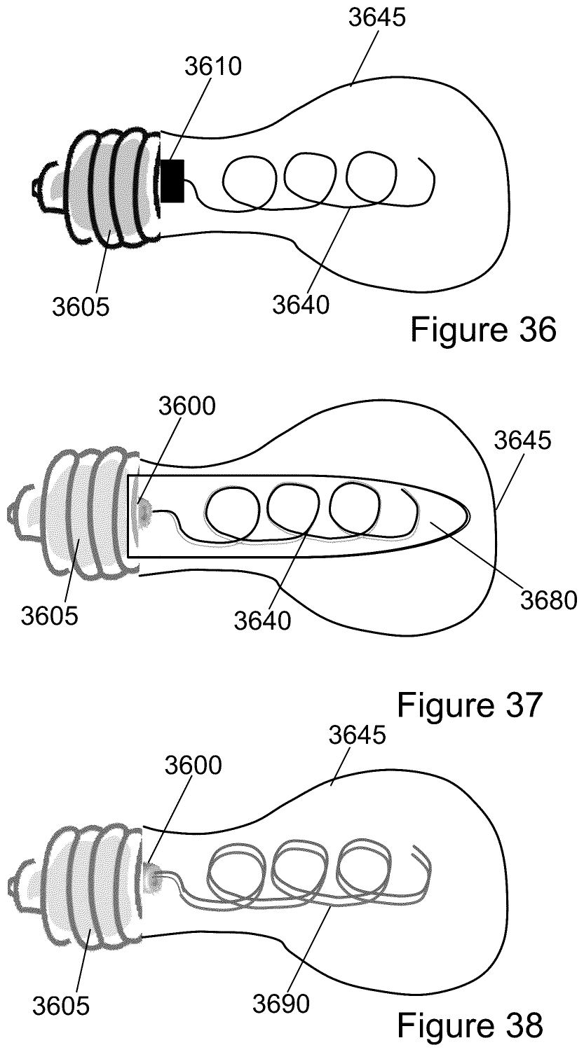

FIG. 36 is a schematic diagram of a laser-based fiber-coupled white light bulb according to an embodiment of the present invention. In the embodiment, the laser-based fiber-coupled white light bulb is provided as an application of a leaky fiber in the laser-based fiber-coupled white light source described in FIG. 35. In the embodiment, a base component 3605 of the light bulb includes an electrical connection structure that has a traditional threaded connection feature, although many other connection features can also be implemented. Inside the connection structure, an AC to DC converter and/or a voltage transformer, not explicitly shown, can be included in the base component 3605 to provide a DC driving current for a laser diode mounted in a miniaturized white light emitter 3610. In the embodiment, the white light emitter 3610 includes a wavelength converting material such as a phosphor configured to generate a phosphor emission induced by a laser light emitted from the laser diode therein. The wavelength converting material is packaged together with the white light emitter 3610. The laser diode is configured to have an active region containing gallium and nitrogen element and is driven by the driving current to emit the laser light in a first wavelength in violet or blue spectrum. The phosphor emission has a second wavelength in yellow spectrum longer than the first wavelength in blue spectrum. A white light is generated by mixing the phosphor emission and the laser light and emitted out of the phosphor. In the embodiment, the wavelength converting material is packaged together with the white light emitter 3610 so that only the white light is emitted from the white light emitter 3610. The laser-based fiber-coupled white light bulb further includes a section of leaky fiber 3640 coupled to the white light emitter 3610 to receive (with certain coupling efficiency) the white light. The section of leaky fiber 3640 has a certain length wining in spiral or other shapes and is fully disposed in an enclosure component 3645 of the light bulb which is fixed to and sealed with the base component 3605. As the white light emitter 3610 is operated to emit the white light coupling into the leaky fiber 3640, the leaky fiber 3640 effectively allows the white light to leak out from outer surface of the fiber, becoming a lighting filament in a light bulb that can be used as a white light illumination source.

FIG. 37 is a schematic diagram of a laser light bulb according to another embodiment of the present invention. In this embodiment, the laser light bulb includes a base component 3605 configured as an electrical connection structure, an outer threaded feature similar to one shown in FIG. 36, although other forms of the electrical connection structure can be implemented. An AC to DC converter and/or a voltage transformer are installed inside the base component 3605 to provide a driver current to a laser device 3600 installed near an output side of the base component 3605. The laser device 3600 is configured to be a laser diode having an active region containing gallium and nitrogen element and is driven by the driving current to emit a laser light of a first wavelength in blue spectrum. In the embodiment, the laser device 3600 is coupled to a fiber 3640 configured to be a leaky fiber embedded in a wavelength converting material 3680 such as a phosphor. The fiber 3640 is configured to couple the laser light emitted from the laser device 3600 into its core with a 20%, 40%, or 60% or greater coupling efficiency. As the laser device 3600 is operated to emit the laser light, the laser light that is incorporated into the fiber 3640 is leaked from the core through outer surface of the fiber 3640 into the wavelength converting material 3680. The leaked laser light is thus converted to white light emitted from the wavelength converting material 3680. In the embodiment, the fiber 3640 has a proper length winded into a certain size of the wavelength converting material 3680 which is fully disposed within an enclosure component 3645 of the laser light bulb. The white light emitted out of the wavelength converting material 3680 in the enclosure 3645, which is set to be a transparent one, just forms an illumination source for lighting application.

FIG. 38 is a schematic diagram of a multi-filament laser light bulb according to yet another embodiment of the present invention. As shown, laser light bulb includes a base component 3605 configured as an electrical connection structure, an outer threaded feature similar to one shown in FIG. 36, although other forms of the electrical connection structure can be implemented. An AC to DC converter and/or a voltage transformer are installed inside the base component 3605 to provide a driver current to a laser device 3600 installed near an output side of the base component 3605. The laser device 3600 is configured to be a packaged gallium and nitrogen containing laser diode and is driven by the driving current to emit a laser light of a first wavelength in blue spectrum. The output of the laser device 3600 is coupled to an input port coupled to multiple optical fibers 3690 to allow the laser light of the first wavelength to be coupled into the fibers 3690 in >20%, >40%, or >60% coupling efficiency. In the embodiment, each of the multiple optical fibers 3690 is a section of leaky fiber coated or embedded (surrounded) with a wavelength converting material such as phosphors. Again, the multiple optical fibers 3690 are all disposed within an enclosure component 3645 of the laser light bulb which is fixed and sealed with the base component 3605. As each section of leaky fiber is received a laser light, the laser light is partially leaked out from outer surface of the fiber into the wavelength converting material and is converted to white light out of outer surface of the wavelength converting material. Each fiber coated by the wavelength converting material thus becomes an illuminating filament for the laser light bulb. In an embodiment, different sections of leaky fibers are coated with different phosphor mixtures so that different (warmer or cooler) white colored light can be respectively emitted from multiple sections of leaky fibers. In the embodiment, overall light color of the laser light bulb is dictated by relative brightness of each illuminating filament based in respective section of leaky fiber and can be controlled by the coated mixtures of phosphors around the multiple sections of leaky fibers.

### Applications for Laser-Based Fiber Coupled White Lighting System

In the present invention, the laser-based fiber coupled white light system is configured for a lighting application. Such lighting applications include, but are not limited to specialty lighting applications, general lighting applications, mobile machine lighting applications such as automotive lighting, truck lighting, avionics on lighting, drone lighting, marine vehicle lighting, infrastructure lighting application such as bridge lighting, tunnel lighting, down-hole lighting, architectural lighting applications, safety lighting applications, applications for appliance or utility lighting such as in refrigerators, freezers, ovens, or other appliances, in a submerged lighting application such as for lighting spas, lighting for jacuzzis, lighting for swimming pools, or even lighting in natural bodies of water including lakes, oceans, or rivers.

### General Description of Laser-Based White Light System

In a preferred embodiment, the present invention comprising a laser-based fiber-coupled white light source is configured in a distributed or central lighting system. In this preferred embodiment one or more laser-based light sources are housed in a first designated location. An electrical power source is coupled to an electrical driver unit configured to supply current and voltage to the laser-based white light source. The supplied power is configured to activate one or more laser diodes comprised in the laser-based light source to generate white light. One or more fibers are optically coupled to the one or more laser-based white light sources. The one or more optical fibers are configured to transport the white light from the first designated location to one or more illumination locations. In some examples, the illumination locations could be configured at short distances from the first designated source location such as less than 5 meters or less 1 meter. In other examples, the illumination locations could be configured at longer distances from the first designated source location such as more than about 5 meters or more than about 50 meters. In other examples the illumination locations could be configured at a very large distance from the first designated source location such as more than about 500 meters.

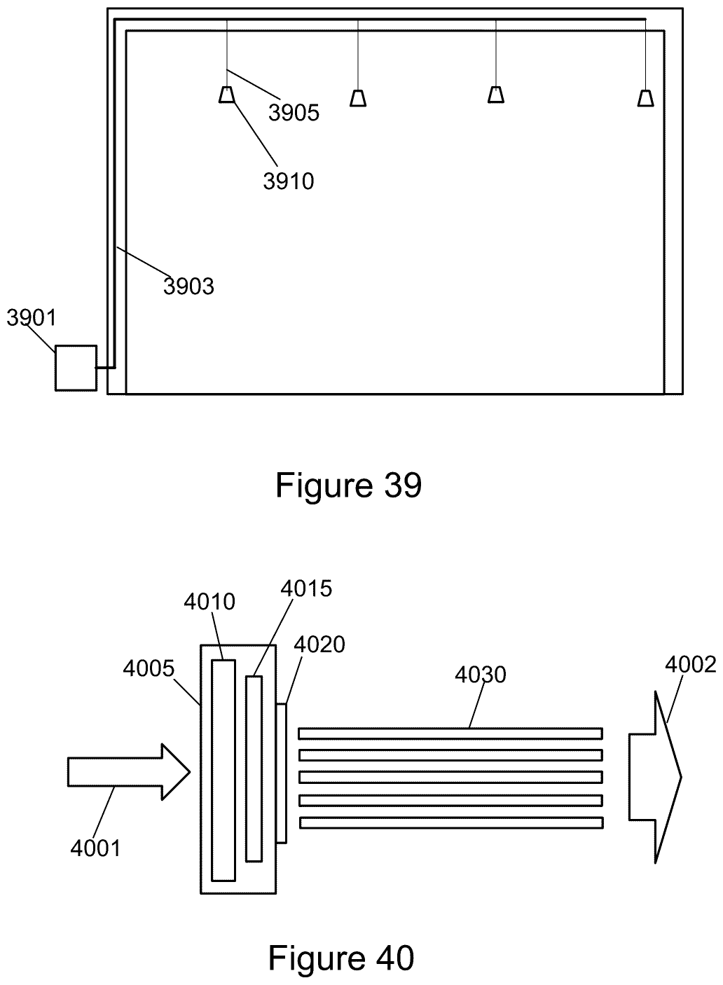

FIG. 39 presents a schematic diagram of a laser-based white lighting system according to an embodiment of the present invention. As seen in FIG. 39, a laser-based white light source 3901 is located in a first designated source location. One or more optical transport fibers 3903 are optically coupled to the white light source 3901. The white light enters the one or more optical transport fibers 3903. The optical transport fibers 3903 serve as waveguide to transport the white light to one or more illumination areas. The total optical coupling efficiency of the white light emission to the one or more fibers could range from about 30% to 50%, 50% to 70%, 70% to 90%, or greater than 90%. As shown in FIG. 39, the white light is transported to a designated illumination space. Optionally, the illumination space is an interior room, which could be located in a home, office, workspace, store, warehouse, or other types spaces where light would be needed. The transport fibers 3903 are routed to different illumination locations within the designated illumination space. The white light transported by the fibers 3903 enters various luminaire members configured to emit the white light in a pre-determined pattern on specific locations within the illumination space. In some configurations there are multiple fibers 3903 coupled to the white light source 3901 wherein each of the fibers 3903 is routed to its own unique illumination location. In other configurations there is one (or more) fiber 3903 coupled to the white light source 3091 wherein the one (or more) fiber is then split into multiple fibers and the multiple fibers are then routed to the individual illumination locations. Optionally, the multiple fibers are scattering or leaky fibers 3905 configured to emit or leak the white light. Optionally, the splitting of the white light from the one (or more) fiber to the multiple fibers could be accomplished with fiber splitters, switches, or mirrors.

Optionally, the luminaire members include one or more passive luminaries 3910. In the example of FIG. 39, passive luminaires 3910 are deployed at the end of the one or more transport fibers to modify the light before the light interacts with the target location. The passive luminaires 3910 function to modify the light by one or more of directing the light, scattering the white light, shaping the white light, reflecting the white light, modify the color temperature or rendering index of the white light, or other effects. In addition to the passive luminaire members 3910 of the white light system according to FIG. 39, scattering fiber or leaky fiber elements 3905 could be included in the white light system. Optionally, the leaky fibers form line emitting white light sources in the illumination space, which could be in combination with the passive luminaires 3910 or could be standalone and embedded into the architectural design features such as baseboard or crown molding.

### Benefits of Laser-Based Fiber Coupled White Lighting Systems

There are many advantages to such a central or distributed lighting system. By running passive optical fibers throughout infrastructure such as homes or buildings to deliver light instead of electrical wires the cost and complexity of the lighting system can be reduced and the risk of fire or other hazards would be lower providing a safe environment. Since there are thousands of feet of copper wire within the walls, ceilings, and floors of conventional buildings that could be replaced with lower cost glass or plastic fibers, laser-based white lighting systems provide a tremendous cost saving opportunity. Moreover, since the copper wires powering conventional lighting systems are often charged with high voltage, elimination or reduction of such high voltage lines from the building can reduce the risk of arcing or sparking, and thereby reduce the risk of fires.

Another benefit according to the present invention is an improved styling lighting system. With large amounts of light [200 lumens to 3000 lumens] delivered from a tiny optical fiber [core diameter of 100 μm to 2 mm, or greater such as 3 to 4 mm], the lighting fixtures used to manipulate, shape, and direct the light to the desired target can be drastically smaller than conventional lights based on LEDs or bulb technology, greatly improving the styling and reduce the cost of the lighting system. Additionally, since leaky fibers can be used to create a distributed or line light source that is not efficiently possible with LED, improved light styling can be achieved and light can actually be integrated into the building material such that it is “hidden” without discrete and acute light fixtures, which are often ugly to the human eye.

Energy savings can be realized in a laser-based central lighting system according to the present invention since the light source can be located remote from the illumination area. That is, the light source which generates a substantial amount of heat generation can be spatially isolated from an illumination area to prevent adding any unwanted thermal energy into the illumination area. For example, in a hot weather climate where air conditioners are running continuously to cool indoor environments, it is desirable to remove all heat generating objects and processes from the space. With conventional lighting where the light source is fixed to the location of emission [co-located], the light sources effectively act as heaters and counteract the cooling processes, making the system less efficient. For example, a single light source can dissipate from 1 W to 100 W, so in a situation where each light dissipates 10 W of heat in a large area where 100 or more of these lights would be required, over 1 kW of waste heat would be dissipated in the illumination area. With a fiber delivered laser-based white light source all of the heat generation from the source could be de-coupled from the illumination area, and thereby not contribute to undesired heating. However, in situations where heat was desired in the area of illumination [e.g., cold climate], the heat could be collected from the laser-based white light system and transported to the area via a duct or other means.

In yet an additional benefit of this central lighting or distributed lighting embodiment according to the present invention on fiber delivered laser-based white light, the replacement of a defective or failed laser-based light source or upgrade to an improved source would have reduced complexity compared to that of replacing conventional bulb or LED technology. With conventional sources where the actual light generating source is co-located with the emission area [e.g., in a ceiling] one must access the emission location to replace a failed or defective source, or upgrade their lights to improved or differentiated lights. Since the emission area or location of lighting are often in high areas that are not easily acceptable, it can be very time consuming, expensive and even dangerous to replace such sources. It can take hours or even days to replace the overhead lighting in offices or homes and may require special equipment such as ladders and mechanically powered lifts. In more extreme examples such as street lighting, bridge lighting, or tunnel lighting, the job to replace the light sources can include strong dangers associated with the equipment and the environment, and carry very high costs, which are incurred by the corporations, the private parties, or even by the taxpayers in government or municipal applications. In the present invention wherein the laser-based white light sources are located in an area remote from the emission points, the light sources could be contained in an easily accessed location where source change out could be fast, efficient, safe, and require no specialized equipment that can add to the cost and complexity of light source.

### Descriptions of Example Laser-Based White Lighting Sources

In the present embodiment according to this invention configured as a central lighting system or distributed lighting system, the white light generated by the laser-based white light source is transported from the first designated source location to one or more illumination locations where the white light is configured to illuminate one or more objects and/or areas. In one example the laser-based white light source is comprised of a surface mount device (SMD) type source wherein one or more laser diodes and co-packaged with one or more wavelength converting elements such as phosphor members. The overall laser-based white light source could be comprised of multiple individual sources such as multiple laser-based white light emitting SMD sources. The multiple sources could be arranged in a common housing with a common power supply configured in arrangements such as arrayed or stack arrangements. In an alternative arrangement the individual sources are configured in separate housing members with separate power supplies. In one preferred embodiment, the design would enable the replacement of the one or more laser-based white light sources when a source failure occurs, a defective source is encountered, or an upgrade or modification is desired.

According to the present embodiment, each of the one or more laser-based white light sources could be coupled to one or more transport optical fibers, wherein the transport optical fiber is configured to transport the white light from the first designated source location to one or more illumination areas. As an example, one of the one or more SMD sources could be configured to generate between 50 and 5000 lumens emitting from an emission area on the phosphor of 50 μm to about 1 mm, or to about 3 mm, or larger. In another example, the laser-based white light source could be configured with a T0-cannister package.

In another example configuration of the laser-based white lighting system according to the present invention includes one or more laser-based white light sources configured with a laser beam formed from the combination of multiple laser diode chips either by combining the beam from multiple individually packaged laser diodes or by combing the laser beams from the laser chips within a multi-chip laser package configured to combine the output emission beams from the multiple laser chips. In some examples, a combination of packaged laser types are used. The combined laser beams could be collimated using optical members in some embodiments and would be configured to excite a phosphor and generate the white light. The white light emission from the phosphor generated by the combined laser beams is coupled into an optical fiber member wherein the optical fiber member is configured to transport the white light and/or scatter the white light to create a line source. By using multi-chip package or multi-chip configurations the total optical power in the combined laser beam can be >10 W, >30 W, >50 W, 100 W, or greater than 500 W. With such high optical powers, very large white light lumen levels can be generated at one or more phosphors. For example, greater than 1,000 lumens, greater than 2,000 lumens, greater than 5,000 lumens, greater than 10,000 lumens, or greater than 100,000 lumens can be generated. This generated white light at the one or more phosphor members can then be fiber coupled to transport fibers to deliver the white light to one or more desired illumination areas. The one or more transport fibers could be comprised from one or more solid core fibers, one or more fiber bundles, a combination of solid core and fiber bundle type fibers, or other types of fibers. In some embodiments leaky or scattering fibers are included to make a line source.

In some embodiments, the combined laser beams from a multi-chip package or from multiple separate packaged lasers are coupled into an optical fiber wherein the optical fiber is configured to transport the laser light to a remote phosphor to form a remote white light source. By using multi-chip package or multi-chip configurations the total optical power in the combined laser beam can be >10 W, >30 W, >50 W, 100 W, or greater than 500 W. With such high optical powers, very large white light lumen levels can be generated at one or more phosphors. For example, greater than 1,000 lumens, greater than 2,000 lumens, greater than 5,000 lumens, greater than 10,000 lumens, or greater than 100,000 lumens can be generated. This generated white light at the one or more phosphor members can then be fiber coupled to transport fibers to deliver the white light to one or more desired illumination areas. The one or more transport fibers could be comprised from one or more solid core fibers, one or more fiber bundles, a combination of solid core and fiber bundle type fibers, or other types of fibers. In some embodiments leaky or scattering fibers are included to make a line source.

In one specific embodiment, a high lumen emission spot from the phosphor is configured to emit 1000 to 5000 lumens or more lumens of white light from a spot area of about 300 μm to about 3 mm, or larger. One or more plastic or glass optical transport fibers are coupled to the white light emission from the phosphor such that between 5% and 95% of the emitted white light is coupled into the one or more optical fibers. The one or more optical fibers comprising 1 to about 10 fibers, or 10 to about 50 fibers, or 50 to about 1500 fibers. The one or more optical fibers could be comprised of solid core optical fibers with core diameters in the range of about 100 μm to about 2 or about 3 mm, or could be comprised of fiber bundled cores wherein the individual strands comprising the bundle could have diameters from about 25 μm to about 250 μm to comprise a “bundled core” diameter of about 200 μm to about 2 mm, or greater such as 3 to 4 mm. The 1 or more optical transport fibers are then routed from the first designated source location to one or more designated illumination locations where they deliver the white light to target or area.

In another specific embodiment, a low to mid lumen emission spot from the phosphor is configured to emit 50 to 1000 lumens of white light from a spot area of about 50 μm to about 1 mm. One or more plastic or glass optical transport fibers are coupled to the white light emission from the phosphor such that between 5% and 95% of the emitted white light is coupled into the one or more optical fibers. The one or more optical fibers comprising 1 to about 5 fibers, or 5 to about 20 fibers, or 20 to about 40 fibers. The one or more optical fibers could be comprised of solid core optical fibers with core diameters in the range of about 100 μm to about 2 mm or greater, or could be comprised of fiber bundled cores wherein the individual strands comprising the bundle could have diameters from about 25 μm to about 250 μm to comprise a “bundled core” diameter of about 200 μm to about 2 mm or greater such as 3 to 4 mm. The 1 or more optical transport fibers are then routed from the first designated source location to one or more designated illumination locations where they deliver the white light to target or area.

Several central lighting systems based on laser-based fiber-coupled white light source are disclosed below. FIG. 40 presents a schematic diagram of a laser-based white light source coupled to more than one optical fibers according to an embodiment of the present invention. As shown in the FIG. 40, the laser-based white-light source 4010 is enclosed in a housing member 4005. The white light source 4010 is configured to receive electrical input 4001 to activate white light emission. Optionally, the white light source 4010 includes an electrical driver or circuit board member configured to condition the electrical input 4001. Optionally, the white light emission from the laser-based source 4010 is shaped with optional optical elements 4015 such as collimating lens elements and/or focusing lens elements and is fed into multiple optical fibers 4030 configured to transport the white light 4002. Optionally, connector units 4020 can be included to make for easy detachability of the optical fibers 4030, which would enable replacement of parts or entirety in the housing member 4005 for the light source 4010 or replacement of one or more of the transport optical fibers.

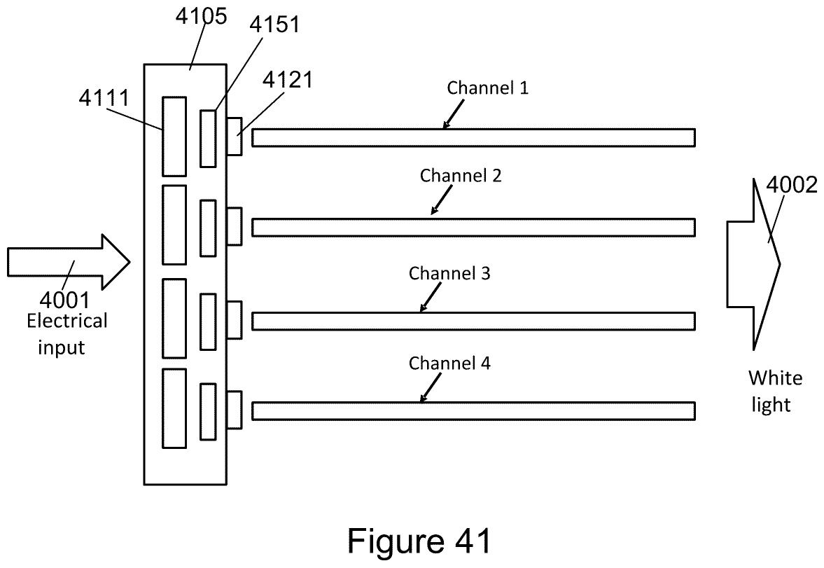

FIG. 41 presents a schematic diagram of multiple laser-based white light sources coupled to more than one optical fibers according to another embodiment of the present invention. As shown in the FIG. 41, the multiple laser-based white-light sources 4111 are enclosed in a single housing member 4105. All the white light sources 4111 are configured to receive electrical input 4001 to activate white light emission. Optionally, each of the multiple white light source 4111 includes an electrical driver or circuit board member configured to condition the electrical input 4001. The white light emission from each of the laser-based white light source 4111 is shaped with optional optical elements 4151 such as collimating lens elements and/or focusing lens elements and is fed into a channel (e.g., Channel 1) to transport or output the white light 4002. Optionally, each channel, e.g., Channel 1, includes multiple transport waveguides or fibers configured to transport the white light. Optionally, connector units 4121 can be included to make for easy detachability of the optical fibers for each channel to the respective white light source. The connector units 4121 enable replacement of the light source or replacement of the transport fiber elements in each channel.

According to the embodiments of the central lighting or distributed lighting system based on laser-based fiber-coupled white light source, one or more transport fibers in one or more channels could transport the white light from the first designed source area to one or more illumination areas. In one example, the laser-based white light source would provide light through a transport fiber to illuminate a single object or area in a given location or space. In another example, multiple transport fibers are coupled to the one or more white light sources to deliver white light to multiple objects and/or areas within a given area or location such as within a single room. In yet another example, multiple transport fibers are coupled to the one or more white light sources to deliver white light to multiple objects and/or areas within multiple areas or locations such as to different rooms of the same building or house.

In such a “central lighting” system including a laser-based white light source, the illumination locations could include more than one location in a single room or more than one location in more than one room of a structure, and even include indoor and outdoor illumination locations. For example, the laser-based central lighting system could be used to provide illumination to a complete home, a complete office structure, a complete shopping or business building, etc. An important design aspect of the laser-based lighting system is the system efficiency and the related capability to enable tuning the brightness or lumen output independently for each of the different illumination locations. In a simple example, the light output at a given location is controlled by tuning the white light output of the laser-based white light source providing the light to the given location by controlling the electrical input to the source. Although this is a simple approach to control the light output and would be sufficient if the specified laser-based white light source was only providing light to a single illumination location, in configurations wherein one laser-based white light source is coupled into multiple fibers to illuminate multiple locations it does not provide the flexibility to independently control the level of light delivered to each of the multiple locations.

Optical Switching or Routing of White Light from the Source

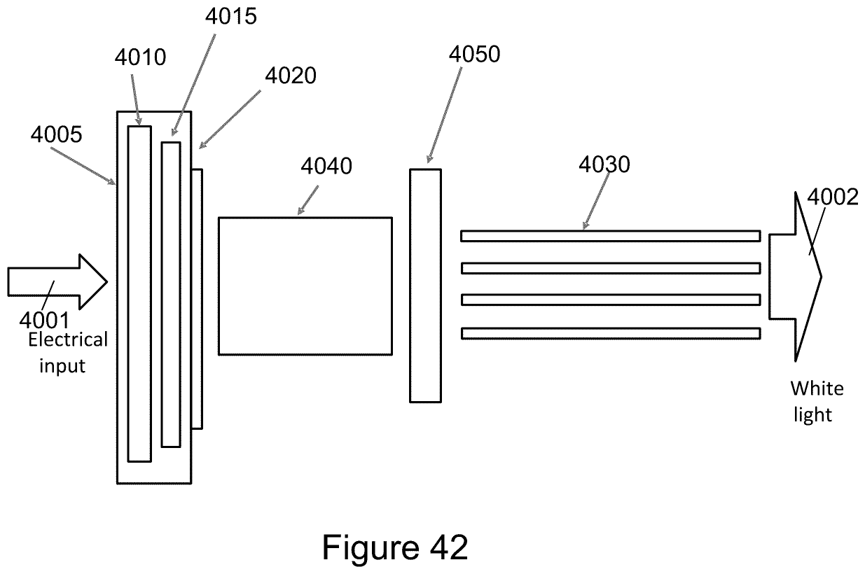

In the laser-based white light system according to the present invention, there are several configurations that can provide independent adjustment of the light levels delivered to each of the illumination locations. FIG. 42 presents a schematic diagram of a laser-based white light system including an optical switch device or module according to an embodiment of the present invention. Referring to FIG. 42, the laser-based white light generated from the laser-based white light source 4010 is captured or optically coupled via an coupling optics element 4015 through an optical connector 4020 into a white light supply member 4040. Optionally, the laser-based white light source 4010 is housed by a housing member 4005 and activated by receiving electrical input 4001 as described in the Laser-based white light system in FIG. 40. Optionally, the white light supply member 4040 is comprised of a single medium such as a large diameter fiber, a waveguide, or other, or is comprised of a multi-component medium such as a fiber bundle. The white light supply member 4040 delivers the optically coupled white light to an optical switching system 4050. The optical switching system 4050 is configured to direct the supplied white light to one or more output transport fibers 4030. Each of the output transport fibers 4030 delivers the white light 4002 to a designated illumination area. By utilizing the optical switching system, light can be directed only to illumination locations wherein the light is needed.

Optionally, the optical switch system 4050 shown in FIG. 42 is a device that selectively switches optical illumination signals on or off as an optical modulator. In some embodiments, the optical switch system is configured to switch data signals on or off as an data-signal modulator. In some embodiments, the optical switch system 4050 is configured to select signals from the white light supply member 4040 to a designated channel as an optical space switch of router to deliver the illumination to a designated location. Since the switching operation of the optical switch system 4050 can be temporal or spatial, such switching operations are analogous to one-way or two-way switching in electrical circuits. Independent of how the light itself is switched, systems that route light beams to different locations are often referred to as “photonic” switches. In general, optical modulators and routers can be made from each other.

Optionally, the optical switch system 4050 may operate by mechanical means, such as physically shifting an optical fiber to drive one or more alternative fibers, or by electro-optic effects, magneto-optic effects, or other methods such as scanning fiber tip or micro positioners. Optionally, low speed optical switches may be used solely for routing optical illumination to designated illumination sources. In one example of a low speed optical switch, the optical fibers are configured to physically move to route the illumination light from the source to the illumination area. Optionally, high speed optical switches, such as those using electro-optic or magneto-optic effects, may be used to route the optical illumination from the source to the desired illumination area and to perform logic operations.

Optionally, the optical switching system 4050 according to the present invention includes MEMS devices such as scanning micro-mirrors or digital light processing chips (DLP) including arrays of micromirrors that can deflect the laser-based illumination light to the appropriate receiver or designated illumination area. Optionally, the optical switching system 4050 according to the present invention includes piezoelectric beam steering devices involving piezoelectric ceramics function to direct the laser-based illumination light to the appropriate receiver or designated illumination area. Additionally, the optical switching system 4050 according to the present invention includes one based on scanning fiber tip technology, micro-positioners, inkjet methods involving the intersection of two waveguides, liquid crystal technology such as liquid crystal on silicon (LCOS), thermal methods, acousto-optic, magneto-optic technology approaches function to direct the laser-based illumination light to the appropriate receiver or designated illumination area.

Optionally, the optical switching system 4050 according to the present invention can be comprised of digital type switches that have only have two positions. The first position corresponds to the light being nominally turned “off” such that minimal amounts of light is coupled into the transport fiber and delivered to the illumination location. The second position corresponds to the light being turned “on” such that the white light is delivered to the designated illumination location. Digital switch configurations could include micro-mirrors, MEMS technology including scanning mirrors and arrays of mirrors, electro-optic valves, etc. In other laser-based white light systems according to the present invention, the switch system 4050 includes analog switches that can provide a dynamic range level of light in between the “off” state and the “on” state. Such analog switches can provide a valve function enabling a light “dimming” function. The capability to dim the light at specific illumination locations is an important function for many lighting applications.

As shown in the FIG. 42, the laser-based white-light source 4010 is enclosed in a housing member 4005. The white light source 4010 is configured to receive electrical input 4001 (including power and control signals) to activate the laser-based white-light source 4010 to produce white light emission. Optionally, the white light source 4010 includes an electrical driver or circuit board member configured to condition the power and electrical input 4001. The white light emission from the laser-based source 4010 is optionally shaped with optional optical elements 4015 such as collimating lens elements and/or focusing lens elements. The white light emitted from the white light source 4010 is coupled to an optional optical supply member 4040 configured to transport the light from the white light source 4010 to the optical switching device or module 4050. The optical supply member 4040 could range in length dimensions from very short lengths of about 1 mm to much longer lengths of 10 meters or longer. The optical supply member 4040 may be configured from a light pipe such as a solid waveguide, an optical fiber formed from a glass material or a plastic material or other material, a bundle of optical fibers, or could be configured from a free space design. The optical supply member 4040 is configured to deliver the white light to an optical switching device or module 4050. The optical switching performed by the optical switching device or module 4050 is designed and configured to route the white light to a network of optical transport fibers 4030. The optical transport fibers 4030 distribute and deliver the white light to desired illumination areas. By actuating the optical switching module 4050, the white light can be switched “on” to certain optical fibers directed to locations where the light is needed and switched “off” to the certain other optical fibers directed to locations where the light is not needed. In some examples of the laser-based white lighting system including an optical switching module, a white light supply member 4040 may not be included wherein the white light from the laser-based white light source 4010 is directly coupled into the optical switching module 4050.

Optionally, the optical switching module in FIG. 42 can include MEMS devices such as scanning micro-mirrors, or digital light processing chips (DLP) including arrays of micromirrors that can deflect the laser-based illumination light to the appropriate receiver or designated illumination area. In another configuration according to the present invention, the optical switching module 4050 includes piezoelectric beam steering devices, devices based on one of scanning fiber tip technology, micro positioners, inkjet methods involving the intersection of two waveguides, liquid crystal technology such as liquid crystal on silicon (LCOS), thermal methods, acousto-optic, magneto-optic technology and are configured to direct the laser-based illumination light to the appropriate receiver or designated illumination area. In some embodiments, combinations of various switching technologies are included.

Optionally, the switching module 4050 in FIG. 42 includes digital type switches to turn the light “on” and “off” in certain locations. Optionally, the switching module 4050 includes analog type switches that enable control of the amount of light delivered to certain locations to provide a dimming function. Optionally, the switching module 4050 includes a combination of digital type and analog type switches. Digital switch configurations could include micro-mirrors, MEMS technology, electro-optic valves, etc. In other laser-based white light systems, the analog switches employed in the switch module can provide a dynamic range level of light in between the “off” state and the “on” state. Such analog switches can provide a valve function enabling a light “dimming” function. This capability to dim the light at specific illumination locations according to the laser-based white light system is an important function for many lighting applications since different occasions, time of day, occupants' preferences, and other factors demand different light levels at a given location at different times.

### Minimized Power Consumption Lighting System

In various embodiments according to the present invention, the laser-based white lighting system is configured to provide energy savings compared to the current art. By configuring the central lighting system with optical switches and routers to preferentially direct the light from the source to where the light is desired as described above, along with providing the capability to adjust the light generated at the source level and the associated input power to drive the source, the system operation state can be optimized to minimize the power consumption for a given operating requirement.

In addition to the digital and analog switching capability to enable precise control of the light levels delivered from the laser-based white light source to the desired illumination areas described above, the amount of light output from the one or more white light source modules can be adjusted to provide an added level of control of the white light system's generation and distribution of the light to the illumination locations. By careful consideration of the system's characteristics and the lighting requirements at a given use condition, the optical switches can be adjusted in conjunction with adjusting the input power driving the laser-based source to generate the white light for an optimized system efficiency. By adjusting the power or current delivered to the one or more laser-based white light sources, the amount of input electrical power and output luminous flux generated by the white light source is changed. During times when only a relatively low amount of white light is needed such as when light is only needed in few locations such as during day time or late at night when only 1-3 lights are on in a home, the one or more white light source can be run at relatively low luminous flux output levels, which would require less input power and hence save energy.

For optimum utilization efficiency of the light generated by the laser-based white light source and hence optimum power consumption efficiency, it is necessary that a high fraction of the useful generated light from the source can be directed into the specific transport fibers delivering the light to the desired illumination locations at a given time. In a spatially static system lighting system that could even include an optical switching module, it is an extreme technical challenge to make such efficient use of all generated light.

For purposes to illustrate an example of energy efficiency in a laser-based white lighting system we describe a system comprising a single laser-based white light source feeding ten optical transport fibers routed to ten separate illumination locations. The optical transport fibers are optically coupled to the white light source using a coupling pathway and optical switches functioning to control the light level at each illumination location. In the case that light is desired at all ten illumination locations the white light source is powered to generate the desired level of light at the source and all light switches are in the “on” position for digital type switches or open to the desired level for analog type switches. In this configuration, assuming the fiber coupling architecture is well designed, the laser-based white light system can operate in an optimum energy efficiency condition. However, in the case that light is only desired at two of the ten locations, such a spatially static system the light switches for the 2 transport fibers feeding these two locations would be configured in the “on” position for digital type switches or “open” to the desired level for analog type switches. The light switches for the 8 transport fibers feeding the light to illumination locations where light is not desired would be configured in the “off” position for digital type switches or in the “closed” position for analog type switches. In such a configuration, all of the light directed to the transport fiber locations wherein the optical switches were configured in the “off” or “closed” position would be wasted light. In this case only about two-tenths of the useful light in the system would be delivered to illumination areas, providing only a 20% efficiency of the useful fiber coupled light.

One solution to this efficiency challenge to create a most energy efficient laser-based white light system is to add a spatial modulation capability. By including a spatial modulation feature, the white light supplied from the laser-based white light source can be spatially directed to the select transport fibers delivering light to the locations where light is desired at any given time. That is, in the example scenarios given above including a laser-based white light source feeding into ten optical transport fibers the system could operate at high energy efficiency in both cases. In the first case where light is desired at all ten illumination locations, the spatial modulator would be driven to spatially direct the source light to all ten fiber inputs distributing all of, or most of, the useful light from the source to the ten illumination locations. In the second case where light is only desired at two of the ten illumination locations, the spatial modulator would be driven to spatially direct the source light only to the two fiber inputs transporting the light to the two illumination locations where light is desired. To optimize the energy efficiency of the system in the latter case, the input power to the laser-based light source could be reduced such that the light source only generates about 20% of the light of the first case, assuming that the light required in all locations is about equal. By doing this, the amount of wasted light would be minimized.

The spatial modulation apparatus comprised in the laser-based white lighting system could be configured as part of the optical switching module or device, could be the optical switching module device itself, or could be configured separate from the optical switching module. In some embodiments, the spatial modulation device is included as the switching module since the spatial modulation effect itself can serve to turn transport fibers “on” by directing light into them or turn transport fibers “off” by directing light away from them.

In some embodiments according to the present invention, the spatial modulation may be a “slow” modulation wherein the source light is configurable from one static position where it can operate with one desired supply of light to transport fibers to multiple other static positions where it can operate with other desired supply of light to transport fibers. This system can be viewed as a reconfigurable static system wherein the spatial modulator can change the supply light to predetermined locations to supply light to predetermined transport fibers. This spatial modulation can be accomplished with electro-mechanical mechanisms, piezoelectric mechanisms, micro-electromechanical system (MEMS) mechanisms such as scanning mirrors and/or digital mirror arrays such as DMDs, liquid crystal mechanisms, beam steering mechanisms, acousto-optic mechanisms, and other mechanisms. Many of these mechanisms are in existence today and are deployed as optical switches, modulators, micro-displays, or other technologies in various systems such as in telecommunication systems.

In some embodiments according to the present invention, the spatial modulation may be a “fast” modulation wherein the source light is actively or dynamically scanned across a spatial field comprising the optical input paths to the transport fibers. This “fast” spatial modulation configuration enables the addition of a time domain element to the spatial modulation. With the ability to actively spatial modulate over a spatial area at high speeds the scanning rate and pattern can be designed to provide a higher time averaged amount of light to certain optical transport fiber inputs, a lower time averaged amount of light to certain other optical transport fiber inputs, and even no or a very low amount of time averaged light to certain other transport fiber inputs such that the light level entering each transport fiber can be tuned to the desired level of light associated with the corresponding illumination area. In this spatial modulation embodiment including a fast modulation capability the supply light from the laser-based white light source would be configured such that a majority or large fraction of the usable white light from the source is within the light beam being scanned across the spatial field and available for entry into the transport fibers. Such a scanning configuration coupled with the ability to tune the total light output of the laser-based white light source by controlling the input electrical power would provide a highly efficient white lighting system since the amount of light generated at the source can be tuned to provide only the level of the light needed at the one or more illumination locations to avoid wasting light by illuminating unnecessary areas.

The fast spatial modulation of the laser-based white light according to the present invention can be accomplished in many ways. To name a few, the fast switching can be accomplished with electro-mechanical mechanisms, piezoelectric mechanisms, micro-electromechanical system (MEMS) mechanisms such as scanning mirrors and/or digital mirror arrays such as DMDs, liquid crystal mechanisms, beam steering mechanisms, acousto-optic mechanisms, and other mechanisms.

In one embodiment of the present invention, the fast switching is accomplished with a MEMS technology. According to the present invention, the light from the laser-based white light source is collimated into a beam of white light. The beam of white light is then directed to one or more scanning MEMS mirrors. The scanning MEMS mirrors can then direct the beam of white light toward a spatial field containing the optical pathways to the input of the transport fibers such that when the MEMS mirror is scanning the beam of white light it can direct the light toward any of the optical transport fibers based on a control circuit driving the MEMS so that a predetermined amount of time averaged light can be optically coupled into the desired transport fibers to deliver a select amount of light to select illumination areas. The MEMS mirrors can be selected from a electro-static activated mirror, an electromagnetic activated mirror, a piezo-activated mirror, and can be operated in a resonant or a non-resonant vector scanning mode. The MEMS mirror could be configured to scan on a single-axis to scan 1D array of transport optical transport fiber input paths, could be configured as a bi-axial scanning mirror to scan 2D arrays of optical fiber input paths, or could be configured with multiple MEMS mirrors such as using 2 single-axis scanning MEMS mirrors, or other configurations.

The scanning rate of a “fast” spatially modulated light may range from the hertz range, to the kilohertz range, to the megahertz range, and even into the gigahertz range. The scanning rate of the spatially modulated light signal would be preferentially be fast enough so that it was not detectable by the human eye. In some spatial modulation approaches, the modulation could be adaptable to a fast scanning or a slow scanning depending on the instantaneous needs of the laser-based white lighting system. For example, by using a non-resonant vector scanning MEMS mirror the supply of white light could be directed to only a static position of the field such that light was only coupled into select transport fibers, but could also scan the entire field with a predetermined pattern to couple light into all of the transport fibers with the desired amount.

In some embodiments of the present invention including a spatial modulation, the white light supply would be modulated in conjunction with the spatial modulation. That is, either by modulating the current to the laser-based white light source or using an external modulator, the white light level can be turned up and down as the spatial modulator scans the supply white light across the spatial field including the optical inputs to the transport fibers. By including an amplitude modulation of the white light supply a further level of energy efficiency can be achieved since the light source can be turned off or substantially off when the spatial position of the supply light is in between transport fiber inputs to eliminate the wasted light that would result when the spatial modulator is moving the source light in-between fiber inputs. Moreover, by modulating the light level another level of selectively tuning the amount of light coupled into the various transport fibers can be achieved. This feature enables the ability to selectively dim and brighten the light levels at the independent illumination positions fed by the transport fibers.

In another example of a laser-based white light system with a low energy consumption, the system is configured with a spatial modulation capability to selectively direct and optically couple the source white light into multiple transport fibers, the capability for amplitude modulation of the laser-based white light source output, and an optional optical switching module comprised of analog switches that can open and close to various levels to enable a range of white light amounts to pass through and be delivered to the desired illumination location. By adjusting the spatial modulation scanning pattern and characteristics [e.g., scanning frequency and repetition rate] along with the amplitude of the light generated by the laser-based white light source and the analog switches within each of the optical pathways to the multiple illumination location, the desired amount of light can be delivered to the illumination locations at an optimized efficiency.

In a specific example of the present embodiment, we outline two use conditions to illustrate how such a system can optimize energy efficiency. In the first scenario, there is a high demand of total light from the central lighting system. An example of a high light demand time could be during the early evening hours just after the sun is set and people are still well awake either working, in their home, or out at shopping or entertainment locations. During this first scenario where there is a high light demand, perhaps every room in the home or building equipped with the central lighting system would need high illumination. In this configuration, the input power to the one or more laser-based white light sources would be turned up to a high level, for example, near a maximum rated level, and the spatial modulator would scan the supply white light generated from the one or more white light sources across the entire field including the optical coupling pathways to the transport fibers to deliver light to all illumination locations. By adjusting some combination of the spatial modulation scanning characteristic, an amplitude modulation pattern on the laser-based white light sources, and the analog switches on each of the transport fibers the precise level of desired light can be delivered to each independent illumination location. In a second scenario an intermediate level of light is desired in the home. An example time for such an intermediate time may be after dinner time and before bed time when many of the lights are not used in the home, there are still a few active rooms in the home, and some rooms where only a low level of light is desired such as a reading light. In this scenario, the spatial scanning characteristic of the spatial modulator and/or the amplitude modulation pattern of the white light source would be modified to eliminate directing light in the spatial field that includes the optical coupling inputs for the transport fibers feeding the illumination locations wherein light is not desired. Moreover, the optical switches to these locations could be turned off to prevent any low levels of light. The adjusted spatial modulation characteristic and/or adjusted white light amplitude modulation pattern would provide input source light to the spatial field that includes the input coupling pathways for the transport fibers feeding the illumination locations wherein desired high and low levels of illumination. The optical switches on each of the transport fiber channels could fine tune the light levels.

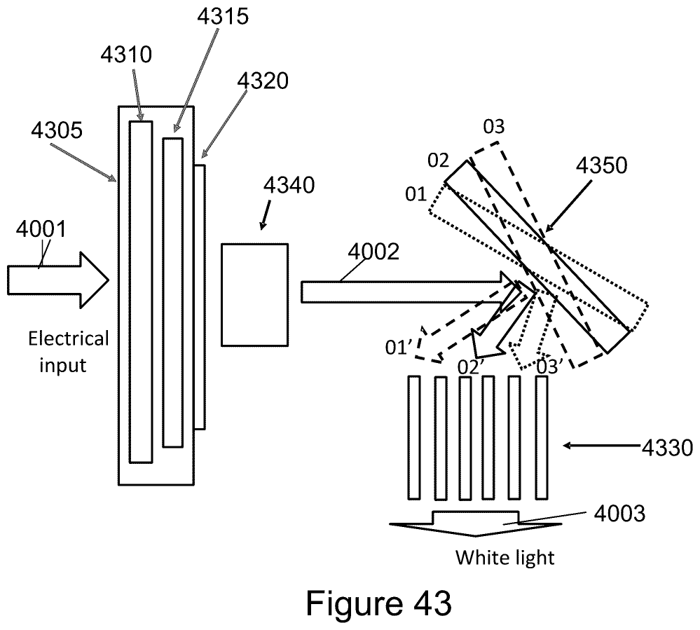

FIG. 43 presents a schematic illustration of a laser-based white light system including a fast switching optical switch unit according to a specific embodiment of the present invention. As can be seen in the FIG. 43, the laser-based white-light source 4310 is enclosed in a housing member 4305. The white light source 4310 is configured to receive electrical input 4001 (including power and control signals) to activate and produce white light emission. Optionally, the white light source 4310 includes an electrical driver or circuit board member configured to condition the electrical input 4001. The white light emission from the laser-based source 4310 is optionally shaped with optional optical elements 4315 such as collimating lens elements and/or focusing lens elements. The white light emission is coupled to an optional optical supply member 4340 through optical connector unit 4320. The optical supply member 4340 is configured to transport the white light 4002 from the white light source 4310 to the optical switching module 4350. The optical supply member 4340 is configured to be in a length range from very short lengths of about 1 mm to much longer lengths of 10 meters or longer. The optical supply member 4340 may be configured from a light pipe such as a solid waveguide, an optical fiber formed from a glass material or a plastic material or other material, a bundle of optical fibers, or could be configured from a free space design. Optionally, the optical supply member 4340 is configured to deliver the white light 4002 to an optical switching module 4350. Optionally, the optical switching module 4350 is a fast optical switching module configured to route the supplied white light 4002 to a network of optical transport fibers 4330. The optical transport fibers 4330 are configured to distribute and deliver the white light 4003 to desired illumination areas.

In the example according to FIG. 43, the fast optical switching module 4350 uses a MEMS mirror to reflect the supplied white light 4002 and direct to the inputs of the optical transport fibers 4330. The optical transport fibers 4330 can be configured in 1-dimensional arrays or 2-dimensional arrays. Optionally, the MEMS mirror can be configured to scan on one axis of the 1D array of optical fibers 4330 or can be configured for bi-axial scanning to feed 2D arrays of optical transport fibers 4330. By actuating the scanning MEMS mirror to various positions, such as 01, 02, 03, the supplied white light 4002 is reflected properly to different directions 01′, 02′ 03′ respectively leading to different inputs of the optical transport fibers 4330. Therefore, different levels of scanning mirror deflection correspond to coupling light to different transport fiber inputs, and hence control the supply of light to the transport fibers 4330. The fast switching of the MEMS scanning mirror combined with the ability to simultaneously modulate the input white light amplitude level by modulating the laser-based white light source 4310, the precise light level to each transport fiber optical input can be precisely controlled. According to this embodiment, the light level at each illumination location can be precisely controlled. In some examples of the laser-based white lighting system including an optical switching module 4350, a white light supply member 4340 may not be included wherein the white light 4002 from the laser-based white light source 4310 is directly coupled into the switching module 4350.

Optionally, the fast switching module included in FIG. 43 can be comprised with MEMS devices, such as scanning micro-mirrors, integrated with digital light processing chips (DLP) including arrays of micromirrors that can deflect the laser-based illumination light to the appropriate receiver or designated illumination area. In some embodiments, multiple scanning mirrors are included. In other embodiments, scanning mirrors are combined with other switching technologies such as mirror arrays such as DMD or DLP technologies. In yet other embodiments, different fast switching technologies are used.

In another example of the optical switching system configurations according to the present invention, the optical switching module according to the present invention, comprises piezoelectric beam steering devices, involving piezoelectric ceramics function to direct the laser-based illumination light to the appropriate receiver or designated illumination area. In additional examples of the optical switching system according to the present invention, scanning fiber tip technology, micro positioners, inkjet methods involving the intersection of two waveguides, liquid crystal technology such as liquid crystal on silicon (LCOS), thermal methods, acousto-optic, magneto-optic technology approaches function to direct the laser-based illumination light to the appropriate receiver or designated illumination area. In some embodiments, combinations of various switching technologies are included.

### Smart Lighting

In various embodiments according to the present invention, the laser-based white lighting system is configured for a smart lighting capability. In one example, by equipping the laser-based central lighting system with sensors for feedback to adjust the lighting based on the said sensor feedback a smart lighting system can be realized. In this example, photovoltaic light sensors can be used to turn-lights off in the presence of ambient light or turn them on when it is dark. Additionally, motion sensors IR sensors could be used to detect human presence and only activate the illumination to the area when it is needed. In a further example of a smart lighting system based on laser-based white light, by enabling the laser-based white lighting system to serve as a visible light communication system to transmit data such as LiFi, the laser-based white lighting system according to the present invention can be a smart lighting system.

The present disclosure provides a smart lighting system or a smart lighting apparatus configured with various sensor-based feedback loops integrated with gallium and nitrogen containing laser diodes based on a transferred gallium and nitrogen containing material laser process and method of manufacture and use thereof. Merely by examples, the invention provides remote and integrated smart laser lighting devices and methods, projection display and spatially dynamic lighting devices and methods, LIDAR, LiFi, and visible light communication devices and methods, and various combinations of above in applications of general lighting, commercial lighting and display, automotive lighting and communication, defense and security, industrial processing, and internet communications, and others.

The laser-based white light system according to the present disclosure can include a smart or intelligent lighting function. Such a smart or intelligent function can include features and functions such as sensors for feedback, reaction responses based on sensor feedback or other input, memory storage devices, central processing units and other processors that can execute algorithms, artificial intelligence (AI), connectivity such as on the internet of things (IoT), data transmission such as using a visible light communication (VLC) or LiFi, data receiving such as with photodetectors or other sensors, communication, sensing such as range finding or 3D imaging, LIDAR, temporal or spatial modulation, a dynamic spatial modulation, color tuning capabilities, brightness level and pattern capability, and any combination of these features and functions, including others. Examples are included in U.S. application Ser. No. 15/719,455, filed Sep. 28, 2017, the entire contents of which are incorporated herein by reference in their entirety for all purposes.

In some embodiments, the light source of the laser-based fiber coupled white lighting system is configured for visible light communication or LiFi communication. Optionally, the light source includes a controller comprising a modem and a driver. The modem is configured to receive a data signal. The controller is configured to generate one or more control signals to operate the driver to generate a driving current and a modulation signal based on the data signal. In one configuration, the electrical modulation signal is coupled to the laser diode device in the laser-based white light source to drive the laser according to the signal and generate a corresponding output optical signal from the laser diode. In one example wherein the laser-based white source comprised a gallium and nitrogen containing diode operating in the violet/blue wavelength range of 400-480 nm and a phosphor member serving as a wavelength conversion member, the modulation signal would be primarily carried by the violet/blue direct diode wavelength from the light source to a received member.

Optionally, as used herein, the term “modem” refers to a communication device. The device can also include a variety of other data receiving and transferring devices for wireless, wired, cable, or optical communication links, and any combination thereof. In an example, the device can include a receiver with a transmitter, or a transceiver, with suitable filters and analog front ends. In an example, the device can be coupled to a wireless network such as a meshed network, including Zigbee, Zeewave, and others. In an example, the wireless network can be based upon an 802.11 wireless standard or equivalents. In an example, the wireless device can also interface to telecommunication networks, such as 3G, LTE, 5G, and others. In an example, the device can interface into a physical layer such as Ethernet or others. The device can also interface with an optical communication including a laser coupled to a drive device or an amplifier. Of course, there can be other variations, modifications, and alternatives.

In some embodiments of the laser-based fiber coupled white lighting system according to the present disclosure, the lighting system includes one or more sensors being configured in a feedback loop circuit coupled to the controller. The one or more sensors are configured to provide one or more feedback currents or voltages based on the various parameters associated with the target of interest detected in real time to the controller with one or more of light movement response, light color response, light brightness response, spatial light pattern response, and data signal communication response being triggered.

Optionally, the one or more sensors include one or a combination of multiple of sensors selected from microphone, geophone, motion sensor, radio-frequency identification (RFID) receivers, hydrophone, chemical sensors including a hydrogen sensor, CO₂ sensor, or electronic nose sensor, flow sensor, water meter, gas meter, Geiger counter, altimeter, airspeed sensor, speed sensor, range finder, piezoelectric sensor, gyroscope, inertial sensor, accelerometer, MEMS sensor, Hall effect sensor, metal detector, voltage detector, photoelectric sensor, photodetector, photoresistor, pressure sensor, strain gauge, thermistor, thermocouple, pyrometer, temperature gauge, motion detector, passive infrared sensor, Doppler sensor, biosensor, capacitance sensor, video cameras, transducer, image sensor, infrared sensor, radar, SONAR, LIDAR.

Optionally, the one or more sensors is configured in the feedback loop circuit to provide a feedback current or voltage to tune a control signal for operating the driver to adjust brightness and color of the directional electromagnetic radiation from the light-emitter in an illumination location correlating to the one or more sensors.

Optionally, the one or more sensors is configured in the feedback loop circuit to provide a feedback current or voltage to tune a control signal for operating the beam steering optical element to adjust a spatial position and pattern illuminated by the beam of the white-color spectrum.

Optionally, the one or more sensors is configured in the feedback loop circuit to send a feedback current or voltage back to the controller to change the driving current and the modulation signal for changing the data signal to be communicated through at least a fraction of the directional electromagnetic radiation modulated by the modulation signal.

Optionally, the controller further is configured to provide control signals to tune the beam shaper for dynamically modulating the white-color spectrum based on feedback from the one or more sensors.

Optionally, the controller is a microprocessor disposed in a smart phone, a smart watch, a computerized wearable device, a tablet computer, a laptop computer, a vehicle-built-in computer, a drone.

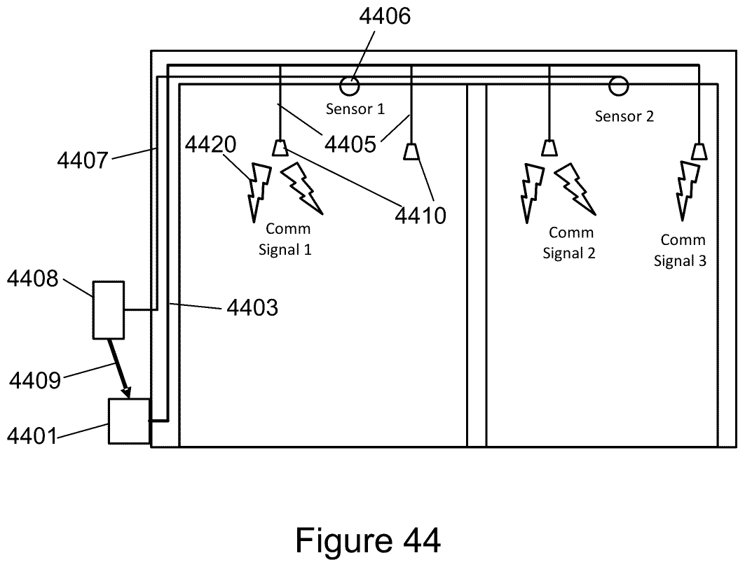

In some embodiments the smart lighting system is comprised with both sensors for feedback loops and a communication function such as LiFi or VLC. FIG. 44 presents a schematic illustration of a smart lighting system according to an embodiment of the present invention. The smart lighting system includes a laser-based fiber coupled white light source configured with both sensors for feedback loops and a communication function. As shown in FIG. 44, the system includes one or more laser-based white light sources 4401 wherein the white light is delivered to one or more illumination locations with optical transport fibers 4403. The optical transport fibers 4403 are configured to deliver the white light to passive luminaire elements 4410 which also shape or pattern the light and direct it to respective illumination targets. The laser-based fiber-coupled white light system according to FIG. 44 also includes sensors 4406 coupled with the fibers 4403 and positioned near the one or more illumination locations. These sensors 4406 are configured to sense desired characteristics of the environment or situation such as the temperature, motion, ambient light level, occupancy of the area, profile or characteristics of the occupancy, status of a situation, or others which could include any possible characteristic that is capable of being sensed. The sensor signals are configured with a connection to a processing unit 4408. The connection of the sensors 4406 to the processing unit 4408 could be realized with a wired line 4407 such as an electrical cable or an optical cable, or through a wireless transmission. The processing unit 4408 is then configured to interpret the sensor input data and provide a feedback response 4409 to the laser-based white light source 4401. When certain sensor signals are detected, the processing unit 4408 triggers certain feedback responses to command operation of the laser-based white light source 4401. These commands include increasing or decreasing the level of light delivered to the illumination area, changing the color temperature or CRI of the light, changing the spatial pattern of the light, or other possible responses.

The laser-based fiber coupled white light system in FIG. 44 also includes a communication function to provide a communication signal 4420. The one or more laser-based white light sources 4401 are modulated or encoded with data to be cast or projected to one or more illumination locations. In some embodiments, different data streams are provided to different locations or illumination locations by encoding on different laser-based white light sources 4401 that are respectively configured to deliver light to the different locations. Optionally, the different data streams are provided by encoding on one light source yet through a high-speed switching functional unit (not shown) to deliver to respective different locations. Optionally, the communication scheme could be a LiFi or a VLC communication. Optionally, the communication is operated with data rates of >0.5 Gb/s, >1 Gb/s, >5 Gb/s, >10 Gb/s, or greater than 50 Gb/s. In some embodiments, the sensors 4406 provide a feedback signal to the processing unit 4408 that triggers a change in the communication signal 4420. In one example, if certain electronic devices, objects, or living entities such as humans or animals are detected by the sensors 4406, certain communication signal 4420 could be triggered to be transmitted.

Of course, there can be many variations in the embodiment of the smart lighting system shown in FIG. 44. In some implementations, sensors are included without the communication function. In other implementations, the communication function is included without the sensor members. In yet other implementations, there are more features included, for example, the system can provide a connectivity hub for the internet of things.

Lighting Apparatus with Laser-Based Fiber Coupled White Light

In another preferred embodiment, the present invention comprising a laser-based fiber-coupled white light source is configured in an architectural lighting apparatus. Optionally, the lighting apparatus is associated with the distributed or central lighting system according to the present disclosure. In one example, the architectural lighting apparatus includes a passive luminaire. The passive luminaire is configured to shape the white light, pattern the white light, or provide a desired lighting effect. The passive luminaire may include features and designs for scattering the white light, reflecting the white light, waveguiding the white light, distributing the white light, modifying the color temperature of the white light, modifying the color rendering characteristic of the white light, creating distribution patterns with varied color, brightness, or other characteristic, other effects, or a combination.

In an embodiment, a lighting apparatus is configured with a laser driven phosphor high luminance light source coupled to a fiber optic cable. Optionally, the fiber optic cable is disposed at the top end of the apparatus. The lighting apparatus at this configuration and is functionality is called the active assembly or light engine. The light travels downward along the length of the fiber optic cable and emerges at a bottom end of the cable where an optical assembly is coupled. This optical assembly at the bottom end is called the passive assembly. The entire length of the lighting apparatus is intended to be hung from an architectural element and extends downward by gravity. Optionally, the overall fixture is called a pendant fixture.

In one example of an active assembly, the laser and phosphor are arranged within a surface mounted device (SMD) component that is mounted on a printed electric circuit board so that electric power may be supplied from outside to the device. The SMD optical window is arranged close to optical lenses that collect the maximum practical amount of light and direct the light into the fiber optic cable top end. Since the light source is very small, the optical assembly and casing may also be quite small on the order of 3 cm diameter or less.

Since the laser driven phosphor high luminance light source is very small, the fiber optic cable may also have a small diameter, 1 mm or less, while still transporting a large fraction of the total light from the source. Alternatively, a larger fiber optic cable may collect the light and then be split into two or more cables that all transport their portion of the light. In this way, one light engine may potentially provide light to multiple fiber optic cables for different pendant fixtures. Optionally, the fiber optic cable may be made of glass or transparent plastic like acrylic (PMMA) or polycarbonate. The fiber optic cable may be of any length where in lighting applications the length will typically be from the ceiling or beam to a work surface or one to ten meters. The pendant fixtures may also be applied outdoors from a building element, truss or pole. Optionally, the emission of light may be scattered by inclusions within a transparent fiber so that it exits the cylindrical surface of the fiber. In this way the fiber appears to glow in whole or in part for a decorative or lighting effect. Optionally, the fiber optic cable may also solely transport the light to the bottom end and may also be jacketed or coated so as to appear dark or any other color. While gravity alone will lead the cable to be straight and pointed downward, additional frames and structures may be applied in order to give the fiber optic cable a curve, form or shape where the bottom or distal end may still point downward or any other direction.

Optionally, the bottom end of the fiber optic cable may be fitted with a connector with screw threads or bayonet mount or any other type of connection mechanism whereby an optical element may be applied. One or more optical elements and passive assembly may consist of a lens and housing so that the light is directed toward the work surface. Alternatively, the optical elements may scatter the light sideways with lenses or decorative elements or a combination of these. Since these optical elements collect light from a small diameter fiber optic cable, the passive assembly may be configured to be a very small size, 3 cm or less, while still directing a large fraction of the light emitted or also creating a straight narrow collimated beam in the directional lighting example. Alternatively, the passive assembly may be made to appear like a conventional lighting fixture or light bulb like a track head, MR-16 lamp, candelabra decorative lamp, utility or rough service lamp, chandelier or conventional incandescent light bulb. Unlike these conventional lamps though, the interior of the passive assembly does not contain any electrical parts that can fail or generate heat.

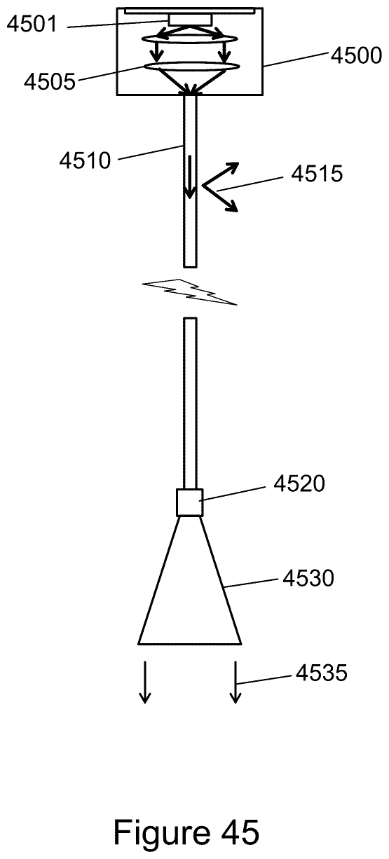

A schematic diagram of pendant light illuminated with a laser-based white light source according to an embodiment of the present invention is shown in FIG. 45. As shown in the figure, the laser-based light source 4500 is configured remotely from the passive luminaire element 4530, but is still located nearby to the luminaire, to form a pendant lighting apparatus. For example, the laser-based white light source 4500 may be located within a few inches, to a few feet, to 10-100 feet from the luminaire element 4530. Moreover, the laser-based white light source 4500 is configured to only supply light to a discreet luminaire 4530, which is not part of a larger laser white light distribution system. The laser-based white light source is a light engine as described above, including a SMD laser and phosphor component 4501 formed on a PCB and a set of fiber optic coupling lenses 4505. The laser-based white light source is a light engine 4500 is optically coupled to a fiber optic cable 4510 so that the white light is guided to reach the passive luminaire 4530. In one example the fiber optic cable 4510 may be a transport fiber such that the white light with substantially high coupling efficiency of greater than 20% up to 90% is guided from the laser-based white light source 4500 to the to the passive luminaire 4530 for directional or uniform light illumination 4535. In another example, the fiber optic cable 4510 is configured with scattering elements to create a leaky fiber such that the fiber itself emits the white light 4515 and “glows”. In yet another example, the fiber optic cable 4510 is composed of multiple sections having different guiding and scattering effects. As shown in FIG. 45, the passive optical luminaire 4530 could be configured with a connector 4520 to attach to the fiber optic cable 4510. This would enable easy replacement of the passive luminaire 4530 in any cases. The connector 4520 could be a threaded connector such as an SMA, but could be other connectors such as snap in connectors.

The pendant lighting apparatus has its optical assembly much smaller in size than conventional means of pendant lights. The light engine, fiber and passive assembly present a fine and minimally invasive appearance while still lighting effectively and attractively. The whole (both active and passive) assembly is also lighter and requires less mechanical support. The passive assembly has no electrical or moving parts so it is more reliable and less subject to damage despite being near the work surface. The light engine or active assembly is relatively far away from the area of activity and may be arranged in such a way for more convenient servicing while not generating obstacles to the work area.

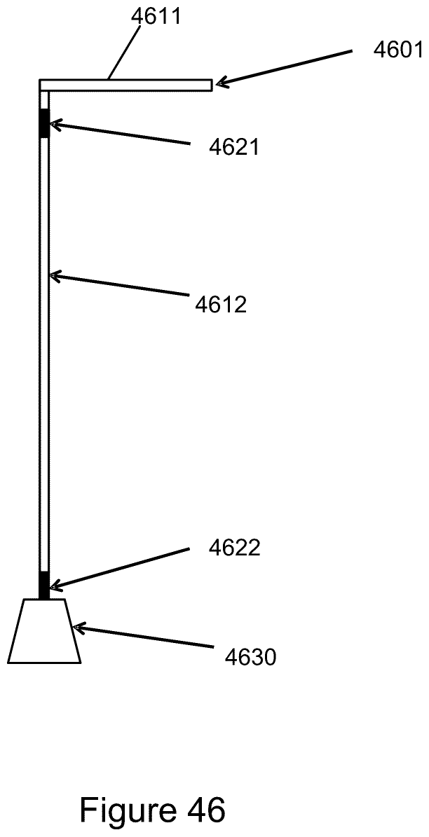

In some embodiments, the passive luminaire is configured in a laser-based lighting system wherein the laser-based white light is transported to the passive luminaire from a remote white light source located in a designated source location. FIG. 46 presents a schematic diagram of pendant light illuminated with a remote laser-based white light source according to an embodiment of the present disclosure. As shown in the FIG. 46, the passive luminaire element 4630 is fed by a white light source (not shown) that is part of a larger laser-based white light distribution system. For example, the white light source may be located several feet from the passive luminaire element 4630, could be located from 10 to 100 feet, or more than 100 feet or 1000 feet away from the luminaire source 4630. Moreover, the laser-based white light source can be configured to only supply to many illumination locations within a larger laser white light distribution system. In this lighting system, the laser-based white light is distributed from one or more sources to multiple illumination locations.

Referring to FIG. 46, the laser-based light source is configured in a centralized location to supply the white light 4601. Optionally, one or more white light sources provide the white light 4601 for a network of illumination areas comprising a plurality of passive optical elements like one pendant light 4630 as shown in FIG. 46. The laser-based white light source is optically coupled to a fiber optic cable 4611 so that the white light 4601 is guided to reach the passive luminaire 4630. Optionally, the fiber optic cable 4611 is a transport fiber which is coupled to a second optical fiber cable 4612 via a connector 4621. The second optical fiber cable 4612 is configured to deliver the white light directly to the passive luminaire 4630. In one example, the second optical fiber cable 4612 may be also a transport fiber such that substantially all the light is guided from the laser light source to the to the passive luminaire 4630. In another example, the second optical fiber cable 4612 is configured with scattering elements to create a leaky fiber such that the fiber itself emits white light and “glows”. In yet another example, the second optical fiber cable 4612 is composed of multiple sections having different guiding and scattering effects. As shown in FIG. 46, the passive optical luminaire 4630 could be configured with a connector 4622 to attach to the second optical fiber cable 4612. This would enable easy changing of the passive luminaire 4630 to a new one or different type of luminaire or to perform maintenance work to the passive luminaire 4630. The connector 4622 could be a threaded connector such as an SMA, but could be other connectors such as snap-in connectors.

The embodiments of implementing passive luminaires enabled by the fiber-coupled white light system provide unprecedented flexibility that can extend to many benefits and form factors. A primary benefit is that with the passive luminaire the electronics, heat-sinks, and other components do not have to be included in the visible luminaire member. This not only enables the designer to separate the heat load from the light emission point, but also allows for the luminaires to be made much smaller, lighter, and/or cheaper than conventional luminaire members with the light sources co-located with the emission point. The passive luminaire members can be made to any shape or form including line sources, pendant lights, etch, and can be designed to be totally novel concepts or could replicate existing light fixtures to provide a faux luminaire. Example faux luminaire types could include any type of already existing bulb or new bulbs, including MR type bulbs such as the MR-16, A-lamp bulbs, PAR type bulbs such as the PAR30, Edison type bulbs, tube light such as T-type bulbs, and other types of bulbs that commercially available. The light sources could be included as recessed cove lighting, indirect pendant lighting fixtures, direct/indirect pendant lighting fixtures, recessed lighting fixtures, wall wash light fixtures, wall sconces, task lighting, under cabinet light fixtures, recessed ceiling luminaires, ceiling luminaires, recessed wall luminaires, wall luminaires, in-ground luminaires, floodlights, underwater luminaires, bollards, garden and pathway luminaires, and others.

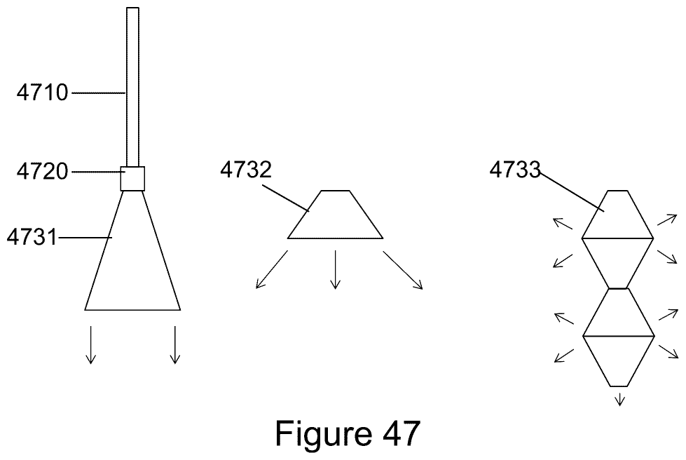

FIG. 47 presents schematic diagrams of passive assembly optic attachments for a pendant light according to some embodiments of the present disclosure. Referring to FIG. 47, the passive assembly optic attachment includes a transport fiber cable 4710 and a connector 4720 are configured with a passive assembly 4731 including one or more collimating optics. In another example, the passive assembly 4732 includes a very small flood light optical element. In another example, the passive assembly 4733 includes features for side scattering.

In some embodiments, connectors are used for easy replacement of the passive luminaires and fixtures. New fixtures can easily be replaced and updated, and can offer a lower cost since the fixtures will not comprise electronics or heat-sink members. In some embodiments, the fiber coupled laser-based white light system of the present disclosure can be configured to change décor of the passive luminaire, change the color of the light by changing the color of the source light or by the passive luminaire modifying the color, or could change the beam pattern, or a combination.

### Lighting Fixture Powered by Laser Light SMD Fiber Coupled Module

In another embodiment, the active assembly may be positioned as a light source or light engine for a decorative lighting fixture that is suspended from the ceiling of a structure such as a chandelier. A chandelier has numerous points of emissive light, often more than ten. With conventional lighting, each point of light in the assembly employs an individual electrical lighting lamp like for example an incandescent or LED candelabra decorative lamp. Over the operating period of the chandelier, any of the lamps may fail and thereby disturb the aesthetic whole of the chandelier. Replacing the lamp results in operating costs and inability to utilize the space since chandeliers are often mounted at great height. Replacing lamps at great height requires equipment, time and staff that result in great expense.

Optionally, the light engine is coupled to a fiber optic cable that transports the light to the chandelier. Optionally, the fiber optic cable may be split into multiple fiber optic cables that lead to the lighting endpoints of the chandelier. At each of these lighting endpoints, the fiber optic cable delivers the light into an optical element that distributes the light according to the design of the chandelier. In order to duplicate the effect of a candelabra lamp, the optic element at the endpoint of the chandelier optionally scatters the light in a wide-angle pattern.

The benefits of this chandelier design include ease of service and maintenance. The single remote source may be located in a convenient area where a repair or replacement may be accomplished with little disturbance to the lighting area that may be at great height. The lighting effect will be more uniform since there is a single source instead of multiple sources operating independently with different characteristics. Since the laser-based white light source size is made much smaller than other light sources, the fiber optic cable and other fixture components may be much smaller, finer and less visible in order to create a better aesthetic effect.

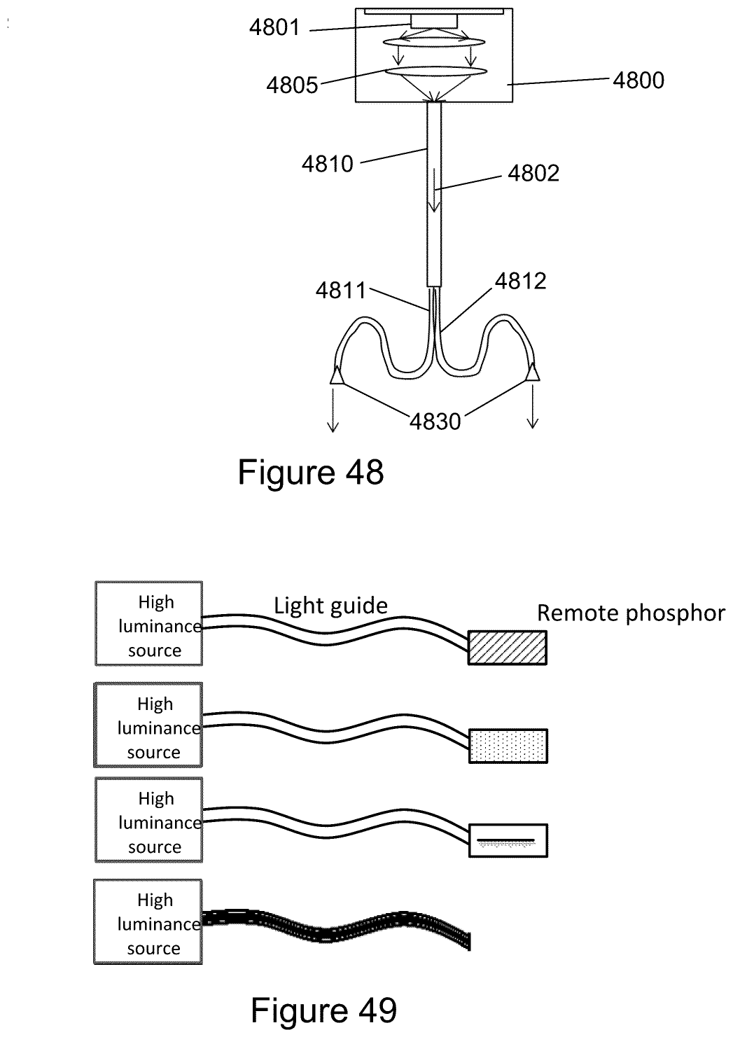

FIG. 48 presents a schematic diagram of a passive decorative luminaire according to an embodiment of the present invention. As shown in the FIG. 48, the white light is generated within a laser-based white light source 4800 such as a laser diode combined with a wavelength converting phosphor member in a package such as a surface mount device package. The white light 4802 is then coupled into a supply waveguide 4810 such as a fiber optic cable as depicted in FIG. 48. The white light 4802 in the supply waveguide 4810 is then split into 2 or more channels 4811 and 4812 of white light. The two or more channels are then routed to multiple lighting endpoints 4830 to emit the white light in this decorative lighting system. In this application, the multiple lighting endpoints can also be comprised of line sources such as scattering fibers, discrete emission points, or some combination of the two.

### Color Temperature and Cri

One of the significant advantages of white light generated by illuminating phosphors with a blue solid-state laser is the high luminance. This high luminance enables efficient coupling of white light to optical fibers or small optical elements. However, the high luminance of these white light sources generate significant heat in a small volume because of stokes losses and other inefficiencies in phosphors.

The common working temperature limitations of down-conversion materials (typically <250) C.° requires approaches to either limit the concentration of down-conversion rate or effectively spread the heat.

Several strategies can be employed to efficiently spread heat, including a combination of choice of down-conversion material, concentration of down-conversion material in a matrix, geometry of a down-conversion material and matrix combination, matrix thermal conductivity properties, and engineering thermal pathways from down-conversion and matrix.

A common approach is embedding down-conversion material in a high thermal conductivity matrix that is optically transparent (e.g. Al₂O₃). However common manufacturing techniques for Al₂O₃ requires high-temperature sintering which limits the available choices of down-conversion materials to ones with melting points close-to or higher than Al₂O₃. Commonly used down-conversion and matrix combination for laser-based lighting sources are yttrium aluminum garnet doped with cerium (YAG:Ce³⁺) in Al₂O₃. However commonly used red down-converting materials (e.g. Eu²⁺ doped nitrides) have much lower melting points and are not compatible with sintering process for Al₂O₃.

An alternative strategy is to manage heat and materials compatibility is to limit the down-conversion rate of one or more colors from the white or off-white source. This can be achieved for example by utilizing a blue-to-green color light source that is optically coupled to a fiber or other designated optical elements. These optical elements can come in the form of a remote phosphor that is a solid element, or one with varying phosphor concentration gradients, or a fiber or optical guide that contains phosphors. This can be thought of as a system with a high luminance source that is coupled to a light guide and a remote phosphor, some examples are shown in FIG. 49. This allows for the high luminance source to use a phosphor and composite combination that can effectively dissipate heat. The high luminance source is effectively coupled to optical elements. This also allows the use of other phosphors that have thermal, optical, or mechanical features that prevent them from being incorporated into the high luminance area of the system. One optical limitation that is overcome with this type of system is the use of low blue-light absorption cross-section materials (e.g. Eu³⁺ phosphors) where the volume or concentration of phosphor is impractical for confined systems.

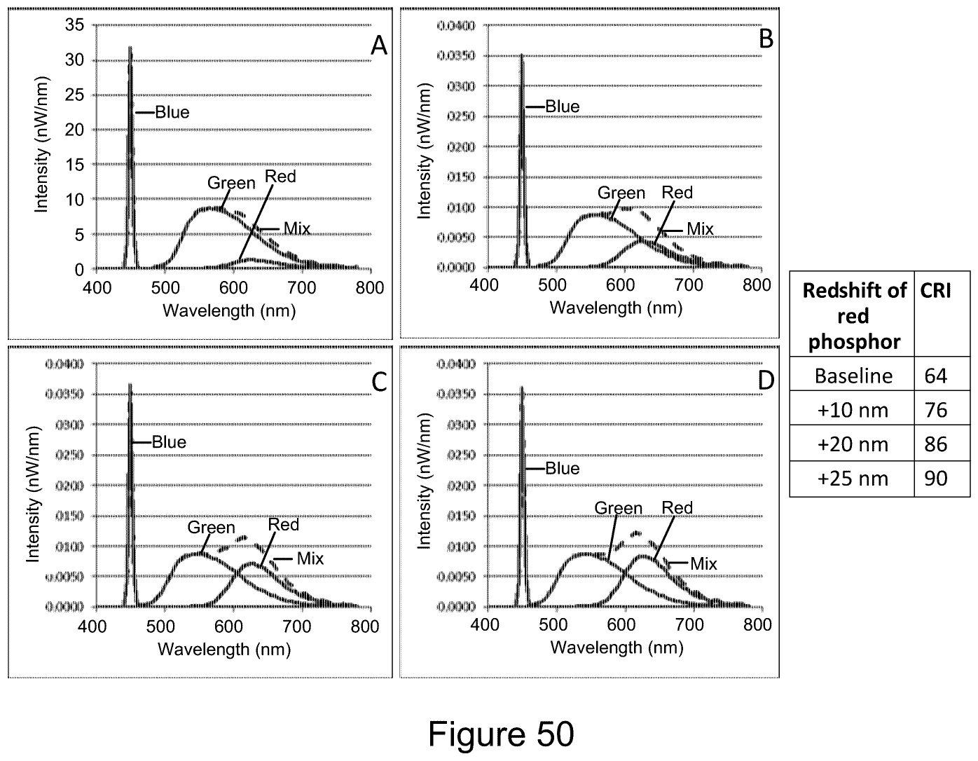

The addition of a red phosphor to a blue-shifted yellow light source can enable warmer white (i.e. lower correlated color temperature-CCT) and higher CRI sources. By adjusting the amount and wavelength of red-down-conversion the effective CRI of the source can be adjusted. For example, as shown in FIG. 50, simulation results indicate that the CRI value can be adjusted from 65 to 90 by adjusting wavelength red shift of the red phosphor from a baseline up to +25 nm.

### Line Source

In another preferred embodiment, the laser-based fiber-coupled white light source of the present disclosure is configured with a leaky fiber in an architectural lighting component or system to provide a line source of white light. In some embodiments, the leaky fiber emitting white light as a line source is configured to emit white light in a uniform pattern around the radial axis of the fiber. In other embodiments, the leaky fiber emitting white light as a line source is configured with an optional optical element to emit white light in a directional pattern from a predetermined portion of the radial axis. The optical fiber, along with the optional optic element, will be referred to as a ‘directional line source’. In one embodiment, the optical fiber is equipped with light extraction features that extract light along the length of the fiber. Optionally, the light extraction features are designed according to one of these two ways, or a combination of the two:
1. To extract light in a radially non-symmetric pattern
2. To extract light in a radially symmetric pattern, and an external optic element is configured outside or is attached to the fiber, such that the fiber and optic element together produce a radially non-symmetric pattern

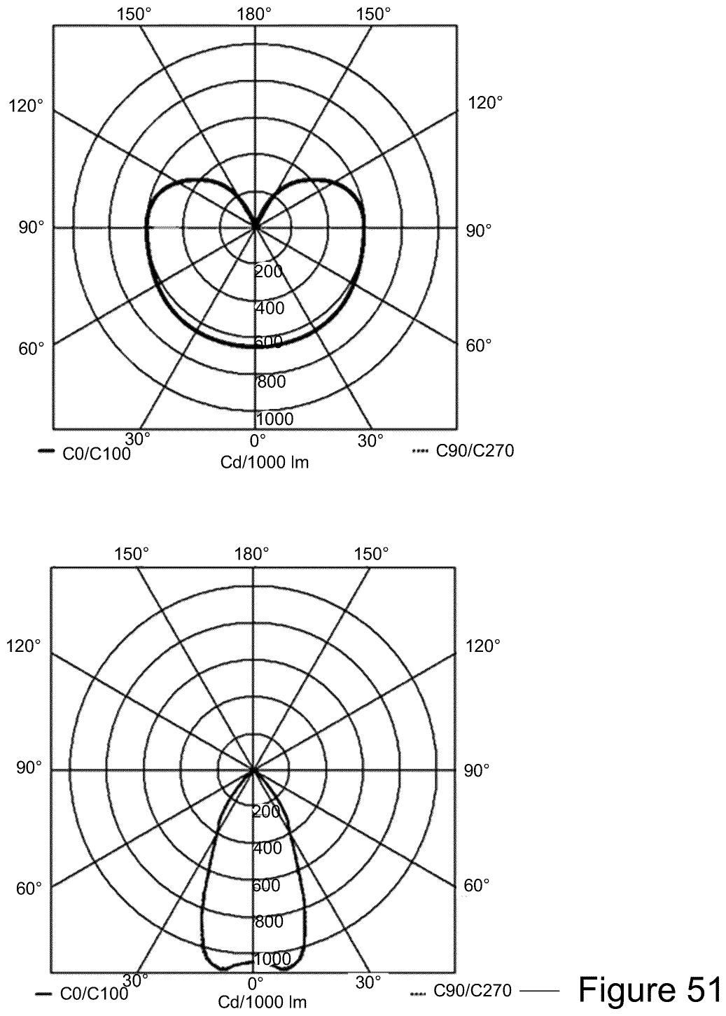

FIG. 51 presents examples of luminous intensity distribution curves by an optical fiber with optional external optical element according to some embodiments of the present disclosure. The optical fiber can be modified to achieve such a directional/non-radial-uniform or asymmetric mission pattern in various ways. In some examples, the optical fiber can be shaped or roughened. In other examples, the optical fiber cladding can be selectively removed or patterned to preferentially emit light from a pre-determined surface or side of the fiber. In other examples, the optical fiber can be embedded with particles, voids, or other objects to induce a selective scattering.

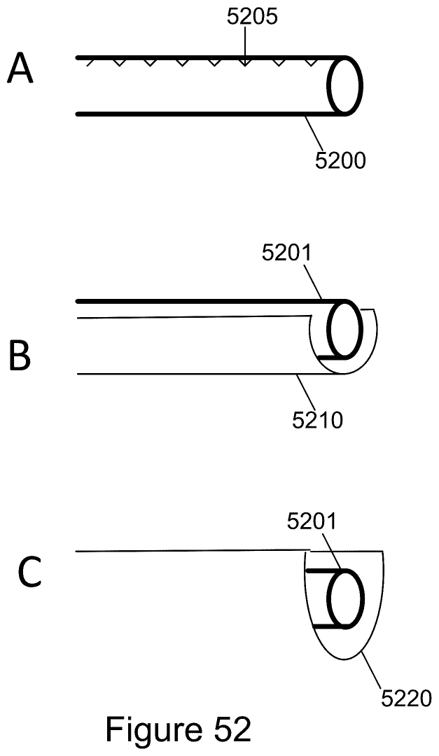

FIG. 52 presents schematic examples of directional emitting line white light sources based on emitting optical fibers. There are many possible approaches to generating a directional emission or a radially asymmetric emission pattern of the white light from the fiber. In one example presented in part A of FIG. 52, the optical fiber 5200 includes light extraction features 5205 producing a radially non-symmetric pattern. The light extraction features 5205 could be comprised with a carefully designed index of refraction arrangement within the fiber using air bubbles, modified core regions, modified cladding regions, non-uniformly impregnated fibers, implanted fiber, shaped fiber so that it is no totally symmetric.

The directional line source may be configured with secondary reflectors and lenses to produce a uniform illuminance on the wall surface. The reflector and lens assembly convert the uniform candlepower intensity of the linear line source into a variable and asymmetric intensity distribution. In the example where the line source is installed at the ceiling, the intensity can be very low at the area of the wall close to the ceiling in order to produce the desired level of illuminance in flux per area. The level of intensity increases with increasing distance along the wall toward the floor. The maximum level of intensity will be at the wall area closest to the floor in order that the illuminance level is the same as that near the ceiling. As a result, the entire wall will have the same illuminance over its surface and with overall uniform reflectivity will appear to an observer as being evenly lit.

Part B of FIG. 52 presents an illustration of an optical fiber 5201 with light extraction features producing a symmetric radial emission pattern and equipped with a reflector optical element 5210 that directs light upward. By combining the uniformly emitting fiber with the reflector optical element 5210 that wraps around >180 degrees of the fiber 5201, the light will be directed outward from the reflector optical element 5210. By careful design and selection of the reflector optical element 5210, the directional emission pattern from the light source can be configured to provide the desired emission patter and have the desired effect.

In another example, part C of FIG. 52 presents an illustration of an optical fiber 5200 with light extraction features producing a symmetric radial emission pattern and equipped with an alternative reflector optical element 5220 that directs light upward. In this configuration the symmetrically emitting fiber 5201 is recessed fully within the reflector optical element 5220 such that the fiber 5201 would be hidden from many viewing angles and that the light is emitted with a high directionality. These are merely examples of how the laser-based fiber coupled white light line source can be configured to emit light in a desired direction or pattern, but of course there can be many others.

The radially uniform emitting or directional emitting line source using a scattering or leaky fiber according to the present invention including a fiber coupled laser-based white light source can be applied to many lighting applications. In one application the line source is used to illuminate interior or exterior walls, ceilings, bridges, tunnels, roadways, runways, down holes, in caves, in cars, planes, boats, trains, or any other mobile machine, and could be many others including swimming pools, spas, appliances like refrigerators and freezers.

In one embodiment according to the present invention, the directional line source is integrated into the crown molding of a room to provide a wall wash. The line source is positioned such that a person standing or sitting in the room at a typical distance from the walls will not have a direct view of the line source. The line source has directional emission that illuminates the wall adjacent to it. A line source comprising a narrow optical fiber and an optic element allows the optic element to shape the light (generate a luminous intensity distribution) that illuminates the wall in a desired pattern, e.g. uniform illumination, without requiring the size of the optical element to be unpractically large.

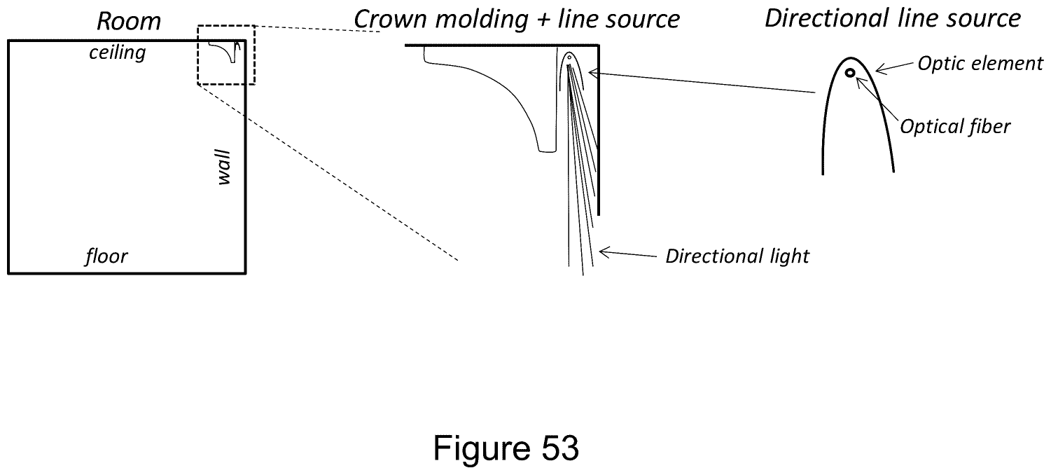

FIG. 53 presents a schematic configuration for applying laser-based white light directional line sources according to an embodiment of the present disclosure. Referring to FIG. 53, the laser-based white light directional line source is implemented into crown molding for wall illumination. The laser-based white light source is coupled to a scattering or leaky fiber to emit white light in a symmetric or directional pattern. The leaky fiber is then embedded into an architectural or construction feature of the environment. In the example presented in FIG. 53 the line source is embedded into a crown molding. The leaky fiber is positioned against the wall within the crown-molding or in a gap between the crown molding and the wall to provide directional light downward along the wall surface to provide a wall wash illumination. Optionally, an optical element such as a reflector can be added to enhance the formation of the directional light emitted out of the line source (e.g., the leaky fiber).

Alternative configurations for the directional line source are possible. Embodiments include dedicated wall wash fixtures mounted at/near the intersection of walls and ceiling, on the wall away from ceiling and floor, or at/near the intersection of walls and floor, such as in the baseboard members. In some embodiments, the directional line source is oriented to illuminate the wall adjacent to it, and a structural element that blocks direct view of the line source from people in typical positions in the room. In other embodiments, the directional line source is integrated into the baseboard located at/neat the intersection of walls and floor.

In yet another embodiment, the directional line source can be configured to illuminate the ceiling while integrated into crown molding. Other configurations are possible, where a ceiling illuminating direction line source is integrated with a structural element that block direct view of the line source from people in typical positions in the room. Said structural element can be integrated into the construction of the wall or ceiling, forming cove lighting when a directional line source is integrated with it. The directional line source together with the structural element can also form a ceiling-illuminating light fixture that is mounted on the wall, typically above eye height to avoid glare for room occupants.

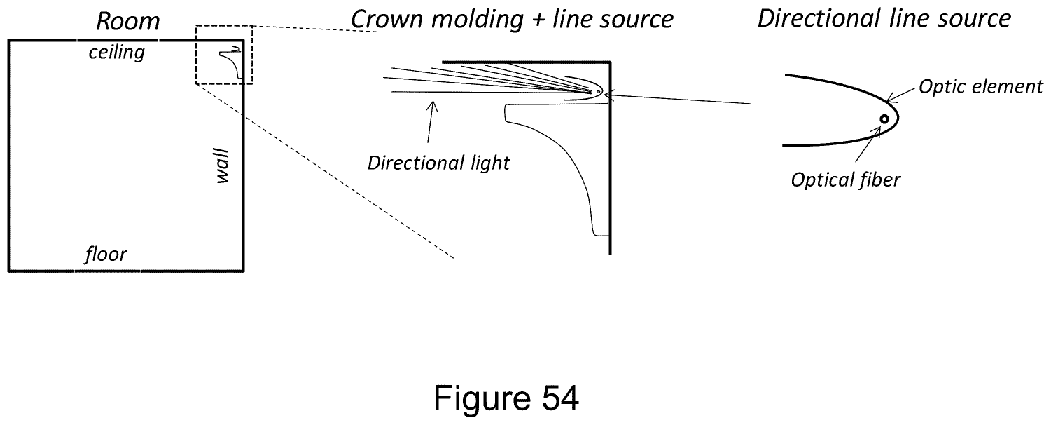

FIG. 54 presents a schematic configuration for applying laser-based white light directional line sources according to another embodiment of the present disclosure. Referring to FIG. 54, the laser-based white light directional line source is implemented into crown molding, for ceiling illumination. The laser-based white light line source is coupled to a scattering or leaky fiber line source. The leaky fiber is then embedded into an architectural or construction feature of the environment. Optical elements such as one or more reflector members can be included. In the example presented in FIG. 54 the laser-based white light line source is embedded into a crown molding. The fiber is positioned against the ceiling within the crown-molding or in a gap between the crown molding and the ceiling. The light is then directed across the ceiling to provide a ceiling wash illumination.

A laser-based white light directional line source can be routed from one wall to an opposing wall, at a height above the floor where it does not physically obstruct typical activities of room occupants. The laser-based white light line source is physically anchored at the two opposing walls, with optional anchor points to the ceiling in one or more points along the length of the line source. The laser-based white light line source can optionally be fitted with a structural element along its length that reduces or eliminated light emitted in a downward direction in order to reduce glare for occupants in the room. The structural element can also add mechanical strength to the line source in order to prevent damage resulting from accidental contact with items handled by occupants inside the room. Several line sources can be configured in a room to create the desired level, pattern, and uniformity of ceiling illumination.

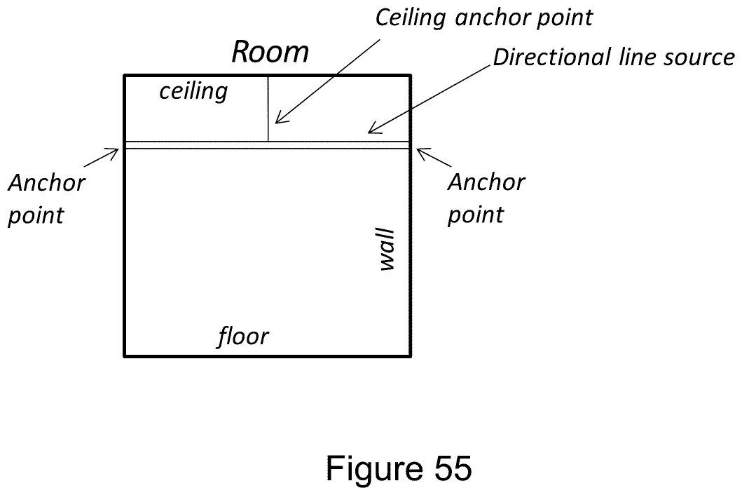

FIG. 55 presents a schematic configuration for applying laser-based white light directional line sources according to yet another embodiment of the present disclosure. Referring to FIG. 55, the laser-based white light line source is implemented in a wall-to-wall configuration for ceiling illumination. In this configuration, the laser-based white light line source is attached between two walls or suspended from the ceiling by an anchor point. The laser-based white light line source is configured to emit the light upward toward the ceiling to light the ceiling. In other examples, the light can be directed toward the floor or the walls.

Optionally, the laser-based white light directional line source includes secondary optics like lenses and reflectors to illuminate uniformly a ceiling field from one or both edges. Optionally, it is to generate a level of illuminance higher than the rest of the field in one particular zone of the ceiling that moves across the ceiling over time. In one example, the high illuminance zone would begin early in the daytime at one corner of the ceiling and gradually move across the ceiling and end the day at the opposite corner of the ceiling. This effect could be generated by mechanically moving optics but is most expediently accomplished by using liquid crystal lenses in the optics of the directional line source. With electronic control, the uniformity of the ceiling illuminance could be modulated. The high illuminance zone on the ceiling partially simulates the motion of the sun across the sky over the day and has benefits to circadian rhythms and health in humans and animals. Natural light is not always uniform and changes throughout the daytime generating shadows that change and greater indoor comfort is generated by lighting that has a gradient and/or direction of incidence. Additional benefit is provided by implementing multiple sources in the directional line source of different color temperatures. When the relative power levels of the different sources are modulated, the output color temperature may be changed to improve the simulation of natural light since the color of the light changes along with the relative position of the sun in the sky.

2D Waveguided Light into Building and Architectural Features

In some embodiments of the present invention including a waveguide coupled laser-based white light source, the waveguide comprises a 2-dimensional (2D) waveguide wherein at least some portion of the 2D waveguide emits white light. In some examples the laser-based white light sources are coupled into a troffer type luminaire wherein they can emit over the emitting surface region of the troffer. Other examples of existing 2D luminaire types include wafer lights, disc lights, accents lights, and back-lighting such as back-lighting stone or other architectural features.

In some embodiments the high brightness of the laser diode based white light source enables a superior coupling and performance characteristic of coupling into existing elements in building, architecture, nature or other such as to make elements of our pre-existing environment become light emitters. This embodiment of the present invention provides key advantages of existing technology. One advantage is that it could improve the aesthetics of the environment by removal of discrete conventional light sources that can degrade the beauty of an object or structure. For example, by providing lighting from existing elements, lighting fixtures such as canned lights or bulb type lights could be eliminated or reduced in number. Surfaces such as ceilings could be clean and free from light fixtures that are not always nice to look at. Additionally, this embodiment can save costs or complexity of a system because less conventional lighting infrastructure would need to be installed into a building or home.

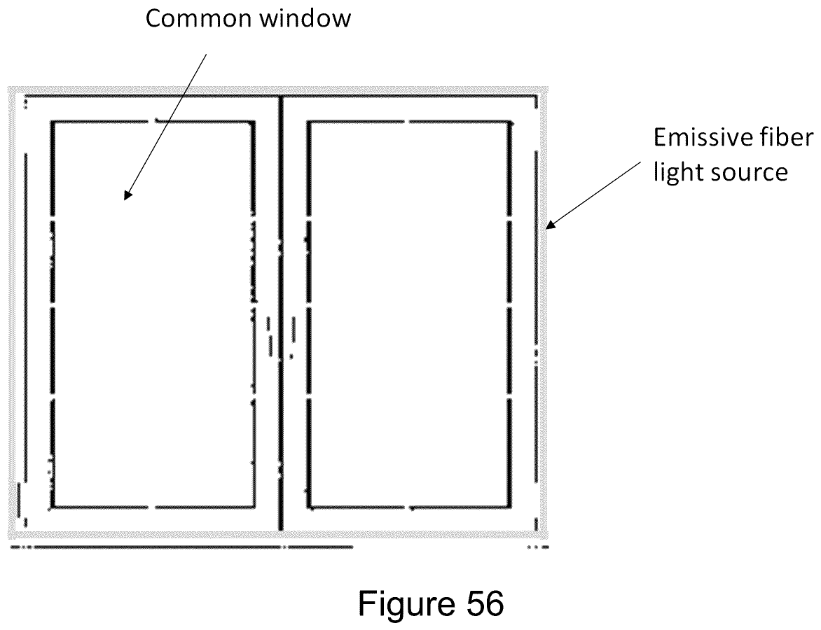

The unique white light line source enabled by the present invention including a waveguide coupled laser-based white light can be deployed for interior or exterior lighting in a myriad of ways. In one example a white light emitting waveguide element such as an optical fiber is configured to outline or line certain features or objects comprising an environment or structure. In one example of the present embodiment white light emitting fibers are configured around window members to provide an illumination pattern that outlines the window. The illumination could serve as a decorative illumination and/or could serve to provide useful light for illuminating the surrounding area. As an example, FIG. 56 is included to show a window member with an one-dimensional white light line source configured to surround the window. In other examples of this embodiment the laser-based white light line source can be configured around other objects such as doorways, etc.

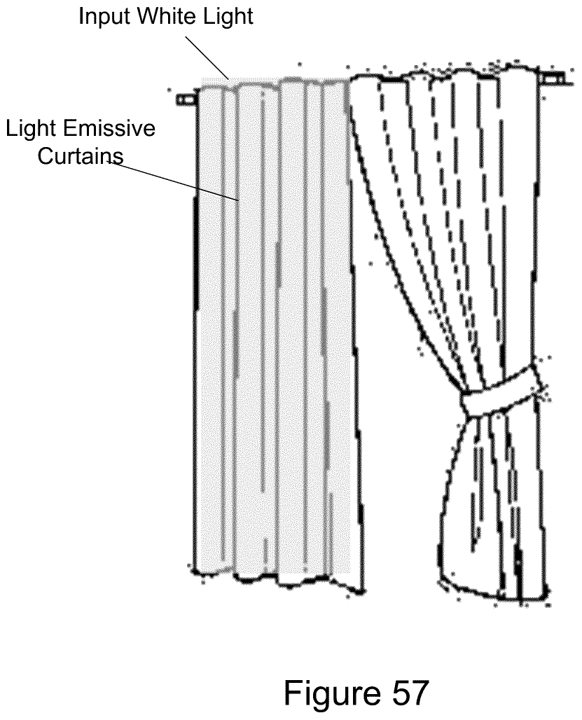

FIG. 57 presents an embodiment according to the present invention wherein a laser-based white light source (not shown) is coupled into window coverings such as curtains, and the curtains are configured by light-emissive material to receive input white light from the laser-based white light source and emit the light outside or provide light to inner part of a semi-transparent outer material. By achieving a waveguiding and a uniform scattering or emitting design, the curtains optionally appear to glow with white light and provide lighting to the environment. Curtains make an attractive choice for 2D illumination objects since they represent locations in a home or building wherein light would be entering the space during daylight hours. Therefore, by having the curtains, window dressings, or other objects on or around the window glowing the home, office, store, or other building could be illuminated in a way to represent natural daylight conditions. In some examples, the curtains include a continuous film material configured to waveguide the white light and provide the scattering. The continuous film material could be formed from a plastic or organic material, ceramic, metal, or other material. In other embodiments, the curtains are comprised of a network of fibers such as plastic fibers or glass fibers that are woven together. In some embodiments, the curtains are configured by light-emitting material to directionally emit the light such that a majority of the light is emitted toward front of the curtain to illuminate the room or area the curtain exists within, and only a small fraction or no light is emitted to the back toward a window or wall behind the curtain. Moreover, there are many similar 2D objects that could be used for light emission, the curtain embodiment is just one example according to the present invention using laser-based white light sources.

In another example, the white light is emitted directly from the window members or from clear devices that can be places on the windows. FIG. 58 presents an embodiment according to the present invention wherein a laser-based white light source (not explicitly shown) is coupled directly into a window member or a window accessory member attached to the window and designed to be fully transparent and not noticed during the day time or when the illumination function is not activated. By achieving a waveguiding in the window or window accessory member along with a uniform scattering or emitting pattern, the window or window accessory can glow with input white light from the laser-based white light source. The glowing window member (e.g., glass) provides lighting to the environment. Window members or window accessory members make an attractive choice for 2D illumination objects since they represent locations in a home or building wherein natural light would be entering the space during daylight hours. Therefore, by having the windows glowing the home, office, store, or other building could be illuminated in a way to represent natural daylight conditions. In some examples, the windows are formed from a continuous material configured to waveguide the white light and provide the scattering. The continuous material could be formed from a plastic, glass, organic material, ceramic, metal, or other material. In other embodiments the window or window accessories are comprised of a network of fibers such as plastic fibers or glass fibers that are woven together. In some embodiments the light emitting windows are configured to directionally emit the light such that a majority of the light is emitted toward the inside of the building or home to illuminate the room or area the window exists within, and only a small fraction or no light is emitted to the back toward the outside. Moreover, there are many similar 2D objects that could be used for light emission, the window or window accessory embodiment is just one example according to the present invention using laser-based white light sources.

### Appliances

In the present invention, the white light from the laser-based white light source is coupled into a waveguide member and transported to an emission point wherein the light is directed from a passive element to the outside environment. In this configuration the active elements of the light source requiring an electrical power input and dissipating heat can be configured in a remote location from the environment where the white light emission is desired. Among other advantages of the present invention, the remote source configuration can provide an energy savings since the heat dissipation associated with the source does not need to be located in areas that require lighting, but are also required to be held at cool temperatures and often need active cooling. Using conventional lighting solutions wherein the heat is dissipated at the source and the source is collocated with the emission intended for the target location the light sources will inevitably heat up the environment and have a counter-productive effect on the cooling of the environment. In many cases this will force the active cooling system of the environment to work harder and consume more energy, providing a less overall efficiency. The waveguide delivered white light system according to the present invention provides a superior solution that offers energy efficiency savings since the laser-based white light source can be located in a remote location relative to where the illumination is required.

In an embodiment, the waveguide delivered laser-based white light system delivers the white light via a delivery system to a location remote from the active elements of the light source. The delivery system includes passive optical elements, passive luminaire members, or passive light emitting members (such as scattering fibers). Optionally, these passive light delivering members can be designed for low cost and high resistance. Optionally, the passive light emitting members can be located in harsh environments such as under water, in extreme conditions such as ultra-high or low temperatures, corrosive environments, explosive environments, etc. Using a conventional light source wherein such harsh condition would rapidly damage or degrade the light source or wherein an electrified source could have a potential to react badly with the environment such as causing an explosion, extreme and often costly measures are taken to protect the light source and replacement can be complicated and costly. For example, lighting underwater environments such as swimming pools, spas, or industrial underwater applications with conventional sources requires the use of a carefully water proof housing and specialized components, which adds size, weight, complexity, and cost. Moreover, changing the light source often requires doing work underneath water, which can require special gear and create a time consuming and expensive process. However, with a waveguide delivered laser-based white light according to the present invention, the light source can be maintained in a dry area that is easily accessible for replacement. The passive waveguide such as a plastic or glass fiber would deliver the light to the submerged illumination area. Other examples include harsh environments such as chemical treatment plants, chemical processing plants, industrial plants and factories, semiconductor processing, etc.

In one group of preferred embodiments leveraging the benefits of remote delivery of white light enabled by the present invention, the waveguide delivered white light source is configured in an appliance apparatus or a utility apparatus. Such appliances could include, but are not limited to refrigerators, freezers, ovens, microwaves, dishwashers, washers, dryers, wine cellars, and others. The appliances can range in application from private or household use to commercial use such as in stores, offices, and other outlets, and to industrial use including very large appliances. Applications that would require the lights to always be on or be on for a majority of the time would offer the strongest energy savings benefits. For example, appliances such as refrigerators or freezers with a clear or glass door so that outside viewers can always see the contents of the refrigerator or freezer would require the internal lights to be on for a large fraction of the time. Other examples wherein the present invention would provide substantial amounts of energy savings would be in appliances with large areas that need to be illuminated or where extreme levels of illumination are needed. For example, industrial types of freezers such as warehouse freezers used to store large inventories of frozen or cold goods require ample lighting for work to be performed in the actively cooled freezer warehouse. By locating the active light sources outside of the cooled environment and fiber coupling the white light into the freezer area, the light sources will not add heat to the inside of the freezer area.

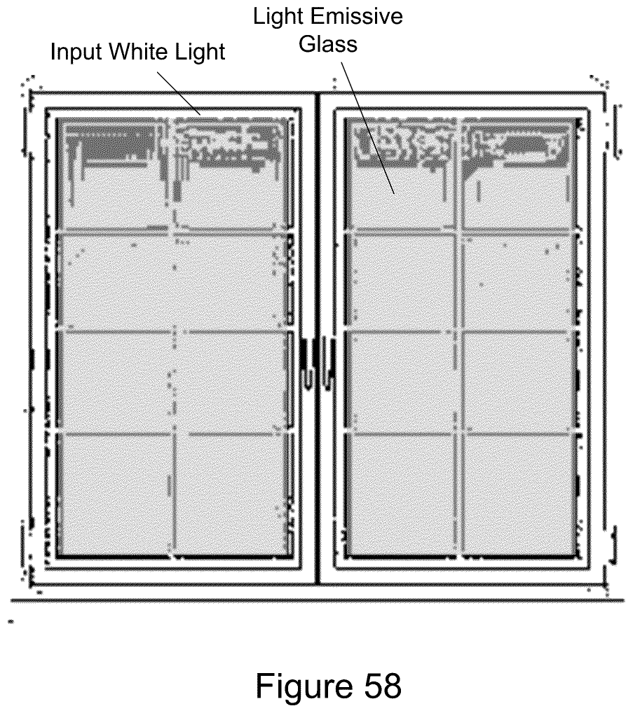

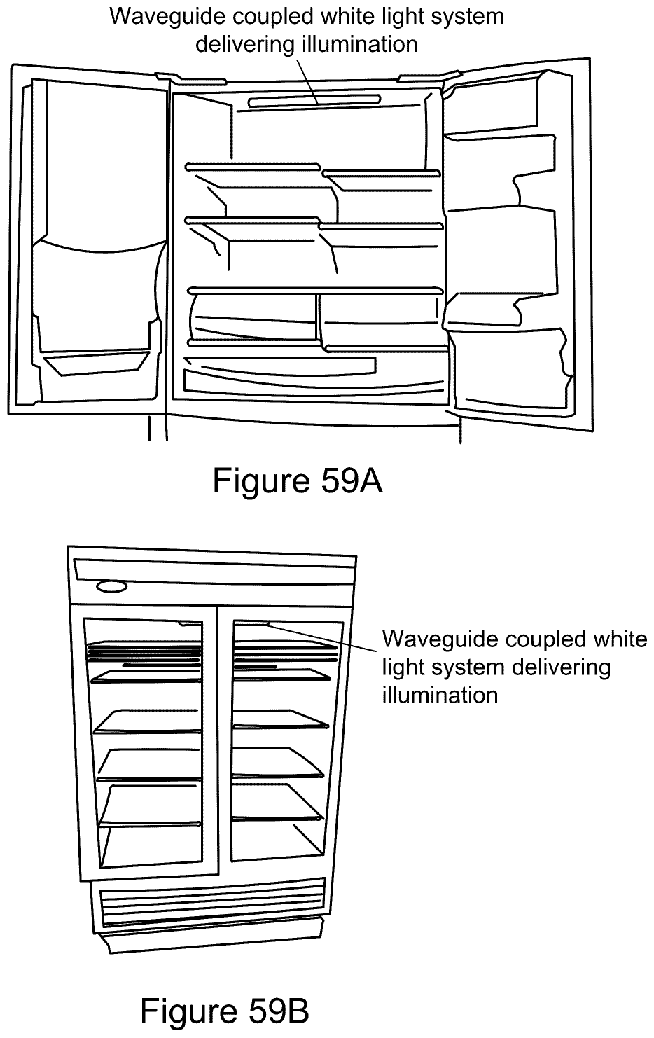

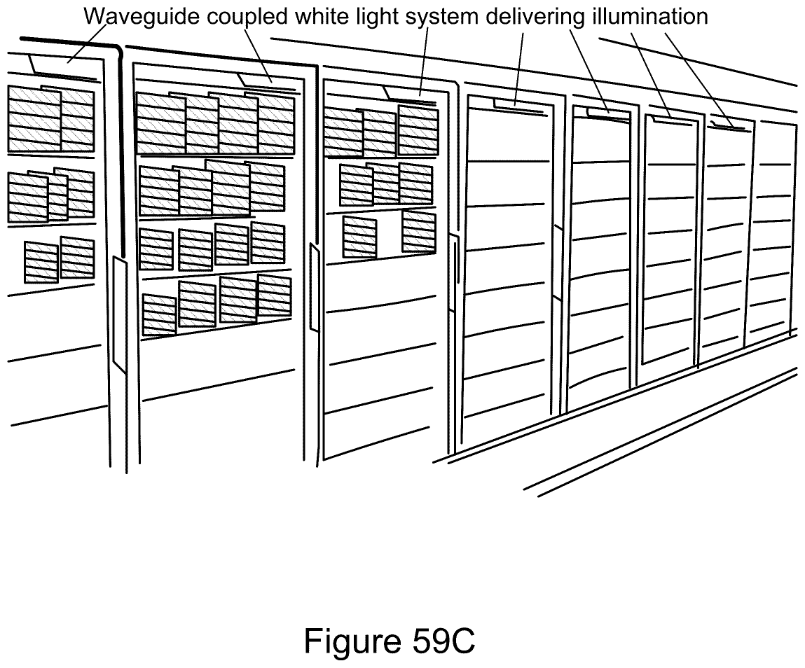

FIGS. 59A, 59B, and 59C present some embodiments of the waveguide delivered laser-based white light for use in refrigerators and freezers according to the present invention. As shown in FIG. 59A, a residential type refrigerator has the refrigerator compartment equipped with lighting such that when the compartment doors are opened, the light is activated. In this example, the white light is delivered from the laser-based white light source into the refrigerator compartment using a waveguide or fiber member. By having the laser-based light source outside the compartment that is actively cooled by a heat pump (mechanical, electronic or chemical), the thermal dissipation from the heat source does not function to warm the cooled compartment and cause the heat pump to work harder and consume more energy.

Optionally, the same energy efficiency benefit of the remote light source can have a larger impact in locations that require the light to be on for a large fraction of the time. As shown in FIG. 59B, a commercial or residential mid-size refrigerator or freezer has the cooled compartment enclosed with clear type doors such that an outside viewer can see the contents of the cooled compartment. The cooled compartment is equipped with lighting such that the outside viewer can easily see the contents. In retail applications the lights could be required to be on for 16 to 24 hours a day, 7 days a week. In this example of a freezer or refrigerator with a clear enclosure shown in FIG. 59B, the white light is delivered from the laser-based white light source into the refrigerator or freezer compartment using a waveguide or fiber member. By having the laser-based light source outside the compartment that is actively cooled by a heat pump (mechanical, electronic or chemical), the thermal dissipation from the heat source does not function to warm the cooled compartment and cause the heat pump to work harder and consume more energy.

Optionally, the same energy efficiency benefit of the remote light source can have a major impact in large volume cooled compartments that require the light to be on for a large fraction of the time. As shown in FIG. 59C, a commercial or industrial large type refrigerator or freezer has the large cooled compartment enclosed with clear type doors such that an outside viewer can see the contents of the cooled compartment. The cooled compartment is equipped with lighting such that when the compartment doors are not opened the outside viewer can still see the contents inside. In retail applications the lights could be required to be on for 16 to 24 hours a day, 7 days a week, the light is activated. In this example, similar to the freezer or refrigerator with a clear enclosure shown in FIG. 59B, the white light is delivered from the laser-based white light source into the refrigerator or freezer compartment using a waveguide or fiber member. By having the laser-based light source outside the compartment that is actively cooled by a heat pump (mechanical, electronic or chemical), the thermal dissipation from the heat source does not function to warm the cooled compartment and cause the heat pump to work harder and consume more energy.

### Swimming Pools and Jacuzzis

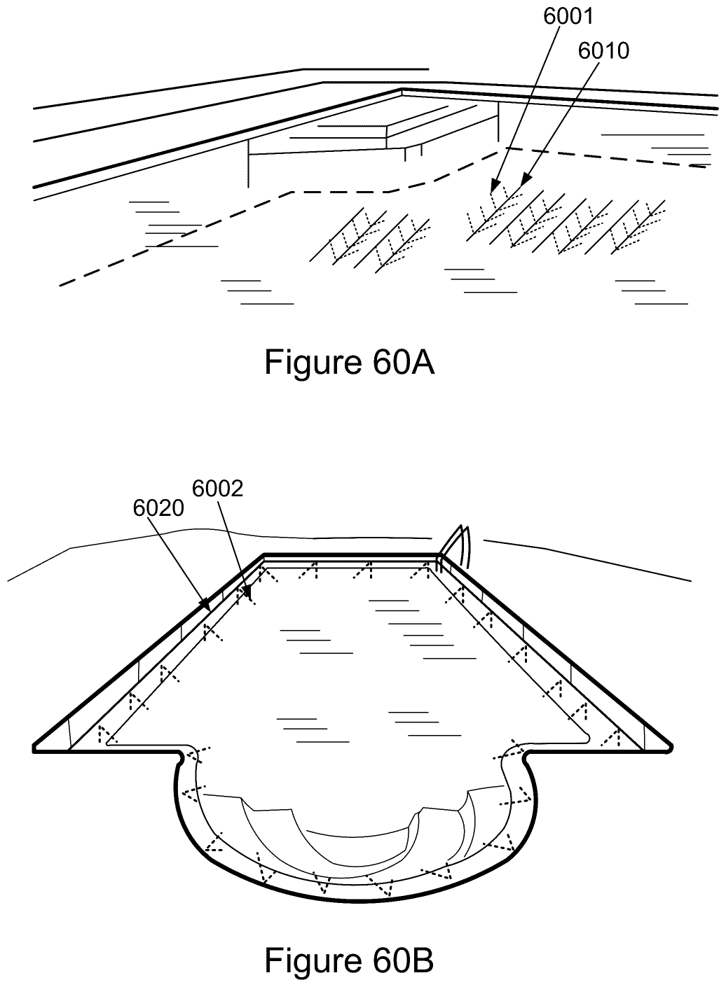

In another group of preferred embodiments, the waveguide delivered laser-based white light is utilized in submerged or harsh environment applications, providing a substantial benefit over conventional light source technologies. In these applications the illumination light is required in locations under water or within other chemicals and environments that are not easily accessible. In one example, the waveguide or fiber delivered laser-based white light source is used for swimming pools. As shown in FIG. 60A, the fiber delivered white light 6001 can be submerged under the water and provide a uniform light underneath the water. In another configuration show in FIG. 60B, the fiber delivered white light source can be positioned above the water and configured to provide white light 6002 for illuminating down into the water. In both of these examples, the white light (6001 or 6002) is emitted from an emissive waveguide such as scattering or leaky fibers (6010 or 6020) and provides a very beautiful and even white light distribution. In some examples, the color of the light can be tuned, including changing the color temperature of the white light or changing to pure colors such as red, blue, green, violet, yellow, orange, or other colors. In these examples, the laser-based white light sources are located outside of the swimming pool area, such as in a small enclosure nearby to the swimming pool. The swimming pool can be an above ground pool or an in-ground pool.

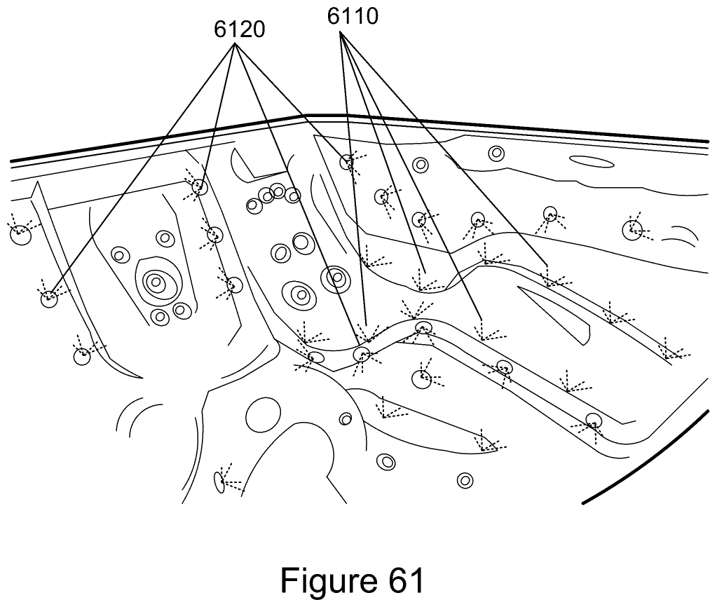

In another embodiment, the waveguide delivered laser-based light is delivered to a hot tub or jacuzzi. As shown in FIG. 61, the fiber delivered white light can be configured as submerged illumination light 6110 under the water and provide a uniform light pattern in the hot-tub. In this example the white light 6110 is emitted from an emissive waveguide such as scattering or leaky fiber (as schematically indicated by the curved lines) and provides a very beautiful and even white light distribution. Also shown in the FIG. 61, the fiber delivered white light source can be configured to deliver the light to discrete passive luminaires 6120 under the water to create a network of point lights. In this example transport fibers (not shown) are used to transport the light from the laser-based light source to the passive luminaires 6120. In some examples, combinations of discrete passive luminaires and emissive waveguide luminaires are included such as scattering optical fibers. In some examples, the color of the light can be tuned, including changing the color temperature of the white light or changing to pure colors such as red, blue, green, violet, yellow, orange, or other colors. In these examples, the laser-based light sources are located outside of the hot tub area, such as in a small enclosure or underneath the hot-tub. The swimming pool can be an above ground pool or an in-ground pool.

In all of the side pumped and transmissive and reflective embodiments of this invention the additional features and designs can be included. For example, shaping of the excitation laser beam for optimizing the beam spot characteristics on the phosphor can be achieved by careful design considerations of the laser beam incident angle to the phosphor or with using integrated optics such as free space optics like collimating lens. Safety features can be included such as passive features like physical design considerations and beam dumps and/or active features such as photodetectors or thermistors that can be used in a closed loop to turn the laser off when a signal is indicated. Moreover, optical elements can be included to manipulate the generated white light. In some embodiments, reflectors such as parabolic reflectors or lenses such as collimating lenses are used to collimate the white light or create a spot light that could be applicable in an automobile headlight, flashlight, spotlight, or other lights.

In one embodiment, the present invention provides a laser-based fiber-coupled white light system. The system has a pre-packaged laser-based white light module mounted on a support member and at least one gallium and nitrogen containing laser diode devices integrated with a phosphor material on the support member. The laser diode device, driven by a driver, is capable of providing an emission of a laser beam with a wavelength preferably in the blue region of 425 nm to 475 nm or in the ultra violet or violet region of 380 nm to 425 nm, but can be other such as in the cyan region of 475 nm to 510 nm or the green region of 510 nm to 560 nm. In a preferred embodiment the phosphor material can provide a yellowish phosphor emission in the 560 nm to 580 nm range such that when mixed with the blue emission of the laser diode a white light is produced. In other embodiments, phosphors with red, green, yellow, and even blue colored emission can be used in combination with the laser diode excitation source to produce a white light emission with color mixing in different brightness. The laser-based white light module is configured a free space with a non-guided laser beam characteristic transmitting the emission of the laser beam from the laser diode device to the phosphor material. The laser beam spectral width, wavelength, size, shape, intensity, and polarization are configured to excite the phosphor material. The beam can be configured by positioning it at the precise distance from the phosphor to exploit the beam divergence properties of the laser diode and achieve the desired spot size. In other embodiments free space optics such as collimating lenses can be used to shape the beam prior to incidence on the phosphor. The beam can be characterized by a polarization purity of greater than 60% and less than 100%. As used herein, the term “polarization purity” means greater than 50% of the emitted electromagnetic radiation is in a substantially similar polarization state such as the transverse electric (TE) or transverse magnetic (TM) polarization states, but can have other meanings consistent with ordinary meaning. In an example, the laser beam incident on the phosphor has a power of less than 0.1 W, greater than 0.1 W, greater than 0.5 W, greater than 1 W, greater than 5 W, greater than 10 W, or greater than 10 W. The phosphor material is characterized by a conversion efficiency, a resistance to thermal damage, a resistance to optical damage, a thermal quenching characteristic, a porosity to scatter excitation light, and a thermal conductivity. In a preferred embodiment the phosphor material is comprised of a yellow emitting YAG material doped with Ce with a conversion efficiency of greater than 100 lumens per optical watt, greater than 200 lumens per optical watt, or greater than 300 lumens per optical watt, and can be a polycrystalline ceramic material or a single crystal material. The white light apparatus also has an electrical input interface configured to couple electrical input power to the laser diode device to generate the laser beam and excite the phosphor material. The white light source configured to produce a luminous flux of greater than 1 lumen, 10 lumens, 100 lumens, 250 lumens, 500 lumens, 1000 lumens, 3000 lumens, or 10000 lumens. The support member is configured to transport thermal energy from the at least one laser diode device and the phosphor material to a heat sink. The support member is configured to provide thermal impedance of less than 10 degrees Celsius per watt or less than 5 degrees Celsius per watt of dissipated power characterizing a thermal path from the laser device to a heat sink. The support member is comprised of a thermally conductive material such as copper, copper tungsten, aluminum, SiC, sapphire, AlN, or other metals, ceramics, or semiconductors.

In one embodiment, a laser driver is provided in the pre-packaged laser-based white light module. Among other things, the laser driver is adapted to adjust the amount of power to be provided to the laser diode. For example, the laser driver generates a drive current based one or more pixels from the one or more signals such as frames of images, the drive currents being adapted to drive a laser diode. In a specific embodiment, the laser driver is configured to generate pulse-modulated signal at a frequency range of about 50 to 300 MHz. The driver may provide temporal modulation for applications related to communication such as LiFi free-space light communication, and/or data communications using optic fiber. Alternatively, the driver may provide temporal modulation for applications related to LiDAR remote sensing to measure distance, generate 3D images, or other enhanced 2D imaging techniques.

In certain embodiments, the pre-packaged laser-based white light module includes an electrostatic discharge (ESD) protection element. For example, an ESD protection element would be used to protect the white light module from damage that could occur with a sudden flow of current resulting from a build-up of charge. In one example, a transient voltage suppression (TVS) element is employed. In one example, a temperature sensor such as a thermistor is disposed for monitor laser device temperature. In one example, one or more photodetectors are installed for monitor optical power for safely alarming.

In certain embodiments, the pre-packaged laser-based white light module comprises a heat sink thermally coupled to the common support member. In one example the heat sink has fins or a measure for increased surface area.

In certain embodiments, the pre-packaged laser-based white light module comprises a heat spreader coupled between the common support member and the heat sink.

In certain embodiments, the pre-packaged laser-based white light module comprises an optical coupler coupled with one or more optical fibers.

In certain embodiments of the pre-packaged laser-based white light module, the laser beam emitted from the laser device therein is geometrically configured to optimize an interaction with a phosphor material.

In certain embodiments of the pre-packaged laser-based white light module, a package is hermetically sealed.

In certain embodiments of the pre-packaged laser-based white light module, the package comprises one selected from a flat package(s), surface mount packages such as SMDs, TO9 Can, TO56 Can, TO-5 can, TO-46 can, CS-Mount, G-Mount, C-Mount, micro-channel cooled package(s), and others.

In certain embodiments of the pre-packaged laser-based white light module, the emitted white light is collimated using a lens.

In certain embodiments of the laser-based fiber-coupled white light module, the waveguide device is coupled to the pre-packaged white light module via a collimation lens to capture the white light emission in a FWHM cone angle of at least 120 degrees with 20%, 40%, 60%, or 80% coupling efficiency.

In certain embodiments of the laser-based fiber-coupled white light module, the waveguide device includes an optical fiber of an arbitrary length, including a single mode fiber (SMF) or a multi-mode fiber (MMF), with core diameters ranging from about lum to 10 μm, about 10 μm to 50 μm, about 50 μm to 150 μm, about 150 μm to 500 μm, about 500 μm to 1 mm, or greater than 1 mm. The optical fiber is aligned with a collimation optics member to receive the collimated white light emission with a numerical aperture about 0.05 to 0.7 in a cone angle ranging from 5 deg to 50 deg.

In certain embodiments of the laser-based fiber-coupled white light module, the waveguide device includes a leaky fiber of a certain length for distributing side-scattered light through the length.

In certain embodiments of the laser-based fiber-coupled white light module, the waveguide device includes a lensed fiber of a certain length, the lensed fiber being directly coupled with the pre-packaged white light module without extra collimation lens.

In certain embodiments of the laser-based fiber-coupled white light module, the waveguide device includes a planar waveguide formed on glass, semiconductor wafer, or other flat panel substrate.

In a specific embodiment, the present invention provides a laser-based fiber-delivered white light source. The laser-based white light source includes at least one gallium and nitrogen containing laser diode and a wavelength conversion member such as a phosphor. The laser generates a first wavelength in the range of 385 nm to 495 nm and wavelength conversion member generates a second wavelength that is longer than the first wavelength. The laser beam emission generates a spot on the phosphor member to induce a phosphor-excited emission which comprises emission with a mix of the first wavelength and the second wavelength to produce a white light emission. The white light emission from the phosphor member comprises and emission pattern such as a Lambertian emission pattern.

In one embodiment, the white light emission from the laser-based white light source is directly coupled into a first end of an optical fiber member. The optical fiber member may be comprised of glass fiber, a plastic optical fiber (POF), a hollow fiber, or an alternative type of multi-mode or single mode fiber member or waveguide member The first end of the fiber may be comprised of a flat surface or could be comprised of a shaped or lensed surface to improve the input coupling efficiency of the white light into the fiber. The first end of the fiber member may be coated with an anti-reflective coating or a reflection modification coating to increase the coupling efficiency of the white light into the fiber member. The fiber or waveguide member controls the light based on step index or gradual index changes in the waveguide, refractive diffractive sections or elements, holographic sections or elements, polarization sensitive sections or elements, and/or reflective sections or elements. The fiber or waveguide is characterized by a core waveguide diameter and a numerical aperture (NA). The diameter ranges from 1 μm to 10 μm, 10 μm to 100 μm, 100 μm to 1 mm, 1 mm to 10 mm, or 10 mm to 100 mm. The NA could range from 0.05 to 0.1, 0.1 to 0.2, 0.2 to 0.3, 0.3 to 0.4, 0.4 to 0.5, 0.5 to 0.6, or 0.6 to 0.7. Transmission ranges from 30 to 40%, 40 to 50%, 50 to 60%, 60 to 70%, 70 to 80%, 80 to 90%, and 90 to 100%. The fiber may transport the light to the end, or directional side scattering fiber to provide preferential illumination in a particular angle, or both. The fiber may include a coating or doping or phosphor integrated inside or on a surface to modify color of emission through or from fiber. The fiber may be a detachable fiber and may include a connector such as an SMA, FC and/or alternative optical connectors. The fiber may include a moveable tip mechanism on the entry or exit portion for scanning fiber input or output, where the fiber tip is moved to generate changes in the in coupling amount or color or other properties of the light, or on the output side, to produce a motion of light, or when time averaged, to generate a pattern of light. The leaky fiber could be a bundled leaky fiber. For example, the leak fiber could be a bundle of 3 or more, or 19 or more fibers with diameters in the 20 μm to 200 μm range with a total core diameter of 0.4 mm to 4 mm. The bundled fibers could be comprised from glass fibers or plastic fibers.

In a preferred embodiment, the white light emission from the laser-based white light source is directed through a collimating lens to reduce the divergence of the white light. For example, the divergence could be reduced from 180 degrees full angle or 120 degrees full width half maximum, as collected from the Lambertian emission to less than 12 degrees, less than 5 degrees, less than 2 degrees, or less than 1 degree. The lenses may include reflective surfaces, step index or gradual gradient index changes in the material, refractive sections or elements, diffractive sections or elements, holographic sections or elements, polarization sensitive sections or elements, and/or reflective sections or elements including total internal reflective elements. The lens may include combination of diffractive lensing and or reflection sections, such as a total internal reflection (TIR) optic. Lens diameter ranges from 1 μm to 10 μm, 10 μm to 100 μm, 100 μm to 1 mm, 1 mm to 10 mm, or 10 mm to 100 mm. The NA could range from 0.05 to 0.1, 0.1 to 0.2, 0.2 to 0.3, 0.3 to 0.4, 0.4 to 0.5, 0.5 to 0.6, or 0.6 to 0.7. Transmission ranges from 30 to 40%, 40 to 50%, 50 to 60%, 60 to 70%, 70 to 80%, 80 to 90%, and 90 to 100%.

The first end of the fiber may be comprised of a flat surface or could be comprised of a shaped or lensed surface to improve the input coupling efficiency of the white light into the fiber. The first end of the fiber member may be coated with an anti-reflective coating or a reflection modification coating to increase the coupling efficiency of the white light into the fiber member. The optical fiber member may be comprised of glass fiber, a plastic optical fiber (POF), or an alternative type of fiber member. The first end of the fiber may be comprised of a flat surface or could be comprised of a shaped or lensed surface to improve the input coupling efficiency of the white light into the fiber. The fiber is characterized by a core waveguide diameter and a numerical aperture (NA). The diameter ranges from 1 μm to 10 μm, 10 μm to 100 μm, 100 μm to 1 mm, 1 mm to 10 mm, or 10 mm to 100 mm. The NA could range from 0.05 to 0.1, 0.1 to 0.2, 0.2 to 0.3, and 0.3 to 0.4, 0.4 to 0.5, 0.5 to 0.6, or 0.6 to 0.7. Transmission ranges from 30 to 40%, 40 to 50%, 50 to 60%, 60 to 70%, 70 to 80%, 80 to 90%, and 90 to 100%. The fiber may transport the light to the end, or directional side scattering fiber to provide preferential illumination in a particular angle, or both. The fiber may include a coating or doping or phosphor integrated inside or on a surface to modify color of emission through or from fiber. The fiber may be a detachable fiber and may include a connector such as an SMA, FC and/or alternative optical connectors. The fiber may include a moveable tip mechanism on the entry or exit portion for scanning fiber input or output, where the fiber tip is moved to generate changes in the in coupling amount or color or other properties of the light, or on the output side, to produce a motion of light, or when time averaged, to generate a pattern of light.

In another preferred embodiment, the white light emission from the laser-based white light source is directed through a collimating lens to reduce the divergence of the white light. For example, the divergence could be reduced from 120 degrees as collected from the Lambertian emission to less than 12 degrees, less than 5 degrees, less than 2 degrees, or less than 1 degree. The lenses may include reflective surfaces, step index or gradual gradient index changes in the material, refractive sections or elements, diffractive sections or elements, holographic sections or elements, polarization sensitive sections or elements, and/or reflective sections or elements including total internal reflective elements. The lens may include combination of diffractive lensing and or reflection sections, such as a total internal reflection (TIR) optic. Lens diameter ranges from 1 μm to 10 μm, 10 μm to 100 μm, 100 μm to 1 mm, 1 mm to 10 mm, or 10 mm to 100 mm. The NA could range from 0.05 to 0.1, 0.1 to 0.2, 0.2 to 0.3, 0.3 to 0.4, 0.4 to 0.5, 0.5 to 0.6, or 0.6 to 0.7. Transmission ranges from 30 to 40%, 40 to 50%, 50 to 60%, 60 to 70%, 70 to 80%, 80 to 90%, and 90 to 100%. The leaky fiber could be a bundled leaky fiber. For example, the leak fiber could be a bundle of 3 or more, or 19 or more fibers with diameters in the 20 μm to 200 μm range with a total core diameter of 0.4 mm to 4 mm. The bundled fibers could be comprised from glass fibers or plastic fibers.

The first end of the fiber may be comprised of a flat surface or could be comprised of a shaped or lensed surface to improve the input coupling efficiency of the white light into the fiber. The first end of the fiber member may be coated with an anti-reflective coating or a reflection modification coating to increase the coupling efficiency of the white light into the fiber member. The optical fiber member may be comprised of glass fiber, a plastic optical fiber (POF), or an alternative type of fiber member. The first end of the fiber may be comprised of a flat surface or could be comprised of a shaped or lensed surface to improve the input coupling efficiency of the white light into the fiber. The fiber is characterized by a core waveguide diameter and a numerical aperture (NA). The diameter ranges from lum to 10 μm, 10 μm to 100 μm, 100 μm to Imm, 1 mm to 10 mm, or 10 mm to 100 mm. The NA could range from 0.05 to 0.1, 0.1 to 0.2, 0.2 to 0.3, and 0.3 to 0.4, 0.4 to 0.5, 0.5 to 0.6, or 0.6 to 0.7. Transmission ranges from 30 to 40%, 40 to 50%, 50 to 60%, 60 to 70%, 70 to 80%, 80 to 90%, and 90 to 100%. The fiber may transport the light to the end, or directional side scattering fiber to provide preferential illumination in a particular angle, or both. The fiber may include a coating or doping or phosphor integrated inside or on a surface to modify color of emission through or from fiber. The fiber may be a detachable fiber and may include a connector such as an SMA, FC and/or alternative optical connectors. The fiber may include a moveable tip mechanism on the entry or exit portion for scanning fiber input or output, where the fiber tip is moved to generate changes in the in coupling amount or color or other properties of the light, or on the output side, to produce a motion of light, or when time averaged, to generate a pattern of light. The leaky fiber could be a bundled leaky fiber. For example, the leak fiber could be a bundle of 3 or more, or 19 or more fibers with diameters in the 20 μm to 200 μm range with a total core diameter of 0.4 mm to 4 mm. The bundled fibers could be comprised from glass fibers or plastic fibers.

As describe previously, the optical fiber member may be comprised of glass fiber, a plastic optical fiber, or an alternative type of fiber member. The core or waveguide region of the fiber may have a diameter ranging from 1 μm to 10 μm, 10 μm to 100 μm, 100 μm to 1 mm, 1 mm to 10 mm, or 10 mm to 100 mm. The white light emission is then transferred through the fiber to an arbitrary length depending on the application. For example, the length could range from 1 cm to 10 cm, 10 cm to 1 m, 1 m to 100 m, 100 m to 1 km, or greater than 1 km.

In one embodiment, the optical fiber member transport properties are designed to maximize the amount of light traveling from the first end of the fiber to a second end of the fiber. In this embodiment, the fiber is design for low absorption losses, low scattering losses, and low leaking losses of the white light out of the fiber. The white light exits the second end of the fiber where it is delivered to its target object for illumination. In one preferred embodiment the white light exiting the second end of the fiber is directed through a lens for collimating the white light. The lens may include reflective surfaces, step index or gradual gradient index changes in the material, refractive sections or elements, diffractive sections or elements, holographic sections or elements, polarization sensitive sections or elements, and/or reflective sections or elements including total internal reflective elements. The lens may include combination of diffractive lensing and or reflection sections, such as a total internal reflection optic, e.g. TIR optic. Lens diameter ranges from 1 μm to 10 μm, 10 μm to 100 μm, 100 μm to 1 mm, 1 mm to 10 mm, or 10 mm to 100 mm. The NA could range from 0.05 to 0.1, 0.1 to 0.2, 0.2 to 0.3, 0.3 to 0.4, 0.4 to 0.5, 0.5 to 0.6, or 0.6 to 0.7. Transmission ranges from 30 to 40%, 40 to 50%, 50 to 60%, 60 to 70%, 70 to 80%, 80 to 90%, and 90 to 100%.

Additionally, a beam shaping optic can be included to shape the beam of white light into a predetermined pattern. In one example, the beam is shaped into the required pattern for an automotive standard high beam shape or low beam shape. The beam shaping element may be a lens or combination of lenses. The lens may include reflective surfaces, step index or gradual gradient index changes in the material, refractive sections or elements, diffractive sections or elements, holographic sections or elements, polarization sensitive sections or elements, and/or reflective sections or elements including total internal reflective elements. The lens may include combination of diffractive lensing and or reflection sections, such as a total internal reflection optic, e.g., TIR optic. A beam shaping diffusers may also be used, such as a holographic diffuser. Lens and or diffuser diameter ranges from 1 μm to 10 μm, 10 μm to 100 μm, 100 μm to 1 mm, 1 mm to 10 mm, or 10 mm to 100 mm. Lens shape may be non-circular, such as rectangular or oval or with an alternative shape, with one of the dimensions being from 1 μm to 10 μm, 10 μm to 100 μm, 100 μm to 1 mm, 1 mm to 10 mm, or 10 mm to 100 mm. The NA could range from 0.05 to 0.1, 0.1 to 0.2, 0.2 to 0.3, 0.3 to 0.4, 0.4 to 0.5, 0.5 to 0.6, or 0.6 to 0.7. Transmission ranges from 30 to 40%, 40 to 50%, 50 to 60%, 60 to 70%, 70 to 80%, 80 to 90%, and 90 to 100%. The leaky fiber could be a bundled leaky fiber. For example, the leak fiber could be a bundle of 3 or more, or 19 or more fibers with diameters in the 20 μm to 200 μm range with a total core diameter of 0.4 mm to 4 mm. The bundled fibers could be comprised from glass fibers or plastic fibers.

In another embodiment, the optical fiber member is intentionally designed to be leaky such that the white light exits the fiber along its axis to produce a distributed white light source. The fiber design can include air bubbles, voids, composite materials, or other designs to introduce perturbations in the index of refraction along the axis of the waveguide to promote scattering of the white light.

In yet another preferred embodiment, the fiber can be designed allow light to leak out of the core waveguide region and into the cladding region. In some embodiments, the leaky fiber is designed to leak the white light from only certain directions from the fibers circumference. For example, the fiber may directionally leak and emit light from 180 degrees of the fibers 360 degrees circumference. In other examples, the fiber may leak and emit light from 90 degrees of the fibers 360 degrees circumference.

The leaky fiber embodiment of the fiber coupled white light invention described can fine use in many applications. One such example application using the leaky fiber as distributed light source included as day time running lights in an automobile headlight module. Additionally, the distributed light sources could be used in automotive interior lighting and tail lighting. In another application the source is used as distributed lighting for tunnels, streets, underwater lighting, office and residential lighting, industrial lighting, and other types of lighting. In another application the leaky fiber could be included in a light bulb as a filament. The leaky fiber could be a bundled leaky fiber. For example, the leak fiber could be a bundle of 3 or more, or 19 or more fibers with diameters in the 20 μm to 200 μm range with a total core diameter of 0.4 mm to 4 mm. The bundled fibers could be comprised from glass fibers or plastic fibers.

In still another preferred embodiment, an electronic board may be used with the light source. It may include a section that provides initial heatsinking of the light source, with a thermal resistance of less than 1 degree Celsius per watt, or 1 to 2 degree Celsius per watt, or 2 to 3 degree Celsius per watt, or 3 to 4 degree Celsius per watt, or 4 to 5 degree Celsius per watt, or 5 to 10 degree Celsius per watt. The electronic board may provide electrical contact for anode(s) and cathode(s) of the light source. The electronic board may include a driver for light source or a power supply for the light source. The electronic board may include driver elements that provide temporal modulation for applications related to communication such as LiFi free-space light communication, and/or data communications using optic fiber. The electronic board may include driver elements that provide temporal modulation for applications related to LiDAR remote sensing to measure distance, generate 3D images, or other enhanced 2D imaging techniques. The electronic board may include sensors for SMD such as thermistor or process detectors from SMD such as photodetector signal conditioning or fiber sensors. The electronic board may be interfaced with software. The software may provide machine learning or artificial intelligent functionality. The electronic board diameter may range from 1 μm to 10 μm, 10 μm to 100 μm, 100 μm to 1 mm, 1 mm to 10 mm, or 10 mm to 100 mm. The electronic board shape may be non-circular, such as rectangular or oval or with an alternative shape, with one of the dimensions being from 1 μm to 10 μm, 10 μm to 100 μm, 100 μm to 1 mm, 1 mm to 10 mm, or 10 mm to 100 mm. The NA could range from 0.05 to 0.1, 0.1 to 0.2, 0.2 to 0.3, 0.3 to 0.4, 0.4 to 0.5, 0.5 to 0.6, or 0.6 to 0.7.

In still a preferred embodiment, a heatsink may be used with the light source. The heatsink may have a thermal resistance of less than 1 degree Celsius per watt, or 1 to 2 degree Celsius per watt, or 2 to 3 degree Celsius per watt, or 3 to 4 degree Celsius per watt, or 4 to 5 degree Celsius per watt, or 5 to 10 degree Celsius per watt. The heat sink may be cylindrical with a diameter that may range from 1 μm to 10 μm, 10 μm to 100 μm, 100 μm to 1 mm, 1 mm to 10 mm, or 10 mm to 100 mm. The heatsink shape may be non-cylindrical with an alternative shape, with one of the dimensions being from 1 μm to 10 μm, 10 μm to 100 μm, 100 μm to 1 mm, 1 mm to 10 mm, or 10 mm to 100 mm. The heatsink frame may be manufactured with lathe turning in order to provide flexible aesthetic looks from a common light source module underneath.

Additionally, a mechanical frame may be used, on which to affix the light source, optic, fiber, electronic board, or heatsink. The mechanical frame may be cylindrical with a diameter that may range from 1 μm to 10 μm, 10 μm to 100 μm, 100 μm to 1 mm, 1 mm to 10 mm, or 10 mm to 100 mm. The heatsink shape may be non-cylindrical with an alternative shape, with one of the dimensions being from 1 μm to 10 μm, 10 μm to 100 μm, 100 μm to 1 mm, 1 mm to 10 mm, or 10 mm to 100 mm. The mechanical frame may be manufactured with lathe turning in order to provide flexible aesthetic looks from a common light source module underneath.

Optionally, the light source may be configured with a single fiber output with collimating optic and beam pattern generator. Optionally, the light source may be configured with multiple fiber outputs, each with collimating optic and beam pattern generator. Optionally, multiple light sources may be configured to single fiber output with collimating optic and beam pattern generator. Optionally, multiple light sources may be configured to multiple fiber bundle output with collimating optic and beam pattern generator. Optionally, multiple light sources may be configured to multiple fiber bundle output, each with collimating optic and beam pattern generator. Optionally, multiple light sources with different color properties may be configured to one or more fibers to generate different color properties of emission.

### Laser-Based Fiber-Coupled White Light Illumination System

1. A laser-based fiber-coupled white light illumination system comprising:
one or more white light source modules located at a source position, each comprising:
   a laser device comprising a gallium and nitrogen containing material and configured as an excitation source, the laser device comprising an output facet configured to output a laser emission with a first wavelength ranging from 385 nm to 495 nm;
   a phosphor member configured as a wavelength converter and an emitter and disposed to allow the laser electromagnetic radiation being optically coupled to a primary surface of the phosphor member;
   an angle of incidence configured between the laser electromagnetic radiation and the primary surface of the phosphor member, the phosphor member configured to convert at least a fraction of the laser electromagnetic radiation with the first wavelength landed in a spot greater than 5 μm on the primary surface to a phosphor emission with a second wavelength that is longer than the first wavelength;
   a light-emission mode characterizing the phosphor member with a white light emission being generated from at least an interaction of the laser electromagnetic radiation with the phosphor emission, the white light emission comprising of a mixture of wavelengths characterized by at least the second wavelength from the phosphor member;
   one or more fibers configured to have first ends to couple with the one or more white light source modules to output the white light emission to respective second ends; and
   one or more passive luminaries substantially free of electrical power supply disposed at an illumination location coupled to the respective second ends to distribute the white light emission to one or more illumination patterns, wherein the illumination location is separated from the one or more white light source module location by a remote distance.

2. The laser-based fiber-coupled white light illumination system of claim 1, wherein each of the one or more white light source modules comprises a surface-mount device (SMD) type package.

3. The laser-based fiber-coupled white light illumination system of claim 1, wherein each of the one or more white light source modules comprises a package selected from a flat package, TO9 Can, TO56 Can, TO-5 can, TO-46 can, CS-Mount, G-Mount, C-Mount, and micro-channel cooled package.

4. The laser-based fiber-coupled white light illumination system of claim 1, wherein the one or more white light source modules are configured to generate the white light emission from a source diameter of about 0.10 mm to about 3 mm with a total luminous flux of about 100 lumens to about 2000 lumens or greater.

5. The laser-based fiber-coupled white light illumination system of claim 1, wherein the one or more fibers comprises waveguides laid on a 2-dimensional substrate, optical fiber cables disposed in a one-dimensional configuration.

6. The laser-based fiber-coupled white light illumination system of claim 1, wherein each of the one or more fibers comprises a glass fiber or a plastic fiber with core diameter of about 100 μm to about 2 mm or greater, and wherein the fiber core can be configured from a solid core fibers, or a fiber bundle core, or a combination of solid core and fiber bundle type fibers.

7. The laser-based fiber-coupled white light illumination system of claim 1, wherein one or more fibers are directly coupled to the one or more white light source modules or wherein the leaky fibers are coupled to the respective second ends of the one or more fibers to deliver the white emission.

8. The laser-based fiber-coupled white light illumination system of claim 1, comprising an optical connector for detachably connecting the one or more passive luminaries to the respective second ends of the one or more fibers to deliver the white emission.

9. The laser-based fiber-coupled white light illumination system of claim 8, further comprising a white light supply member optically coupled to one or more white light source modules least a level selected from greater than 20%, greater than 40%, greater than 60%, and greater than 80%.

10. The laser-based fiber-coupled white light illumination system of claim 9, further comprising an optical switch module configured to switch one input of white light emission to one of multiple outputs respectively to multiple optical channels respectively coupled to multiple passive luminaries, a fast switching MEMS mirror to generate spatial modulation to the one or more illumination patterns, one or more sensors to collect environmental information at the illumination location, and a controller including sensor signal input unit, processing unit, and driver unit configured to process the sensor signal to generate a feedback control signal to drive the one or more white light source modules.

11. The laser-based fiber-coupled white light illumination system of claim 10, wherein the one or more white light source modules is configured to adjust the laser electromagnetic radiation from the laser device and the phosphor emission from the phosphor member to achieve color tuning and illumination pattern adjustment of the white light emission.

12. The laser-based fiber-coupled white light illumination system of claim 1, wherein the light-emission mode characterizing the phosphor member with a white light emission comprises one of a reflection mode or a transmission mode, wherein in the reflection mode the white light emission is emitted from the same surface of the phosphor member that the laser beam is incident upon and in the transmission mode the white light emission is emitted from at least a different surface of the phosphor member than the laser beam is incident upon.

13. The laser-based fiber-coupled white light illumination system of claim 1, wherein the one or more passive luminaries comprises one or more leaky fibers respectively coupled with the one or more fibers by one or more detachable optical connectors or by splicing.

14. The laser-based fiber-coupled white light illumination system of claim 13, wherein the leaky fiber comprises a scattering feature therein to produce uniform light scattering over illumination angles up to 360 degrees around.

15. The laser-based fiber-coupled white light illumination system of claim 13, wherein the leaky fiber comprises a scattering feature therein to produce a directional side scattering characteristics yielding preferential illumination in a range of angles off zero degrees along the length of fiber body up to 90 degrees perpendicular to the fiber body.

16. The laser-based fiber-coupled white light illumination system of claim 13, wherein the leaky fiber comprises light-emission features therein based on scattering, reflection, and collimation to produce an illumination pattern in a fixed or varied directional angle range.

17. The laser-based fiber-coupled white light illumination system of claim 13, wherein the leaky fiber comprises a light output characterized by an effective luminous flux of greater than 25 lumens, or greater than 50 lumens, or greater than 150 lumens, or greater than 300 lumens, or greater than 600 lumens, or greater than 800 lumens, or greater than 1200 lumens in an optical efficiency of greater than 35% out of the fiber body.

18. The laser-based fiber-coupled white light illumination system of claim 1, wherein the passive luminary comprises one or more light-emission and light-shaping features therein based on scattering, reflection, color conversion, and/or collimation to produce a desired spatial illumination pattern, color quality, and/or aesthetic characteristic.

19. The laser-based fiber-coupled white light illumination system of claim 1, wherein the one or more passive luminaries comprise pendant lights or chandelier lights.

20. The laser-based fiber-coupled white light illumination system of claim 1, wherein the one or more passive luminaries are comprised in waveguides integrated into troffers, built into fabrics, furniture, and/or building design elements

21. The laser-based fiber-coupled white light illumination system of claim 1, wherein the one or more passive luminaries are included as illumination elements for in-door/outdoor lighting, decorative accessories, architectural features, household or industrial appliances, vehicles, submerged lightings for swimming pools and jacuzzis.

Central Lighting System with Distributed White Light

22. A central lighting system with distributed white light comprising,
one or more laser-based white light sources disposed at one or more dedicated source areas, each light source comprising:
   a laser device comprising a gallium and nitrogen containing material and configured as an excitation source, the laser device comprising an output facet configured to output a laser electromagnetic emission with a first wavelength ranging from 385 nm to 495 nm;
   a phosphor member configured as a wavelength converter and an emitter and disposed to convert the laser electromagnetic emission to emit a second electromagnetic radiation with a second wavelength longer than the first wavelength; and
   a light-emission mode characterizing the phosphor member with a white light emission being generated from at least an interaction of the laser electromagnetic radiation with the second electromagnetic emission as a mixture of wavelengths characterized by at least the second wavelength from the phosphor member;
a white light supply member configured to couple with the one or more laser-based white light sources to form a directed white light emission;
an optical switching module configured to couple the directed white light emission to one or more of multiple channels to control the light intensity level to a predetermined level to be inserted into the one or more multiple channels; and
multiple transport fibers configured to respectively couple with the multiple channels to receive the white light emission from any channel with the predetermined light level status and deliver the white light emission to one or multiple distributed illumination areas.

23. The central lighting system of claim 22, wherein each of the one or more white light sources comprises a surface-mount device (SMD) type package.

24. The central lighting system of claim 22, wherein the light-emission mode characterizing the phosphor member with a white light emission comprises one of a reflection mode or a transmission mode, wherein in the reflection mode the white light emission is emitted from the same surface of the phosphor member that the laser beam is incident upon and in the transmission mode the white light emission is emitted from at least a different surface of the phosphor member than the laser beam is incident upon.

25. The central lighting system of claim 22, further comprising one or more optical connectors to form detachable optical couplings between the one or more white light sources and the white light supply member directing the white light emission.

26. The central lighting system of claim 22, wherein the one or more optical connectors comprise SMA type, FC type, snap-in type.

27. The central lighting system of claim 22, wherein the white light supply member comprises an optical waveguide member such as a fiber and optionally a combination of lenses, mirrors, reflectors for shaping and collimating the white light emission.

28. The central lighting system of claim 22, wherein the optical switching module comprises MEMS devices with scanning micro-mirrors, or digital light processing chips (DLP) including arrays of micromirrors, or piezoelectric beam steering devices, or scanning fiber tip devices, micro positioner devices, inkjet device with an intersection of two waveguides, liquid crystal on silicon (LCOS) devices, or devices based on thermal methods, acousto-optic, magneto-optic technology that can deflect the white light emission to selected one of multiple transport fibers.

29. The central lighting system of claim 22, wherein the optical switching module comprises a digital device that controls an “ON” or “OFF” state to an optical path to guide the white light emission from the white light supply member, or an analog device that enables control of the amount of white light emission delivered to provide a dimming function.

30. The central lighting system of claim 22, wherein the multiple distributed illumination areas comprise a remote area separated from the dedicated source areas with a short distance of at least 6 inches to a long distance in several tens of meters, an area that has an environment substantially free of restrictions in temperature, humidity, radiation, accessibility, and safety set for the dedicated source areas.

31. The central lighting system of claim 22, wherein each of the multiple transport wherein each of the multiple fibers comprises a glass fiber or a plastic fiber with core diameter of about 100 μm to about 2 mm or greater, and wherein the fiber core can be configured from a solid core fibers, or a fiber bundle core, or a combination of solid core and fiber bundle type fibers.

32. The central lighting system of claim 22, wherein each of the multiple transport fibers is configured to transport the white light emission from the white light source with a coupling efficiency being at least in a level selected from greater than 20%, greater than 40%, greater than 60%, and greater than 80%.

33. The central lighting system of claim 22, wherein the one or more transport fibers deliver the white light emission to one or more passive luminaries at an illumination location to distribute the white light emission to one or more illumination patterns.

34. The central lighting system of claim 33, wherein the one or more passive luminaries comprises one or more leaky fibers respectively coupled with the one or more fibers by one or more detachable optical connectors or by splicing, and wherein the leaky fiber is configured with a solid core, a fiber bundled core, or a different type of core.

35. The central lighting system of claim 34, wherein the leaky fiber comprises a scattering feature therein to produce uniform light scattering over illumination angles up to 360 degrees around, or wherein the leaky fiber comprises a scattering feature therein to produce a directional side scattering characteristics yielding preferential illumination in a range of angles off zero degrees along the length of fiber body up to 90 degrees perpendicular to the fiber body, or wherein the leaky fiber comprises light-emission features therein based on scattering, reflection, and collimation to produce an illumination pattern in a fixed or varied directional angle range.

36. The central lighting system of claim 33, wherein the one or more passive luminaries comprises one or more light-emission and light-shaping features therein based on scattering, reflection, color conversion, and/or collimation to produce a desired spatial illumination pattern, color quality, and/or aesthetic characteristic.

37. The central lighting system of claim 33, wherein the one or more passive luminaries comprise pendant lights or chandelier lights.

38. The central lighting system of claim 33, wherein the one or more passive luminaries are comprised in waveguides integrated into troffers, built into fabrics, furniture, and/or building design elements

### Smart Lighting System

39. A smart lighting system comprising,
one or more laser-based white light sources disposed at a source area, the one or more light source comprising:
   a laser device comprising a gallium and nitrogen containing material and configured as an excitation source, the laser device comprising an output facet configured to output a laser electromagnetic emission with a first wavelength ranging from 385 nm to 495 nm;
   a phosphor member configured as a wavelength converter and an emitter and disposed to convert the laser electromagnetic emission to emit a second electromagnetic radiation with a second wavelength longer than the first wavelength; and
   a light-emission mode characterizing the phosphor member with a white light emission being generated from at least an interaction of the laser electromagnetic radiation with the second electromagnetic emission as a mixture of wavelengths characterized by at least the second wavelength from the phosphor member;
one or more transport fibers configured with a first end coupled to the one or more laser-based white light sources to transport the white light emission to a second end at an illumination area at a remote distance;
one or more sensors disposed at the illumination area and configured to collect one or more sensor signals;
a controller configured to receive electrically or optically the one or more sensor signals and to process the one or more sensor signals to generate a feedback signal back to the laser-based white light source to generate a light response.

40. The smart lighting system of claim 39, wherein the one or more laser-based white light sources are comprised in a surface-mount device (SMD) type package.

41. The smart lighting system of claim 39, wherein the laser-based white light source is configured to exit the white light emission from a source diameter of about 0.1 mm to 3 mm with a total luminous flux of about 100 lumens to about 2000 lumens or greater with amplitude modulation capability.

42. The smart lighting system of claim 39, wherein the light-emission mode characterizing the phosphor member with a white light emission comprises one of a reflection mode or a transmission mode, wherein in the reflection mode the white light emission is emitted from the same surface of the phosphor member that the laser beam is incident upon and in the transmission mode the white light emission is emitted from at least a different surface of the phosphor member than the laser beam is incident upon.

43. The smart lighting system of claim 39, further comprising a first optical connector to form a detachable optical coupling between the laser-based white light source and the first end of a transport fiber or supply member.

44. The smart lighting system of claim 39, further comprising a second optical connector to form a detachable optical coupling between the second end of the transport fiber to a passive luminary at the illumination area.

45. The smart lighting system of claim 44, wherein the passive luminary comprises a scattering fiber or leaky fiber configured to yield a light output characterized by an effective luminous flux of greater than 10 lumens, greater than 25 lumens, or greater than 50 lumens, or greater than 150 lumens, or greater than 300 lumens, or greater than 600 lumens, or greater than 800 lumens, or greater than 1200 lumens.

46. The smart lighting system of claim 44, wherein the passive luminary comprises a leaky fiber comprising a scattering feature therein to produce uniform light scattering over illumination angles up to 360 degrees around; and wherein the fiber core can be configured with a solid core, a fiber bundled core, or another type of core.

47. The smart lighting system of claim 44, wherein the passive luminary comprises one or more light-emission and light-shaping features therein based on scattering, reflection, color conversion, and/or collimation to produce a desired spatial illumination pattern, color quality, and/or aesthetic characteristic.

48. The smart lighting system of claim 44, wherein the one or more passive luminaries comprise pendant lights or chandelier lights.

49. The smart lighting system of claim 44, wherein the one or more passive luminaries are comprised in waveguides integrated into troffers, built into fabrics, furniture, and/or building design elements.

50. The smart lighting system of claim 39, further comprising an optical switching module configured to control switching or splitting the white light emission to one or more of multiple passive luminaries disposed in multiple illumination areas, wherein the optical switching module comprises MEMS devices with scanning micro-mirrors, or digital light processing chips (DLP) including arrays of micromirrors, or piezoelectric beam steering devices, or scanning fiber tip devices, micro positioner devices, inkjet device with an intersection of two waveguides, liquid crystal on silicon (LCOS) devices, or devices based on thermal methods, acousto-optic, or a magneto-optic technology.

51. The smart lighting system of claim 50, wherein the optical switching module comprises a digital device that controls an “ON” or “OFF” state to an optical path to guide the white light emission from the white light supply member, or an analog device that enables control of the amount of white light emission delivered to provide a dimming function.

52. The smart lighting system of claim 39, configured for a LiFi or a visible light communication signal that is receivable at least within a range of the illumination area.

53. The smart lighting system of claim 39, wherein the communication based on the lighting system provides communication for a local network, connects smart devices, provides data describing the surroundings or environment, delivers digital content, provides security, optimizes the efficiency of the smart lighting system or other systems, or serves other functions.

54. The smart lighting system of claim 39, wherein one or more sensors comprises one or more selected from microphone, geophone, motion sensor, radio-frequency identification (RFID) receivers, hydrophone, chemical sensors including a hydrogen sensor, CO₂ sensor, or electronic nose sensor, flow sensor, water meter, gas meter, Geiger counter, altimeter, airspeed sensor, speed sensor, range finder, piezoelectric sensor, gyroscope, inertial sensor, accelerometer, MEMS sensor, Hall effect sensor, metal detector, voltage detector, photoelectric sensor, photodetector, photoresistor, pressure sensor, strain gauge, thermistor, thermocouple, pyrometer, temperature gauge, motion detector, passive infrared sensor, Doppler sensor, biosensor, capacitance sensor, video cameras, transducer, image sensor, infrared sensor, radar, SONAR, LIDAR.

55. The smart lighting system of claim 39, wherein the light response based on the sensor feedback comprises an illumination spatial distribution response, an illumination pattern movement response, an illumination color response, an illumination brightness or light level response, a communication signal response, or a combination thereof.

56. The smart lighting system of claim 39, wherein the light response based on the sensor feedback adjusts the lighting characteristics at one or more illumination locations to maximize the energy efficiency of the smart lighting system.

57. The smart lighting system of claim 39, wherein the light response based on the sensor feedback adjusts the lighting characteristics at one or more illumination locations to optimize the lighting characteristics for a given set of circumstances.

58. The smart lighting system of claim 39, wherein the light response based on the sensor feedback provides a communication function to notify or alert users of the smart lighting system that a certain condition is met.

### Fiber-Coupled White Light Illumination Source

59. A fiber-coupled white light illumination source comprising:
one or more laser-based white light sources disposed at a source area, the one or more light sources comprising:
   a laser device comprising a gallium and nitrogen containing material and configured as an excitation source, the laser device comprising an output facet configured to output a laser electromagnetic emission with a first wavelength ranging from 385 nm to 495 nm;
   a phosphor member configured as a wavelength converter and an emitter and disposed to convert the laser electromagnetic emission to emit a second electromagnetic radiation with a second wavelength longer than the first wavelength; and
   a light-emission mode characterizing the phosphor member with a white light emission being generated from at least an interaction of the laser electromagnetic radiation with the second electromagnetic emission as a mixture of wavelengths characterized by at least the second wavelength from the phosphor member;
one or more passive luminaries coupled to the white light emission from the laser based white light source;
the one or more passive luminaries configured to distribute one or more illumination patterns at one or more illumination areas;
the one or more passive luminaries free from an electrical power supply and located at a remote distance from the one or more laser based white light sources; and
optionally an intermediate transport fiber with a first end coupled to the laser-based white light source to transport the white light emission to a second end coupled to the one or more passive luminaries.

60. The fiber-coupled white light illumination source of claim 59, wherein the laser-based white light source comprises a surface-mount device (SMD) type package.

61. The fiber-coupled white light illumination source of claim 59, wherein the laser-based white light source is configured to exit the white light emission from a source diameter of about 0.1 mm to about 3 mm with a total luminous flux of about 100 lumens to about 2000 lumens or greater with amplitude modulation capability.

62. The fiber-coupled white light illumination source of claim 59, wherein the light-emission mode characterizing the phosphor member with a white light emission comprises one of a reflection mode or a transmission mode, wherein in the reflection mode the white light emission is emitted from the same surface of the phosphor member that the laser beam is incident upon and in the transmission mode the white light emission is emitted from at least a different surface of the phosphor member than the laser beam is incident upon.

63. The fiber-coupled white light illumination source of claim 59, wherein the transport fiber comprises a glass fiber or a plastic fiber with core diameter of about 100 μm to about 2 mm or greater, and wherein the fiber core can be configured from a solid core fibers, or a fiber bundle core, or a combination of solid core and fiber bundle type fibers; and wherein the white light emission from the laser-based white light source is coupled via a connector to the one or more passive luminaries with a coupling efficiency being at least a level selected from greater than 20%, greater than 40%, greater than 60%, and greater than 80%.

64 The fiber-coupled white light illumination source of claim 63, wherein the connector comprises a detachable mechanism to separate each passive luminary from the system.

65. The fiber-coupled white light illumination source of claim 59, wherein one or more passive luminaries comprises a scattering or leaky fiber having a built-in feature for producing uniform or directional line illumination source; wherein the leaky fiber core can be configured from a solid core, a fiber bundled core, or another type of core.

66. The fiber-coupled white light illumination source of claim 65, wherein the leaky fiber is configured to yield a light output characterized by an effective luminous flux of greater than 25 lumens, or greater than 50 lumens, or greater than 150 lumens, or greater than 300 lumens, or greater than 600 lumens, or greater than 800 lumens, or greater than 1200 lumens in an optical efficiency of greater than 35%.

67. The fiber-coupled white light illumination source of claim 59, wherein one or more passive luminaries comprises a pendant light with an assembly of collimation lens optics for directional illumination or flood illumination or sideway illumination coupled from the transport fiber or a leaky fiber.

68. The fiber-coupled white light illumination source of claim 59, wherein one or more passive luminaries comprises a chandelier light with multiple illumination branches split from one lead cable coupled from the transport fiber or a leaky fiber.

69. The fiber-coupled white light illumination source of claim 59, wherein one or more passive luminaries comprises one or more phosphors comprising alternative color elements, gradients, light-emission modes coupled from the transport fiber or a leaky fiber to modify the color characteristic of the illumination emitted from the passive luminaries.

70. The fiber-coupled white light illumination source of claim 59, wherein one or more passive luminaries comprises a distributed line source made by a scattering fiber with light extraction features producing a radially non-symmetric pattern.

71. The fiber-coupled white light illumination source of claim 59, wherein one or more passive luminaries comprises a distributed line source made by a scattering fiber with light extraction features producing a radially symmetric pattern, and optionally wherein the distributed line source comprises a reflector optical element that directs the radially symmetric pattern to a restricted angular range.

72. The fiber-coupled white light illumination source of claim 71, wherein the distributed line source is integrated into crown molding for wall or ceiling illumination or distributed to any architectural design features including baseboards, ceiling beams, trims, pillars, windows, doors, stairs.

73. The fiber-coupled white light illumination source of claim 71, wherein the distributed line source is integrated into interior as a waveguided troffer embedded in fabric or glass for semi-transparent glowing illumination.

74. The fiber-coupled white light illumination source of claim 71, wherein the distributed line source is integrated into appliance for interior illumination with open-door trigger or all-time ON with glass door,

75. The fiber-coupled white light illumination source of claim 71, wherein the distributed line source is integrated into submerged areas under water in swimming pool, jacuzzi, liquid storage tank.

While the above is a full description of the specific embodiments, various modifications, alternative constructions and equivalents may be used. Therefore, the above description and illustrations should not be taken as limiting the scope of the present invention which is defined by the appended claims.

1.-58. (canceled)

59. A fiber-coupled white light illumination source comprising:
a laser-based white light source disposed at a source area, the laser-based white light source comprising:
a laser diode comprising:
a substrate;
a gallium and nitrogen containing material disposed on the substrate and configured as an excitation source, the laser device comprising an output facet configured to output a laser electromagnetic emission with a first wavelength ranging from 385 nm to 495 nm, the laser device further comprising a laser stripe region formed in the gallium and nitrogen containing material, the laser stripe region characterized by a cavity extending through a horizontal length of the laser device, wherein a length of the laser stripe region is between 50 microns and 3000 microns;
a p-electrode adjacent the substrate; and
a n-electrode separated from the p-electrode such that the cavity is between the p-electrode and the n-electrode;
a surface-mount device (SMD) type packaging, the SMD type packaging comprising:
a base member and a support member, the support member and the base member configured to conduct heat away from the laser diode;
feedthroughs electrically connected to leads on an outside the SMD type packaging, wherein the SMD type packaging is hermetically sealed; and
wire bonds connecting the p-electrode and the n-electrode of the laser diode to the feedthroughs;
a phosphor member, mounted on the base member or the support member, configured as a wavelength converter and an emitter and disposed to convert the laser electromagnetic emission to emit a second electromagnetic radiation with a second wavelength longer than the first wavelength, wherein:
the phosphor member comprises an excitation surface arranged so that a beam of electromagnetic radiation emitted from the laser diode can land in a spot on the excitation surface of the phosphor member with a spot size in the range of about 50 microns to 5 millimeters;
the phosphor emission of the second wavelength is partially mixed with a portion of the first wavelength from the laser diode to produce a white light beam to form a laser induced white light beam having a luminous flux of at least 500 lumens; and
a reflection mode characterizing the phosphor member with a white light emission being generated from at least an interaction of the laser electromagnetic emission with the second electromagnetic radiation as a mixture of wavelengths characterized by at least the second wavelength from the phosphor member to provide the white light emission with a substantially incoherent and Lambertian emission pattern, wherein in the reflection mode the white light emission is emitted from a same surface of the phosphor member that the laser electromagnetic radiation is incident upon;
a lens member configured to capture the white light emission from the laser based white light source and focus the white light emission;
a plurality of transport fibers with first ends optically coupled to the lens member, wherein the plurality of transport fibers each have a core diameter of between about 100 μm to about 3 mm;
a cover extending around external edges of the laser-based white light source and coupled to a first end portion of the plurality of transport fibers, wherein the first end portion of the plurality of transport fibers extends through a first aperture of the cover and the laser-based white light source is arranged in a second aperture of the cover so that a bottom portion of the laser-based white light source is exposed outside the cover;
a plurality of passive luminaries each coupled to the white light emission from a second end of one of the plurality of transport fibers;
the plurality of passive luminaries configured to distribute one or more illumination patterns at one or more illumination areas; and
the plurality of passive luminaries each free from an electrical power supply and located at a remote distance from the laser-based white light source.

60. The fiber-coupled white light illumination source of claim 59, wherein the laser-based white light source comprises a surface-mount device (SMD) type package.

61. The fiber-coupled white light illumination source of claim 59, wherein the laser-based white light source is configured to exit the white light emission from a source diameter of about 0.1 mm to about 3 mm with a total luminous flux of about 100 lumens to about 2000 lumens or greater with amplitude modulation capability.

62. (canceled)

63. The fiber-coupled white light illumination source of claim 59, wherein the plurality of transport fibers comprise glass fibers or plastic fibers, and wherein the fiber core can be configured from a solid core fibers, or a fiber bundle core, or a combination of solid core and fiber bundle type fibers; and wherein the white light emission from the laser-based white light source is coupled via a connector to the plurality of passive luminaries with a coupling efficiency being at least a level selected from greater than 20%, greater than 40%, greater than 60%, and greater than 80%.

64. The fiber-coupled white light illumination source of claim 63, wherein the connector comprises a detachable mechanism to separate each passive luminary from the system.

65. The fiber-coupled white light illumination source of claim 59, wherein the plurality of passive luminaries comprises a scattering or leaky fiber having a built-in feature for producing uniform or directional line illumination source; wherein a core of the scattering or leaky fiber can be configured from a solid core, a fiber bundled core, or another type of core.

66. The fiber-coupled white light illumination source of claim 65, wherein the scattering or leaky fiber is configured to yield a light output characterized by an effective luminous flux of greater than 25 lumens, or greater than 50 lumens, or greater than 150 lumens, or greater than 300 lumens, or greater than 600 lumens, or greater than 800 lumens, or greater than 1200 lumens in an optical efficiency of greater than 35%.

67. The fiber-coupled white light illumination source of claim 59, wherein the plurality of passive luminaries comprises a pendant light.

68. The fiber-coupled white light illumination source of claim 59, wherein the plurality of passive luminaries comprises a chandelier light with multiple illumination branches split from one lead cable coupled from the plurality of transport fibers.

69. (canceled)

70. The fiber-coupled white light illumination source of claim 59, wherein the plurality of passive luminaries comprises a distributed line source made by a scattering fiber with light extraction features producing a radially non-symmetric pattern.

71. The fiber-coupled white light illumination source of claim 59, wherein the plurality of passive luminaries comprises a distributed line source made by a scattering fiber with light extraction features producing a radially symmetric pattern, and the distributed line source comprises a reflector optical element that directs the radially symmetric pattern to a restricted angular range.

72. The fiber-coupled white light illumination source of claim 71, wherein the distributed line source is integrated into crown molding for wall or ceiling illumination or distributed to any architectural design features.

73. The fiber-coupled white light illumination source of claim 71, wherein the distributed line source is embedded in fabric for semi-transparent glowing illumination, or embedded in glass for a semi-transparent glowing illumination.

74. The fiber-coupled white light illumination source of claim 71, wherein the distributed line source is integrated into appliance for interior illumination with an all-time ON distributed line source with a glass door.

75. The fiber-coupled white light illumination source of claim 71, wherein the distributed line source is integrated into submerged areas under water in at least one of a swimming pool or hot tub.

76. The fiber-coupled white light illumination source of claim 59, wherein the plurality of passive luminaries comprises a distributed line source made by a scattering fiber with a reflector producing a radially non-symmetric pattern.

77. The fiber-coupled white light illumination source of claim 59, further comprising:
a single transport fiber configured to receive the white light emission from the lens member at a first end of the single transport fiber; and
an optical switching module providing a selective coupling between a second end of the single transport fiber and first ends of the plurality of transport fibers, wherein the optical switching module is configured to couple the white light emission from the second end of the single transport fiber to selected ones of the first ends of the plurality of transport fibers.
